(19) United States
(12) Patent Application Publication
(10) Pub. No.: US 2024/0251579 A1
(43) Pub. Date: Jul. 25, 2024

(54) ORGANIC ELECTROLUMINESCENT DEVICE

(71) Applicant: BEIJING SUMMER SPROUT TECHNOLOGY CO., LTD., Beijing (CN)

(72) Inventors: Menglan Xie, Beijing (CN); Jing Wang, Beijing (CN); Huiqing Pang, Beijing (CN); Le Wang, Beijing (CN); Qiang Wang, Beijing (CN); Ziyan Zhang, Beijing (CN); Gaoqi Zhang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/394,592

(22) Filed: Dec. 22, 2023

(30) Foreign Application Priority Data
Dec. 29, 2022 (CN) 202211681239.0
Mar. 10, 2023 (CN) 202310230193.9

(51) Int. Cl. H10K 50/11; H10K 85/30; H10K 85/60

(52) U.S. Cl. CPC H10K 50/11; H10K 85/342; H10K 85/654; H10K 85/6572

(57) ABSTRACT

Provided is an organic electroluminescent device. The organic electroluminescent device comprises a cathode, an anode, and an emissive layer disposed between the cathode and the anode, wherein the emissive layer comprises at least a first host compound, a second host compound, and a first metal complex. A capacitance property of the organic electroluminescent device satisfies the following condition: at 500 Hz, a maximum capacitance value of the organic electroluminescent device is Cₘₐₓ, and Cₘₐₓ−Cₘₐₓ₀≤−0.20 nF, wherein Cₘₐₓ₀ denotes a maximum capacitance value of an organic electroluminescent device A at 500 Hz. The organic electroluminescent device can greatly reduce device capacitance, which is conducive to improving a response rate of the device at a low grayscale and increasing a refresh rate of the device, and further improve device efficiency. Further provided is a display assembly comprising the organic electroluminescent device.

### CROSS-REFERENCE TO RELATED APPLICATION(S)

This application claims priority to Chinese Patent Application No. 202211681239.0 filed on Dec. 29, 2022 and Chinese Patent Application No. 202310230193.9 filed on Mar. 10, 2023, the disclosure of which are incorporated herein by reference in their entireties.

### TECHNICAL FIELD

The present disclosure relates to organic electronic devices, for example, organic electroluminescent devices. More particularly, the present disclosure relates to an organic electroluminescent device with an emissive layer comprising a first host compound, a second host compound and a first metal complex.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Device capacitance is a key factor affecting a response time and a refresh rate of an OLED display device at a low grayscale. For the OLED device, an emissive layer is an important medium for holes and electrons to recombine into excitons and ultimately emit light. The material selection of the emissive layer has an important effect on device performance and device capacitance.

The emissive layer generally includes an emissive doping material and a host material. The prior Chinese Patent Application No. CN202211093543.3 of the Applicant has disclosed a metal complex with a ligand having a structure of

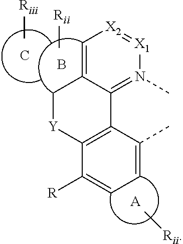

The metal complex is an emissive doping material with excellent performance. This application focuses on excellent properties of the metal complex due to the new ligand, such as high efficiency, and obtains excellent device performance by using a combination of the new metal complex and a bipolar single-host material

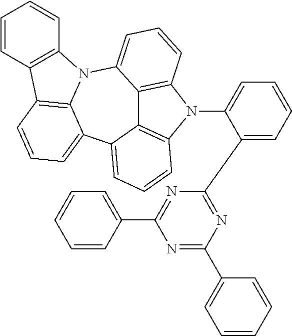 [SMILES: c1ccc(-c2nc(-c3ccccc3)nc(-c3ccccc3-n3c4cccc5c6cccc7c8ccccc8n(c8cccc3c8c54)c67)n2)cc1]

in the emissive layer of the device. However, the capacitance property of the device using this combination has not been noticed in this document.

Although a bipolar host commonly used at present can transport electrons and holes at the same time, the problem of high device capacitance is often difficult to solve due to a limitation of a structural design of the bipolar host. Therefore, it is of great significance to study how to improve the emissive layer of the device to greatly reduce the capacitance of the device, thereby improving the response time and refresh rate of the device at a low grayscale.

### SUMMARY

The present disclosure aims to provide a new organic electroluminescent device with an emissive layer comprising a first host compound, a second host compound, and a first metal complex, so as to solve at least part of the preceding problems. The first metal complex has a structure represented by Formula 1 and may be used as an emissive material in the organic electroluminescent device. The organic electroluminescent device can greatly reduce the capacitance of the device to improve a response time and a refresh rate of the device at a low grayscale and can further improve device efficiency.

According to an embodiment of the present disclosure, an organic electroluminescent device is disclosed. The organic electroluminescent device comprises:
a cathode,
an anode, and
an emissive layer disposed between the cathode and the anode, wherein the emissive layer comprises at least a first host compound, a second host compound, and a first metal complex; and a capacitance property of the organic electroluminescent device satisfies the following condition:
at 500 Hz, a maximum capacitance value of the organic electroluminescent device is Cₘₐₓ, and Cₘₐₓ−Cₘₐₓ₀≤−0.20 nF;
wherein Cₘₐₓ₀ denotes a maximum capacitance value of an organic electroluminescent device A at 500 Hz; and the organic electroluminescent device A is the same as the organic electroluminescent device except that the first host compound and the second host compound in the emissive layer of the organic electroluminescent device are replaced with Compound RH0 as a host compound;
wherein the Compound RH0 has the following structure:

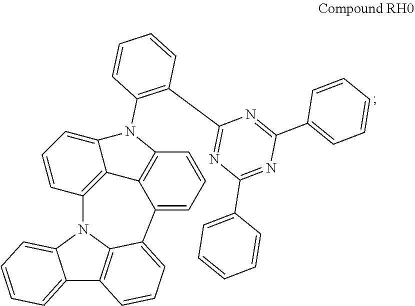 [SMILES: c1ccc(-c2nc(-c3ccccc3)nc(-c3ccccc3-n3c4cccc5c6cccc7c8ccccc8n(c8cccc3c8c54)c67)n2)cc1]

the first metal complex comprises a metal M and a ligand Lₐ coordinated to the metal M, wherein the metal M is selected from a metal with a relative atomic mass greater than 40, and the ligand Lₐ has a structure represented by Formula 1:

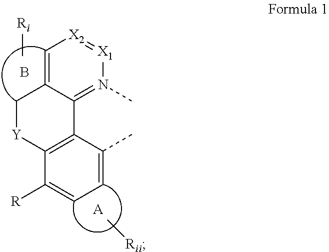

wherein the ring A and the ring B are each independently selected from a five-membered unsaturated carbocyclic ring, an aromatic ring having 6 to 30 carbon atoms, or a heteroaromatic ring having 3 to 30 carbon atoms;
X₁ and X₂ are, at each occurrence identically or differently, selected from CRₓ or N;
Rᵢ and Rᵢᵢ represent, at each occurrence identically or differently, mono-substitution, multiple substitutions, or non-substitution;
at least one of the following two conditions is satisfied:
(1) at least two Rᵢ are joined to form a ring; or
(2) X₁ and X₂ are, at each occurrence identically or differently, selected from CRₓ, and two Rₓ are joined to form a ring;
Y is selected from SiR_{y}R_{y}, GeR_{y}R_{y}, NR_{y}, PR_{y}, O, S, or Se; when two R_{y} are present at the same time, the two R_{y} may be the same or different;
R, Rᵢ, Rᵢᵢ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, Rᵢ, Rᵢᵢ, Rₓ, R_{y} can be optionally joined to form a ring.

According to another embodiment of the present disclosure, a display assembly is disclosed. The display assembly comprises an organic electroluminescent device, wherein the specific structure of the organic electroluminescent device is shown in the preceding embodiment.

The present disclosure discloses a new organic electroluminescent device with an emissive layer comprising a first host compound, a second host compound, and a first metal complex. The first metal complex may be used as an emissive material in the organic electroluminescent device. The organic electroluminescent device can greatly reduce the capacitance of the device, improve the balance of electrons and holes in the device, and further improve device efficiency.

### BRIEF DESCRIPTION OF DRAWINGS

FIG. 1 is an example diagram of a capacitance-voltage (C-V) property curve of an organic electroluminescent device.

FIG. 2 is a schematic diagram of an organic light-emitting apparatus that may include an organic electroluminescent device disclosed herein.

FIG. 3 is a schematic diagram of another organic light-emitting apparatus that may include an organic electroluminescent device disclosed herein.

### DETAILED DESCRIPTION

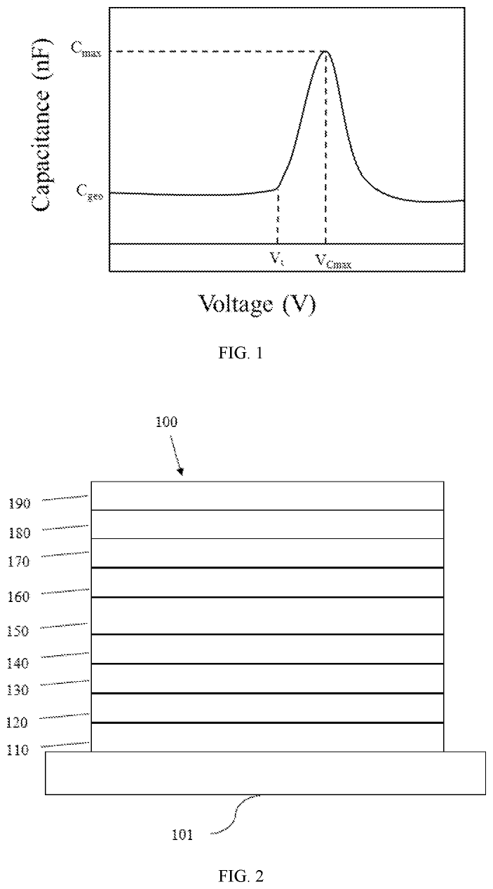

In an OLED device, the movement, distribution, and accumulation of charges in the device may be analyzed by studying the capacitance-voltage (C-V) property of the device. As shown in FIG. 1 which is an example diagram of a C-V property curve of the device, the dynamic study of the charges in the device may be roughly classified into the four cases below according to different bias voltages applied.

(1) When the applied voltage V₀ is lower than an initial voltage Vₜ, that is, V₀<Vₜ, (where the initial voltage Vₜ refers to a corresponding voltage at which point the capacitance starts to increase from C_{geo}), carriers (holes) cannot enter the emissive layer of the device, and the device behaves like an insulator connected between the anode and the cathode. In this case, the capacitance of the device is a constant, which is referred to as the geometric capacitance C_{geo} of the device. A higher initial voltage means that the carriers in the OLED are less likely to accumulate at a low voltage, which is conducive to the balance of carriers in the emissive layer. Therefore, the initial voltage has an effect on the capacitance of the OLED.

(2) When the applied voltage V₀ is higher than the initial voltage Vₜ and lower than a voltage V_{Cmax} corresponding to the maximum capacitance, that is, Vₜ<V₀<V_{Cmax}, holes begin to be injected into the interior of the device. As the holes accumulate inside the device, the capacitance of the device gradually increases.

(3) When the applied voltage V₀ continues to increase, the capacitance value of the device also continues to increase until the applied voltage V₀ is equal to the voltage V_{Cmax} corresponding to the maximum capacitance, that is, V₀=V_{Cmax}, and the capacitance of the device reaches a maximum value Cₘₐₓ.

(4) When the applied voltage V₀ is higher than the voltage V_{Cmax}, that is, V₀>V_{Cmax}, electrons begin to be injected into the device, and then the hole-electron recombination process occurs. As the holes accumulated in the device are consumed, the capacitance of the device gradually decreases.

OLEDs can be fabricated on various types of substrates such as glass, plastic, and metal foil. FIG. 2 schematically shows an organic light emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may comprise a single layer or multiple layers.

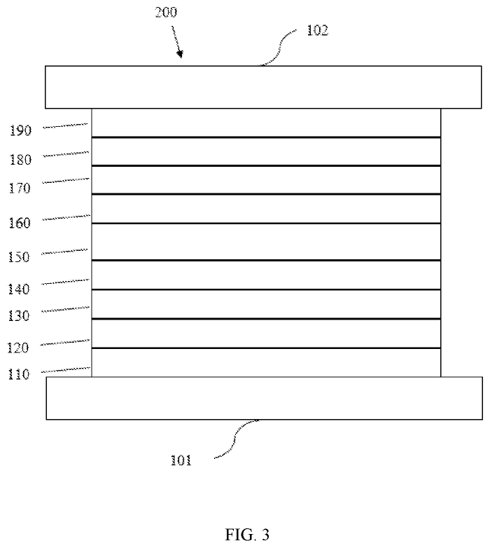

An OLED can be encapsulated by a barrier layer. FIG. 3 schematically shows an organic light emitting device 200 without limitation. FIG. 3 differs from FIG. 2 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, an “emissive area” refers to a corresponding area in an organic electroluminescent device where the anode is in direct contact with organic layers and meanwhile the organic layers are in direct contact with the cathode in a direction perpendicular to the light emission surface. Herein, the emissive area in examples and comparative examples is 0.04 cm².

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states.

Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AES-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups includes saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C-H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl having 3 to 20 carbon atoms, unsubstituted arylgermanyl having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

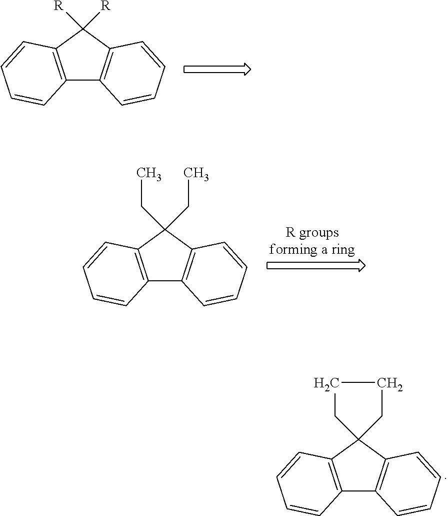

The expression that adjacent substituents can be optionally joined to form a ring is also intended to mean that two substituents bonded to carbon atoms which are directly bonded to each other are joined to each other via a chemical bond to form a ring, which can be exemplified by the following formula:

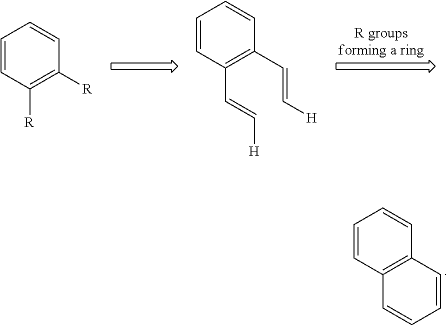

The expression that adjacent substituents can be optionally joined to form a ring is also intended to mean that two substituents bonded to further distant carbon atoms are joined to each other via a chemical bond to form a ring, which can be exemplified by the following formula:

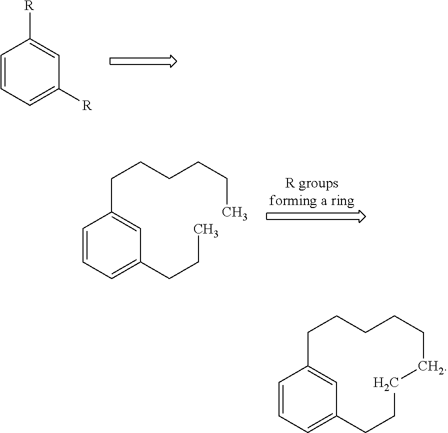

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

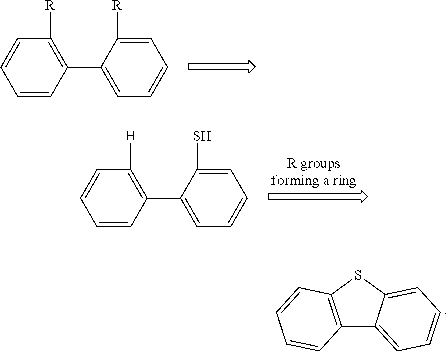

According to an embodiment of the present disclosure, an organic electroluminescent device is disclosed. The organic electroluminescent device comprises:
a cathode,
an anode, and
an emissive layer disposed between the cathode and the anode, wherein the emissive layer comprises at least a first host compound, a second host compound, and a first metal complex; and a capacitance property of the organic electroluminescent device satisfies the following condition:
at 500 Hz, a maximum capacitance value of the organic electroluminescent device is Cₘₐₓ, and Cₘₐₓ−Cₘₐₓ₀≤−0.20 nF;
wherein Cₘₐₓ₀ denotes a maximum capacitance value of an organic electroluminescent device A at 500 Hz; and the organic electroluminescent device A is the same as the organic electroluminescent device except that the first host compound and the second host compound in the emissive layer of the organic electroluminescent device are replaced with Compound RH0 as a host compound;
wherein the Compound RH0 has the following structure:

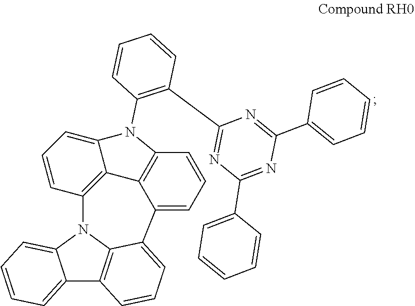 [SMILES: c1ccc(-c2nc(-c3ccccc3)nc(-c3ccccc3-n3c4cccc5c6cccc7c8ccccc8n(c8cccc3c8c54)c67)n2)cc1]

the first metal complex comprises a metal M and a ligand Lₐ coordinated to the metal M, wherein the metal M is selected from a metal with a relative atomic mass greater than 40, and the ligand Lₐ has a structure represented by Formula 1:

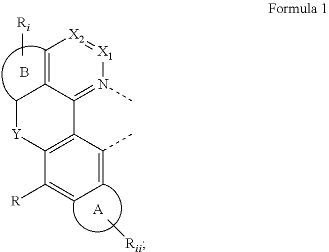

wherein the ring A and the ring B are each independently selected from a five-membered unsaturated carbocyclic ring, an aromatic ring having 6 to 30 carbon atoms, or a heteroaromatic ring having 3 to 30 carbon atoms;
X₁ and X₂ are, at each occurrence identically or differently, selected from CRₓ or N;
Rᵢ and Rᵢᵢ represent, at each occurrence identically or differently, mono-substitution, multiple substitutions, or non-substitution;
at least one of the following two conditions is satisfied:
(1) at least two Rᵢ are joined to form a ring; or
(2) X₁ and X₂ are, at each occurrence identically or differently, selected from CRₓ, and two Rₓ are joined to form a ring;
Y is selected from SiR_{y}R_{y}, GeR_{y}R_{y}, NR_{y}, PR_{y}, O, S, or Se; when two R_{y} are present at the same time, the two R_{y} may be the same or different;
R, Rᵢ, Rᵢᵢ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, Rᵢ, Rᵢᵢ, Rₓ, R_{y} can be optionally joined to form a ring.

In the present disclosure, the expression that “adjacent substituents R, Rᵢ, Rᵢᵢ, Rₓ, R_{y} can be optionally joined to form a ring” is intended to mean that any one or more of groups of adjacent substituents, such as two substituents Rₓ, two substituents R_{y}, two substituents Rᵢᵢ, substituents Rᵢ and Rₓ, substituents Rᵢ and R_{y}, substituents R and R_{y}, and substituents Rᵢᵢ and R, can be joined to form a ring. Obviously, it is also possible that none of these substituents are joined to form a ring.

In the present disclosure, the expression that “Cₘₐₓ₀ denotes a maximum capacitance value of an organic electroluminescent device A at 500 Hz; and the organic electroluminescent device A is the same as the organic electroluminescent device except that the first host compound and the second host compound in the emissive layer of the organic electroluminescent device are replaced with Compound RH0 as a host compound” is intended to mean that: in any organic electroluminescent device (which may be referred to as an organic electroluminescent device Y) claimed in the present disclosure that has the emissive layer comprising the first host compound, the second host compound, and the first metal complex, at 500 Hz, when a voltage (V₀) equal to a voltage V_{Cmax} is applied to the organic electroluminescent device Y, the measured maximum capacitance value of the device is Cₘₐₓ; in another organic electroluminescent device A that differs from the organic electroluminescent device Y only in that the first host compound and the second host compound in the emissive layer of the organic electroluminescent device Y are replaced with Compound RH0, at 500 Hz, when a voltage (V₀) equal to a voltage V_{Cmax0} is applied to the electroluminescent device A, the measured maximum capacitance value of the device is Cₘₐₓ₀. The difference, Cₘₐₓ−Cₘₐₓ₀, described herein is a difference between the maximum capacitance of the organic electroluminescent device Y and the maximum capacitance of the organic electroluminescent device A. It is to be noted that the maximum capacitance value Cₘₐₓ of the organic electroluminescent device Y, the maximum capacitance value Cₘₐₓ₀ of the organic electroluminescent device A, and that Cₘₐₓ−Cₘₐₓ₀≤−0.20 nF are all values measured under the following condition: the emissive area of the organic electroluminescent device Y and the emissive area of the organic electroluminescent device A are both 0.04 cm². It is to be understood by those skilled in the art that if the emissive area of the device changes, the corresponding maximum capacitance values Cₘₐₓ and Cₘₐₓ₀ and Cₘₐₓ−Cₘₐₓ₀ naturally change according to the rule that “a maximum capacitance value per unit of emissive area of the device=the maximum capacitance value/the emissive area”.

According to an embodiment of the present disclosure, at least one of Rᵢ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof.

According to an embodiment of the present disclosure, at least one of Rₓ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a hydroxyl group, a sulfanyl group, a sulfinyl group, a sulfonyl group, a phosphino group, and combinations thereof.

According to an embodiment of the present disclosure, a lowest unoccupied molecular orbital energy level of the second host compound is E_{LUMO}≤−2.75 eV.

According to an embodiment of the present disclosure, the lowest unoccupied molecular orbital energy level of the second host compound is E_{LUMO}≤−2.80 eV.

According to an embodiment of the present disclosure, at 500 Hz, Cₘₐₓ−Cₘₐₓ₀≤−0.30 nF.

According to an embodiment of the present disclosure, at 500 Hz, Cₘₐₓ−Cₘₐₓ₀≤−0.75 nF.

According to an embodiment of the present disclosure, at 500 Hz, 2.0 nF≤Cₘₐₓ₀≤6.0 nF.

According to an embodiment of the present disclosure, at 500 Hz, the maximum capacitance value of the organic electroluminescent device is 0.5 nF≤Cₘₐₓ≤5.5 nF.

According to an embodiment of the present disclosure, the maximum capacitance value of the organic electroluminescent device is 1.0 nF≤Cₘₐₓ≤4.0 nF.

According to an embodiment of the present disclosure, the maximum capacitance value of the organic electroluminescent device is 1.0 nF≤Cₘₐₓ≤3.0 nF.

According to an embodiment of the present disclosure, the maximum capacitance value of the organic electroluminescent device is 1.0 nF≤Cₘₐₓ≤2.0 nF.

According to an embodiment of the present disclosure, at 500 Hz, an initial voltage of capacitance of the organic electroluminescent device is Vₜ, which satisfies that −4.0 V≤Vₜ≤5.0 V.

According to an embodiment of the present disclosure, at 500 Hz, the initial voltage of capacitance of the organic electroluminescent device is Vₜ, which satisfies that −3.0 V≤Vₜ≤3.0 V.

According to an embodiment of the present disclosure, at 500 Hz, the initial voltage of capacitance of the organic electroluminescent device is Vₜ, and an initial voltage of capacitance of the organic electroluminescent device A is V_{tA}, which satisfy that 125%≤Vₜ/V_{tA}.

According to an embodiment of the present disclosure, at 500 Hz, the initial voltage of capacitance of the organic electroluminescent device is Vₜ, and the initial voltage of capacitance of the organic electroluminescent device A is V_{tA}, which satisfy that 130%≤Vₜ/V_{tA}.

According to an embodiment of the present disclosure, at 500 Hz, the initial voltage of capacitance of the organic electroluminescent device is Vₜ, and the initial voltage of capacitance of the organic electroluminescent device A is V_{tA}, which satisfy that 150%≤Vₜ/V_{tA}.

According to an embodiment of the present disclosure, the first host compound has a structure represented by Formula 2 or Formula 3:

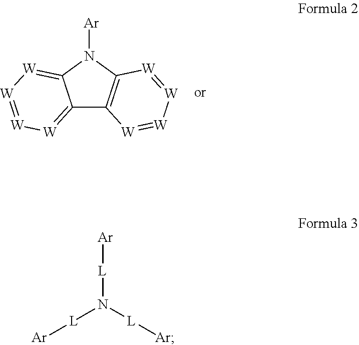

wherein W is, at each occurrence identically or differently, selected from CR_{w} or N, and adjacent substituents R_{w} can be optionally joined to form a ring;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar is, at each occurrence identically or differently, selected from substituted or unsubstituted aryl having 6 to 30 carbon atoms or substituted or unsubstituted heteroaryl having 3 to 30 carbon atoms;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{w} can be optionally joined to form a ring.

In the present disclosure, the expression that “adjacent substituents R_{w} can be optionally joined to form a ring” is intended to mean that any adjacent substituents R_{w} can be joined to form a ring. Obviously, it is also possible that any adjacent substituents R_{w} are not joined to form a ring.

According to an embodiment of the present disclosure, the first host compound has a structure represented by Formula 2-1, Formula 2-2, or Formula 3-1:

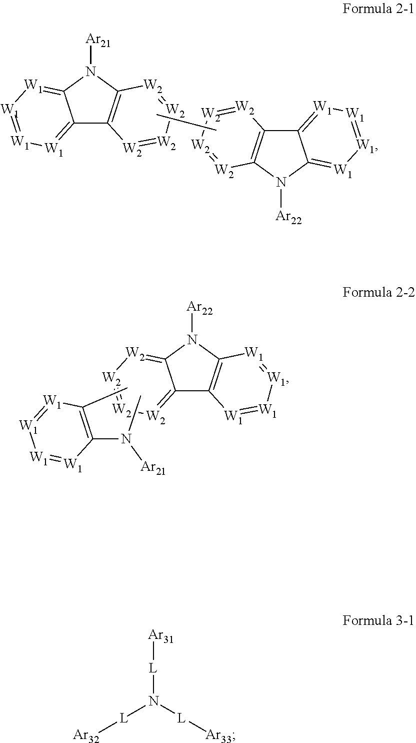

wherein W₁ is, at each occurrence identically or differently, selected from CR_{w} or N;
W₂ is, at each occurrence identically or differently, selected from C, CR_{w}, or N;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar₂₁, Ar₂₂, Ar₃₁, Ar₃₂, and Ar₃₃ are, at each occurrence identically or differently, selected from substituted or unsubstituted aryl having 6 to 30 carbon atoms or substituted or unsubstituted heteroaryl having 3 to 30 carbon atoms;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{w} can be optionally joined to form a ring.

According to an embodiment of the present disclosure, the first host compound has a structure represented by any one of Formula 2-a to Formula 2-h and Formula 3-a:

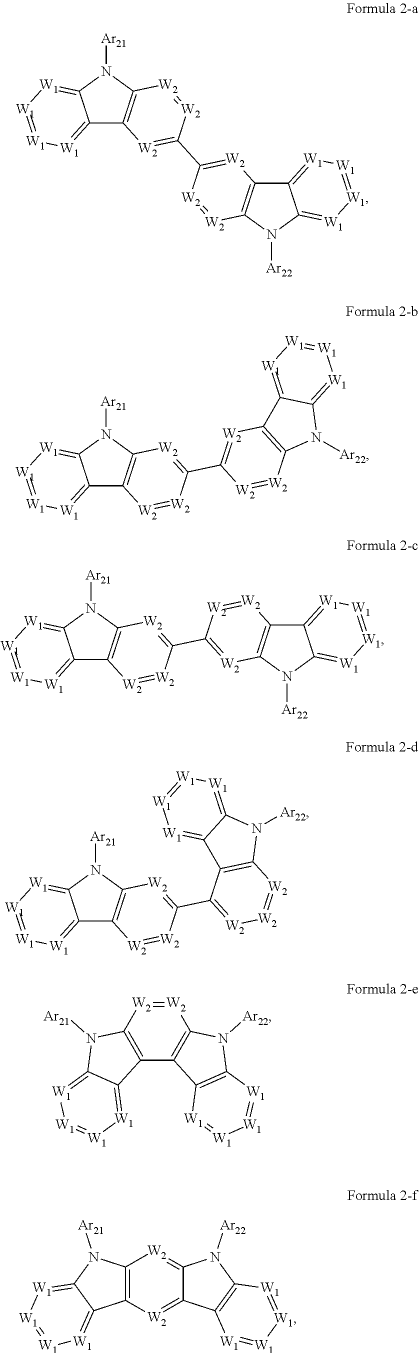

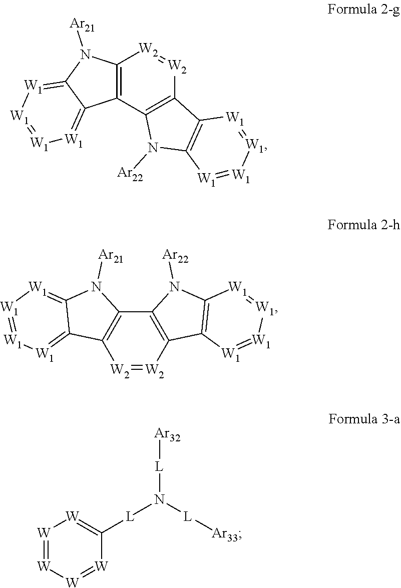

wherein W₁, W₂, and W are, at each occurrence identically or differently, selected from CR_{w} or N;
Ar₂₁, Ar₂₂, Ar₃₂, and Ar₃₃ are, at each occurrence identically or differently, selected from substituted or unsubstituted aryl having 6 to 30 carbon atoms or substituted or unsubstituted heteroaryl having 3 to 30 carbon atoms;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{w} can be optionally joined to form a ring.

According to an embodiment of the present disclosure, the first host compound has a structure represented by any one of Formula 2-a to Formula 2-c, Formula 2-e, and Formula 3-a.

According to an embodiment of the present disclosure, R_{w} is, at each occurrence identically or differently, selected from hydrogen, deuterium, halogen, a cyano group, a hydroxyl group, a sulfanyl group, substituted or unsubstituted alkyl having 1 to 20 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, or a combination thereof.

According to an embodiment of the present disclosure, in the first host compound, Ar₂₁ and Ar₂₂ have, at each occurrence identically or differently, a structure represented by any one of Formula Ar-1 to Formula Ar-4, and Ar₃₂ and Ar₃₃ have, at each occurrence identically or differently, a structure represented by any one of Formula Ar-1 to Formula Ar-6:

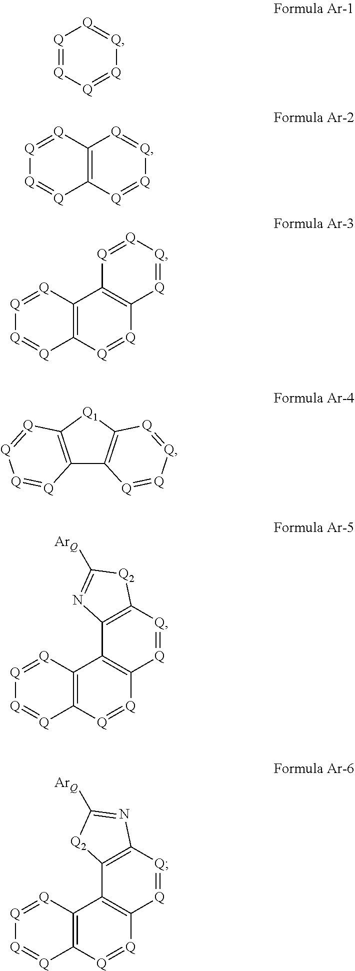

wherein Ar_{Q} is, at each occurrence identically or differently, selected from substituted or unsubstituted aryl having 6 to 30 carbon atoms or substituted or unsubstituted heteroaryl having 3 to 30 carbon atoms;
Q is, at each occurrence identically or differently, selected from C, CR_{Q}, or N; Q₁ is selected from O, S, Se, NR_{Q}, or CR_{Q}R_{Q}; Q₂ is selected from O, S, or Se; when two R_{Q} are present at the same time, the two R_{Q} may be the same or different;
R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{Q} can be optionally joined to form a ring.

In the present disclosure, the expression that “adjacent substituents R_{Q} can be optionally joined to form a ring” is intended to mean that any adjacent substituents R_{Q} can be joined to form a ring. Obviously, it is also possible that any adjacent substituents R_{Q} are not joined to form a ring.

According to an embodiment of the present disclosure, Q is, at each occurrence identically or differently, selected from C or CR_{Q}; Q₁ is selected from O, S, or CR_{Q}R_{Q}; Q₂ is selected from O or S; and R_{Q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, Ar_{Q} is selected from phenyl, naphthyl, biphenyl, pyridyl, or phenanthryl.

According to an embodiment of the present disclosure, the first host compound is selected from the group consisting of Compound 1-1-1 to Compound 1-1-104, Compound 1-2-1 to Compound 1-2-100, and Compound 1-3-1 to Compound 1-3-62:

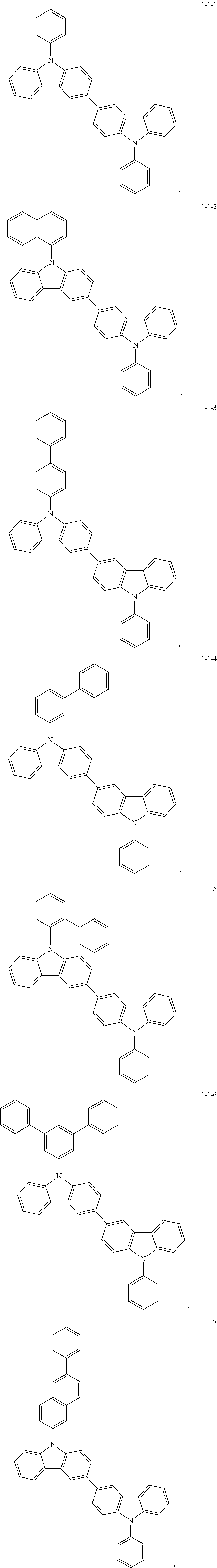

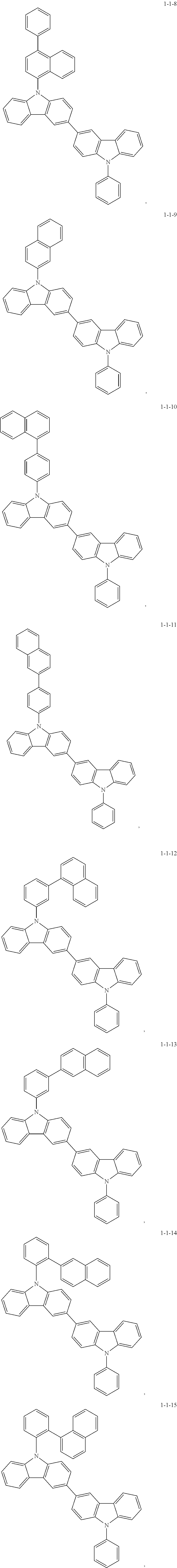

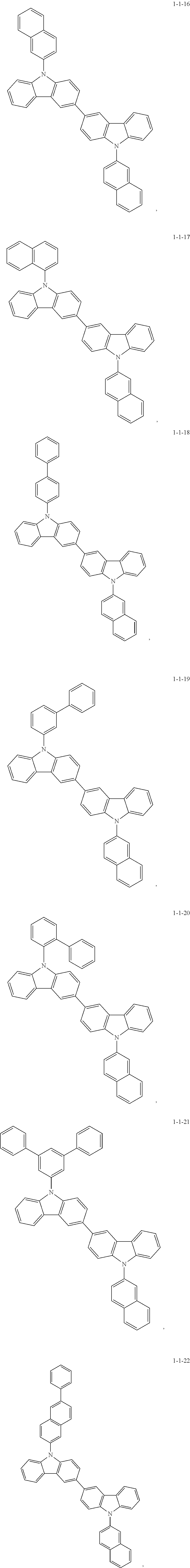

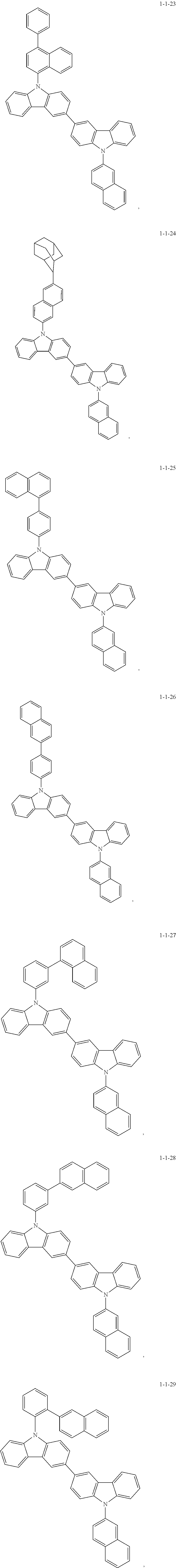

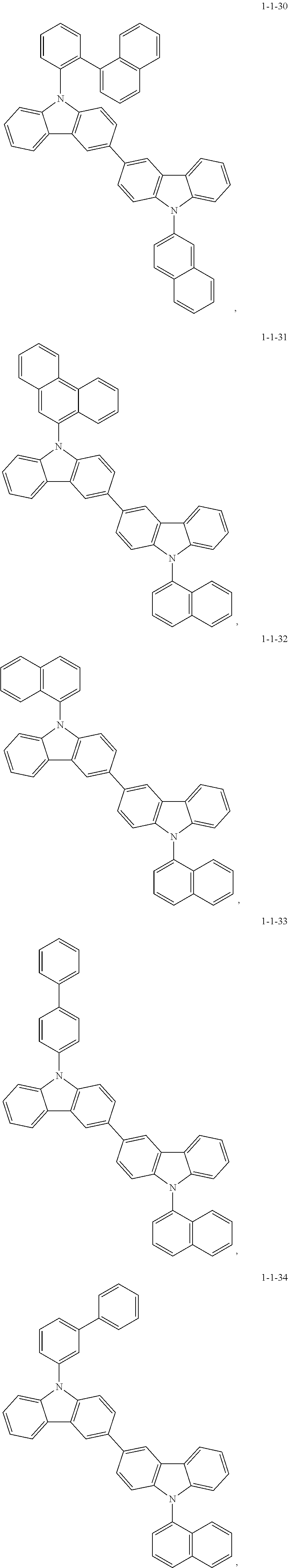 [SMILES: c1ccc(-n2c3ccccc3c3cc(-c4ccc5c(c4)c4ccccc4n5-c4ccc5ccccc5c4)ccc32)c(-c2cccc3ccccc23)c1 ; c1ccc2c(-n3c4ccccc4c4cc(-c5ccc6c(c5)c5ccccc5n6-c5cc6ccccc6c6ccccc56)ccc43)cccc2c1 ; c1ccc2c(-n3c4ccccc4c4cc(-c5ccc6c(c5)c5ccccc5n6-c5cccc6ccccc56)ccc43)cccc2c1 ; c1ccc(-c2ccc(-n3c4ccccc4c4cc(-c5ccc6c(c5)c5ccccc5n6-c5cccc6ccccc56)ccc43)cc2)cc1 ; c1ccc(-c2cccc(-n3c4ccccc4c4cc(-c5ccc6c(c5)c5ccccc5n6-c5cccc6ccccc56)ccc43)c2)cc1]

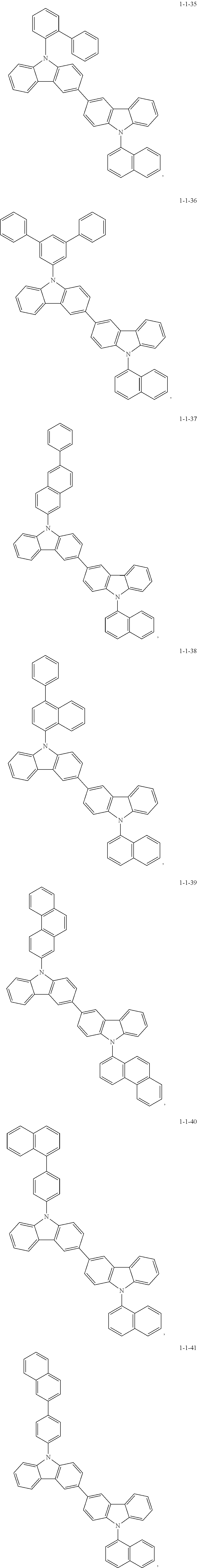

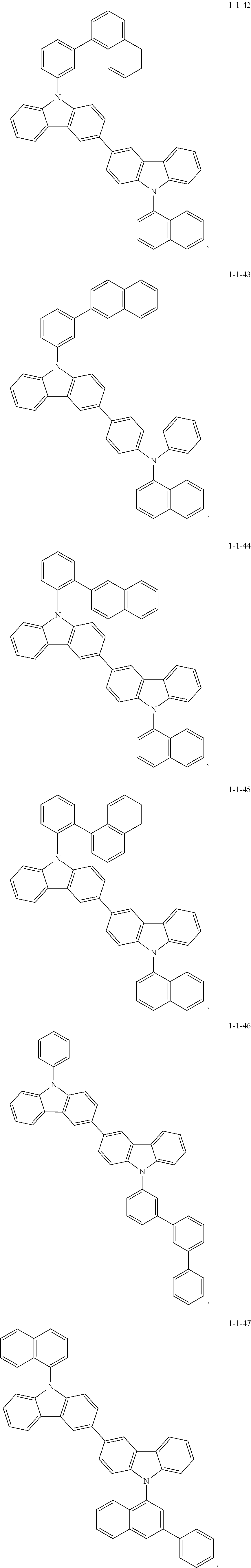

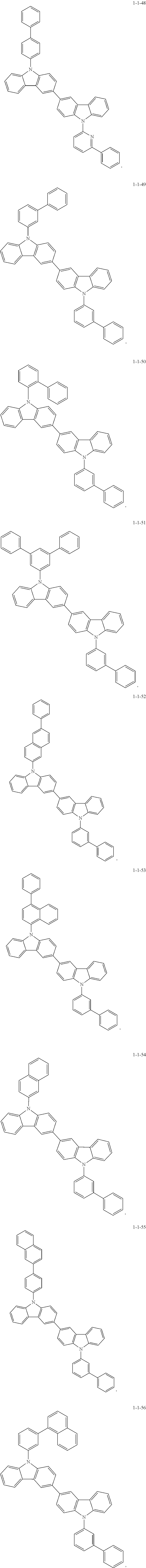

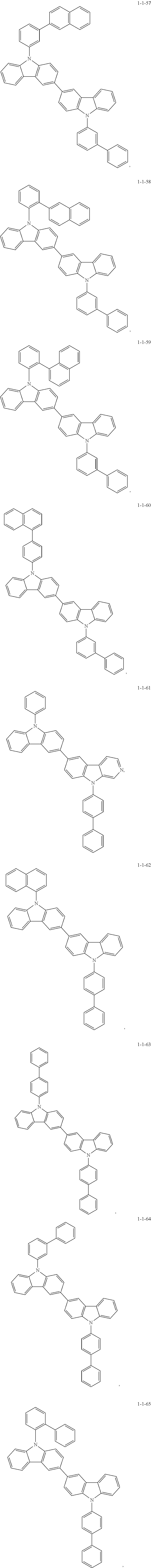

[chemical structure]

[chemical structure]

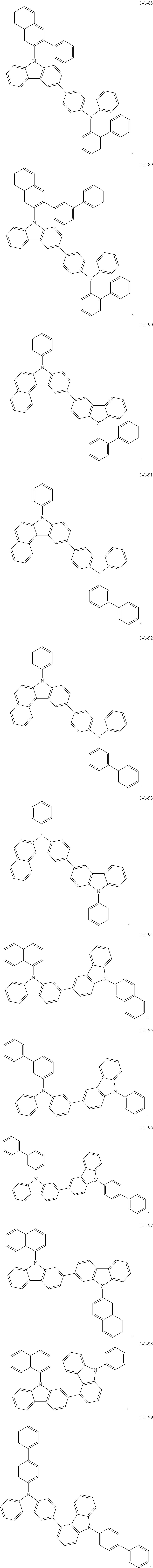

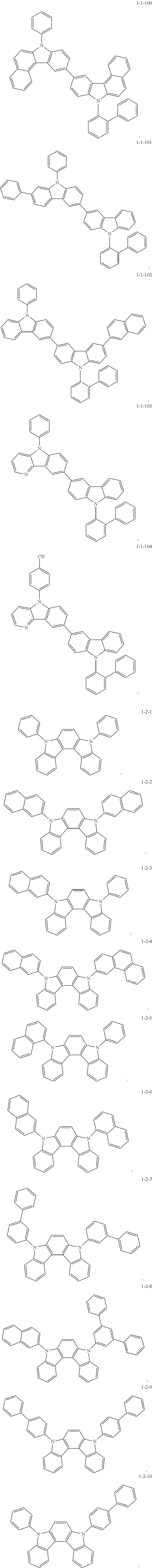

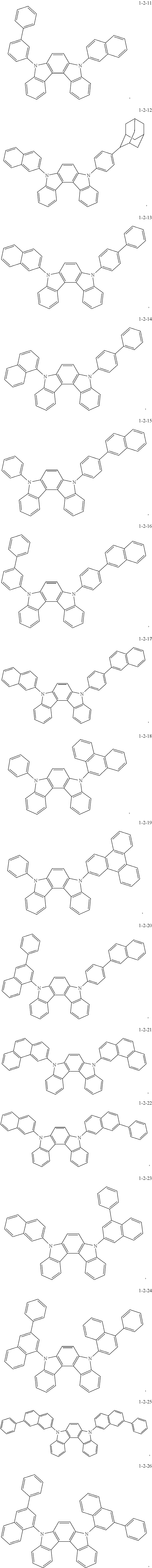

[chemical structure]

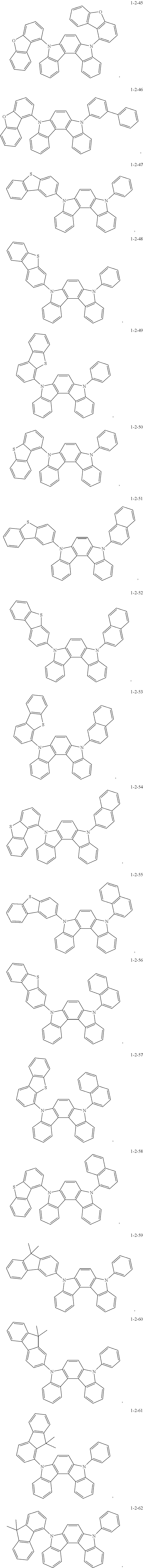

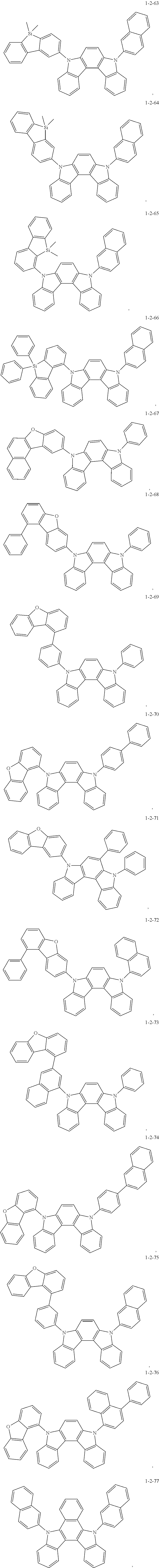

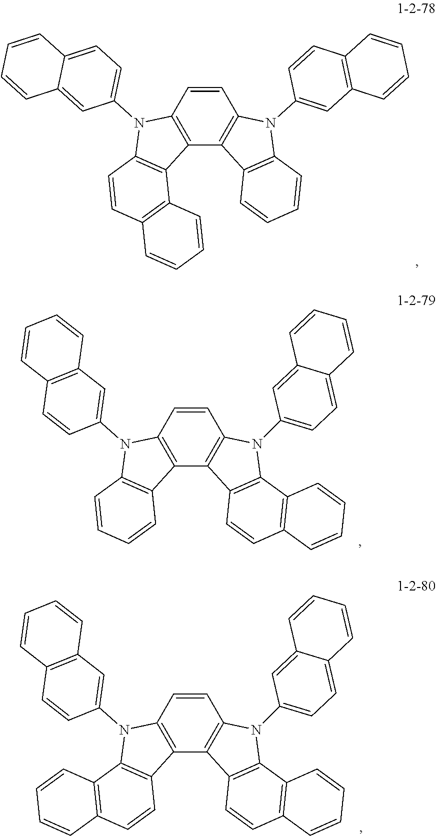

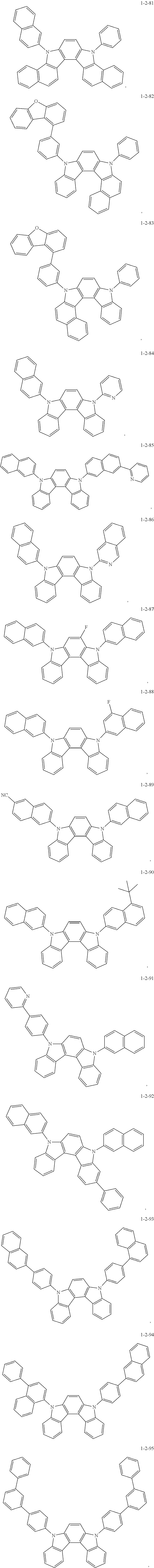

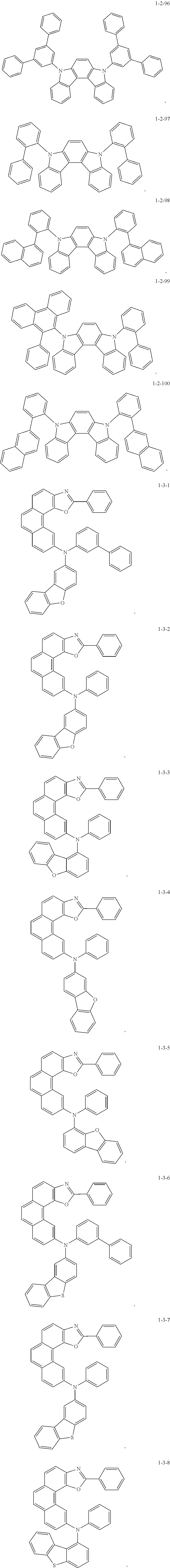

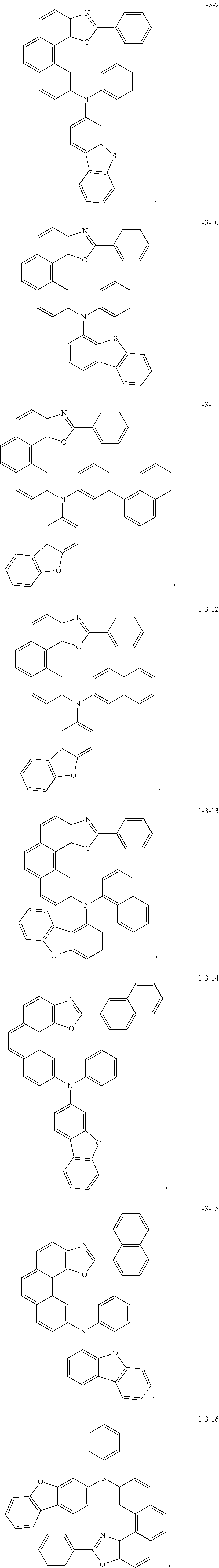

[chemical structure]

[chemical structure]

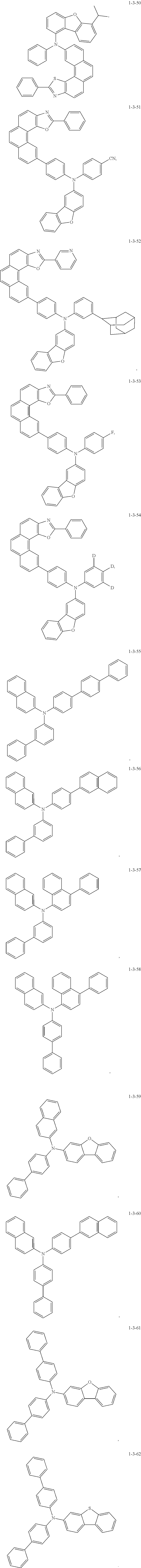

According to an embodiment of the present disclosure, hydrogens in Compound 1-1-1 to Compound 1-1-104, Compound 1-2-1 to Compound 1-2-100, and Compound 1-3-1 to Compound 1-3-62 can be partially or fully substituted with deuterium.

According to an embodiment of the present disclosure, the second host compound has a structure represented by Formula 4:

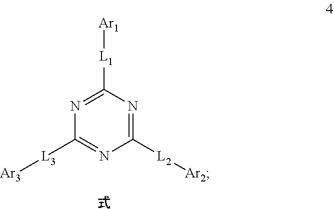

in Formula 4, L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof; and
Ar₁ to Ar₃ are, at each occurrence identically or differently, selected from substituted or unsubstituted aryl having 6 to 30 carbon atoms, substituted or unsubstituted heteroaryl having 3 to 30 carbon atoms, or a combination thereof.

According to an embodiment of the present disclosure, in Formula 4, L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 24 carbon atoms, substituted or unsubstituted heteroarylene having 3 to 24 carbon atoms, or a combination thereof; and

Ar₁ to Ar₃ are, at each occurrence identically or differently, selected from substituted or unsubstituted aryl having 6 to 24 carbon atoms, substituted or unsubstituted heteroaryl having 3 to 24 carbon atoms, or a combination thereof.

According to an embodiment of the present disclosure, the second host compound has a structure represented by Formula 4-1:

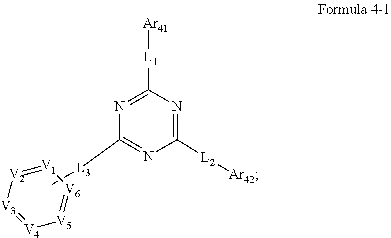

wherein V₁ to V₆ are, at each occurrence identically or differently, selected from C, N, or CRᵥ, and one of V₁ to V₆ is C and joined to L₃;
L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Ar₄₁ and Ar₄₂ are, at each occurrence identically or differently, selected from substituted or unsubstituted aryl having 6 to 30 carbon atoms, substituted or unsubstituted heteroaryl having 3 to 30 carbon atoms, or a combination thereof;
Rᵥ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rᵥ can be optionally joined to form a ring.

According to an embodiment of the present disclosure, the second host compound has a structure represented by Formula 4-1-1 or Formula 4-1-2:

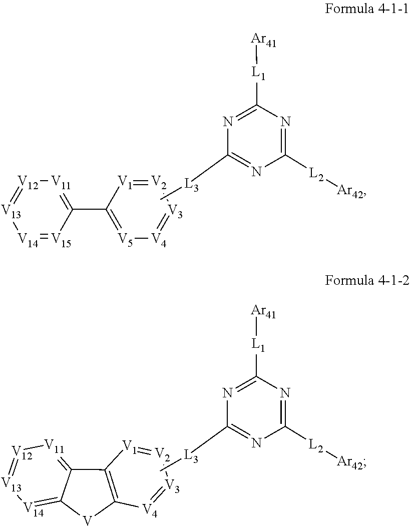

wherein in Formula 4-1-1, V₁ to V₅ are, at each occurrence identically or differently, selected from C, N, or CRᵥ, V₁₁ to V₁₅ are, at each occurrence identically or differently, selected from N or CRᵥ₁, and one of V₁ to V₅ is C and joined to L₃;
in Formula 4-1-2, V₁ to V₄ are, at each occurrence identically or differently, selected from C, N, or CRᵥ, V₁₁ to V₁₄ are, at each occurrence identically or differently, selected from N or CR^{v1}, and one of V₁ to V₄ is C and joined to L₃;
V is selected from O, S, or Se;
L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Ar₄₁ and Ar₄₂ are, at each occurrence identically or differently, selected from substituted or unsubstituted aryl having 6 to 30 carbon atoms, substituted or unsubstituted heteroaryl having 3 to 30 carbon atoms, or a combination thereof;
Rᵥ and Rᵥ₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rᵥ, Rᵥ₁ can be optionally joined to form a ring.

In the present disclosure, the expression that “adjacent substituents Rᵥ, Rᵥ₁ can be optionally joined to form a ring” is intended to mean that any one or more of groups of adjacent substituents, such as adjacent substituents Rᵥ, adjacent substituents Rᵥ₁, and adjacent substituents Rᵥ and Rᵥ₁, can be joined to form a ring. Obviously, it is also possible that none of these substituents are joined to form a ring.

According to an embodiment of the present disclosure, in Formula 4-1-2, V is selected from O or S.

According to an embodiment of the present disclosure, in Formula 4-1-2, V is selected from O.

According to an embodiment of the present disclosure, in Formula 4-1-1, V₁ to V₅ are, at each occurrence identically or differently, selected from C or CRᵥ, and V₁₁ to V₁₅ are, at each occurrence identically or differently, selected from CRᵥ₁; and in Formula 4-1-2, V₁ to V₄ are, at each occurrence identically or differently, selected from C or CRᵥ, and V₁₁ to V₁₄ are, at each occurrence identically or differently, selected from CRᵥ₁.

According to an embodiment of the present disclosure, Rᵥ and Rᵥ₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, in Formula 4-1-1, at least one of V₁ to V₅ is selected from CRᵥ, or at least one of V₁₁ to Vis is selected from CRᵥ₁; in Formula 4-1-2, at least one of V₁ to V₄ is selected from CRᵥ, or at least one of V₁₁ to V₁₄ is selected from CRᵥ₁; and Rᵥ and Rᵥ₁ are, at each occurrence identically or differently, selected from substituted or unsubstituted aryl having 6 to 30 carbon atoms.

According to an embodiment of the present disclosure, Rᵥ and Rᵥ₁ are, at each occurrence identically or differently, selected from the group consisting of: hydrogen, deuterium, substituted or unsubstituted phenyl, substituted or unsubstituted naphthyl, substituted or unsubstituted biphenyl, and combinations thereof.

According to an embodiment of the present disclosure, at least one of Ar₄₁ and Ar₄₂ is a structure with two or three fused rings.

According to an embodiment of the present disclosure, Ar₄₁ and Ar₄₂ are, at each occurrence identically or differently, selected from substituted or unsubstituted aryl having 6 to 20 carbon atoms, substituted or unsubstituted heteroaryl having 3 to 20 carbon atoms, or a combination thereof.

According to an embodiment of the present disclosure, Ar₄₁ and Ar₄₂ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted phenanthryl, substituted or unsubstituted triphenylenyl, substituted or unsubstituted chrysenyl, substituted or unsubstituted fluorenyl, substituted or unsubstituted carbazolyl, substituted or unsubstituted dibenzofuryl, substituted or unsubstituted dibenzothienyl, substituted or unsubstituted pyridyl, substituted or unsubstituted pyrimidinyl, substituted or unsubstituted quinolyl, substituted or unsubstituted indolocarbazolyl, or a combination thereof.

According to an embodiment of the present disclosure, L₁ to L₃ are, at each occurrence identically or differently, selected from a single bond, substituted or unsubstituted arylene having 6 to 20 carbon atoms, substituted or unsubstituted heteroarylene having 3 to 20 carbon atoms, or a combination thereof.

According to an embodiment of the present disclosure, L₁ to L₃ are, at each occurrence identically or differently, selected from a single bond, substituted or unsubstituted phenylene, substituted or unsubstituted naphthylene, substituted or unsubstituted biphenylylene, or a combination thereof.

According to an embodiment of the present disclosure, the second host compound is selected from the group consisting of Compound B-1 to Compound B-227:

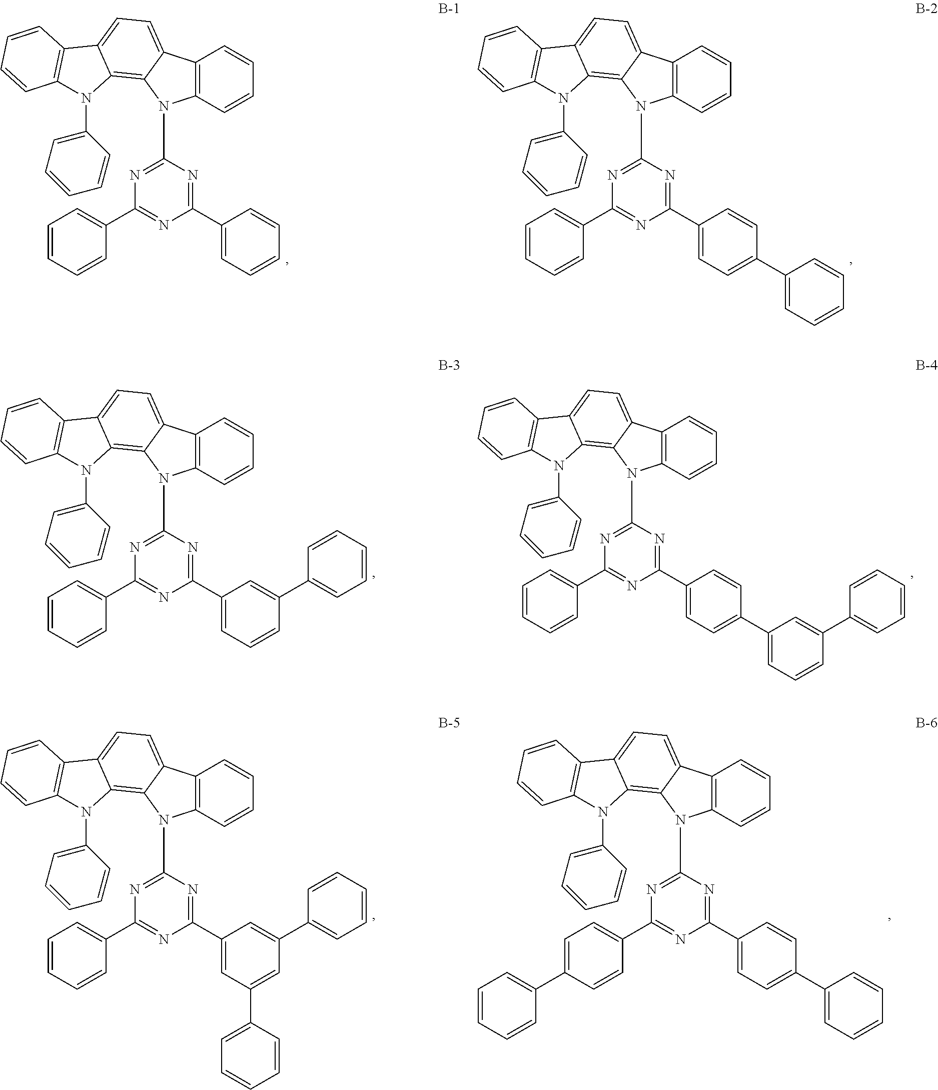

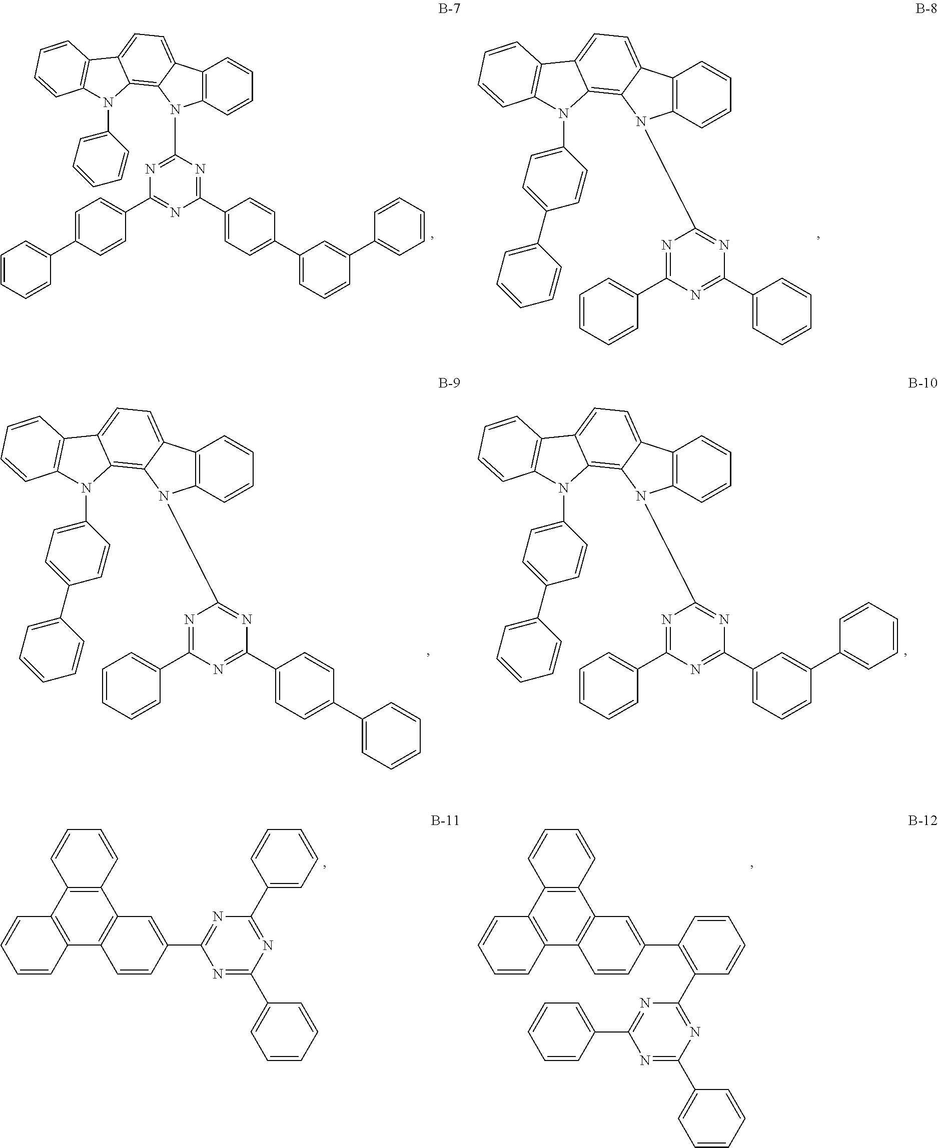

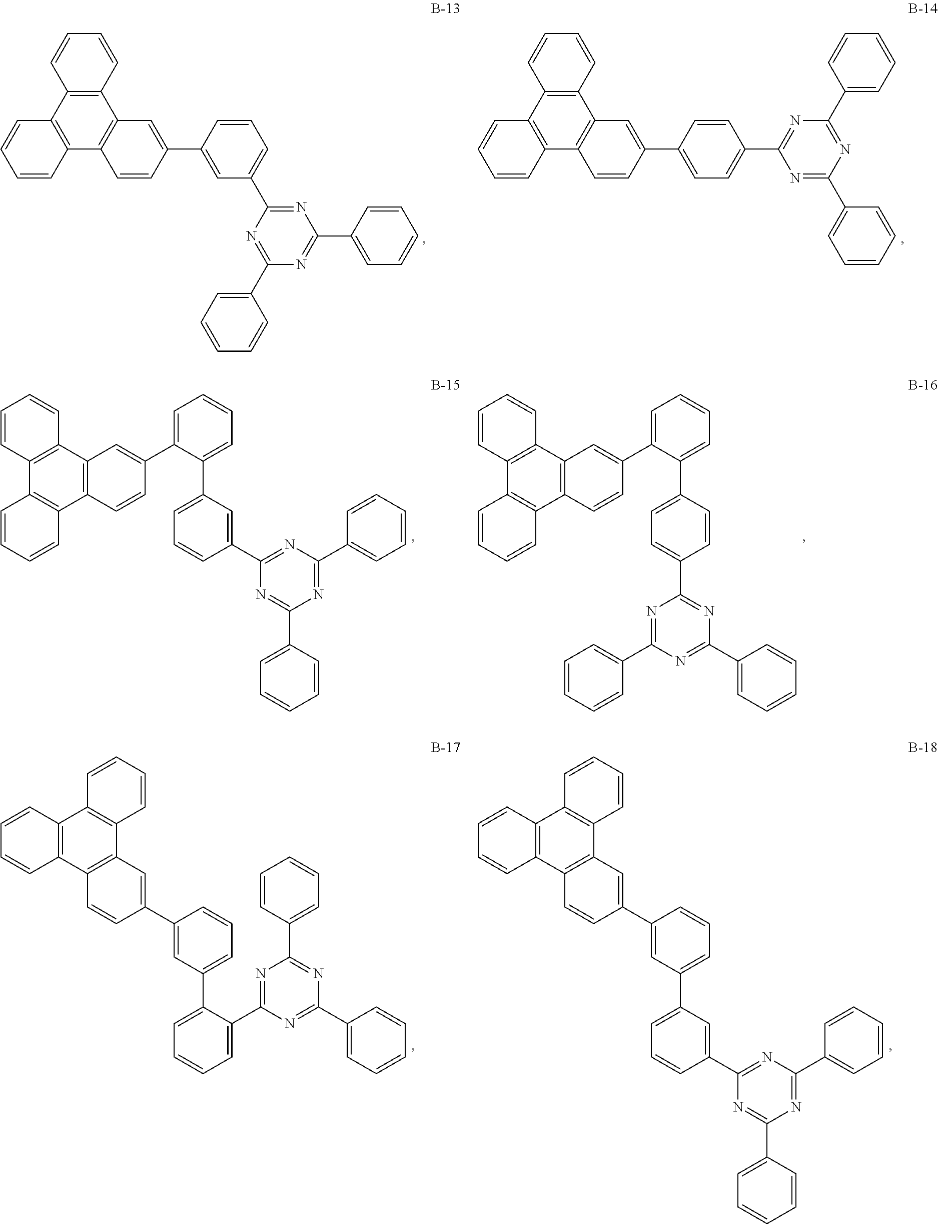

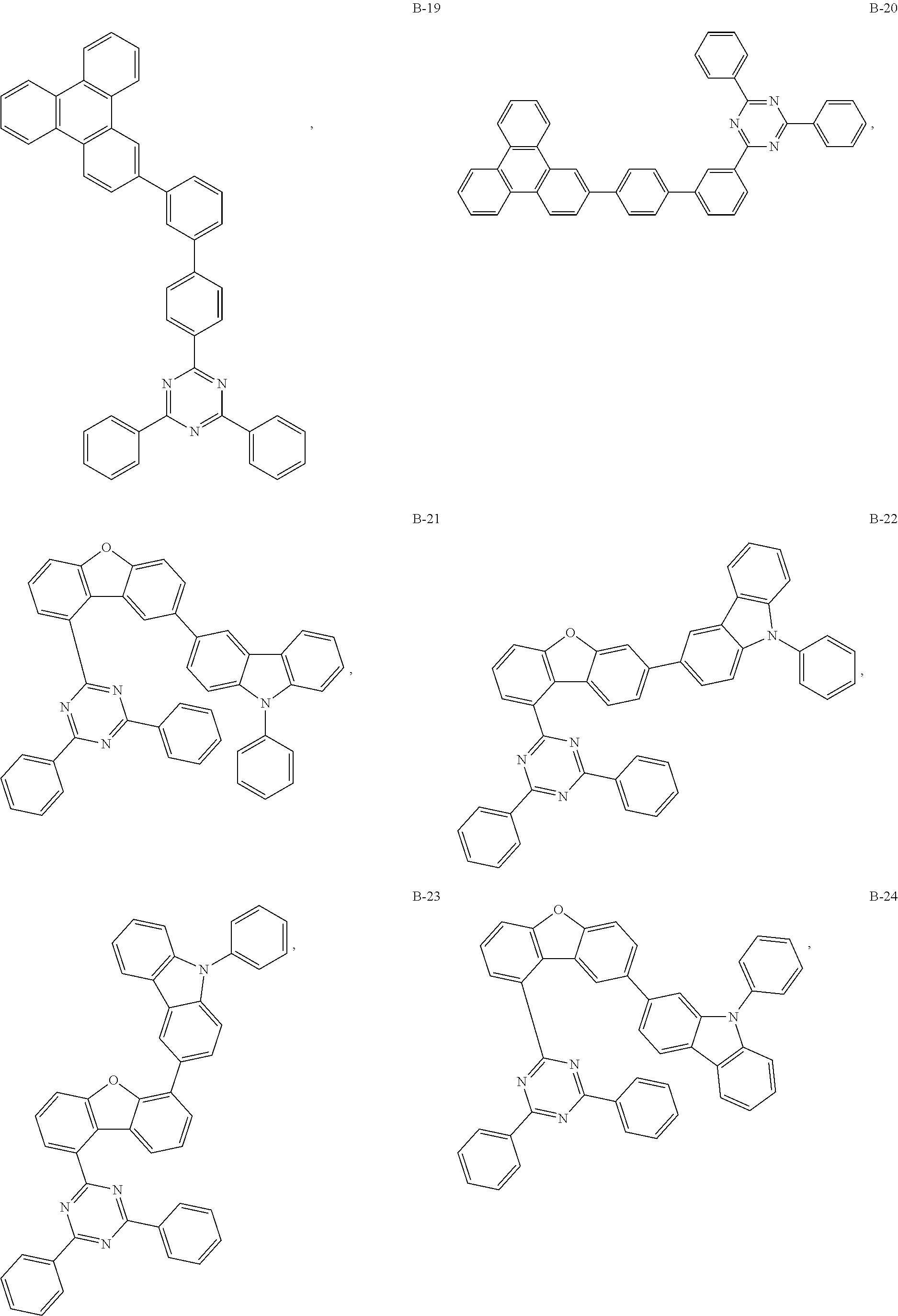

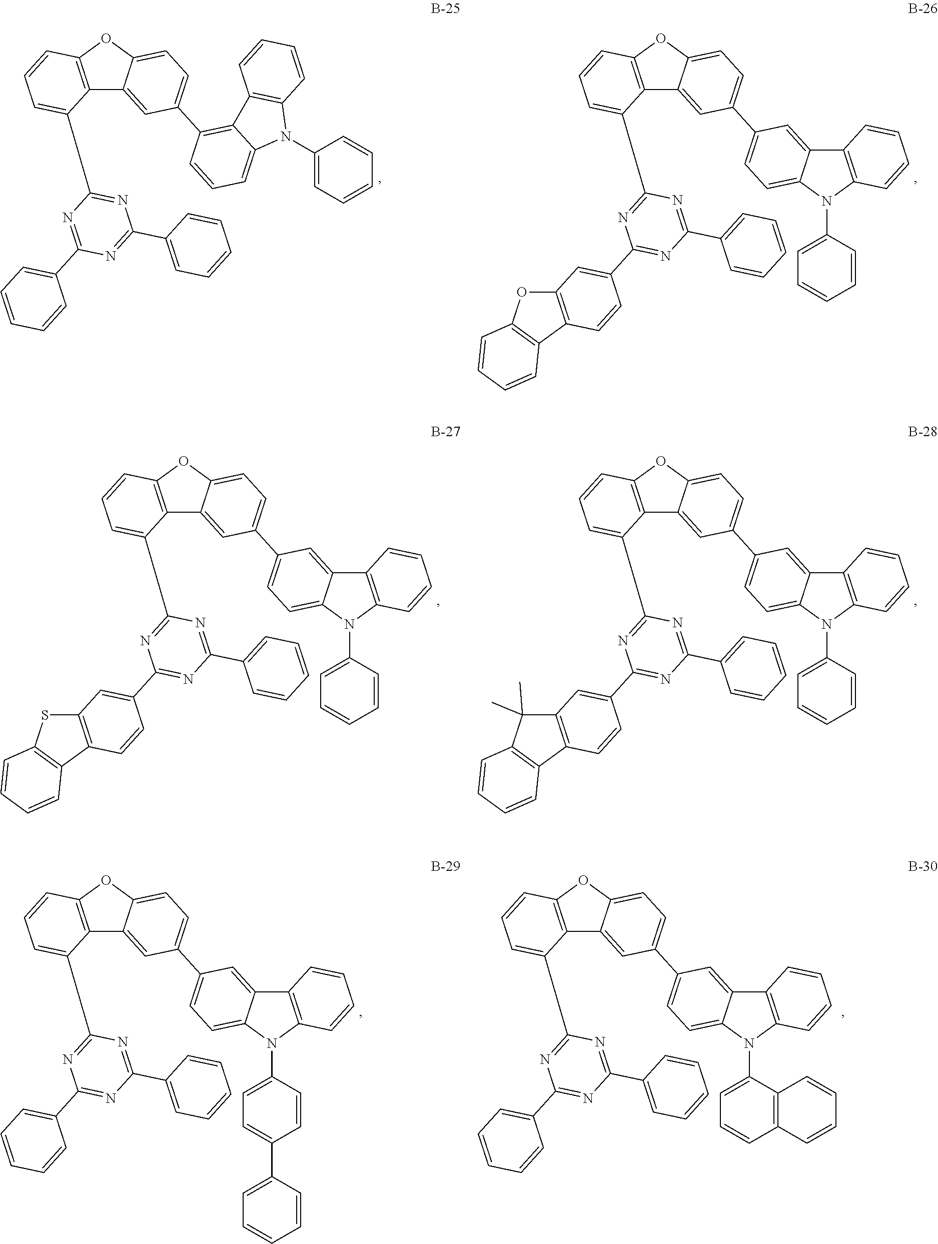

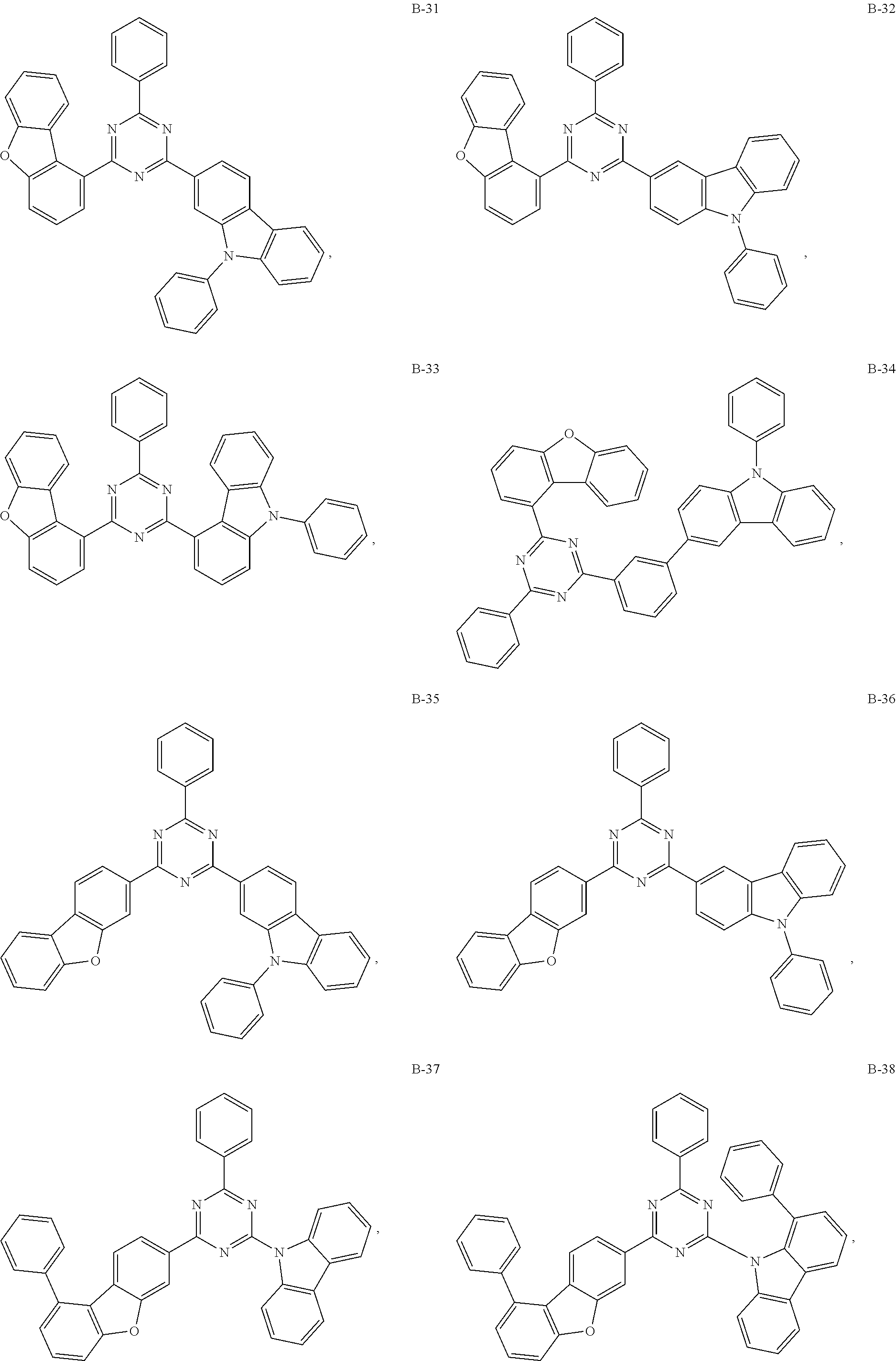

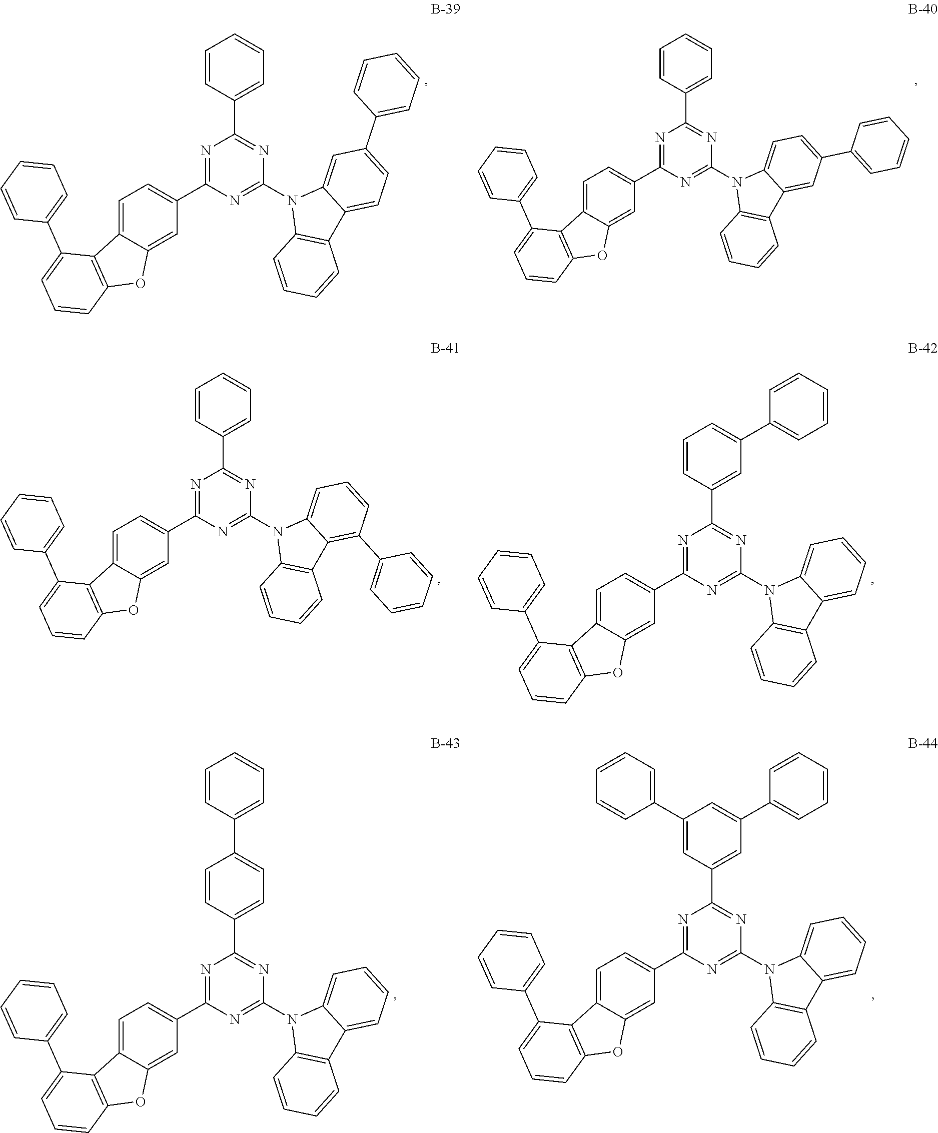

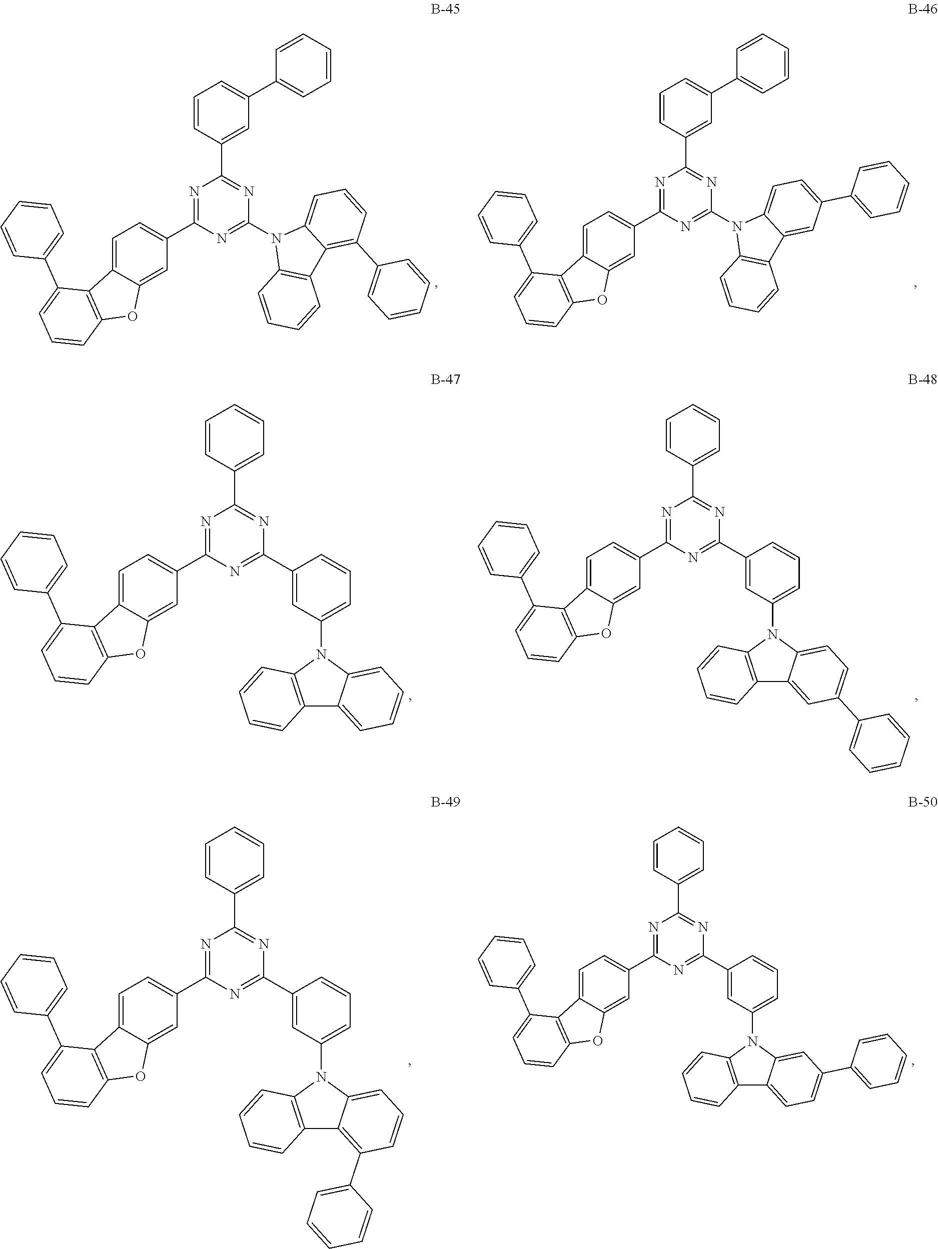

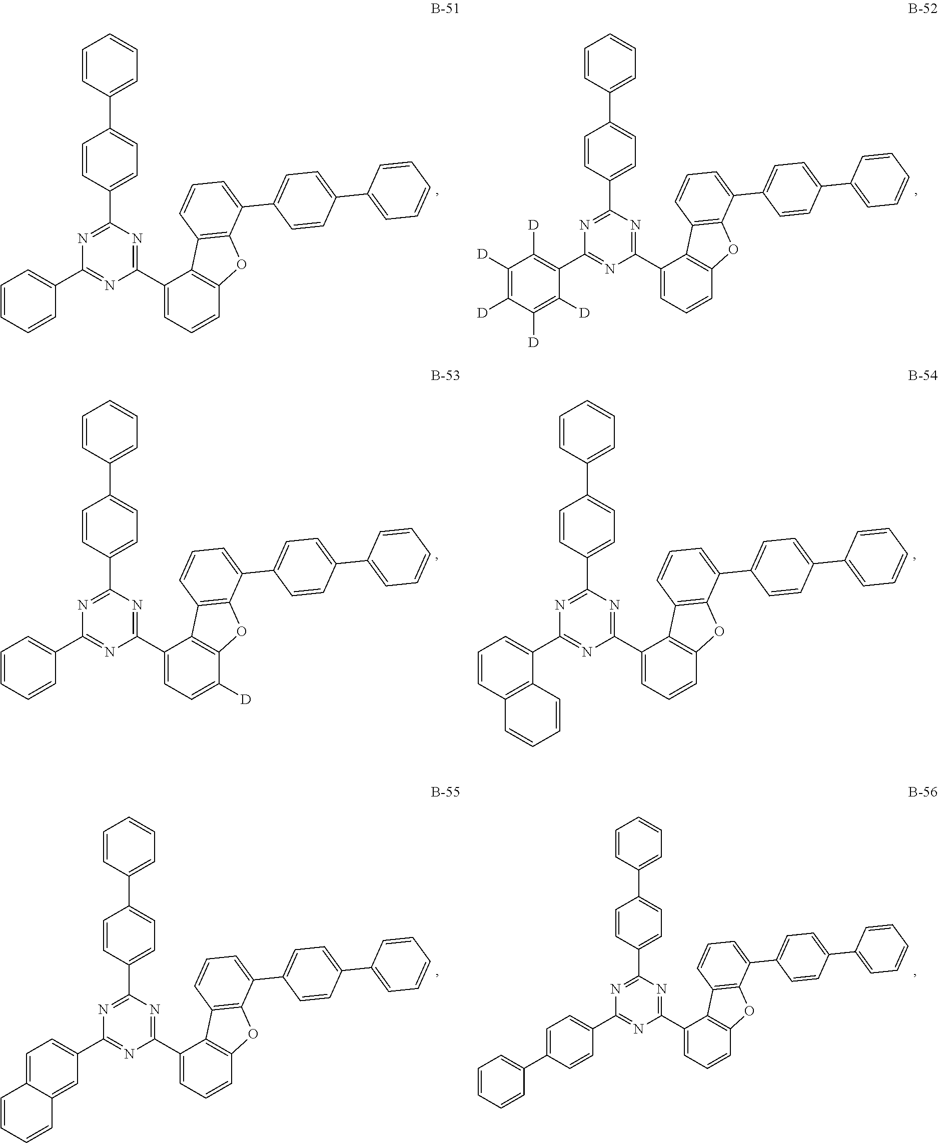

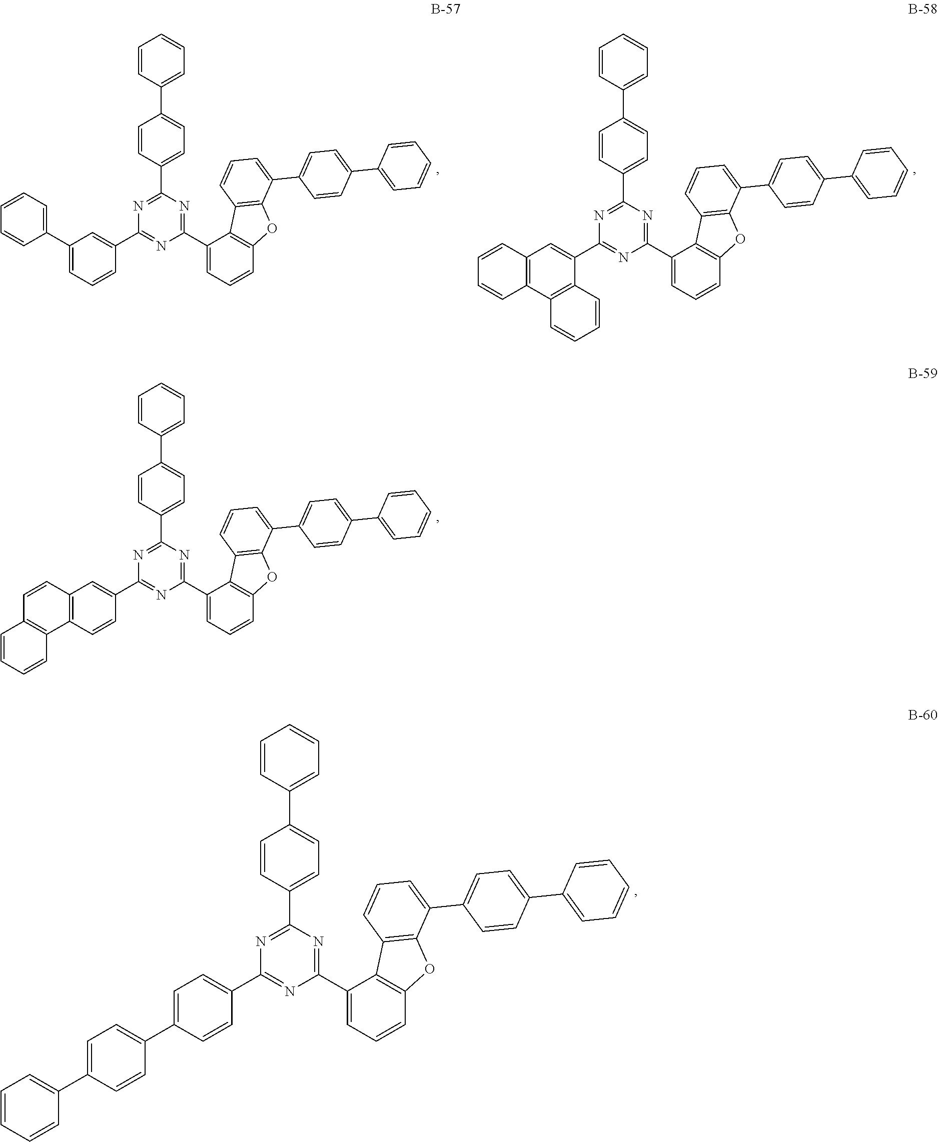 [SMILES: c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4cc5ccccc5c5ccccc45)nc(-c4cccc5oc6c(-c7ccc(-c8ccccc8)cc7)cccc6c45)n3)cc2)cc1 ; c1ccc(-c2ccc(-c3nc(-c4ccc5c(ccc6ccccc65)c4)nc(-c4cccc5oc6c(-c7ccc(-c8ccccc8)cc7)cccc6c45)n3)cc2)cc1 ; c1ccc(-c2ccc(-c3ccc(-c4nc(-c5ccc(-c6ccccc6)cc5)nc(-c5cccc6oc7c(-c8ccc(-c9ccccc9)cc8)cccc7c56)n4)cc3)cc2)cc1]

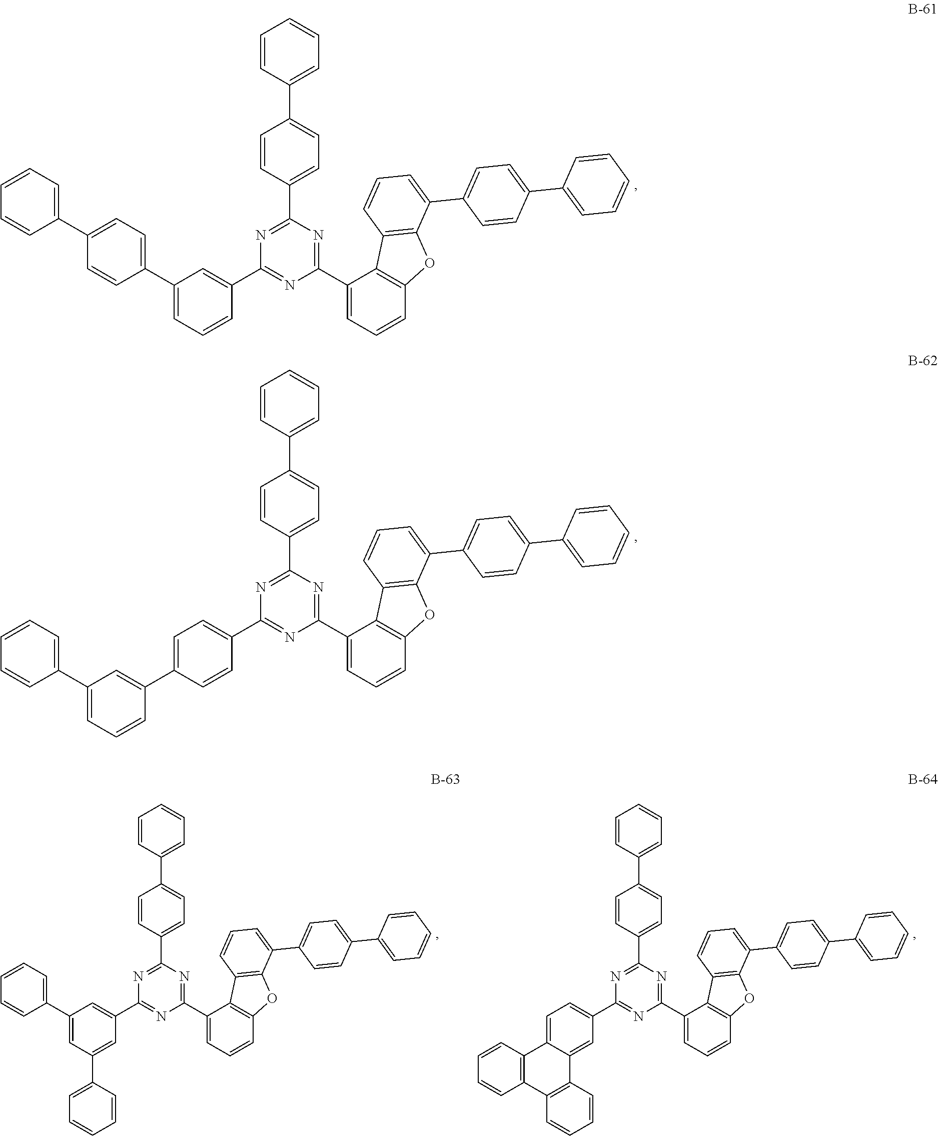 [SMILES: c1ccc(-c2ccc(-c3cccc(-c4nc(-c5ccc(-c6ccccc6)cc5)nc(-c5cccc6oc7c(-c8ccc(-c9ccccc9)cc8)cccc7c56)n4)c3)cc2)cc1 ; c1ccc(-c2ccc(-c3nc(-c4ccc(-c5cccc(-c6ccccc6)c5)cc4)nc(-c4cccc5oc6c(-c7ccc(-c8ccccc8)cc7)cccc6c45)n3)cc2)cc1 ; c1ccc(-c2ccc(-c3nc(-c4cc(-c5ccccc5)cc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccc5c6ccccc6c6ccccc6c5c4)nc(-c4cccc5oc6c(-c7ccc(-c8ccccc8)cc7)cccc6c45)n3)cc2)cc1]

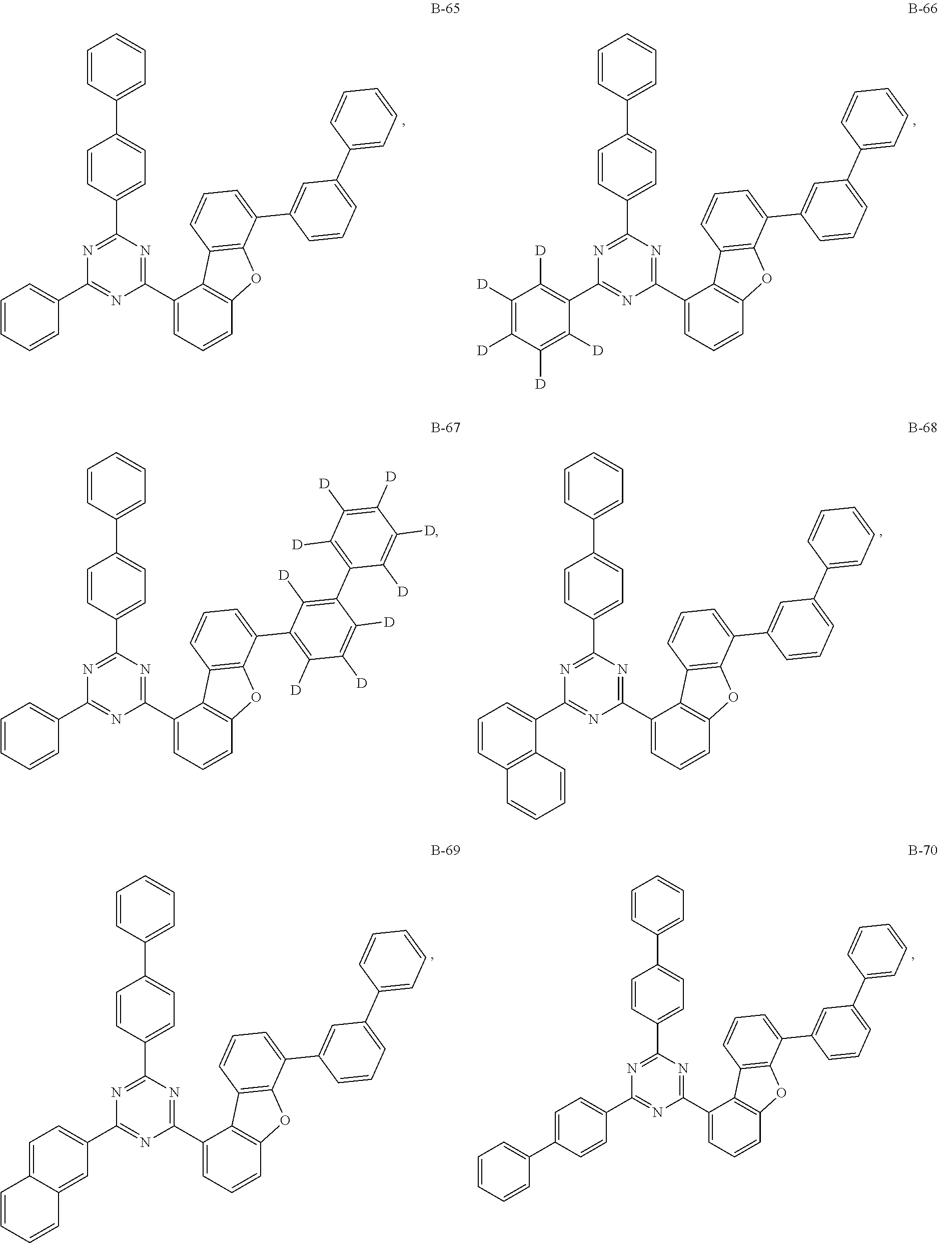

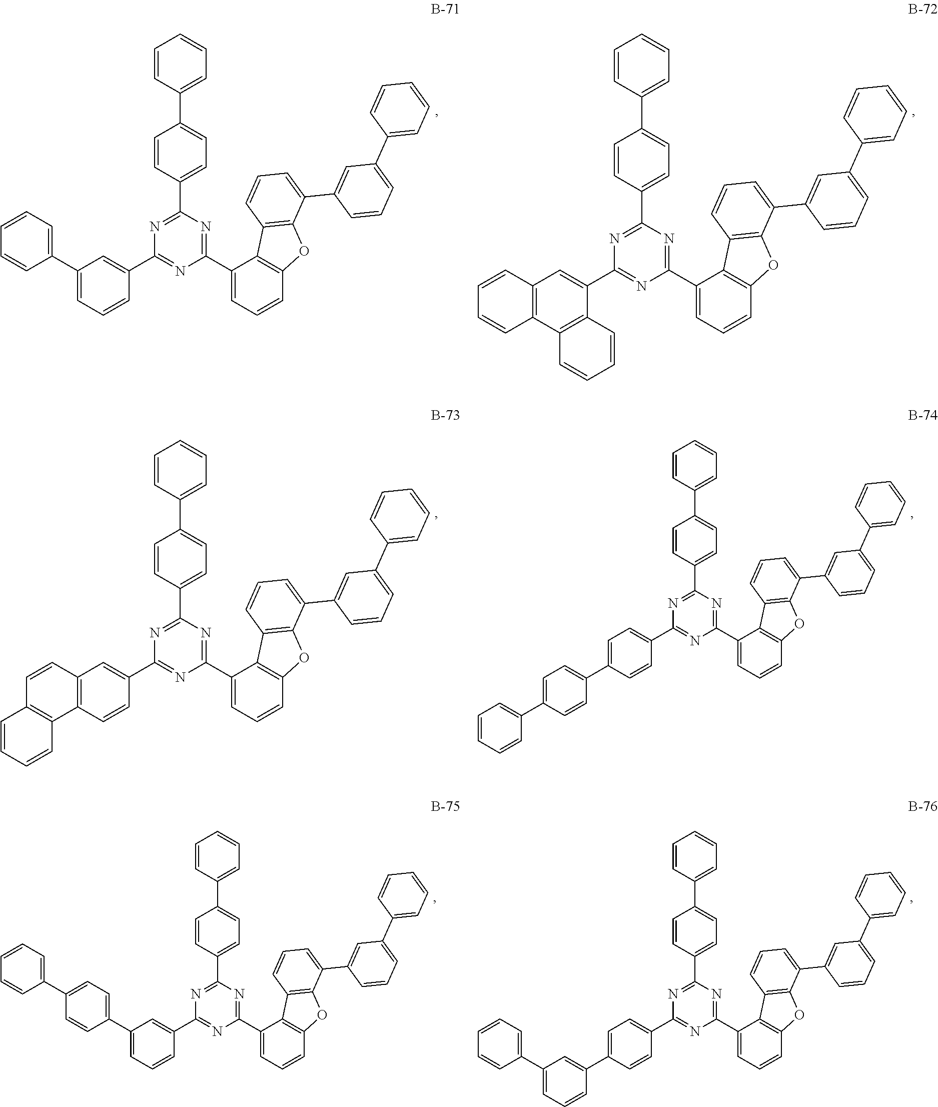

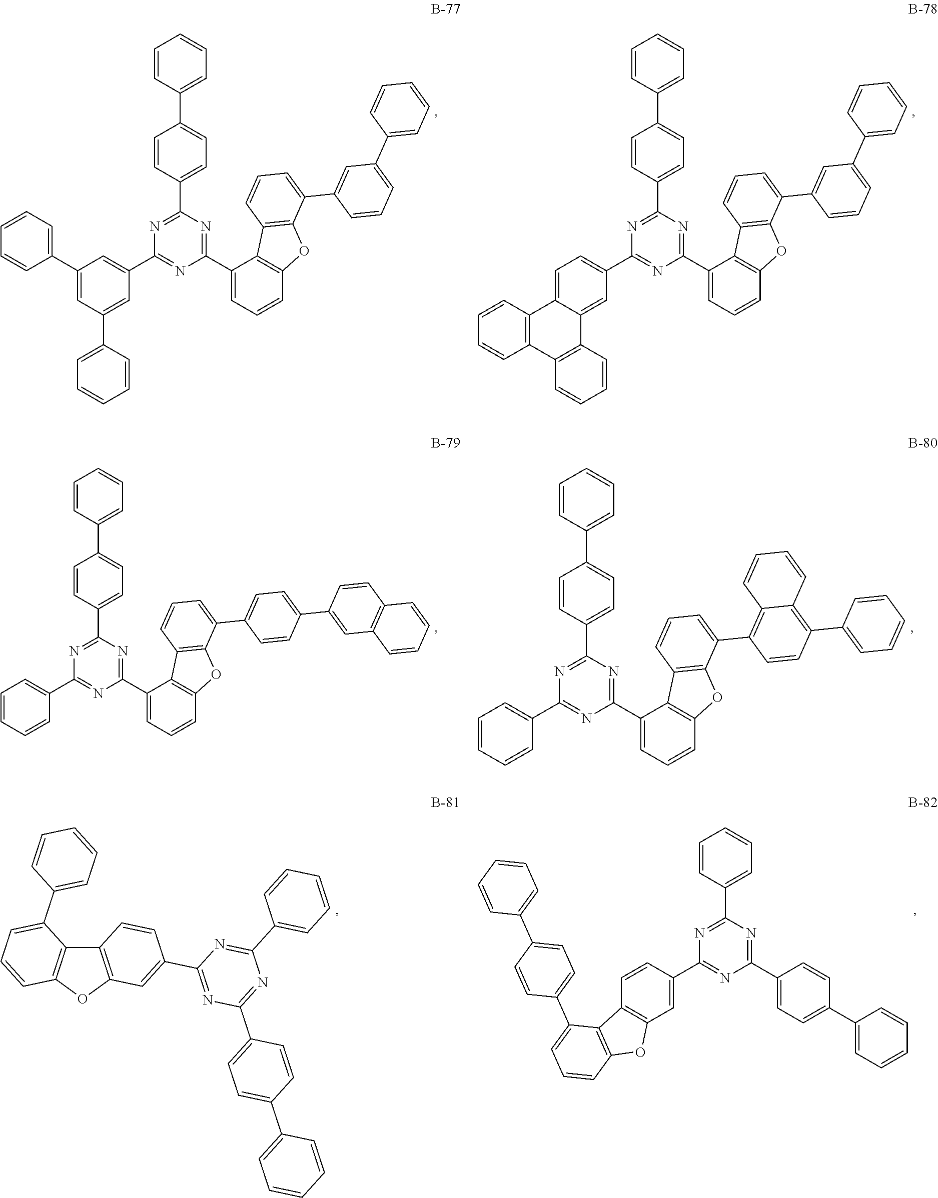

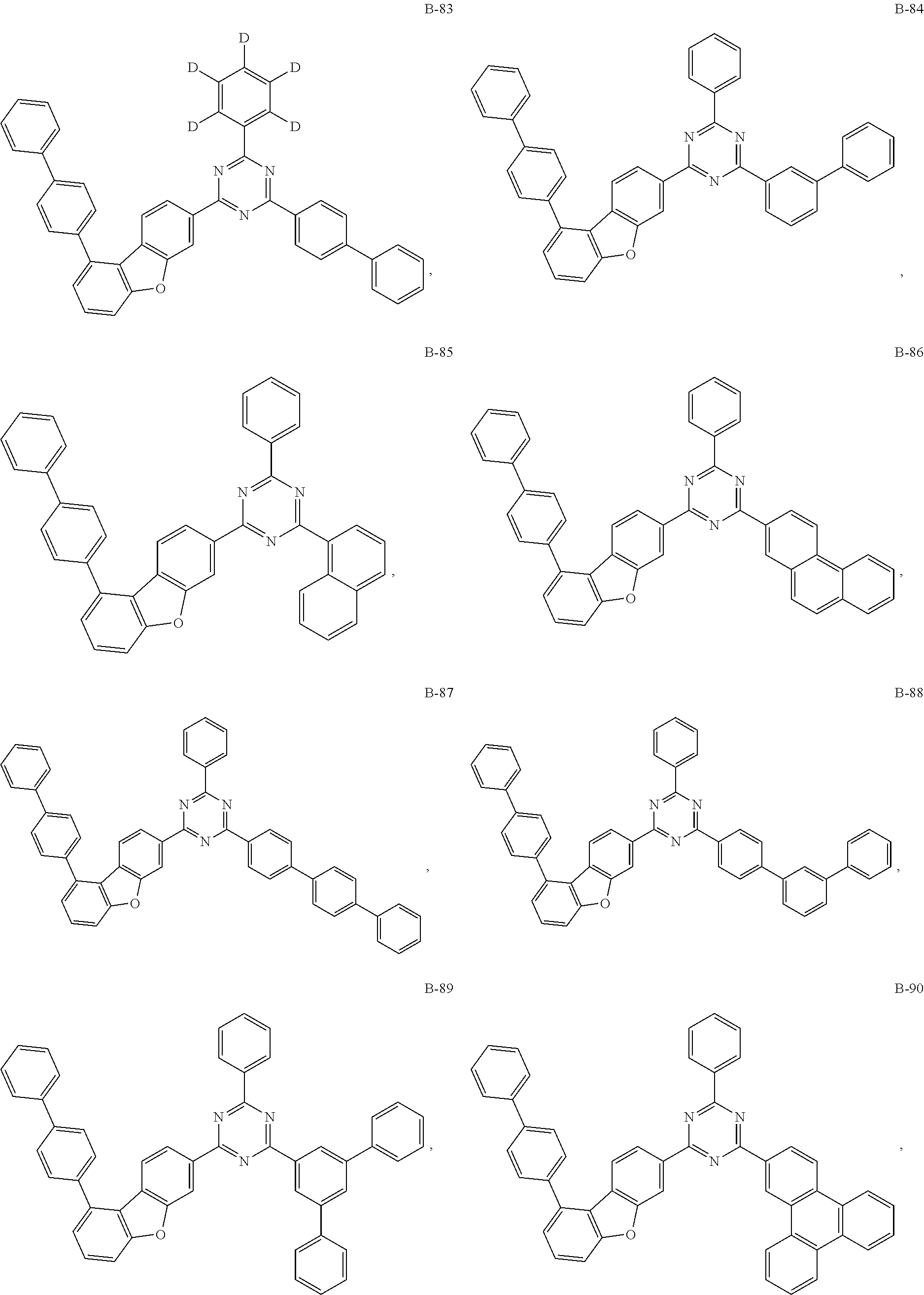

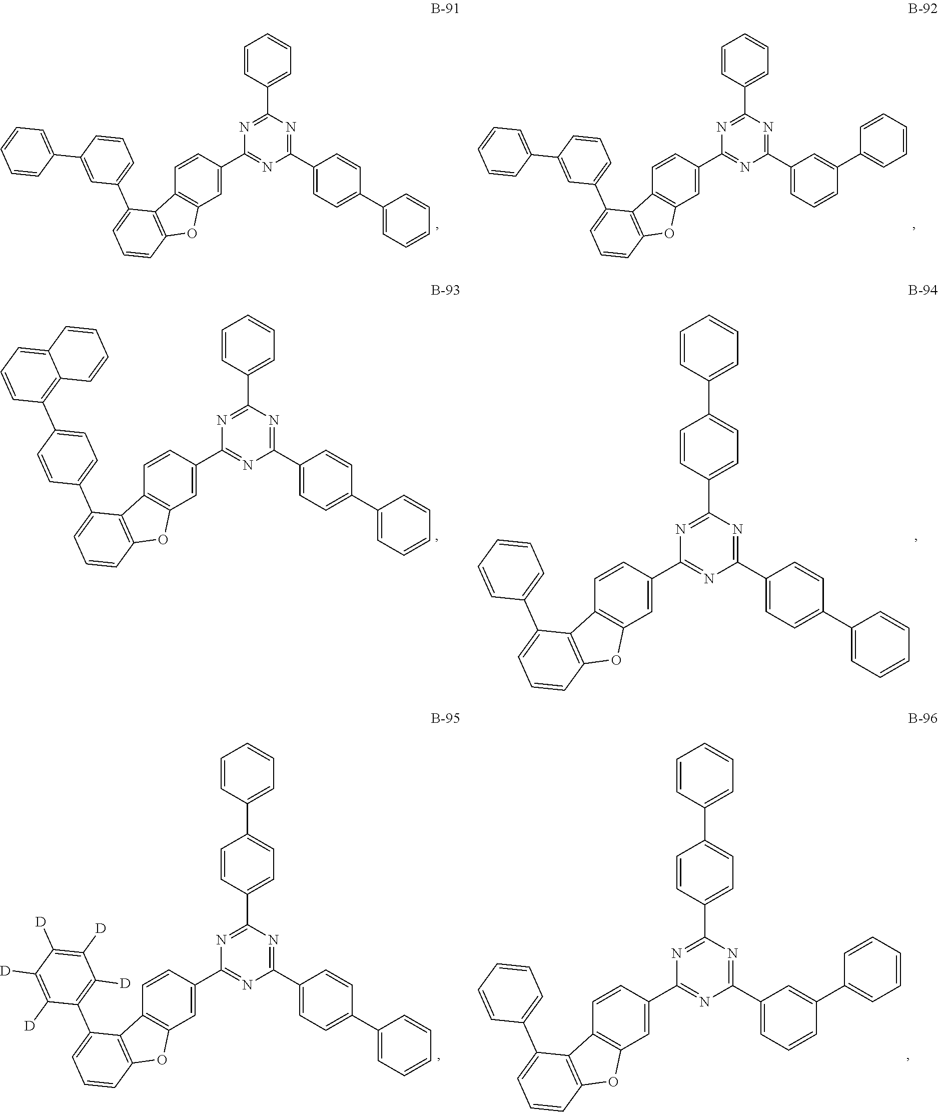

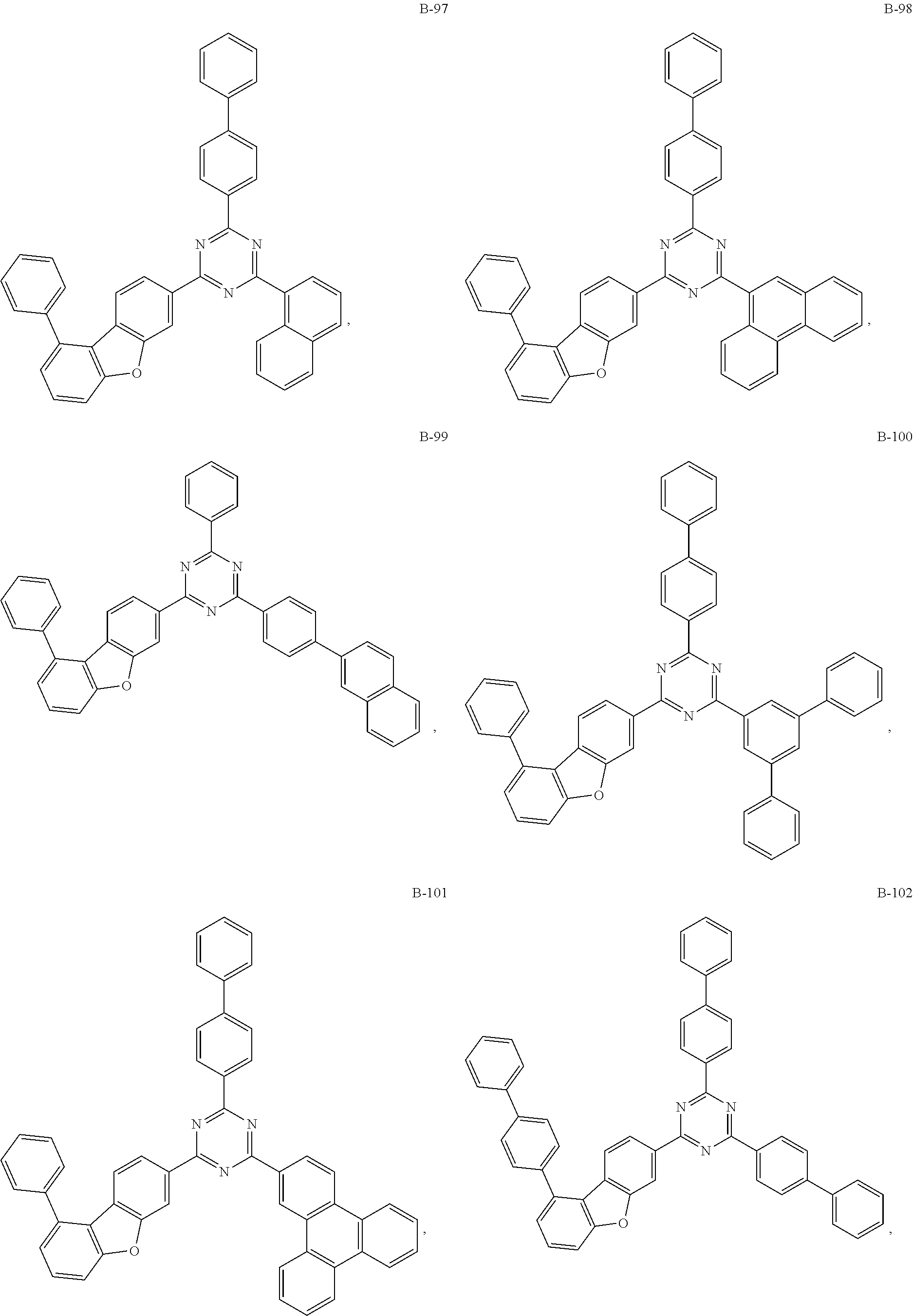

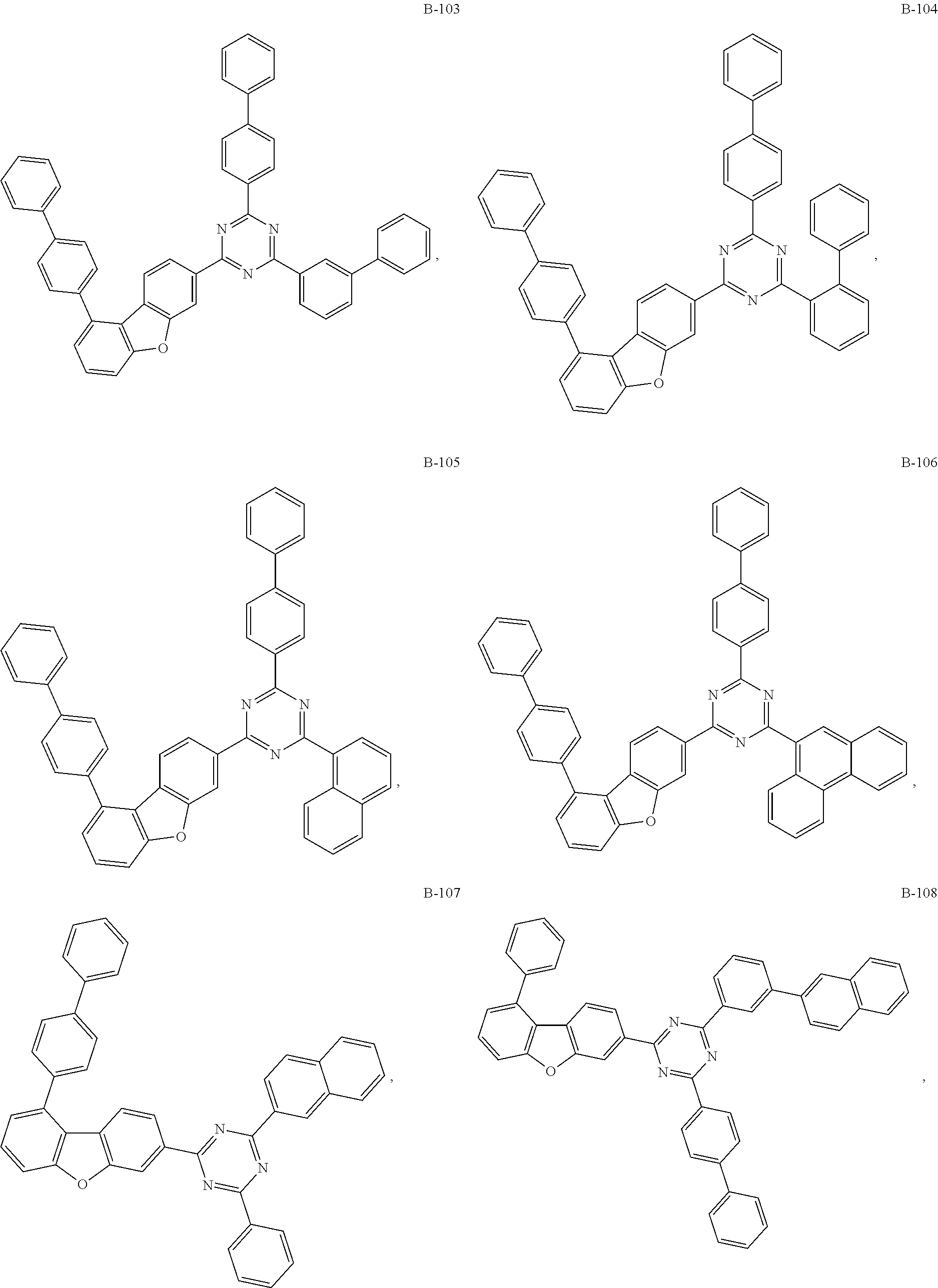

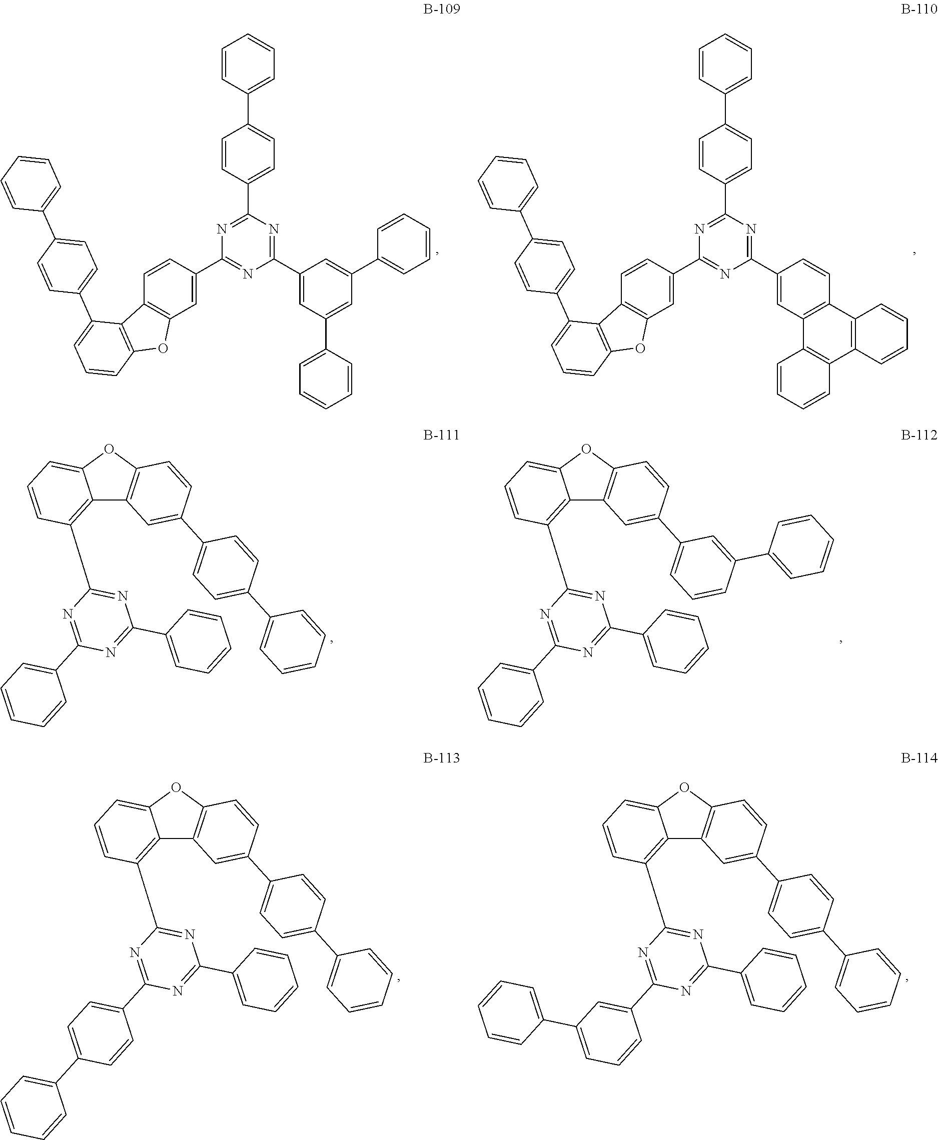

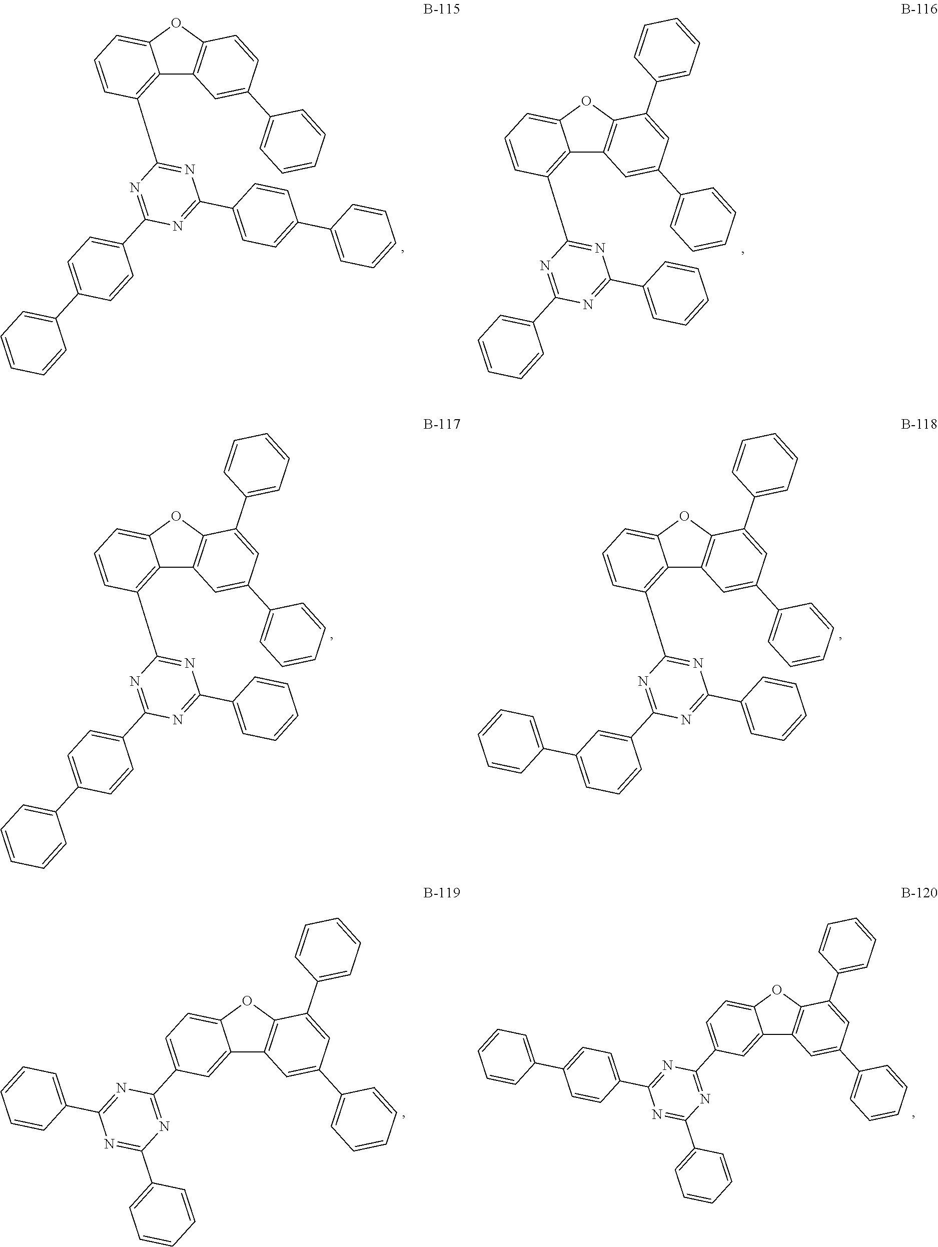

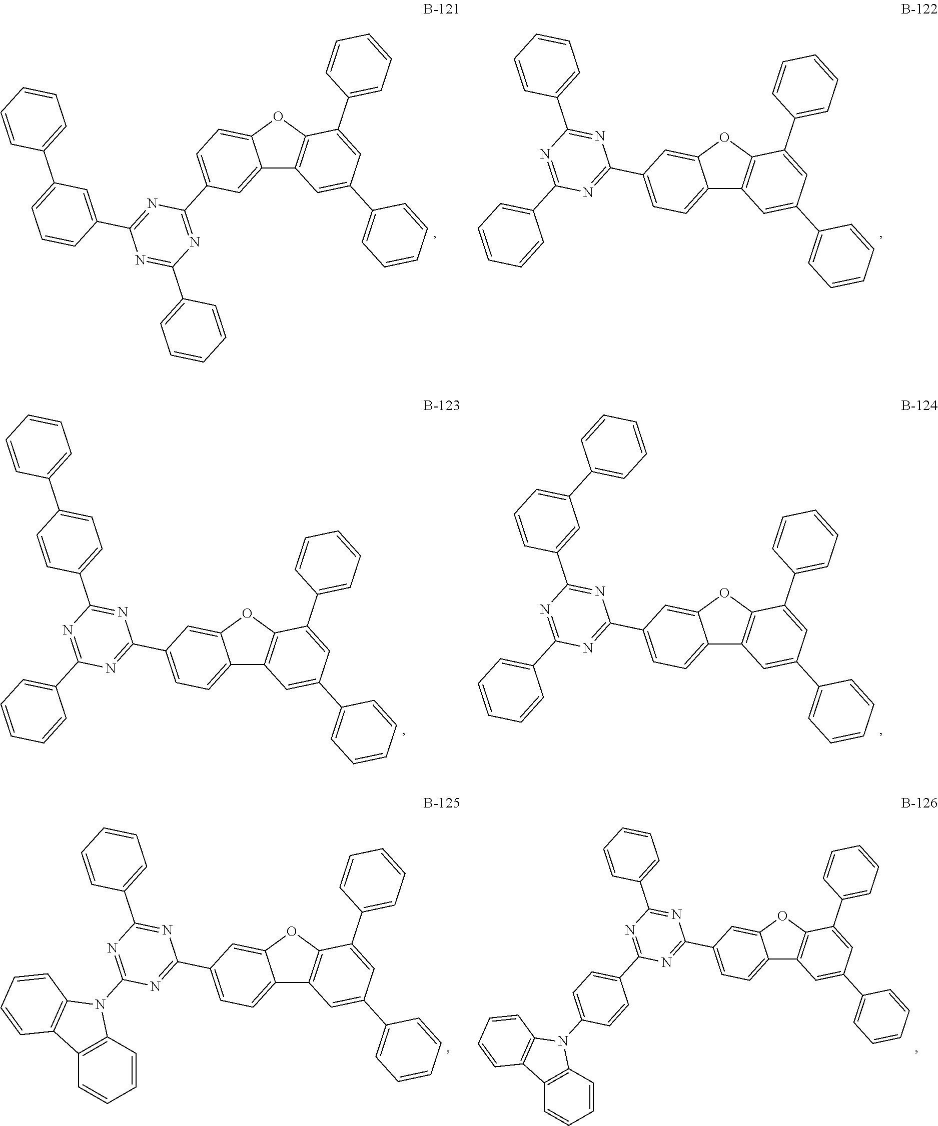

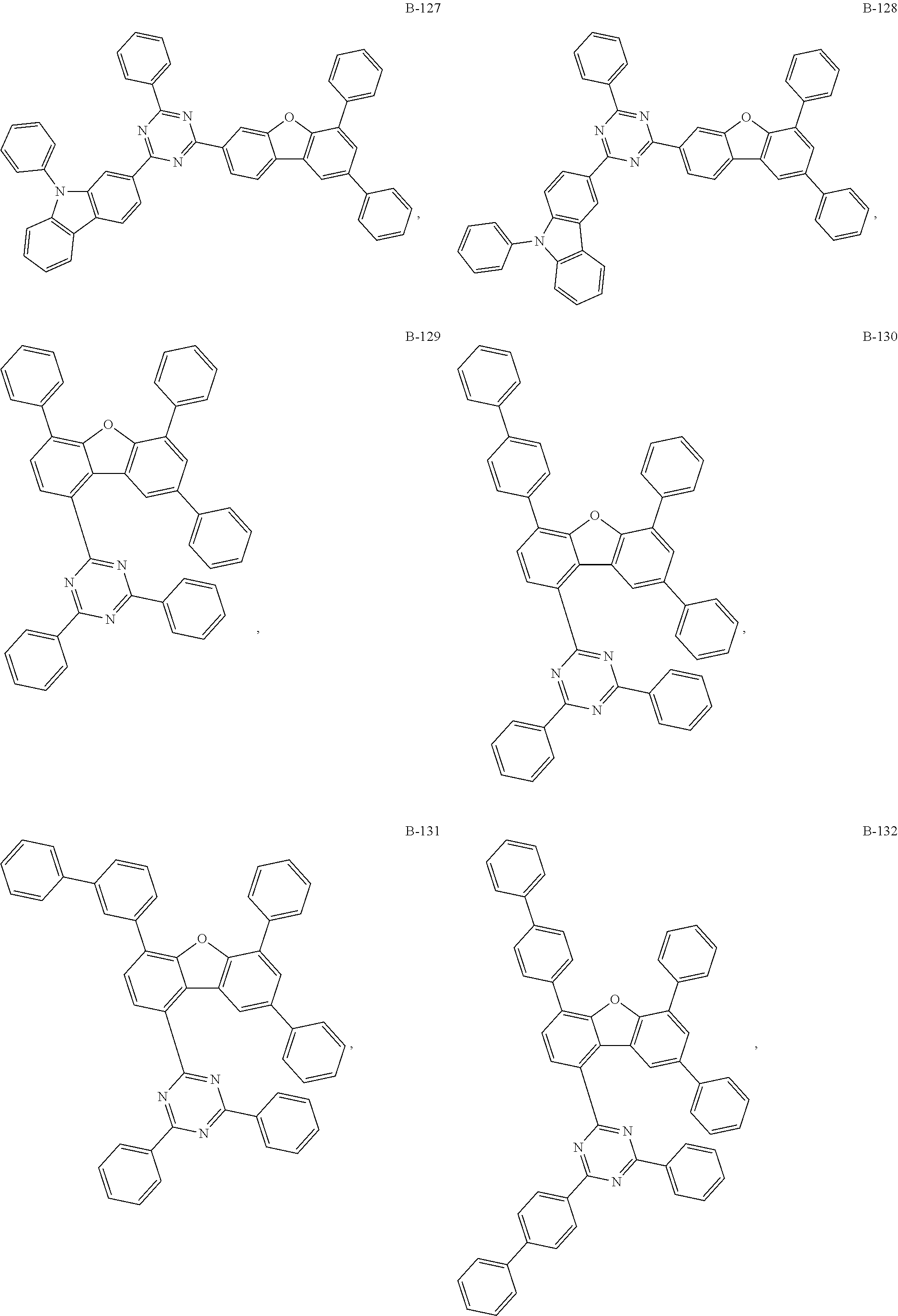

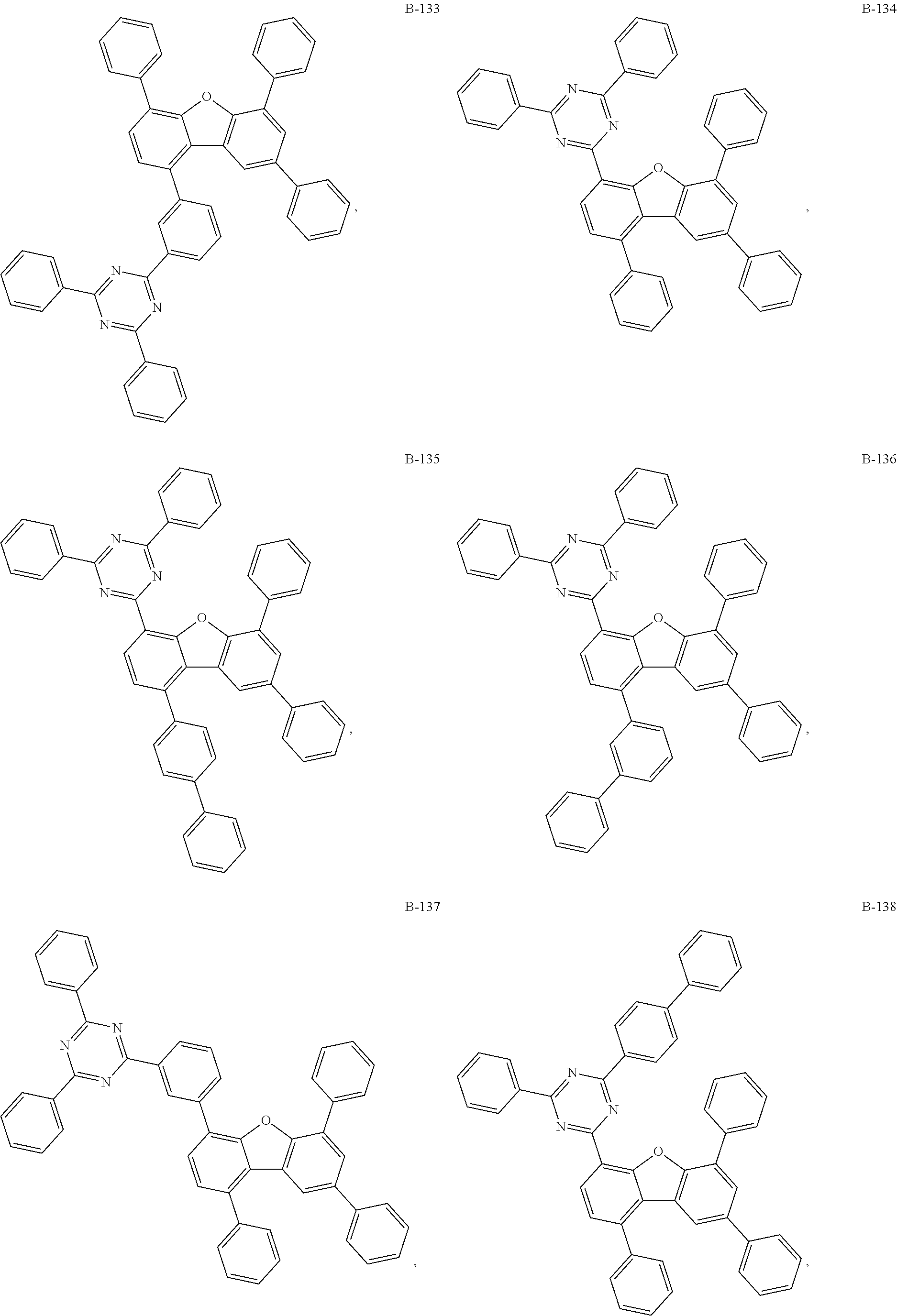

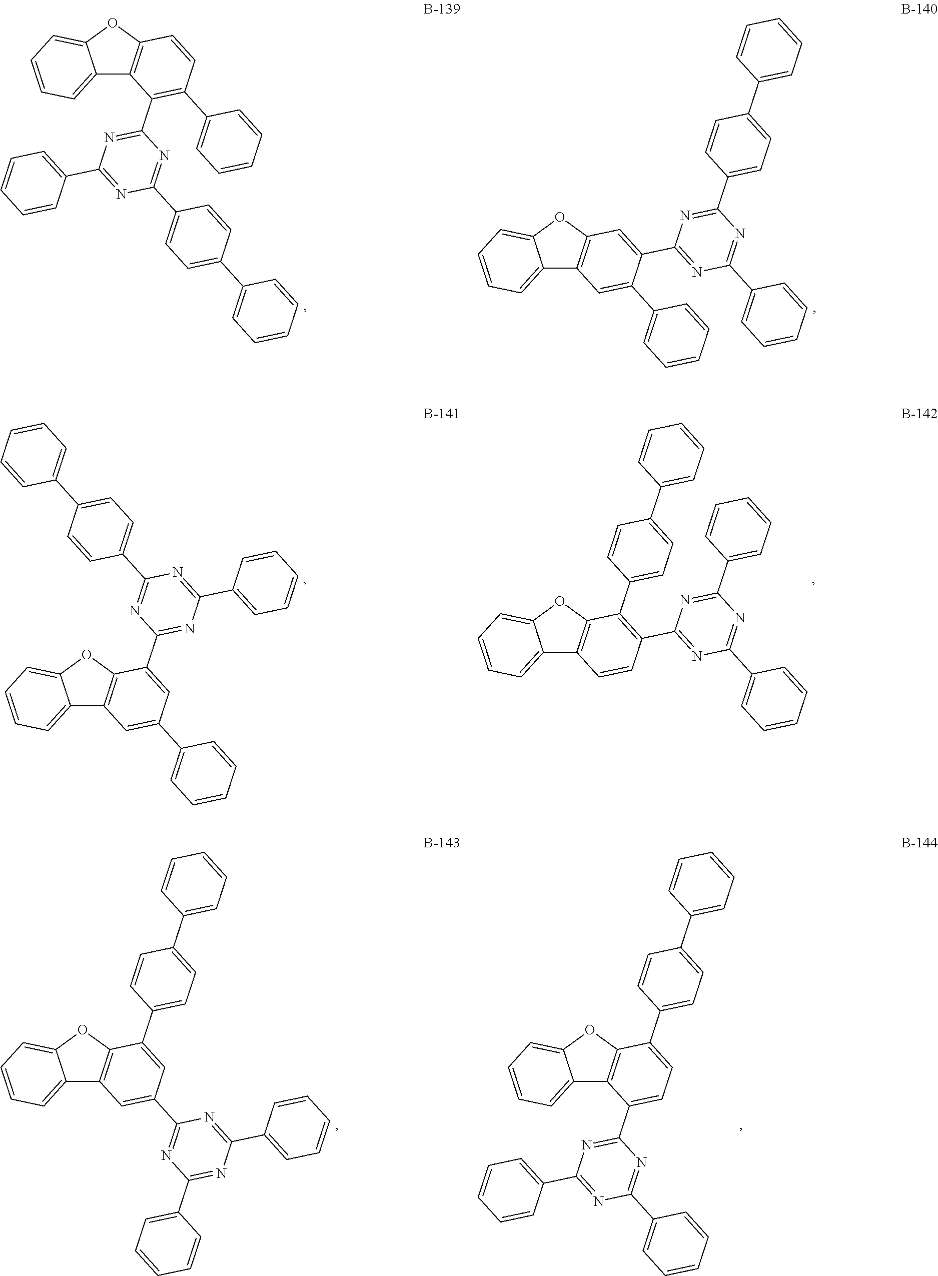 [SMILES: c1ccc(-c2ccc(-c3nc(-c4ccccc4)nc(-c4c(-c5ccccc5)ccc5oc6ccccc6c45)n3)cc2)cc1 ; c1ccc(-c2ccc(-c3nc(-c4ccccc4)nc(-c4cc5oc6ccccc6c5cc4-c4ccccc4)n3)cc2)cc1 ; c1ccc(-c2ccc(-c3nc(-c4ccccc4)nc(-c4cc(-c5ccccc5)cc5c4oc4ccccc45)n3)cc2)cc1 ; c1ccc(-c2ccc(-c3c(-c4nc(-c5ccccc5)nc(-c5ccccc5)n4)ccc4c3oc3ccccc34)cc2)cc1 ; c1ccc(-c2ccc(-c3cc(-c4nc(-c5ccccc5)nc(-c5ccccc5)n4)cc4c3oc3ccccc34)cc2)cc1 ; c1ccc(-c2ccc(-c3ccc(-c4nc(-c5ccccc5)nc(-c5ccccc5)n4)c4c3oc3ccccc34)cc2)cc1]

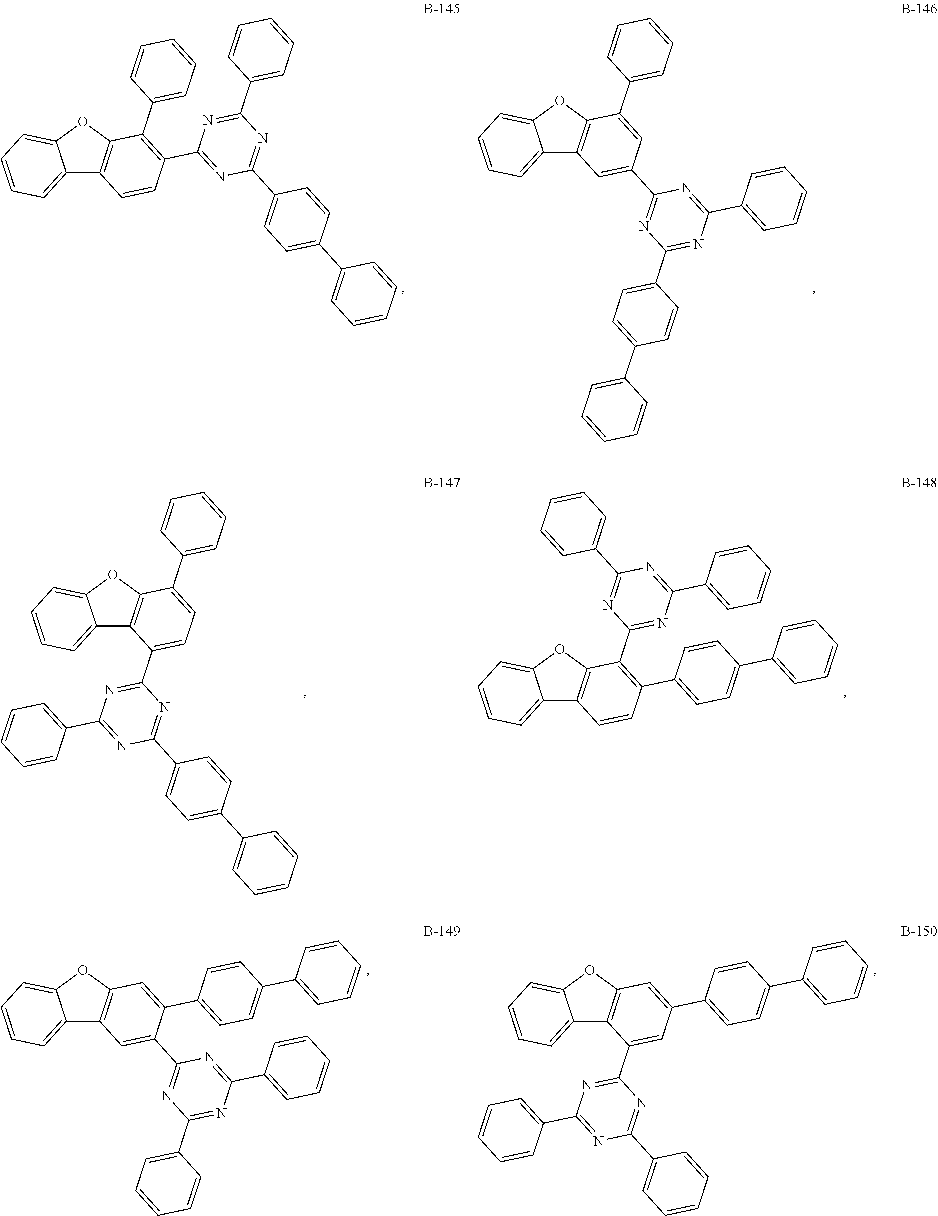 [SMILES: c1ccc(-c2ccc(-c3nc(-c4ccccc4)nc(-c4ccc5c(oc6ccccc65)c4-c4ccccc4)n3)cc2)cc1 ; c1ccc(-c2ccc(-c3nc(-c4ccccc4)nc(-c4cc(-c5ccccc5)c5oc6ccccc6c5c4)n3)cc2)cc1 ; c1ccc(-c2ccc(-c3nc(-c4ccccc4)nc(-c4ccc(-c5ccccc5)c5oc6ccccc6c45)n3)cc2)cc1 ; c1ccc(-c2ccc(-c3ccc4c(oc5ccccc54)c3-c3nc(-c4ccccc4)nc(-c4ccccc4)n3)cc2)cc1 ; c1ccc(-c2ccc(-c3cc4oc5ccccc5c4cc3-c3nc(-c4ccccc4)nc(-c4ccccc4)n3)cc2)cc1 ; c1ccc(-c2ccc(-c3cc(-c4nc(-c5ccccc5)nc(-c5ccccc5)n4)c4c(c3)oc3ccccc34)cc2)cc1]

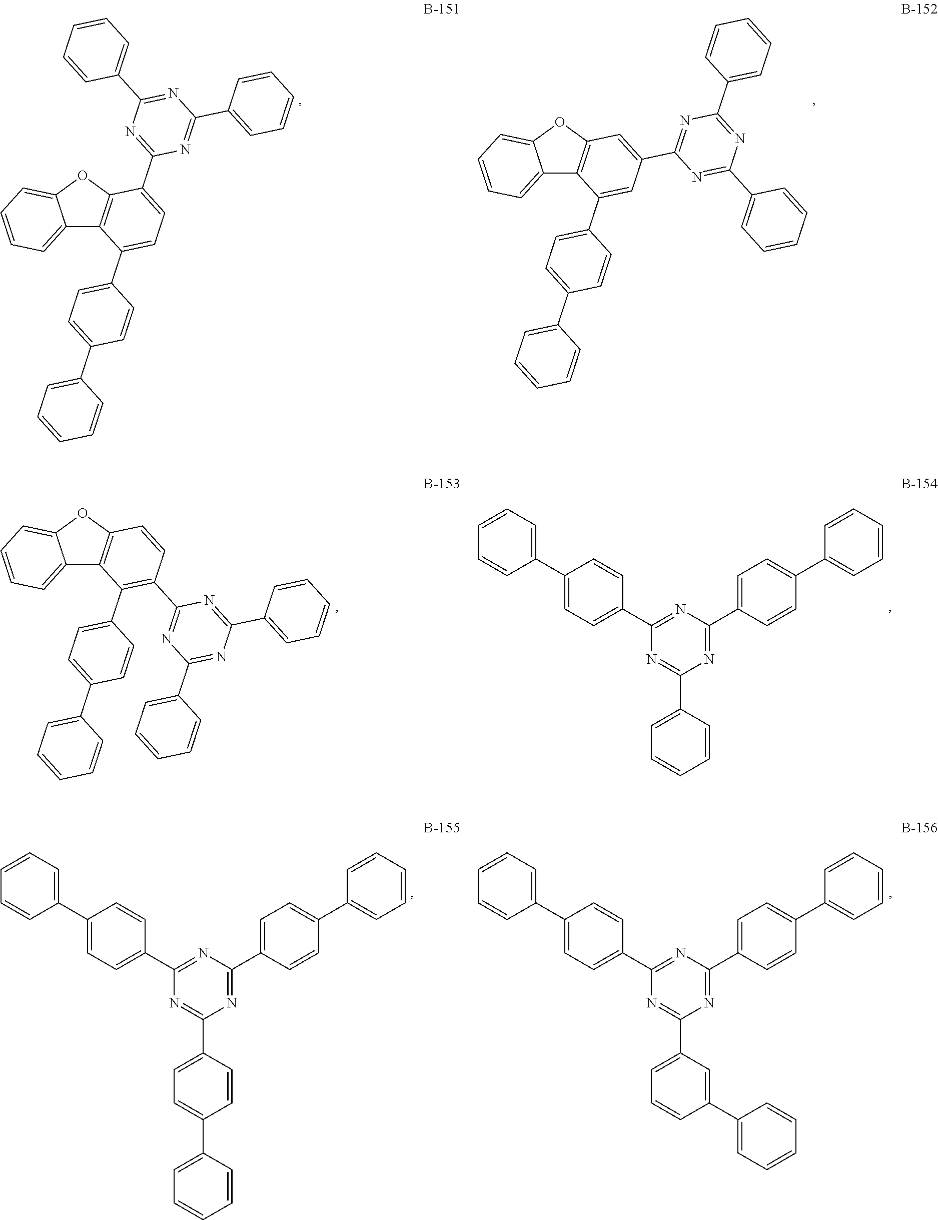 [SMILES: c1ccc(-c2ccc(-c3ccc(-c4nc(-c5ccccc5)nc(-c5ccccc5)n4)c4oc5ccccc5c34)cc2)cc1 ; c1ccc(-c2ccc(-c3cc(-c4nc(-c5ccccc5)nc(-c5ccccc5)n4)cc4oc5ccccc5c34)cc2)cc1 ; c1ccc(-c2ccc(-c3c(-c4nc(-c5ccccc5)nc(-c5ccccc5)n4)ccc4oc5ccccc5c34)cc2)cc1 ; c1ccc(-c2ccc(-c3nc(-c4ccccc4)nc(-c4ccc(-c5ccccc5)cc4)n3)cc2)cc1 ; c1ccc(-c2ccc(-c3nc(-c4ccc(-c5ccccc5)cc4)nc(-c4ccc(-c5ccccc5)cc4)n3)cc2)cc1 ; c1ccc(-c2ccc(-c3nc(-c4ccc(-c5ccccc5)cc4)nc(-c4cccc(-c5ccccc5)c4)n3)cc2)cc1]

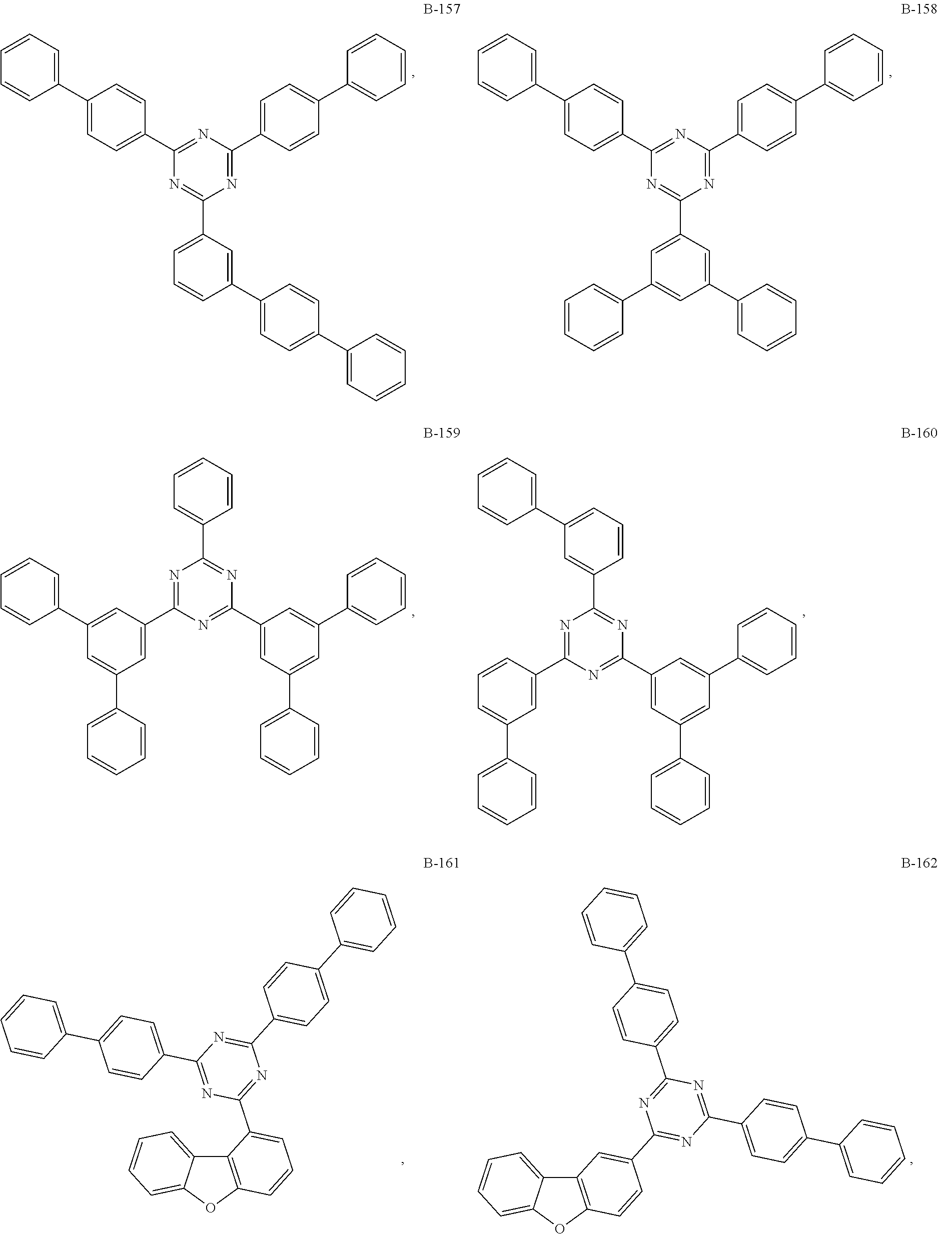

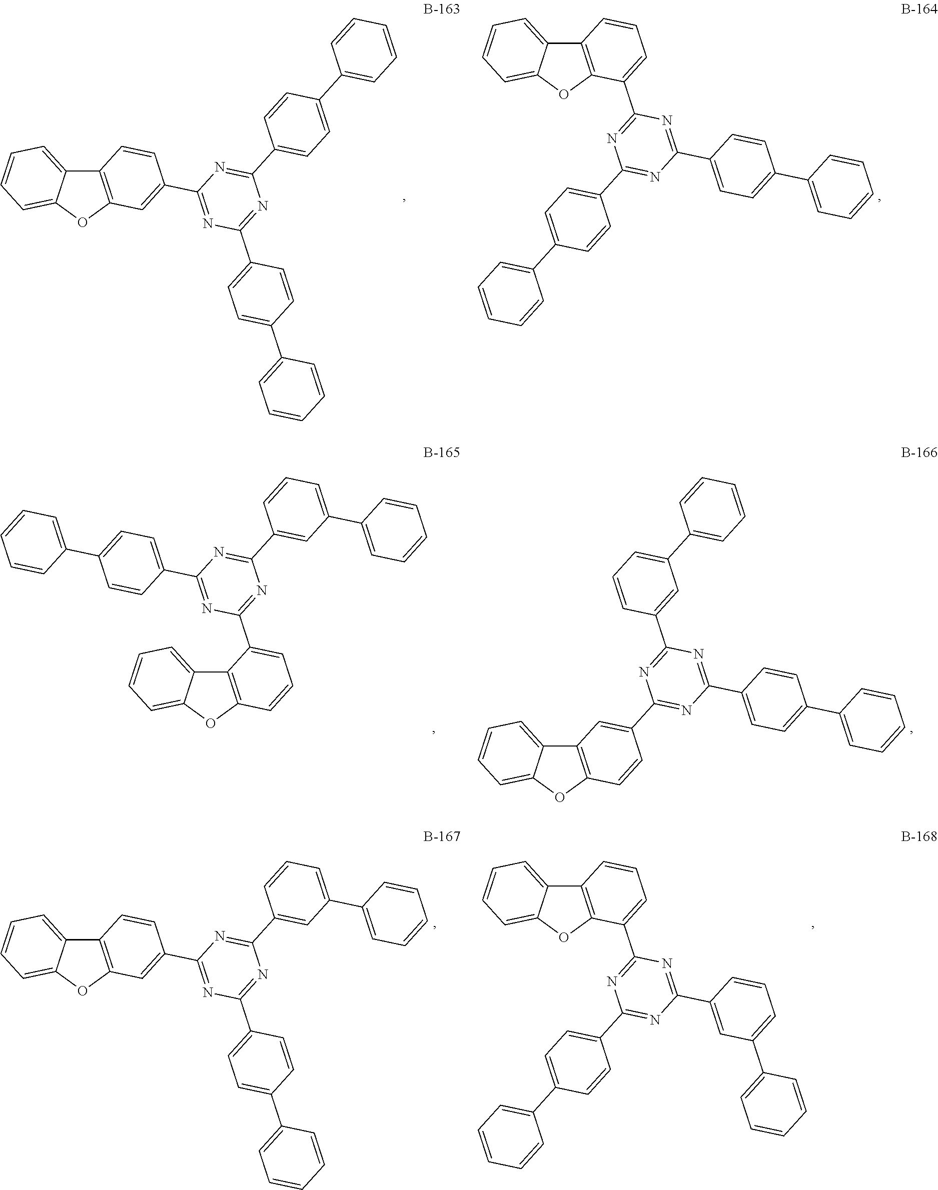 [SMILES: c1ccc(-c2ccc(-c3nc(-c4ccc(-c5ccccc5)cc4)nc(-c4ccc5c(c4)oc4ccccc45)n3)cc2)cc1 ; c1ccc(-c2ccc(-c3nc(-c4ccc(-c5ccccc5)cc4)nc(-c4cccc5c4oc4ccccc45)n3)cc2)cc1 ; c1ccc(-c2ccc(-c3nc(-c4cccc(-c5ccccc5)c4)nc(-c4cccc5oc6ccccc6c45)n3)cc2)cc1 ; c1ccc(-c2ccc(-c3nc(-c4cccc(-c5ccccc5)c4)nc(-c4ccc5oc6ccccc6c5c4)n3)cc2)cc1 ; c1ccc(-c2ccc(-c3nc(-c4cccc(-c5ccccc5)c4)nc(-c4ccc5c(c4)oc4ccccc45)n3)cc2)cc1 ; c1ccc(-c2ccc(-c3nc(-c4cccc(-c5ccccc5)c4)nc(-c4cccc5c4oc4ccccc45)n3)cc2)cc1]

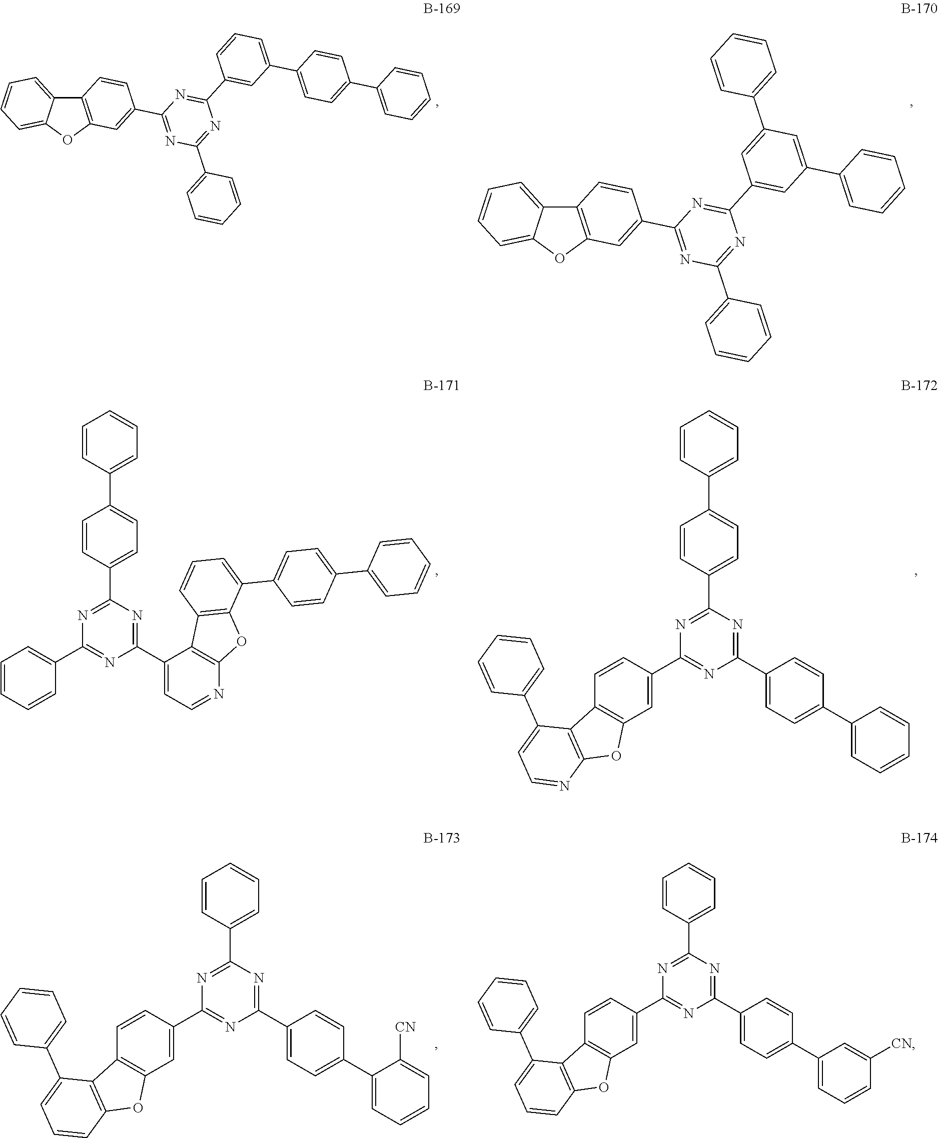 [SMILES: c1ccc(-c2ccc(-c3cccc(-c4nc(-c5ccccc5)nc(-c5ccc6c(c5)oc5ccccc56)n4)c3)cc2)cc1 ; c1ccc(-c2cc(-c3ccccc3)cc(-c3nc(-c4ccccc4)nc(-c4ccc5c(c4)oc4ccccc45)n3)c2)cc1 ; c1ccc(-c2ccc(-c3nc(-c4ccccc4)nc(-c4ccnc5oc6c(-c7ccc(-c8ccccc8)cc7)cccc6c45)n3)cc2)cc1 ; c1ccc(-c2ccc(-c3nc(-c4ccc(-c5ccccc5)cc4)nc(-c4ccc5c(c4)oc4nccc(-c6ccccc6)c45)n3)cc2)cc1 ; N#Cc1ccccc1-c1ccc(-c2nc(-c3ccccc3)nc(-c3ccc4c(c3)oc3cccc(-c5ccccc5)c34)n2)cc1 ; N#Cc1cccc(-c2ccc(-c3nc(-c4ccccc4)nc(-c4ccc5c(c4)oc4cccc(-c6ccccc6)c45)n3)cc2)c1]

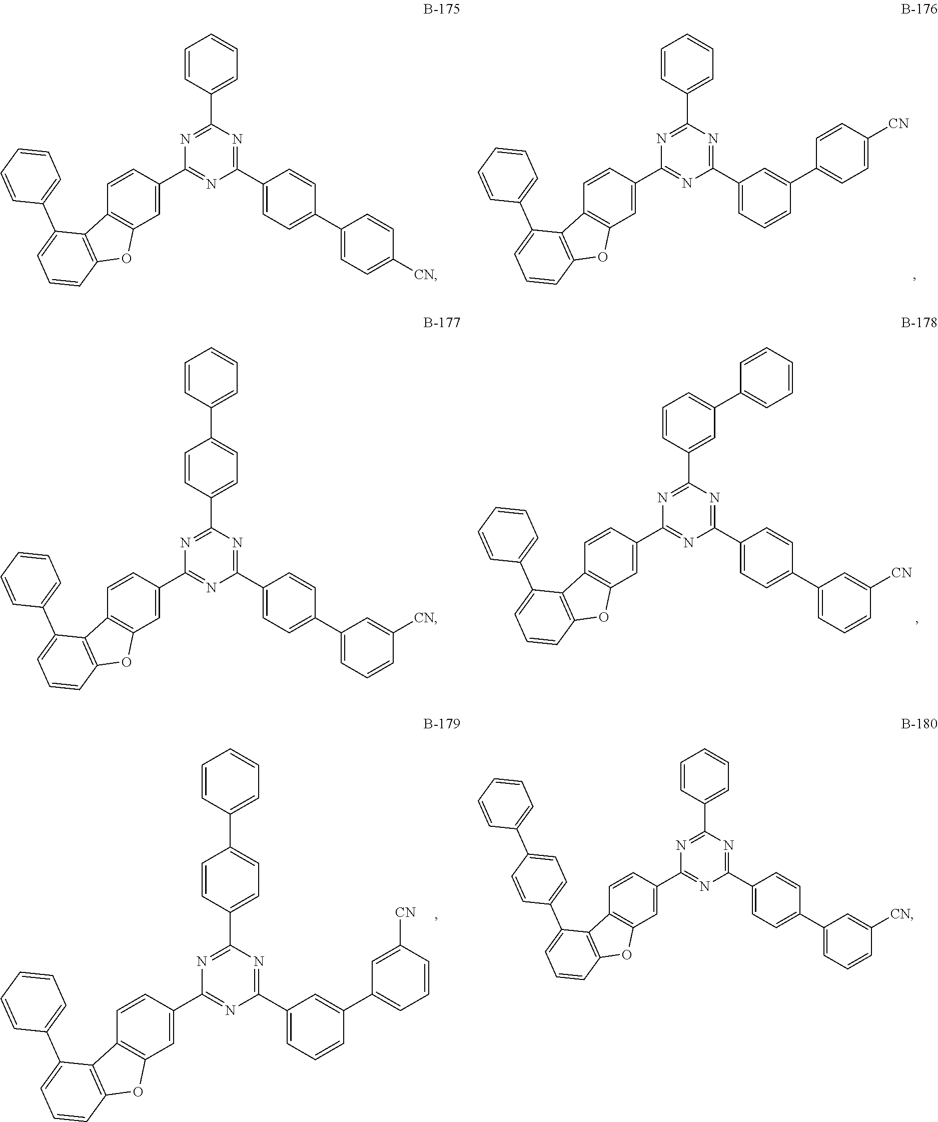

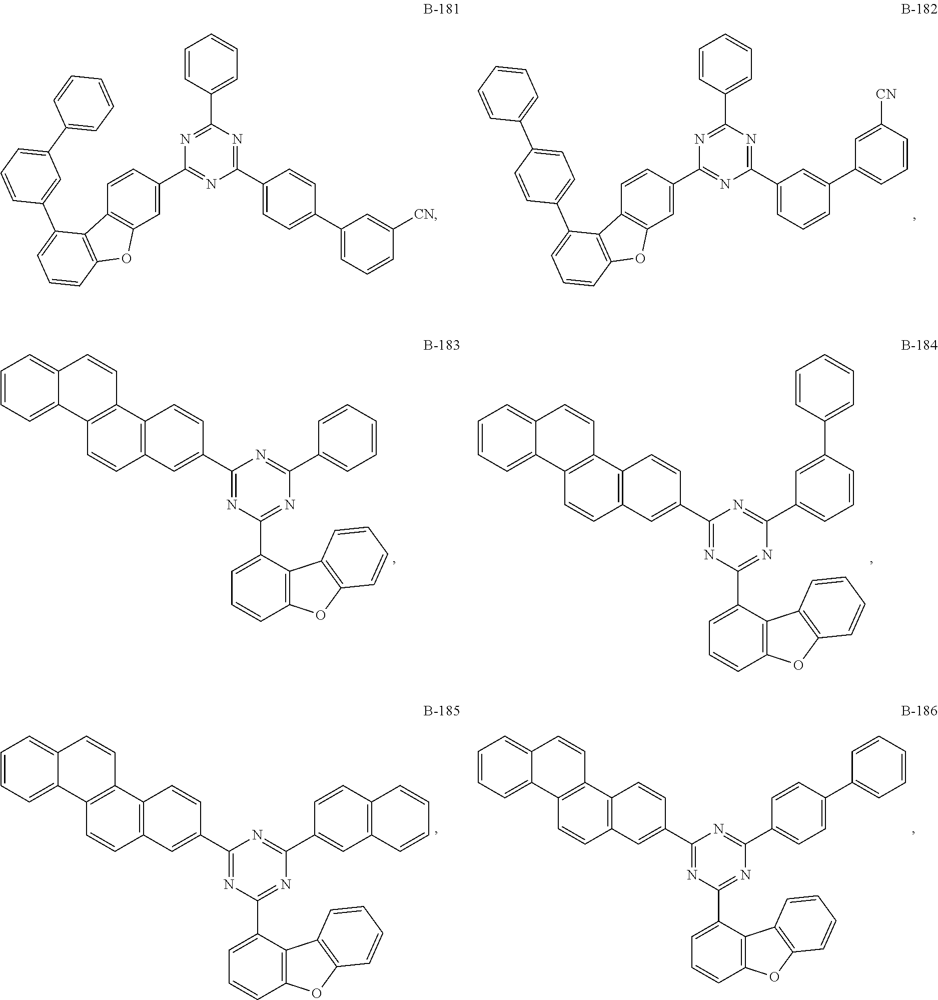

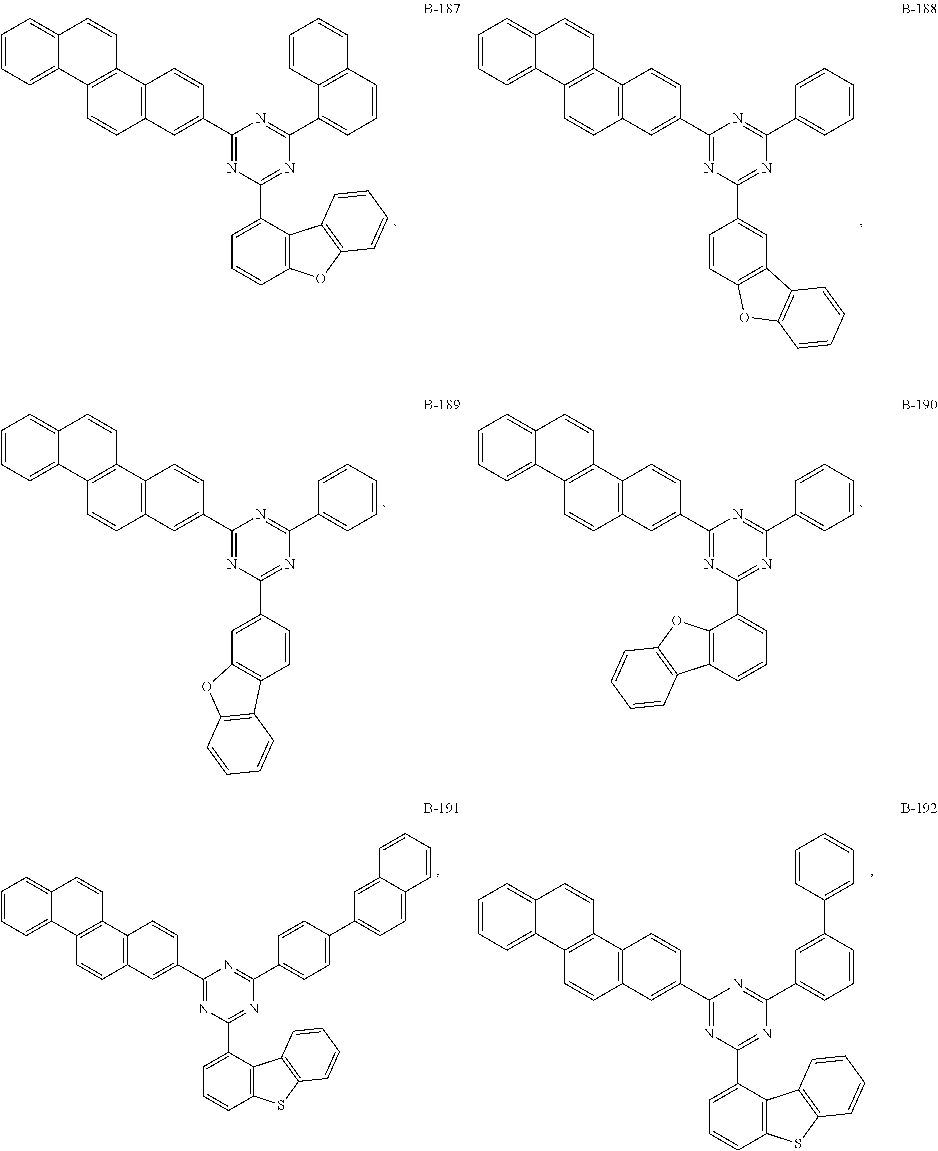 [SMILES: c1ccc2c(-c3nc(-c4ccc5c(ccc6c7ccccc7ccc56)c4)nc(-c4cccc5oc6ccccc6c45)n3)cccc2c1 ; c1ccc(-c2nc(-c3ccc4c(ccc5c6ccccc6ccc45)c3)nc(-c3ccc4oc5ccccc5c4c3)n2)cc1 ; c1ccc(-c2nc(-c3ccc4c(ccc5c6ccccc6ccc45)c3)nc(-c3ccc4c(c3)oc3ccccc34)n2)cc1 ; c1ccc(-c2nc(-c3ccc4c(ccc5c6ccccc6ccc45)c3)nc(-c3cccc4c3oc3ccccc34)n2)cc1 ; c1ccc2cc(-c3ccc(-c4nc(-c5ccc6c(ccc7c8ccccc8ccc67)c5)nc(-c5cccc6sc7ccccc7c56)n4)cc3)ccc2c1 ; c1ccc(-c2cccc(-c3nc(-c4ccc5c(ccc6c7ccccc7ccc56)c4)nc(-c4cccc5sc6ccccc6c45)n3)c2)cc1]

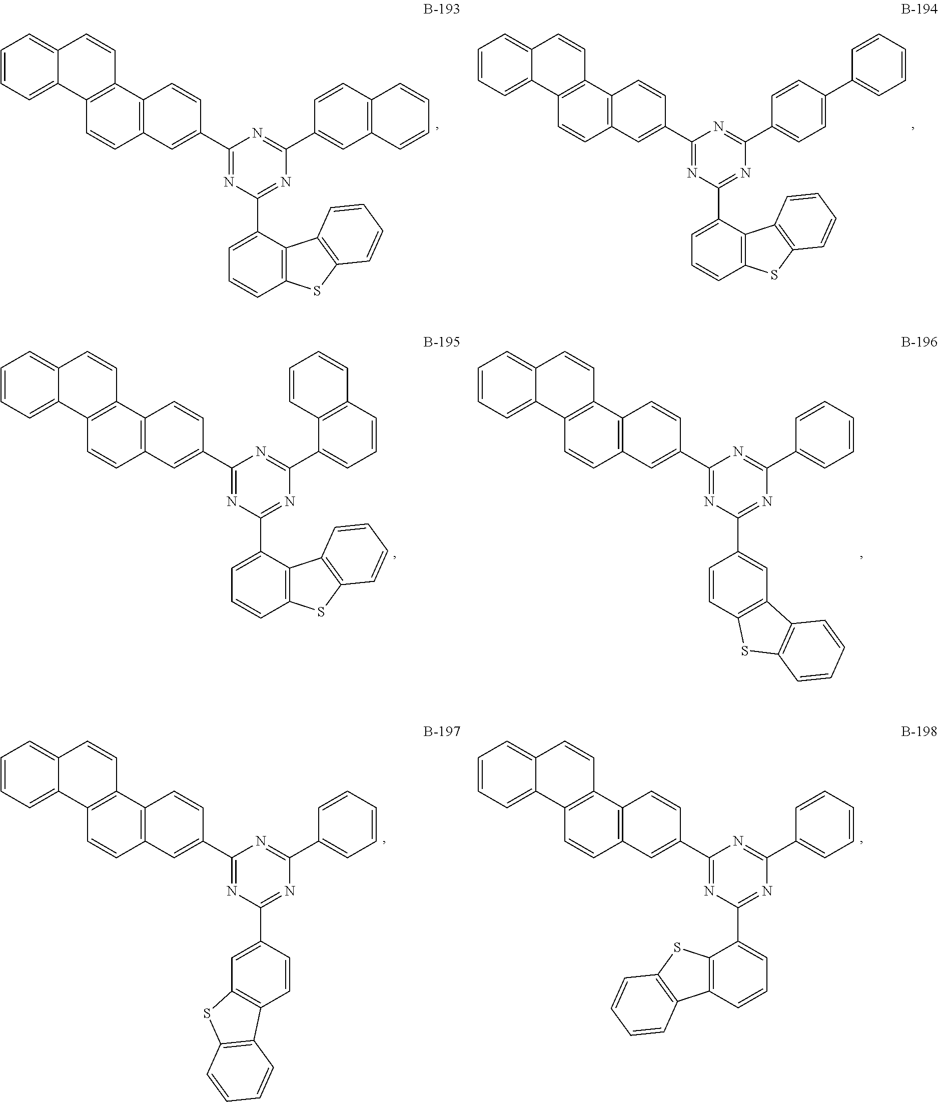 [SMILES: c1ccc2cc(-c3nc(-c4ccc5c(ccc6c7ccccc7ccc56)c4)nc(-c4cccc5sc6ccccc6c45)n3)ccc2c1 ; c1ccc(-c2ccc(-c3nc(-c4ccc5c(ccc6c7ccccc7ccc56)c4)nc(-c4cccc5sc6ccccc6c45)n3)cc2)cc1 ; c1ccc2c(-c3nc(-c4ccc5c(ccc6c7ccccc7ccc56)c4)nc(-c4cccc5sc6ccccc6c45)n3)cccc2c1 ; c1ccc(-c2nc(-c3ccc4c(ccc5c6ccccc6ccc45)c3)nc(-c3ccc4sc5ccccc5c4c3)n2)cc1 ; c1ccc(-c2nc(-c3ccc4c(ccc5c6ccccc6ccc45)c3)nc(-c3ccc4c(c3)sc3ccccc34)n2)cc1 ; c1ccc(-c2nc(-c3ccc4c(ccc5c6ccccc6ccc45)c3)nc(-c3cccc4c3sc3ccccc34)n2)cc1]

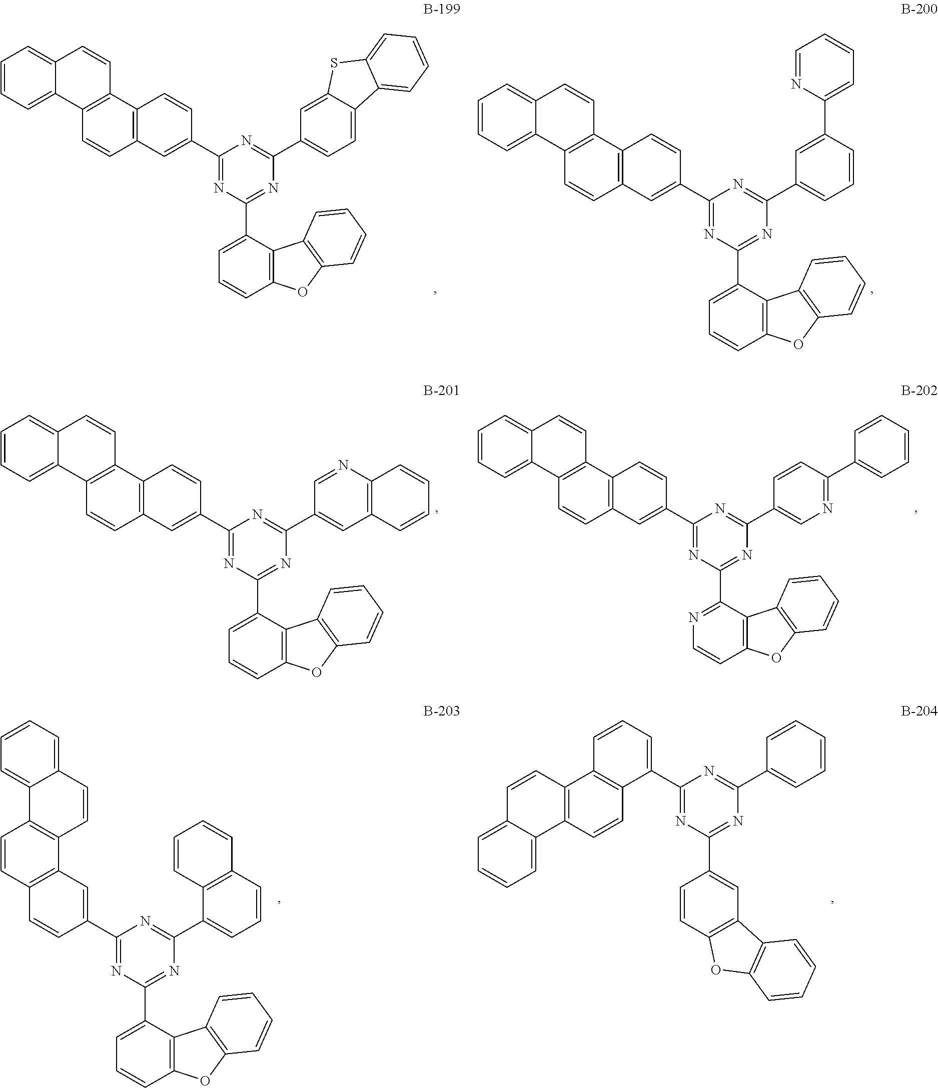 [SMILES: c1ccc2c(c1)ccc1c3ccc(-c4nc(-c5ccc6c(c5)sc5ccccc56)nc(-c5cccc6oc7ccccc7c56)n4)cc3ccc21 ; c1ccc(-c2cccc(-c3nc(-c4ccc5c(ccc6c7ccccc7ccc56)c4)nc(-c4cccc5oc6ccccc6c45)n3)c2)nc1 ; c1ccc2ncc(-c3nc(-c4ccc5c(ccc6c7ccccc7ccc56)c4)nc(-c4cccc5oc6ccccc6c45)n3)cc2c1 ; c1ccc(-c2ccc(-c3nc(-c4ccc5c(ccc6c7ccccc7ccc56)c4)nc(-c4nccc5oc6ccccc6c45)n3)cn2)cc1 ; c1ccc2c(-c3nc(-c4ccc5ccc6c7ccccc7ccc6c5c4)nc(-c4cccc5oc6ccccc6c45)n3)cccc2c1 ; c1ccc(-c2nc(-c3ccc4oc5ccccc5c4c3)nc(-c3cccc4c3ccc3c5ccccc5ccc43)n2)cc1]

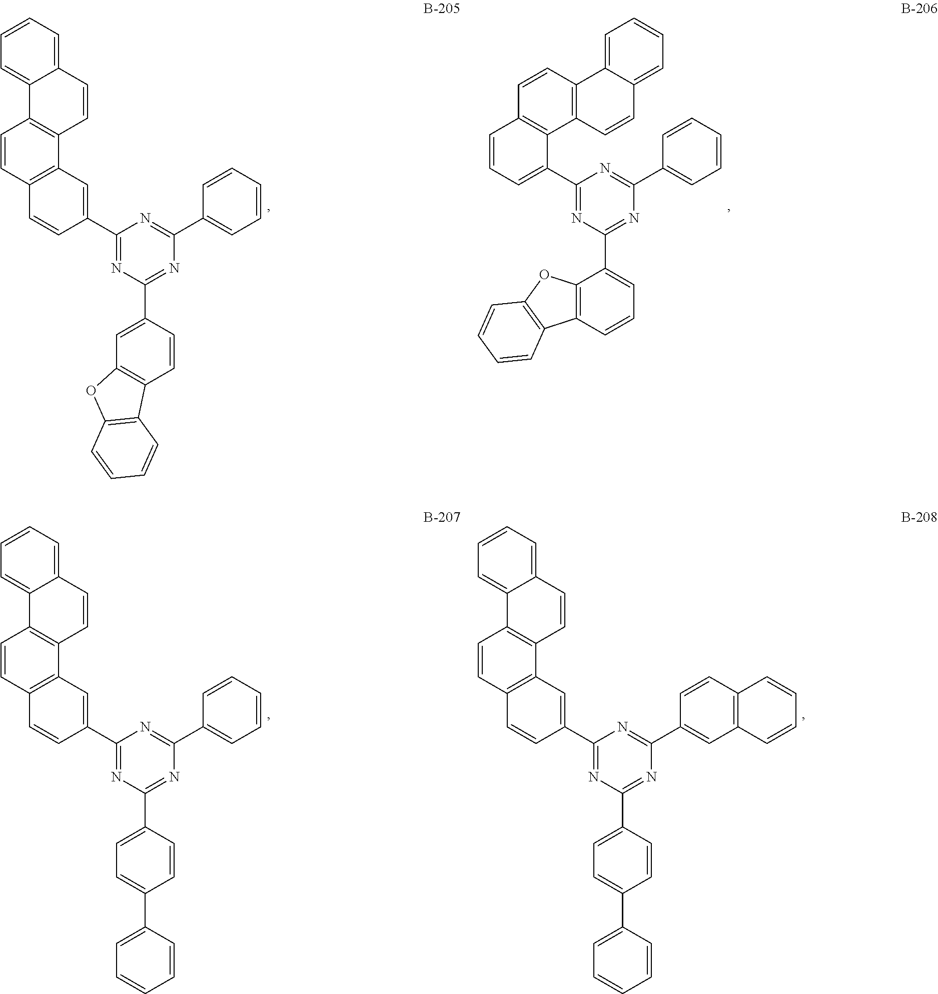 [SMILES: c1ccc(-c2nc(-c3ccc4c(c3)oc3ccccc34)nc(-c3ccc4ccc5c6ccccc6ccc5c4c3)n2)cc1 ; c1ccc(-c2nc(-c3cccc4c3oc3ccccc34)nc(-c3cccc4ccc5c6ccccc6ccc5c34)n2)cc1 ; c1ccc(-c2ccc(-c3nc(-c4ccccc4)nc(-c4ccc5ccc6c7ccccc7ccc6c5c4)n3)cc2)cc1 ; c1ccc(-c2ccc(-c3nc(-c4ccc5ccccc5c4)nc(-c4ccc5ccc6c7ccccc7ccc6c5c4)n3)cc2)cc1]

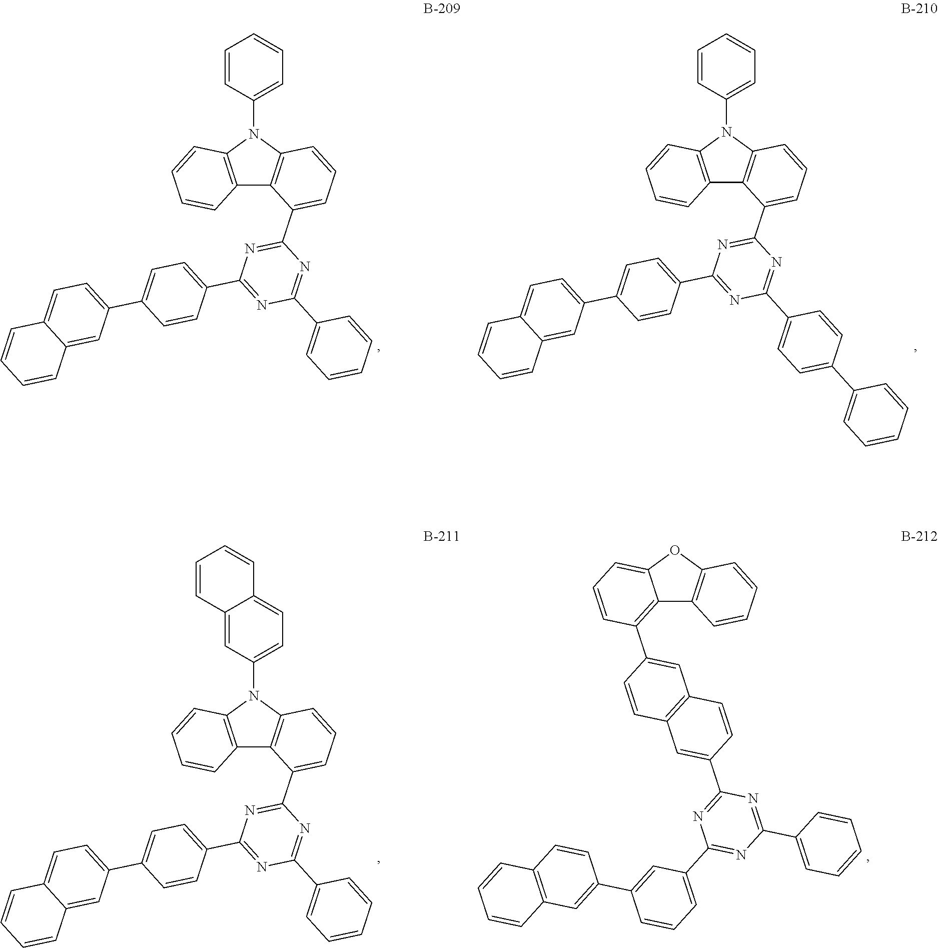 [SMILES: c1ccc(-c2nc(-c3ccc(-c4ccc5ccccc5c4)cc3)nc(-c3cccc4c3c3ccccc3n4-c3ccccc3)n2)cc1 ; c1ccc(-c2ccc(-c3nc(-c4ccc(-c5ccc6ccccc6c5)cc4)nc(-c4cccc5c4c4ccccc4n5-c4ccccc4)n3)cc2)cc1 ; c1ccc(-c2nc(-c3ccc(-c4ccc5ccccc5c4)cc3)nc(-c3cccc4c3c3ccccc3n4-c3ccc4ccccc4c3)n2)cc1 ; c1ccc(-c2nc(-c3cccc(-c4ccc5ccccc5c4)c3)nc(-c3ccc4cc(-c5cccc6oc7ccccc7c56)ccc4c3)n2)cc1]

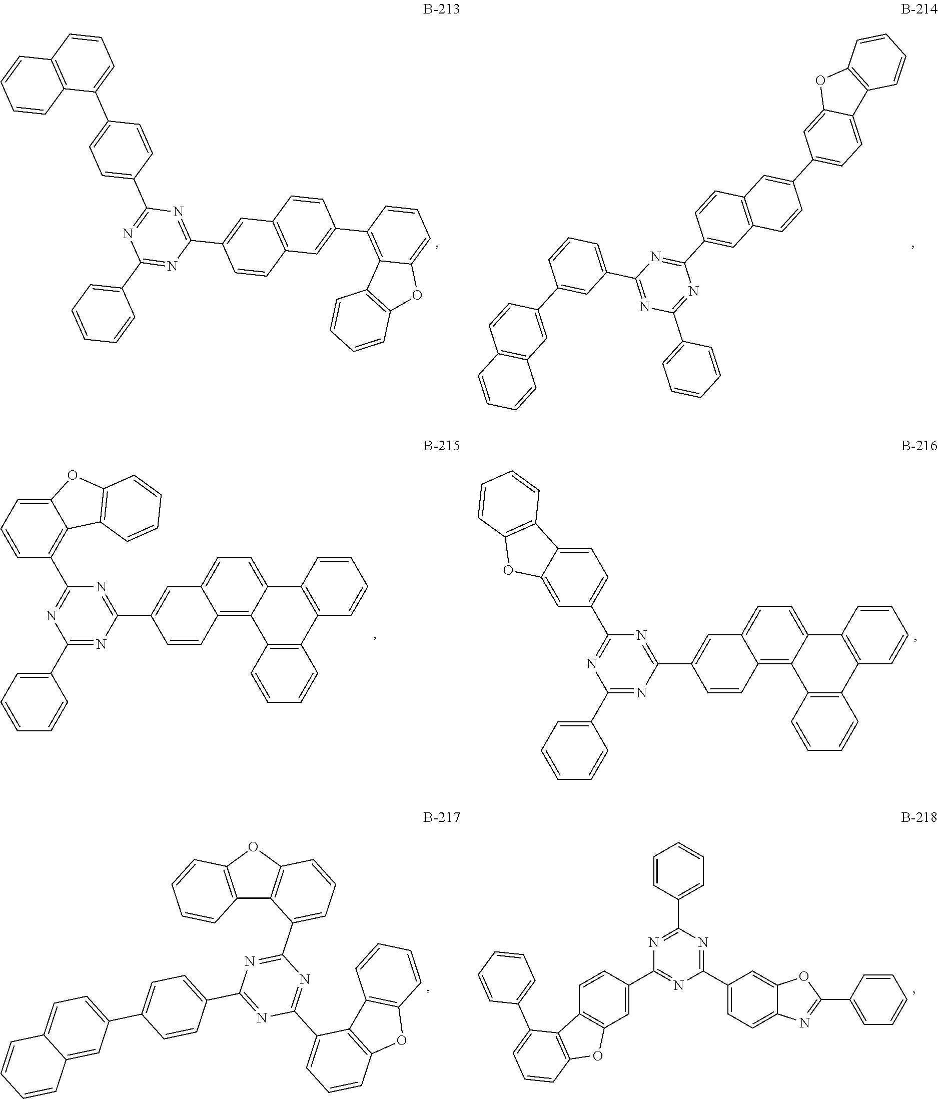

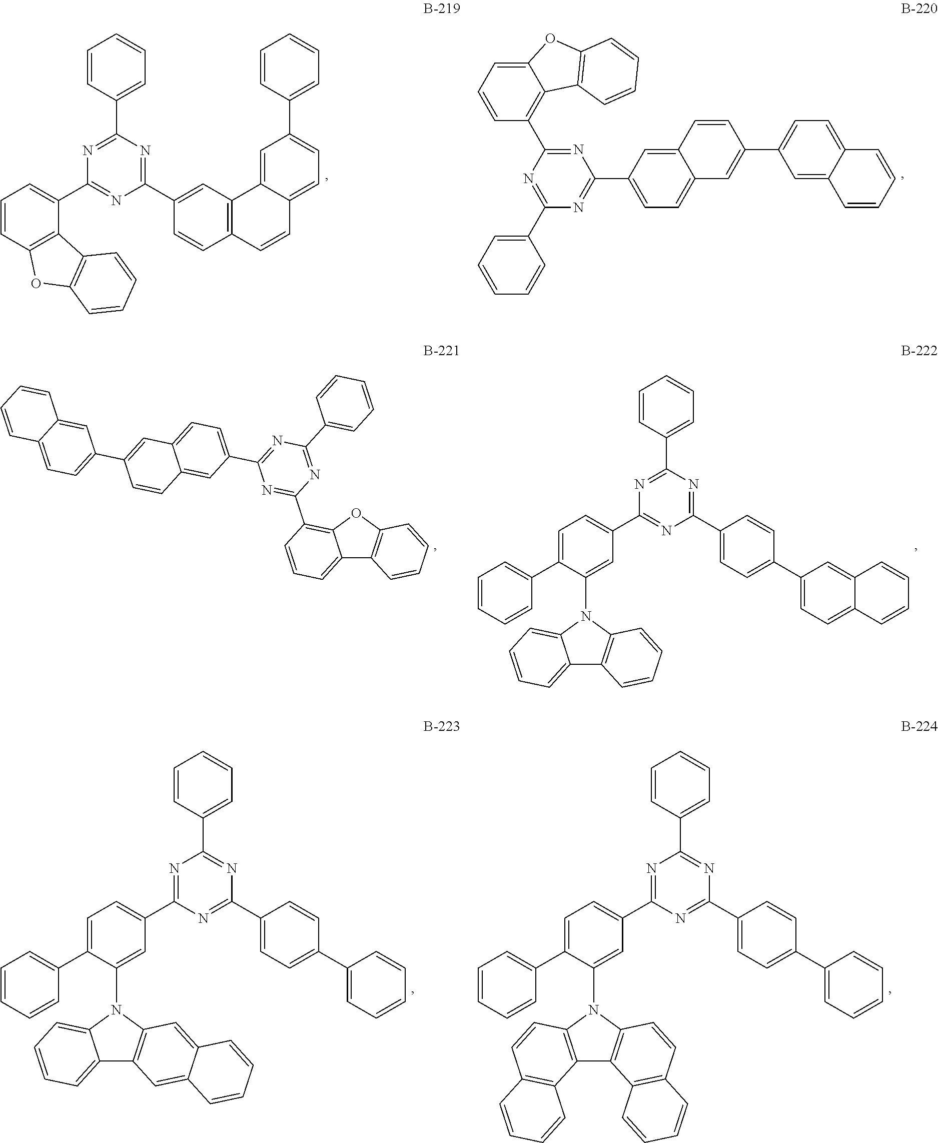

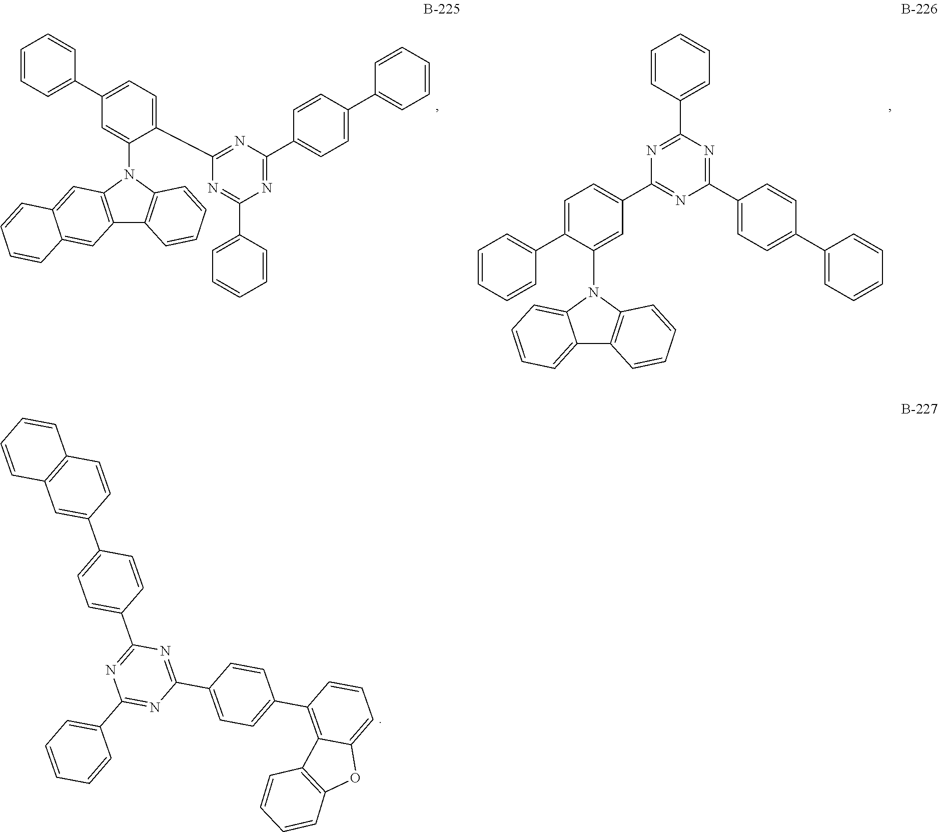 [SMILES: c1ccc(-c2ccc(-c3nc(-c4ccccc4)nc(-c4ccc(-c5ccccc5)cc4-n4c5ccccc5c5cc6ccccc6cc54)n3)cc2)cc1 ; c1ccc(-c2ccc(-c3nc(-c4ccccc4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4cccc5oc6ccccc6c45)cc3)n2)cc1]

According to an embodiment of the present disclosure, hydrogens in Compound B-1 to Compound B-227 can be partially or fully substituted with deuterium.

According to an embodiment of the present disclosure, in the ligand Lₐ of the first metal complex, the ring A and the ring B are each independently selected from a five-membered unsaturated carbocyclic ring, an aromatic ring having 6 to 18 carbon atoms, or a heteroaromatic ring having 3 to 18 carbon atoms.

According to an embodiment of the present disclosure, in the ligand Lₐ of the first metal complex, the ring A or the ring B is each independently selected from a five-membered unsaturated carbocyclic ring, an aromatic ring having 6 to 18 carbon atoms, or a heteroaromatic ring having 3 to 18 carbon atoms.

According to an embodiment of the present disclosure, in the ligand Lₐ of the first metal complex, the ring A and the ring B are each independently selected from a five-membered unsaturated carbocyclic ring, an aromatic ring having 6 to 10 carbon atoms, or a heteroaromatic ring having 3 to 10 carbon atoms.

According to an embodiment of the present disclosure, in the ligand Lₐ of the first metal complex, the ring A or the ring B is each independently selected from a five-membered unsaturated carbocyclic ring, an aromatic ring having 6 to 10 carbon atoms, or a heteroaromatic ring having 3 to 10 carbon atoms.

According to an embodiment of the present disclosure, Lₐ is selected from a structure represented by any one of Formula 1-a to Formula 1-k:

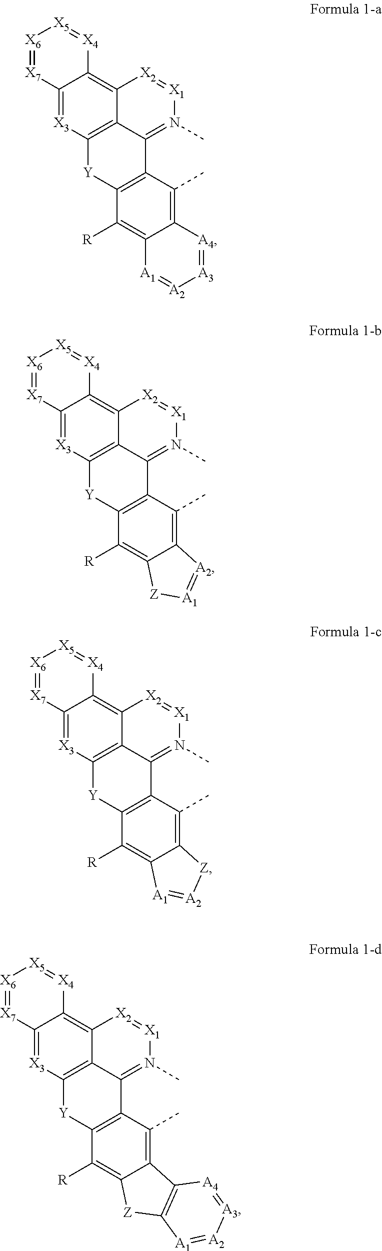

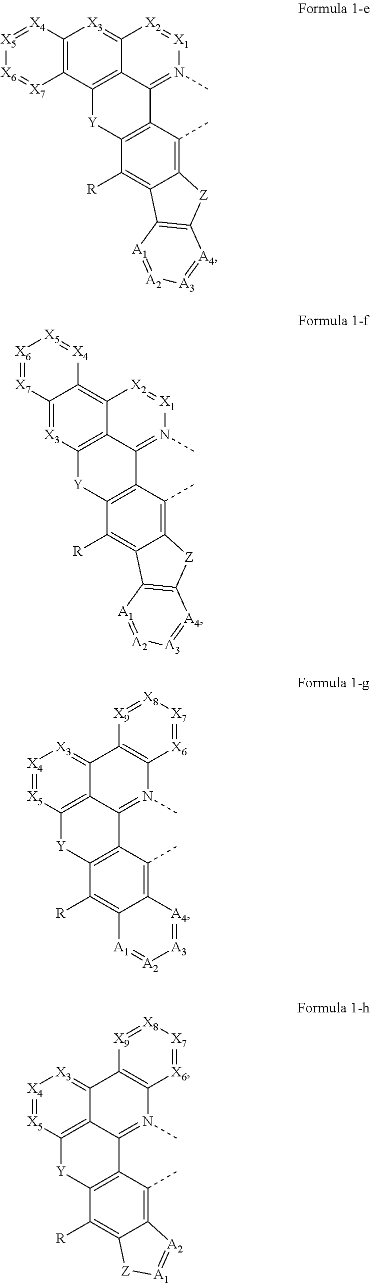

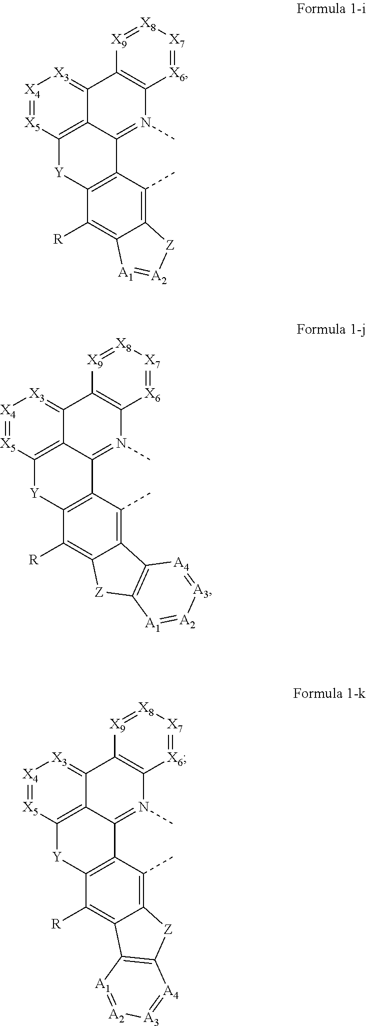

wherein in Formula 1-a to Formula 1-f, X₁ and X₂ are, at each occurrence identically or differently, selected from CRₓ or N, X₃ to X₇ are, at each occurrence identically or differently, selected from CRᵢ or N, and A₁ to A₄ are, at each occurrence identically or differently, selected from CRᵢᵢ or N;
in Formula 1-g to Formula 1-k, X₃ to X₉ are, at each occurrence identically or differently, selected from CRᵢ or N, and A₁ to A₄ are, at each occurrence identically or differently, selected from CRᵢᵢ or N;
Z is, at each occurrence identically or differently, selected from CRᵢᵢᵢRᵢᵢᵢ, SiRᵢᵢᵢRᵢᵢᵢ, PRᵢᵢᵢ, O, S, or NRᵢᵢᵢ; when two Rᵢᵢᵢ are present at the same time, the two Rᵢᵢᵢ are the same or different;
Y is selected from SiR_{y}R_{y}, NR_{y}, PR_{y}, O, S, or Se; when two R_{y} are present at the same time, the two R_{y} are the same or different;
R, Rₓ, R_{y}, Rᵢ, Rᵢᵢ, and Rᵢᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, Rₓ, R_{y}, Rᵢ, Rᵢᵢ, and Rᵢᵢᵢ can be optionally joined to form a ring.

In the embodiment of the present disclosure, the expression that “adjacent substituents R, Rₓ, R_{y}, Rᵢ, Rᵢᵢ, and Rᵢᵢᵢ can be optionally joined to form a ring” is intended to mean that any one or more of groups of adjacent substituents, such as two substituents Rₓ, two substituents R_{y}, two substituents Rᵢ, two substituents Rᵢᵢ, two substituents Rᵢᵢᵢ, substituents Rₓ and Rᵢ, and substituents R and R_{y}, can be joined to form a ring. Obviously, it is also possible that none of these substituents are joined to form a ring.

According to an embodiment of the present disclosure, Lₐ is selected from a structure represented by Formula 1-a.

According to an embodiment of the present disclosure, in Formula 1-a to Formula 1-f, at least one of X₁ to X₇ and/or A₁ to Aₘ is selected from N, wherein the Aₘ corresponds to one with the largest serial number among A₁ to A₄ in any one of Formula 1-a to Formula 1-f. For example, in Formula 1-a, the Aₘ corresponds to A₄ with the largest serial number among A₁ to A₄ in Formula 1-a, that is, in Formula 1-a, at least one of X₁ to X₇ and/or A₁ to A₄ is selected from N.

According to an embodiment of the present disclosure, in Formula 1-g to Formula 1-k, at least one of X₃ to X₉ and/or A₁ to Aₘ is selected from N, wherein the Aₘ corresponds to one with the largest serial number among A₁ to A₄ in any one of Formula 1-g to Formula 1-k. For example, in Formula 1-g, the Aₘ corresponds to A₄ with the largest serial number among A₁ to A₄ in Formula 1-g, that is, in Formula 1-g, at least one of X₃ to X₉ and/or A₁ to A₄ is selected from N.

According to an embodiment of the present disclosure, in Formula 1-a to Formula 1-f, at least one of X₁ to X₇ is selected from N.

According to an embodiment of the present disclosure, in Formula 1-a to Formula 1-f, X₂ is N.

According to an embodiment of the present disclosure, in Formula 1-a to Formula 1-f, X₁ and X₂ are each independently selected from CRₓ, X₃ to X₇ are, at each occurrence identically or differently, selected from CRᵢ, and A₁ to A₄ are each independently selected from CRᵢᵢ; and adjacent substituents Rₓ, Rᵢ, Rᵢᵢ can be optionally joined to form a ring.

According to an embodiment of the present disclosure, in Formula 1-g to Formula 1-k, X₃ to X₉ are, at each occurrence identically or differently, selected from CRᵢ, and A₁ to A₄ are each independently selected from CRᵢᵢ; and adjacent substituents Rₓ, Rᵢ, Rᵢᵢ can be optionally joined to form a ring.

According to an embodiment of the present disclosure, Rₓ, Rᵢ, and Rᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, at least one or two of Rₓ, Rᵢ, and Rᵢᵢ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

According to an embodiment of the present disclosure, in Formula 1-a to Formula 1-k, at least one or two of A₁ to A₄ are selected from CRᵢᵢ, and Rᵢᵢ is, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, Rᵢ is, at each occurrence identically or differently, selected from the group consisting of: hydrogen, deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof; and

Rᵢᵢ is, at each occurrence identically or differently, selected from the group consisting of: deuterium, fluorine, methyl, ethyl, isopropyl, isobutyl, t-butyl, neopentyl, cyclopentyl, cyclopentylmethyl, cyclohexyl, norbornyl, adamantyl, trimethylsilyl, isopropyldimethylsilyl, phenyldimethylsilyl, trifluoromethyl, cyano, phenyl, and combinations thereof.

According to an embodiment of the present disclosure, in Formula 1-a to Formula 1-k, R is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, R is selected from hydrogen, deuterium, fluorine, methyl, ethyl, isopropyl, isobutyl, t-butyl, cyclopentyl, cyclopentylmethyl, cyclohexyl, neopentyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, trimethylsilyl, or a combination thereof.

According to an embodiment of the present disclosure, in Formula 1-a to Formula 1-k, Y is selected from O or S.

According to an embodiment of the present disclosure, in Formula 1-a to Formula 1-f, X₁ and X₂ are each independently selected from CRₓ, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, in Formula 1-a to Formula 1-f, X₁ and X₂ are each independently selected from CRₓ, and Rₓ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, in Formula 1-a to Formula 1-f, X₁ is selected from CRₓ, X₂ is N, and Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, in Formula 1-a to Formula 1-f, X₁ is selected from CRₓ, X₂ is N, and Rₓ is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, the ligand Lₐ has a structure represented by Formula 5:

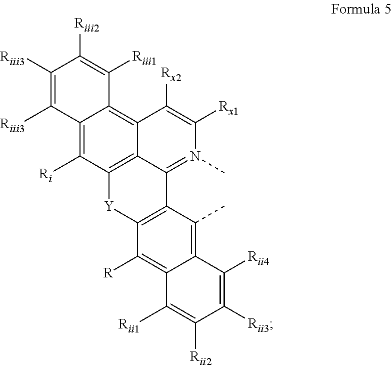

wherein in Formula 5, Y is selected from O or S;
Rₓ₁, Rₓ₂, Rᵢ, Rᵢᵢᵢ, Rᵢᵢ₂, Rᵢᵢ₃, Rᵢᵢ₄, R, Rᵢᵢᵢ₁, Rᵢᵢᵢ₂, Rᵢᵢᵢ₃, and Rᵢᵢᵢ₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, and combinations thereof; and
at least one of Rᵢᵢᵢ₁, Rᵢᵢᵢ₂, Rᵢᵢᵢ₃, and Rᵢᵢᵢ₄ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, and combinations thereof.

According to an embodiment of the present disclosure, at least one or two of Rₓ₁, Rₓ₂, Rᵢᵢᵢ₁, Rᵢᵢᵢ₂, Rᵢᵢᵢ₃, and Rᵢᵢᵢ₄ and/or at least one or two of Rᵢᵢ₁, Rᵢᵢ₂, Rᵢᵢ₃, and Rᵢᵢ₄ are, at each occurrence identically or differently, selected from deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof; and R is selected from halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, at least one or two of Rₓ₁, Rₓ₂, Rᵢᵢᵢ₁, Rᵢᵢᵢ₂, Rᵢᵢᵢ₃, and Rᵢᵢᵢ₄ and/or at least one or two of Rᵢᵢ₁, Rᵢᵢ₂, Rᵢᵢ₃, and Rᵢᵢ₄ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof; and R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, at least one or two of Rᵢᵢᵢ₁, Rᵢᵢᵢ₂, Rᵢᵢᵢ₃, and Rᵢᵢᵢ₄ and at least one or two of Rᵢᵢ₁, Rᵢᵢ₂, Rᵢᵢ₃, and Rᵢᵢ₄ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof; and R is selected from halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to an embodiment of the present disclosure, at least one or two of Rᵢᵢᵢ₁, Rᵢᵢᵢ₂, Rᵢᵢᵢ₃, and Rᵢᵢᵢ₄ and at least one or two of Rᵢᵢ₁, Rᵢᵢ₂, Rᵢᵢ₃, and Rᵢᵢ₄ are, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof; and R is selected from substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof.

According to another embodiment of the present disclosure, in Formula 5, at least one of Rₓ₁, Rₓ₂, Rᵢᵢᵢ₁, Rᵢᵢᵢ₂, Rᵢᵢᵢ₃, Rᵢᵢᵢ₄, Rᵢᵢ₁, Rᵢᵢ₂, Rᵢᵢ₃, Rᵢᵢ₄, and R is, at each occurrence identically or differently, selected from the group consisting of: substituted or unsubstituted alkyl having 3 to 20 carbon atoms, substituted or unsubstituted cycloalkyl having 3 to 20 ring carbon atoms, substituted or unsubstituted alkylsilyl having 3 to 20 carbon atoms, and combinations thereof.

According to another embodiment of the present disclosure, in Formula 5, at least one of Rₓ₁, Rₓ₂, Rᵢᵢᵢ₁, Rᵢᵢᵢ₂, Rᵢᵢᵢ₃, Rᵢᵢᵢ₄, Rᵢᵢ₁, Rᵢᵢ₂, Rᵢᵢ₃, Rᵢᵢ₄, and R is, at each occurrence identically or differently, selected from the group consisting of: substituted or unsubstituted alkyl having 3 to 10 carbon atoms, substituted or unsubstituted cycloalkyl having 3 to 10 ring carbon atoms, and combinations thereof.

According to an embodiment of the present disclosure, Lₐ is, at each occurrence identically or differently, selected from the group consisting of Lₐ₁ to Lₐ₄₀₂, wherein the specific structures of Lₐ₁ to Lₐ₄₀₂ are referred to claim 15.

According to an embodiment of the present disclosure, hydrogens in the structures of Lₐ₁ to Lₐ₄₀₂ can be partially or fully substituted with deuterium.

According to an embodiment of the present disclosure, the first metal complex has a structure of M(Lₐ)ₘ(L_{b})ₙ(L_{c})_{q};
wherein the metal M is selected from a metal with a relative atomic mass greater than 40;
Lₐ, L_{b}, and L_{c} are a first ligand, a second ligand, and a third ligand of the first metal complex, respectively; m is 1, 2, or 3, n is 0, 1, or 2, q is 0, 1, or 2, and m+n+q is equal to an oxidation state of the metal M; when m is greater than 1, multiple Lₐ are the same or different; when n is 2, two L_{b} are the same or different; when q is 2, two L_{c} are the same or different;
Lₐ, L_{b}, and L_{c} can be optionally joined to form a multidentate ligand;
L_{b} and L_{c} are, at each occurrence identically or differently, selected from the group consisting of the following structures:

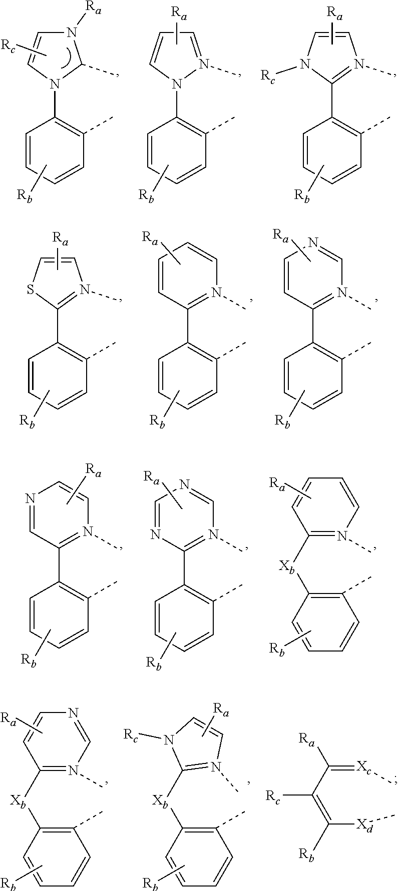

wherein Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{N2}, R_{C1}, and R_{C2} can be optionally joined to form a ring.

In the present disclosure, the expression that “adjacent substituents Rₐ, R_{b}, R_{c}, R_{N1}, R_{N2}, R_{C1}, and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, can be joined to form a ring. For example, adjacent substituents Rₐ and R_{b} in

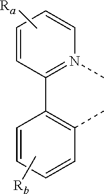

can be optionally joined to form a ring, which can form one or more of the following structures including, but not limited to,

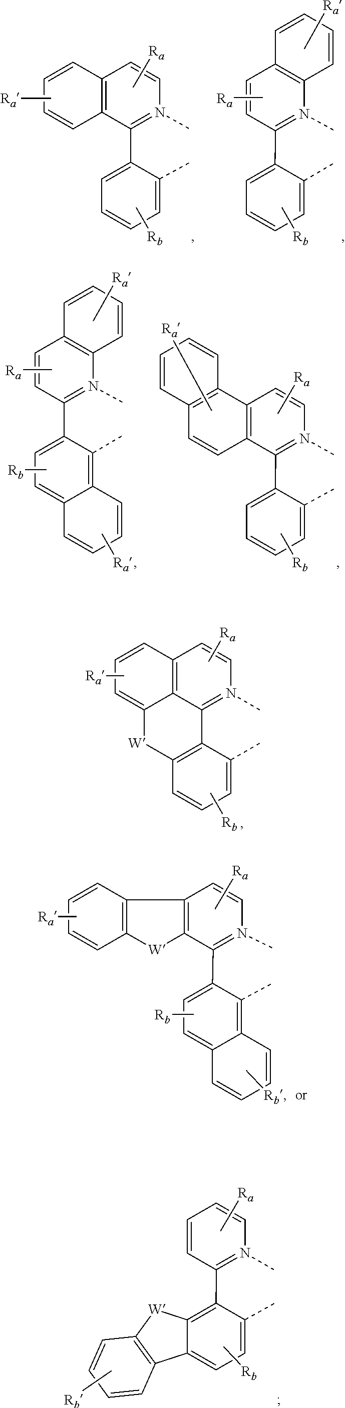

wherein W′ is selected from O, S, Se, NR′, or CR′R′, and R′, Rₐ′, and R_{b}′ are defined the same as Rₐ. Obviously, it is also possible that none of these substituents are joined to form a ring.

According to an embodiment of the present disclosure, the metal M is, at each occurrence identically or differently, selected from the group consisting of Cu, Ag, Au, Ru, Rh, Pd, Os, Ir, and Pt.

According to an embodiment of the present disclosure, the metal M is, at each occurrence identically or differently, selected from Pt or Ir.

According to an embodiment of the present disclosure, L_{b} is, at each occurrence identically or differently, selected from the following structure:

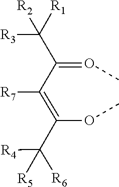

wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₁, R₂, R₃, R₄, R₅, R₆, R₇ can be optionally joined to form a ring.

In the present disclosure, the expression that “adjacent substituents R₁, R₂, R₃, R₄, R₅, R₆, R₇ can be optionally joined to form a ring” is intended to mean that any one or more of groups of adjacent substituents, such as substituents R₁ and R₂, substituents R₁ and R₃, substituents R₂ and R₃, substituents R₄ and R₅, substituents R₄ and R₆, and substituents R₅ and R₆, can be joined to form a ring. Obviously, it is also possible that none of these substituents are joined to form a ring.

According to an embodiment of the present disclosure, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof; and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof.

According to an embodiment of the present disclosure, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

According to an embodiment of the present disclosure, L_{b} is, at each occurrence identically or differently, selected from the group consisting of L_{b1} to L_{b322}, wherein the specific structures of L_{b1} to L_{b322} are referred to claim 18.

According to an embodiment of the present disclosure, L_{c} is, at each occurrence identically or differently, selected from the group consisting of L_{c1} to L_{c231}, wherein the specific structures of L_{c1} to L_{c231} are referred to claim 18.

According to an embodiment of the present disclosure, the first metal complex has a structure of Ir(Lₐ)₂(L_{b}) or Ir(Lₐ)₂(L_{c}) or Ir(Lₐ)(L_{c})₂; wherein when the first metal complex has a structure of Ir(Lₐ)₂(L_{b}), Lₐ is, at each occurrence identically or differently, selected from any one or any two of the group consisting of Lₐ₁ to Lₐ₄₀₂ and L_{b} is selected from any one of the group consisting of L_{b1} to L_{b322}; when the first metal complex has a structure of Ir(Lₐ)₂(L_{c}), Lₐ is, at each occurrence identically or differently, selected from any one or any two of the group consisting of Lₐ₁ to Lₐ₄₀₂ and L_{c} is selected from any one of the group consisting of L_{c1} to L_{c231}; and when the first metal complex has a structure of Ir(Lₐ)(L_{c})₂, Lₐ is selected from any one of the group consisting of Lₐ₁ to Lₐ₄₀₂ and L_{c} is, at each occurrence identically or differently, selected from any one or any two of the group consisting of L_{c1} to L_{c231}.

According to an embodiment of the present disclosure, the first metal complex is selected from the group consisting of Compound RD-1 to Compound RD-114, wherein the specific structures of Compound RD-1 to Compound RD-114 are referred to claim 19.

According to an embodiment of the present disclosure, the first host compound is a p-type host material, the second host compound is an n-type host material, and the first metal complex is an emissive material.

According to an embodiment of the present disclosure, an organic electroluminescent device is disclosed. The organic electroluminescent device comprises:
a cathode,
an anode, and
an emissive layer disposed between the cathode and the anode, wherein the emissive layer comprises at least a first host compound, a second host compound, and a first metal complex; and a capacitance property of the organic electroluminescent device satisfies the following condition:
at 500 Hz, a maximum capacitance value per unit of emissive area of the organic electroluminescent device is Cₘₐₓ₋ₛ, and Cₘₐₓ₋ₛ−Cₘₐₓ₀₋ₛ≤−5 nF/cm²;
wherein Cₘₐₓ₀₋ₛ denotes a maximum capacitance value per unit of emissive area of an organic electroluminescent device A at 500 Hz; and the organic electroluminescent device A is the same as the organic electroluminescent device except that the first host compound and the second host compound in the emissive layer of the organic electroluminescent device are replaced with Compound RH0 as a host compound;
wherein the Compound RH0 has the following structure:

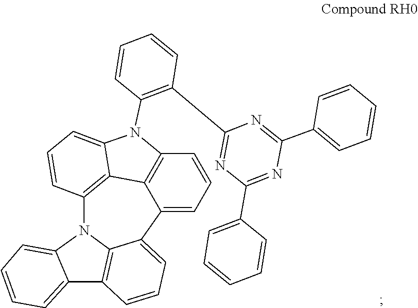 [SMILES: c1ccc(-c2nc(-c3ccccc3)nc(-c3ccccc3-n3c4cccc5c6cccc7c8ccccc8n(c8cccc3c8c54)c67)n2)cc1]

the first metal complex comprises a metal M and a ligand Lₐ coordinated to the metal M, wherein the metal M is selected from a metal with a relative atomic mass greater than 40, and the ligand Lₐ has a structure represented by Formula 1:

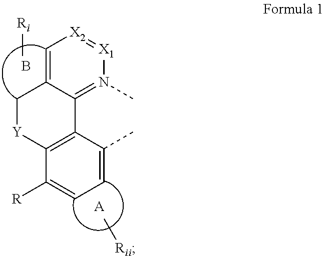

wherein the ring A and the ring B are each independently selected from a five-membered unsaturated carbocyclic ring, an aromatic ring having 6 to 30 carbon atoms, or a heteroaromatic ring having 3 to 30 carbon atoms;
X₁ and X₂ are, at each occurrence identically or differently, selected from CRₓ or N;
Rᵢ and Rᵢᵢ represent, at each occurrence identically or differently, mono-substitution, multiple substitutions, or non-substitution;
at least one of the following two conditions is satisfied:
(1) at least two Rᵢ are joined to form a ring; or
(2) X₁ and X₂ are, at each occurrence identically or differently, selected from CRₓ, and two Rₓ are joined to form a ring;
Y is selected from SiR_{y}R_{y}, GeR_{y}R_{y}, NR_{y}, PR_{y}, O, S, or Se; when two R_{y} are present at the same time, the two R_{y} may be the same or different;
R, Rᵢ, Rᵢᵢ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and Cₘₐₓ₀₋ₛ denotes a maximum capacitance value per unit of emissive area of an organic electroluminescent device A at 500 Hz;
adjacent substituents R, Rᵢ, Rᵢᵢ, Rₓ, R_{y} can be optionally joined to form a ring.

In the embodiment, “the maximum capacitance value per unit of emissive area of the organic electroluminescent device” refers to that if a maximum capacitance value of an organic electroluminescent device Y with an emissive area S (unit: cm²) at 500 Hz is Cₘₐₓ (unit: nF), then the maximum capacitance value per unit of emissive area is Cₘₐₓ₋ₛ=Cₘₐₓ/S (unit: nF/cm²). Similarly, “the maximum capacitance value per unit of emissive area Cₘₐₓ₀₋ₛ of the organic electroluminescent device A at 500 Hz” refers to that if a maximum capacitance value of the organic electroluminescent device A with an emissive area S (unit: cm²) is Cₘₐₓ₀ (unit: nF), then the maximum capacitance value per unit of emissive area is Cₘₐₓ₀₋ₛ=Cₘₐₓ₀/S (unit: nF/cm²). For example, if the maximum capacitance value of the organic electroluminescent device Y with an emissive area S of 0.04 cm² and the maximum capacitance value of the organic electroluminescent device A with an emissive area S of 0.04 cm² at 500 Hz are Cₘₐₓ and Cₘₐₓ₀, respectively, then the maximum capacitance value per unit of emissive area of the organic electroluminescent device Y is Cₘₐₓ₋ₛ=Cₘₐₓ/0.04 (unit: nF/cm²), the maximum capacitance value per unit of emissive area of the organic electroluminescent device A is Cₘₐₓ₀₋ₛ=Cₘₐₓ₀/0.04 (unit: nF/cm²), and a difference between the maximum capacitance values per unit of emissive area of the organic electroluminescent device Y and the organic electroluminescent device A is Cₘₐₓ₋ₛ−Cₘₐₓ₀₋ₛ=Cₘₐₓ/0.04−Cₘₐₓ₀/0.04 (unit: nF/cm²). In another example, when the emissive area of 8 cm², the maximum capacitance value of the organic electroluminescent device Y is 8Cₘₐₓ₋ₛ (unit: nF), the maximum capacitance value of the organic electroluminescent device A is 8Cₘₐₓ₀₋ₛ (unit: nF), and the difference between the maximum capacitance values of the organic electroluminescent device Y and the organic electroluminescent device A is 8Cₘₐₓ₋ₛ−8Cₘₐₓ₀₋ₛ=200Cₘₐₓ−200Cₘₐₓ₀ (unit: nF/cm²).

According to an embodiment of the present disclosure, at 500 Hz, Cₘₐₓ₋ₛ−Cₘₐₓ₀₋ₛ≤−7.5 nF/cm².

According to an embodiment of the present disclosure, at 500 Hz, Cₘₐₓ₋ₛ−Cₘₐₓ₀₋ₛ≤−18.75 nF/cm².

According to an embodiment of the present disclosure, at 500 Hz, 50 nF/cm²≤Cₘₐₓ₀₋ₛ≤150 nF/cm².

According to an embodiment of the present disclosure, at 500 Hz, the maximum capacitance value per unit of emissive area of the organic electroluminescent device is 12.5 nF/cm²≤Cₘₐₓ₋ₛ≤137.5 nF/cm².

According to an embodiment of the present disclosure, the maximum capacitance value per unit of emissive area of the organic electroluminescent device is 25 nF/cm²≤Cₘₐₓ₋ₛ≤100 nF/cm².

According to an embodiment of the present disclosure, the maximum capacitance value per unit of emissive area of the organic electroluminescent device is 25 nF/cm²≤Cₘₐₓ₋ₛ≤75 nF/cm².

According to an embodiment of the present disclosure, the maximum capacitance value per unit of emissive area of the organic electroluminescent device is 25 nF/cm²≤Cₘₐₓ₋ₛ≤50 nF/cm².

According to an embodiment of the present disclosure, a display assembly is disclosed.

The display assembly comprises an organic electroluminescent device, wherein the specific structure of the organic electroluminescent device is shown in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

In the present disclosure, a lowest unoccupied molecular orbital energy level (E_{LUMO}) of a compound is determined through cyclic voltammetry (CV). Specifically, the test used an electrochemical workstation CorrTest CS120 produced by Wuhan Corrtest Instruments Corp., Ltd and used a three-electrode working system where a platinum disk electrode served as a working electrode, a Ag/AgNO₃ electrode served as a reference electrode, and a platinum wire electrode served as an auxiliary electrode; 0.1 mol/L tetrabutylammonium hexafluorophosphate was used as a supporting electrolyte; and anhydrous DMF was used as a solvent, the compound to be tested was prepared into a solution of 10⁻³ mol/L, and nitrogen was introduced into the solution for 10 min for oxygen removal before the test. The parameters of the instrument were set as follows: a scan rate was 100 mV/s, a potential interval was 0.5 mV, a test window of an oxidation potential was 0 V to 1 V, and a test window of a reduction potential was −1 V to −2.9 V. Data on the LUMO energy levels of the second host compound used in the present application and Compound RH0, which were tested by the preceding method, are shown in Table 1.

TABLE 1
Energy level data of the second
host compound and Compound RH0

| Compound | E_{LUMO}/eV |
|---|---|
| B-222 | −2.878 |
| B-227 | −2.829 |
| RHO | −2.748 |

When the concentration of holes transported to an emissive layer of an OLED is far greater than the concentration of electrons transported to the emissive layer, an imbalance of the concentration of carriers in the emissive layer occurs. As shown in Table 1, the E_{LUMO} of a second host compound B-222 (n-type host material) and the E_{LUMO} of a second host compound B-227 (n-type host material) are −2.878 eV and −2.829 eV, respectively, both of which are lower than −2.75 eV. The deeper LUMO energy level helps to increase an electron transport capability of the second host compound. The second host compound in combination with a first host compound (p-type host material) can promote the recombination of electrons and holes in the emissive layer for light emission, reduce the accumulation of holes, better balance the concentration of carriers in the emissive layer, and effectively reduce the capacitance of a device, which is further verified through the device examples below.

### DEVICE EXAMPLE

### Device Example 1

A glass substrate having an indium tin oxide (ITO) anode with a thickness of 1200 Å (with a sheet resistance of 14 to 20 Ω/sq and an emissive area of 0.04 cm²) was cleaned, treated with UV ozone and oxygen plasma, dried in a nitrogen-filled glovebox to remove moisture, and then mounted on a substrate holder and placed in a vacuum chamber. Organic layers were sequentially deposited through vacuum thermal evaporation on the ITO anode at a rate of 0.01-10 Å/s and at a vacuum degree of about 10⁻⁶ Torr. Compound HT-1 and Compound HT-2 were co-deposited for use as a hole injection layer (HIL) with a thickness of 100 Å, where a weight ratio of Compound HT-1:Compound HT-2 was 97:3. Compound HT-1 was deposited for use as a hole transporting layer (HTL) with a thickness of 400 Å. Compound EB was deposited for use as an electron blocking layer (EBL) with a thickness of 50 Å. Compound RD-67 was doped into Compound B-222 and Compound 1-2-2 to form an emissive layer (EML) with a thickness of 400 Å, where a weight ratio of Compound 1-2-2:Compound B-222:Compound RD-67 was 38.8:58.2:3. Compound B-1 was deposited for use as a hole blocking layer (HBL) with a thickness of 50 Å. On the HBL, Compound ET and Liq were co-deposited for use as an electron transporting layer (ETL) with a thickness of 350 Å, where a weight ratio of Compound ET:Liq was 40:60. On the ETL, Liq was deposited for use as an electron injection layer (EIL) with a thickness of 10 Å. Finally, A1 was deposited for use as a cathode with a thickness of 1200 Å. After evaporation, the device was transferred back to the glovebox and encapsulated with a glass lid to complete the device.

### Device Example 2

The implementation mode of Device Example 2 was the same as that of Device Example 1 except that in the emissive layer (EML), Compound B-222 was replaced with Compound B-227.

### Device Example 3

The implementation mode of Device Example 3 was the same as that of Device Example 1 except that in the emissive layer (EML), Compound RD-67 was replaced with Compound RD-2.

### Device Example 4

The implementation mode of Device Example 4 was the same as that of Device Example 2 except that in the emissive layer (EML), Compound RD-67 was replaced with Compound RD-2.

### Device Comparative Example 1

The implementation mode of Device Comparative Example 1 was the same as that of Device Example 1 except that in the emissive layer (EML), Compound B-222 and Compound 1-2-2 were replaced with Compound RH0, where a weight ratio of Compound RH0 to Compound RD-67 was 97:3.

### Device Comparative Example 2

The implementation mode of Device Comparative Example 2 was the same as that of Device Example 3 except that in the emissive layer (EML), Compound B-222 and Compound 1-2-2 were replaced with Compound RH0, where a weight ratio of Compound RH0 to Compound RD-2 was 97:3.

Detailed structures and thicknesses of layers of the devices are shown in Table 2. A layer using more than one material is obtained by doping different compounds at their weight ratio as recorded.

TABLE 2
Part of device structures of Examples 1 to 4 and Comparative Examples 1 and 2

| Device ID | HIL | HTL | EBL | EML | HBL | ETL |
|---|---|---|---|---|---|---|
| Example 1 | Compound HT- | Compound | Compound | Compound 1-2- | Compound | Compound |
| | 1:Compound | HT-1 | EB | 2:Compound B- | B-1 | ET:Liq |
| | HT-2 | (400 Å) | (50 Å) | 222:Compound | (50 Å) | (40:60) |
| | (97:3) | | | RD-67 | | (350 Å) |
| | (100 Å) | | | (38.8:58.2:3) | | |
| | | | | (400 Å) | | |
| Example 2 | Compound HT- | Compound | Compound | Compound 1-2- | Compound | Compound |
| | 1:Compound | HT-1 | EB | 2:Compound B- | B-1 | ET:Liq |
| | HT-2 | (400 Å) | (50 Å) | 227:Compound | (50 Å) | (40:60) |
| | (97:3) | | | RD-67 | | (350 Å) |
| | (100 Å) | | | (38.8:58.2:3) | | |
| | | | | (400 Å) | | |
| Example 3 | Compound HT- | Compound | Compound | Compound 1-2- | Compound | Compound |
| | 1:Compound | HT-1 | EB | 2:Compound B- | B-1 | ET:Liq |
| | HT-2 | (400 Å) | (50 Å) | 222:Compound | (50 Å) | (40:60) |
| | (97:3) | | | RD-2 | | (350 Å) |
| | (100 Å) | | | (38.8:58.2:3) | | |
| | | | | (400 Å) | | |
| Example 4 | Compound HT- | Compound | Compound | Compound 1-2- | Compound | Compound |
| | 1:Compound | HT-1 | EB | 2:Compound B- | B-1 | ET:Liq |
| | HT-2 | (400 Å) | (50 Å) | 227:Compound | (50 Å) | (40:60) |
| | (97:3) | | | RD-2 | | (350 Å) |
| | (100 Å) | | | (38.8:58.2:3) | | |
| | | | | (400 Å) | | |
| Comparative | Compound HT- | Compound | Compound | Compound | Compound | Compound |
| Example 1 | 1:Compound | HT-1 | EB | RHO:Compound | B-1 | ET:Liq |
| | HT-2 | (400 Å) | (50 Å) | RD-67 | (50 Å) | (40:60) |
| | (97:3) | | | (97:3) | | (350 Å) |
| | (100 Å) | | | (400 Å) | | |
| Comparative | Compound HT- | Compound | Compound | Compound | Compound | Compound |
| Example 2 | 1:Compound | HT-1 | EB | RHO:Compoun | B-1 | ET:Liq |
| | HT-2 | (400 Å) | (50 Å) | d RD-2 (97:3) | (50 Å) | (40:60) |
| | (97:3) | | | (400 Å) | | (350 Å) |
| | (100 Å) | | | | | |

The materials used in the devices have the following structures:

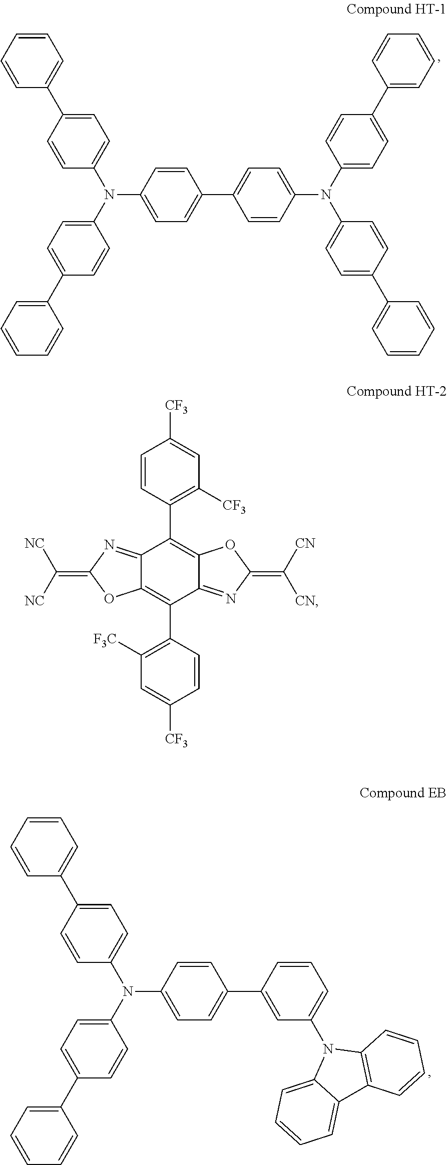 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1 ; c1ccc(-c2ccc(N(c3ccc(-c4ccccc4)cc3)c3ccc(-c4cccc(-n5c6ccccc6c6ccccc65)c4)cc3)cc2)cc1]

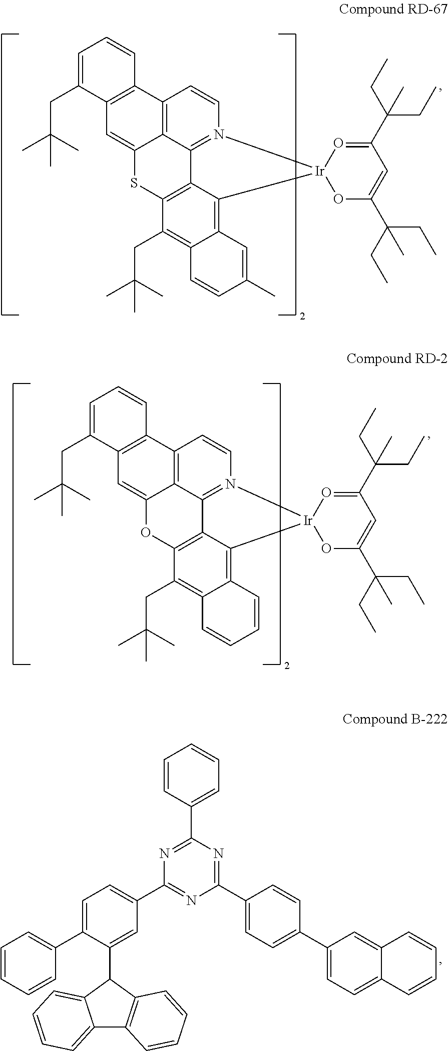

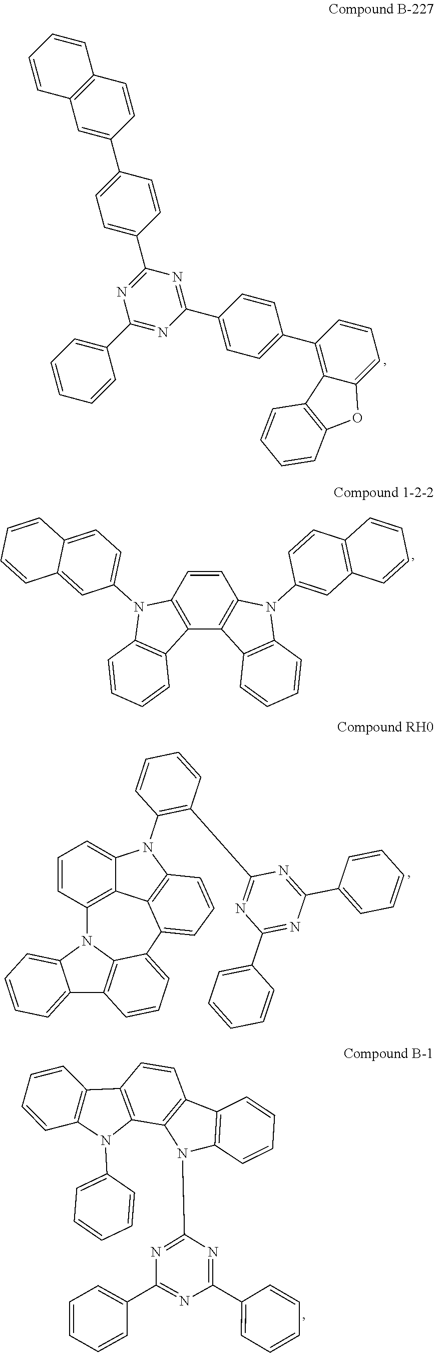 [SMILES: c1ccc(-c2nc(-c3ccc(-c4ccc5ccccc5c4)cc3)nc(-c3ccc(-c4cccc5oc6ccccc6c45)cc3)n2)cc1 ; c1ccc2cc(-n3c4ccccc4c4c5c6ccccc6n(-c6ccc7ccccc7c6)c5ccc43)ccc2c1 ; c1ccc(-c2nc(-c3ccccc3)nc(-c3ccccc3-n3c4cccc5c6cccc7c8ccccc8n(c8cccc3c8c54)c67)n2)cc1 ; c1ccc(-c2nc(-c3ccccc3)nc(-n3c4ccccc4c4ccc5c6ccccc6n(-c6ccccc6)c5c43)n2)cc1]

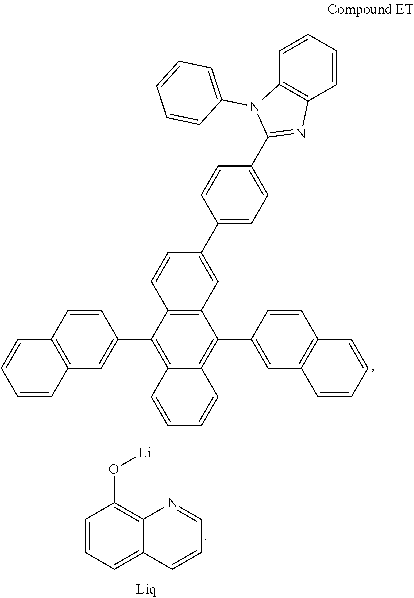

Capacitance testing was performed on the devices by using an impedance analyzer (Keysight E4990A). A direct current bias voltage of −4 V to 5 V was applied to the electrodes at two ends of the device, and a sinusoidal alternating current voltage signal of 100 mV was superimposed at the same time. The testing was performed at alternating current voltages with a frequency of 500 Hz, separately. The C-V curves of the devices were measured, an initial voltage of capacitance (Vₜ and Vₜ₀) and maximum capacitance (Cₘₐₓ and Cₘₐₓ₀) of the devices were obtained, and external quantum efficiency (EQE) of the devices at a current density of 15 mA/cm² was measured. The data are recorded and shown in Table 3.

TABLE 3
Device data of Examples 1 to 4 and Comparative Examples 1 and 2

| | Initial | Maximum | | |
|---|---|---|---|---|
| | Voltage | Capacitance | Cₘₐₓ-Cₘₐₓ₀ | EQE |
| Device ID | [V] | [nF] | [nF] | [%] |
| Example 1 | 1.54 | 1.68 | −0.33 | 26.7 |
| Example 2 | 1.26 | 1.69 | −0.32 | 26.5 |
| Example 3 | 0.77 | 1.99 | −1.02 | 26.8 |
| Example 4 | 1.04 | 2.20 | −0.81 | 26.8 |
| Comparative | 0.91 | 2.01 | 0.00 | 25.4 |
| Example 1 | | | | |
| Comparative | 0.28 | 3.01 | 0.00 | 25.9 |
| Example 2 | | | | |

As can be seen from the data shown in Table 3, Example 1, Example 2, and Comparative Example 1 all used Compound RD-67 of the present disclosure with a ligand having a structure of Formula 1 as an emissive material in the emissive layer, Example 1 used the first host compound 1-2-2 and the second host compound B-222 of the present disclosure as dual host materials in the emissive layer, Example 2 used the first host compound 1-2-2 and the second host compound B-227 of the present disclosure as dual host materials in the emissive layer, and Comparative Example 1 used Compound RH0 as a host material in the emissive layer. Compared with Comparative Example 1, Example 1 and Example 2 both had significantly reduced maximum capacitance, which were reduced by 0.33 nF (that is, the maximum capacitance per unit of emissive area of the device was reduced by 8.25 nF/cm²) and 0.32 nF (that is, the maximum capacitance per unit of emissive area of the device was reduced by 8 nF/cm²), respectively, and the decreases both exceeded 0.20 nF (that is, the maximum capacitance per unit of emissive area of the device was reduced by more than 5 nF/cm²). Additionally, the initial voltages of Example 1 and Example 2 were 1.54 V and 1.26 V respectively, which were 69% and 38% higher than that of Comparative Example 1 respectively, indicating that in Example 1 and Example 2, carriers are less likely to accumulate at a low voltage, which is conducive to the balance of carriers and thus conducive to the reduction of the capacitance. Meanwhile, the EQE of Example 1 and the EQE of Example 2 were as high as 26.7% and 26.5% respectively, which were further significantly improved by 5.1% and 4.3% respectively based on the already extremely high efficiency level of Comparative Example 1, indicating that the use of a combination of the first host compound, the second host compound, and the first metal complex in the device of the present disclosure, especially the use of the first host compound and the second host compound as particular dual host materials, can better balance the carriers in the device, significantly reduce the capacitance of the device, and further improve the EQE.

Example 3, Example 4, and Comparative Example 2 all used Compound RD-2 of the present disclosure with a ligand having a structure of Formula 1 as the emissive material in the emissive layer, Example 3 used the first host compound 1-2-2 and the second host compound B-222 of the present disclosure as the dual host materials in the emissive layer, Example 4 used the first host compound 1-2-2 and the second host compound B-227 of the present disclosure as the dual host materials in the emissive layer, and Comparative Example 2 used RH0 as the host material in the emissive layer. Compared with Comparative Example 2, Example 3 and Example 4 both had significantly reduced maximum capacitance, which were reduced by 1.02 nF (that is, the maximum capacitance per unit of emissive area of the device was reduced by 25.5 nF/cm²) and 0.81 nF (that is, the maximum capacitance per unit of emissive area of the device was reduced by 20.25 nF/cm²), respectively, and the decreases both exceeded 0.20 nF (that is, the maximum capacitance per unit of emissive area of the device was reduced by more than 5 nF/cm²). Additionally, the initial voltages of Example 3 and Example 4 were 0.77 V and 1.04 V respectively, which were greatly improved by 175% and 271% relative to that of Comparative Example 2 respectively, indicating that in Example 3 and Example 4, carriers are less likely to accumulate at a low voltage, which is conducive to the balance of carriers and thus conducive to the reduction of the capacitance. Meanwhile, the EQE of Example 3 and the EQE of Example 4 were both as high as 26.8%, which was further improved by 3.5% based on the already extremely high efficiency level of Comparative Example 2, indicating that the use of the combination of the first host compound, the second host compound, and the first metal complex in the device of the present disclosure, especially the use of the first host compound and the second host compound as particular dual host materials, can better balance the carriers in the device, significantly reduce the capacitance of the device, and further improve the EQE.

The preceding data show that a combination of materials (the combination of the first host compound, the second host compound, and the first metal complex) in the emissive layer of the organic electroluminescent device is selected in the present disclosure so that the balance between electrons and holes in the device can be improved, the capacitance of the device can be reduced, and the device efficiency can be further improved.

To conclude, compared than the device using the widely used Compound RH0 alone as the host material, the device using the metal complex of the present disclosure comprising a ligand Lₐ having a structure of Formula 1 as the emissive material in the emissive layer in combination with the first host compound and the second host compound of the present disclosure as the dual host materials has lower capacitance, which is more conducive to improving a response rate of an OLED display device at a low grayscale and increasing a refresh rate of the device, and the device can further improve the device efficiency. Therefore, the organic electroluminescent device disclosed in the present disclosure has huge advantages and a broad prospect in industrial applications.

It should be understood that various embodiments described herein are merely examples and not intended to limit the scope of the present disclosure. Therefore, it is apparent to those skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

What is claimed is:

1. An organic electroluminescent device, comprising:
a cathode,
an anode, and
an emissive layer disposed between the cathode and the anode, wherein the emissive layer comprises at least a first host compound, a second host compound, and a first metal complex;
and a capacitance property of the organic electroluminescent device satisfies the following condition:
at 500 Hz, a maximum capacitance value of the organic electroluminescent device is Cₘₐₓ, and Cₘₐₓ−Cₘₐₓ₀≤−0.20 nF;
wherein Cₘₐₓ₀ denotes a maximum capacitance value of an organic electroluminescent device A at 500 Hz; and the organic electroluminescent device A is the same as the organic electroluminescent device except that the first host compound and the second host compound in the emissive layer of the organic electroluminescent device are replaced with Compound RH0 as a host compound;
wherein the Compound RH0 has the following structure: 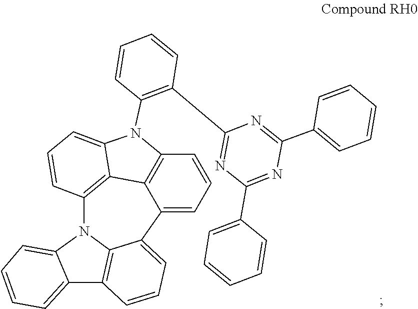 [SMILES: c1ccc(-c2nc(-c3ccccc3)nc(-c3ccccc3-n3c4cccc5c6cccc7c8ccccc8n(c8cccc3c8c54)c67)n2)cc1]
the first metal complex comprises a metal M and a ligand Lₐ coordinated to the metal M, wherein the metal M is selected from a metal with a relative atomic mass greater than 40, and the ligand Lₐ has a structure represented by Formula 1: 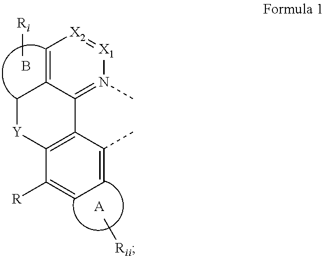
wherein the ring A and the ring B are each independently selected from a five-membered unsaturated carbocyclic ring, an aromatic ring having 6 to 30 carbon atoms, or a heteroaromatic ring having 3 to 30 carbon atoms;
X₁ and X₂ are, at each occurrence identically or differently, selected from CRₓ or N;
Rᵢ and Rᵢᵢ represent, at each occurrence identically or differently, mono-substitution, multiple substitutions, or non-substitution;
at least one of the following two conditions is satisfied:
(1) at least two Rᵢ are joined to form a ring; or
(2) X₁ and X₂ are, at each occurrence identically or differently, selected from CRₓ, and two Rₓ are joined to form a ring;
Y is selected from SiR_{y}R_{y}, GeR_{y}R_{y}, NR_{y}, PR_{y}, O, S, or Se; when two R_{y} are present at the same time, the two R_{y} may be the same or different;
R, Rᵢ, Rᵢᵢ, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, Rᵢ, Rᵢᵢ, Rₓ, R_{y} can be optionally joined to form a ring.

2. The organic electroluminescent device according to claim 1, wherein a lowest unoccupied molecular orbital energy level of the second host compound is E_{LUMO}≤−2.75 eV;
preferably, the lowest unoccupied molecular orbital energy level of the second host compound is E_{LUMO}≤−2.80 eV.

3. The organic electroluminescent device according to claim 1, wherein at 500 Hz, Cₘₐₓ−Cₘₐₓ₀≤−0.30 nF;
preferably, at 500 Hz, Cₘₐₓ−Cₘₐₓ₀≤−0.75 nF.

4. The organic electroluminescent device according to claim 1, wherein at 500 Hz, 0.5 nF≤Cₘₐₓ≤ 5.5 nF;
preferably, 1.0 nF≤Cₘₐₓ≤ 4.0 nF;
more preferably, 1.0 nF≤Cₘₐₓ≤ 3.0 nF.

5. The organic electroluminescent device according to claim 1, wherein at 500 Hz, an initial voltage of capacitance of the organic electroluminescent device is Vₜ, and an initial voltage of capacitance of the organic electroluminescent device A is V_{tA}, which satisfy that 125%≤ Vₜ/V_{tA}; preferably, 130%≤ Vₜ/V_{tA}; more preferably, 150%≤ Vₜ/V_{tA}.

6. The organic electroluminescent device according to claim 1, wherein the first host compound has a structure represented by Formula 2 or Formula 3: 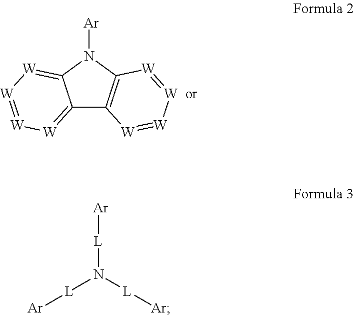
wherein W is, at each occurrence identically or differently, selected from CR_{w} or N, and adjacent substituents R_{w} can be optionally joined to form a ring;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar is, at each occurrence identically or differently, selected from substituted or unsubstituted aryl having 6 to 30 carbon atoms or substituted or unsubstituted heteroaryl having 3 to 30 carbon atoms;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{w} can be optionally joined to form a ring.

7. The organic electroluminescent device according to claim 1, wherein the first host compound has a structure represented by Formula 2-1, Formula 2-2, or Formula 3-1: 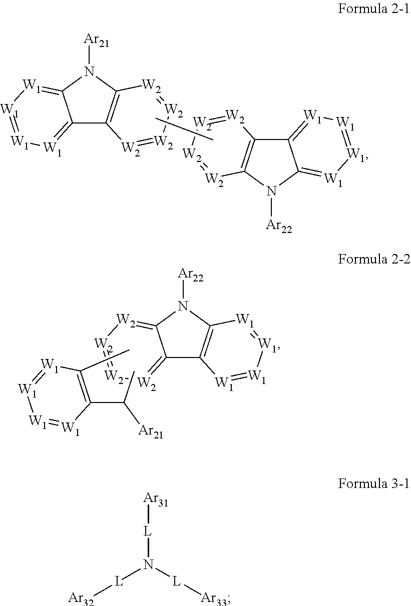
wherein W₁ is, at each occurrence identically or differently, selected from CR_{w} or N;
W₂ is, at each occurrence identically or differently, selected from C, CR_{w}, or N;
L is, at each occurrence identically or differently, selected from a single bond, substituted or unsubstituted arylene having 6 to 30 carbon atoms, substituted or unsubstituted heteroarylene having 3 to 30 carbon atoms, or a combination thereof;
Ar₂₁, Ar₂₂, Ar₃₁, Ar₃₂, and Ar₃₃ are, at each occurrence identically or differently, selected from substituted or unsubstituted aryl having 6 to 30 carbon atoms or substituted or unsubstituted heteroaryl having 3 to 30 carbon atoms;
R_{w} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{w} can be optionally joined to form a ring.

8. The organic electroluminescent device according to claim 1, wherein the second host compound has a structure represented by Formula 4: 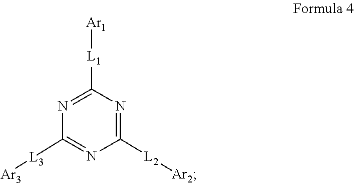
in Formula 4, L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof; and
Ar₁ to Ar₃ are, at each occurrence identically or differently, selected from substituted or unsubstituted aryl having 6 to 30 carbon atoms, substituted or unsubstituted heteroaryl having 3 to 30 carbon atoms, or a combination thereof.

9. The organic electroluminescent device according to claim 1, wherein the second host compound has a structure represented by Formula 4-1-1 or Formula 4-1-2: 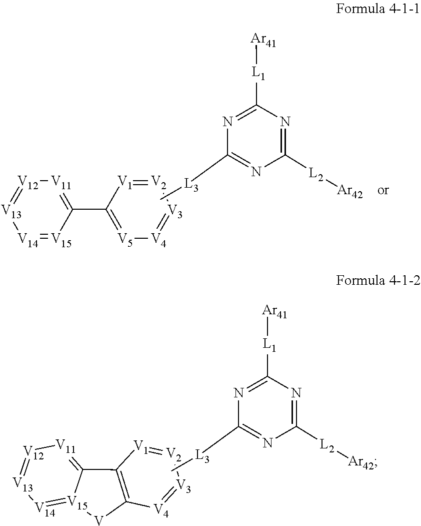
wherein in Formula 4-1-1, V₁ to V₅ are, at each occurrence identically or differently, selected from C, N, or CRᵥ, V₁₁ to Vis are, at each occurrence identically or differently, selected from N or CRᵥ₁, and one of V₁ to V₅ is C and joined to L₃;
in Formula 4-1-2, V₁ to V₄ are, at each occurrence identically or differently, selected from C, N, or CRᵥ, V₁₁ to V₁₄ are, at each occurrence identically or differently, selected from N or CRᵥ₁, and one of V₁ to V₄ is C and joined to L₃;
V is selected from O, S, or Se;
L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms, or a combination thereof;
Ar₄₁ and Ar₄₂ are, at each occurrence identically or differently, selected from substituted or unsubstituted aryl having 6 to 30 carbon atoms, substituted or unsubstituted heteroaryl having 3 to 30 carbon atoms, or a combination thereof;
Rᵥ and Rᵥ₁ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rᵥ, Rᵥ₁ can be optionally joined to form a ring.

10. The organic electroluminescent device according to claim 1, wherein in the ligand Lₐ of the first metal complex, the ring A and/or the ring B are each independently selected from a five-membered unsaturated carbocyclic ring, an aromatic ring having 6 to 18 carbon atoms, or a heteroaromatic ring having 3 to 18 carbon atoms;
preferably, the ring A and/or the ring B are each independently selected from a five-membered unsaturated carbocyclic ring, an aromatic ring having 6 to 10 carbon atoms, or a heteroaromatic ring having 3 to 10 carbon atoms.

11. The organic electroluminescent device according to claim 1, wherein Lₐ is selected from a structure represented by any one of Formula 1-a to Formula 1-k: 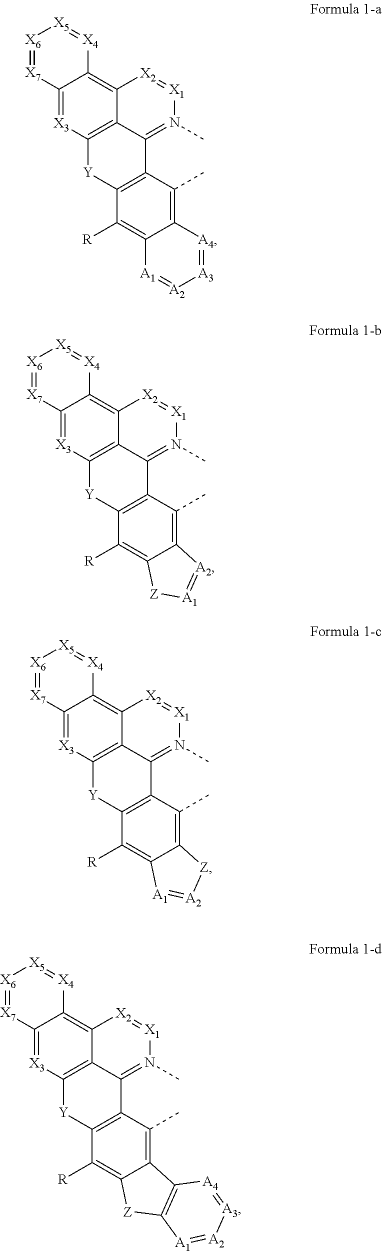 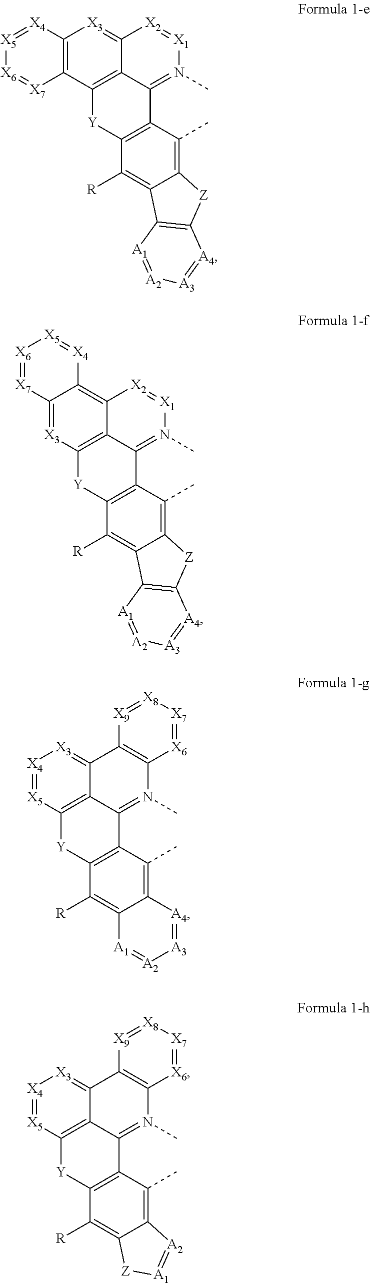 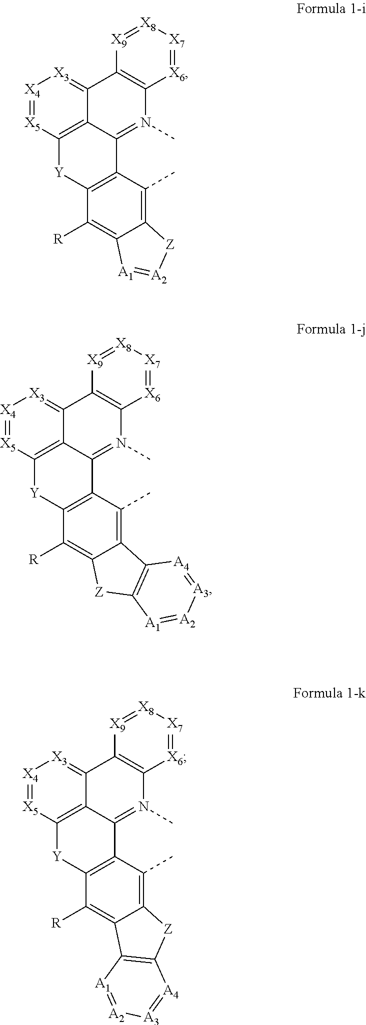
wherein in Formula 1-a to Formula 1-f, X₁ and X₂ are, at each occurrence identically or differently, selected from CRₓ or N, X₃ to X₇ are, at each occurrence identically or differently, selected from CRᵢ or N, and A₁ to A₄ are, at each occurrence identically or differently, selected from CRᵢᵢ or N;
in Formula 1-g to Formula 1-k, X₃ to X₉ are, at each occurrence identically or differently, selected from CRᵢ or N, and A₁ to A₄ are, at each occurrence identically or differently, selected from CRᵢᵢ or N;
Z is, at each occurrence identically or differently, selected from CRᵢᵢᵢRᵢᵢᵢ, SiRᵢᵢᵢRᵢᵢᵢ, PRᵢᵢᵢ, O, S, or NRᵢᵢᵢ; when two Rᵢᵢᵢ are present at the same time, the two Rᵢᵢᵢ are the same or different;
Y is selected from SiR_{y}R_{y}, NR_{y}, PR_{y}, O, S, or Se; when two R_{y} are present at the same time, the two R_{y} are the same or different;
R, Rₓ, R_{y}, Rᵢ, Rᵢᵢ, and Rᵢᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, Rₓ, R_{y}, Rᵢ, Rᵢᵢ, and Rᵢᵢᵢ can be optionally joined to form a ring;
preferably, Lₐ is selected from a structure represented by Formula 1-a.

12. The organic electroluminescent device according to claim 11, wherein in Formula 1-a to Formula 1-f, X₁ and X₂ are each independently selected from CRₓ, X₃ to X₇ are, at each occurrence identically or differently, selected from CRᵢ, and A₁ to A₄ are each independently selected from CRᵢᵢ; in Formula 1-g to Formula 1-k, X₃ to X₉ are each independently selected from CRᵢ, and A₁ to A₄ are each independently selected from CRᵢᵢ; and adjacent substituents Rₓ, Rᵢ, Rᵢᵢ can be optionally joined to form a ring;
preferably, Rₓ, Rᵢ, and Rᵢᵢ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof;
more preferably, at least one or two of R_{y}, Rᵢ, and Rᵢᵢ are, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, cyano, and combinations thereof.

13. The organic electroluminescent device according to claim 11, wherein in Formula 1-a to Formula 1-k, R is selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, or a combination thereof;
preferably, R is selected from hydrogen, deuterium, fluorine, methyl, ethyl, isopropyl, isobutyl, t-butyl, cyclopentyl, cyclopentylmethyl, cyclohexyl, neopentyl, deuterated methyl, deuterated ethyl, deuterated isopropyl, deuterated isobutyl, deuterated t-butyl, deuterated cyclopentyl, deuterated cyclopentylmethyl, deuterated cyclohexyl, deuterated neopentyl, trimethylsilyl, or a combination thereof.

14. The organic electroluminescent device according to claim 11, wherein in Formula 1-a to Formula 1-k, Y is selected from O or S.

15. The organic electroluminescent device according to claim 1, wherein the ligand Lₐ is, at each occurrence identically or differently, selected from the group consisting of Lₐ₁ to Lₐ₄₀₂: 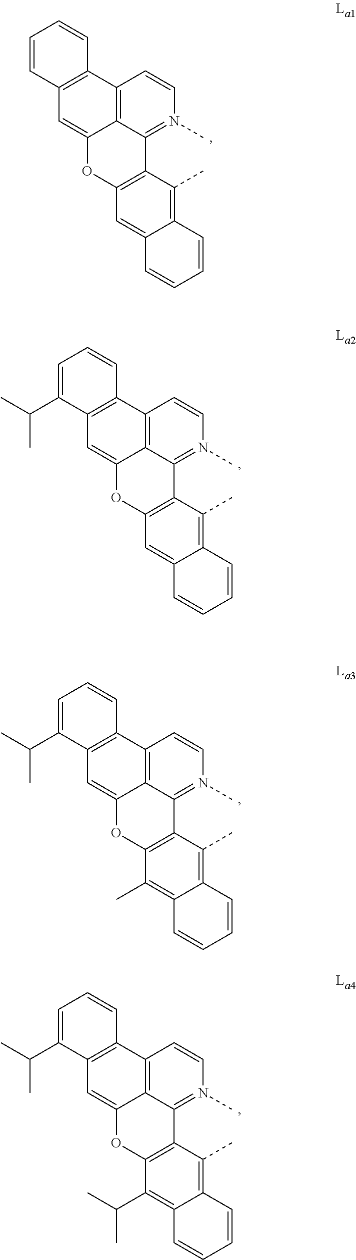 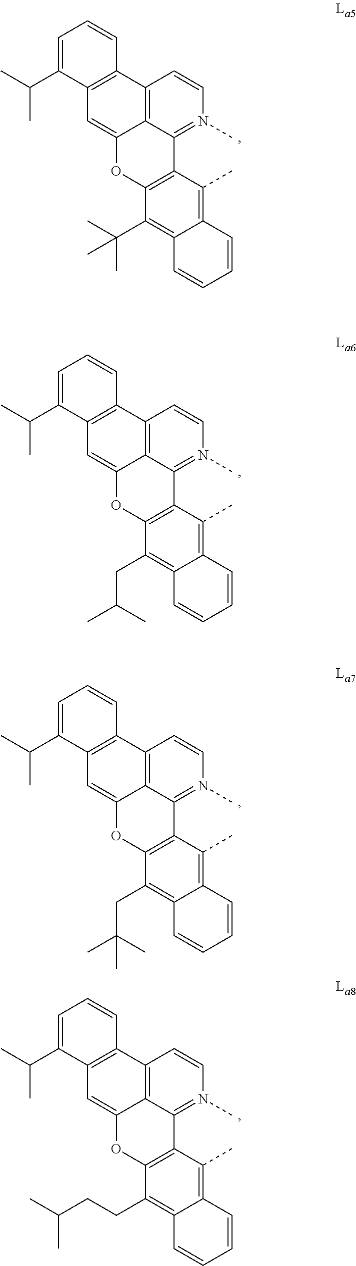 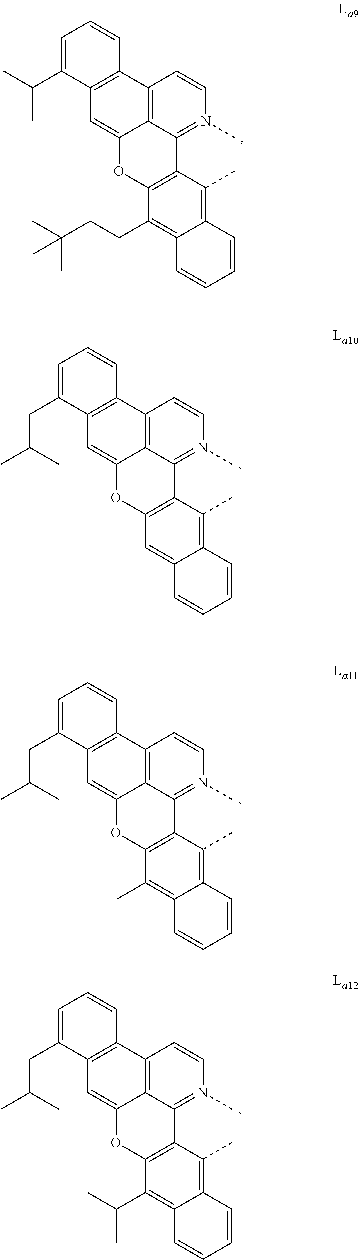 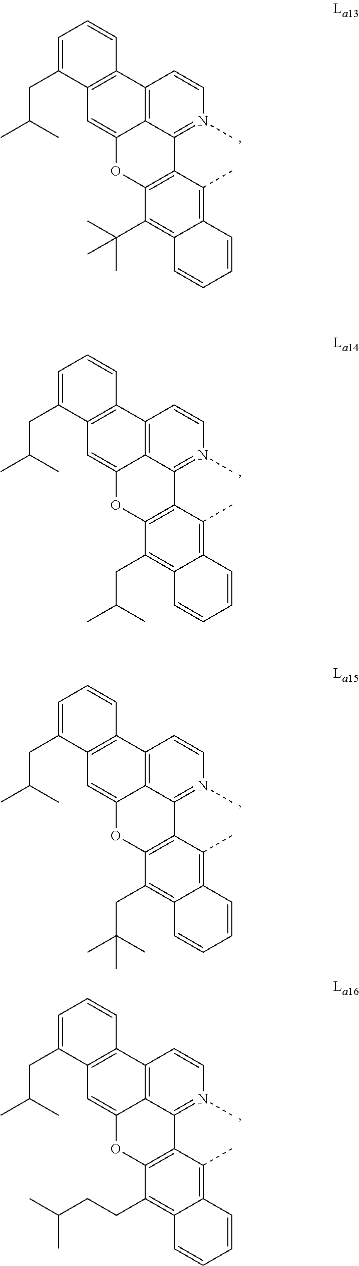 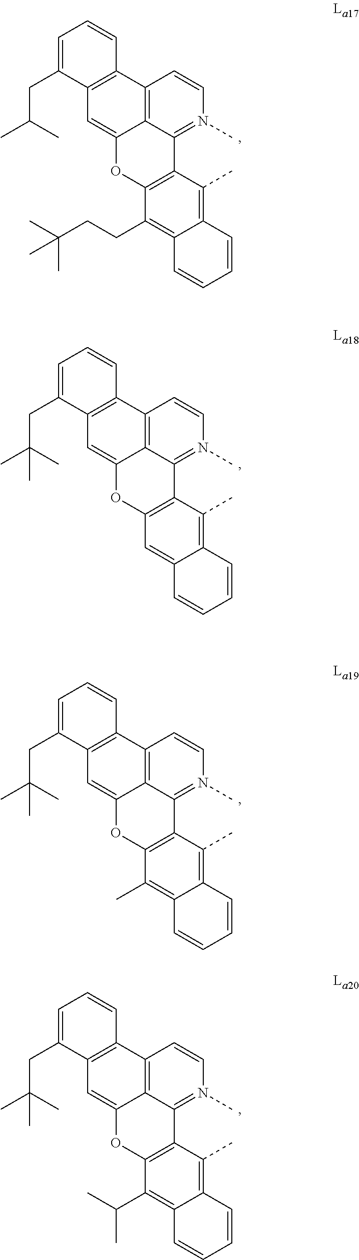 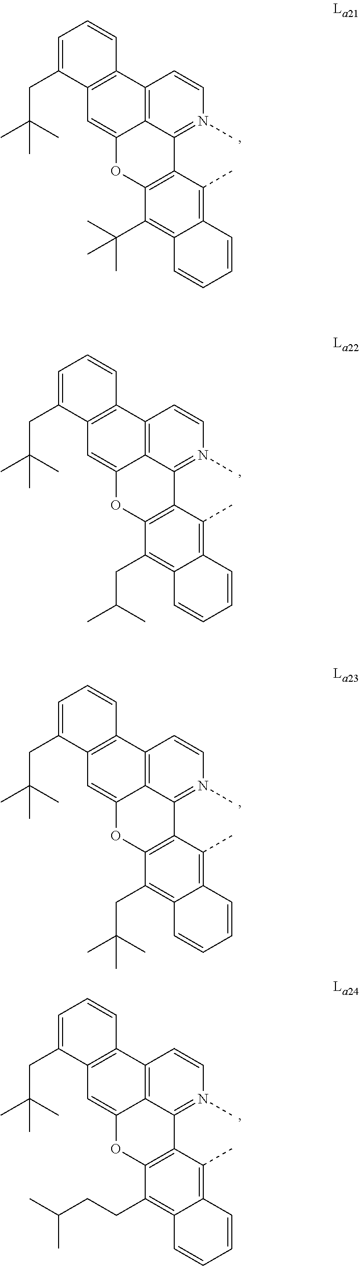 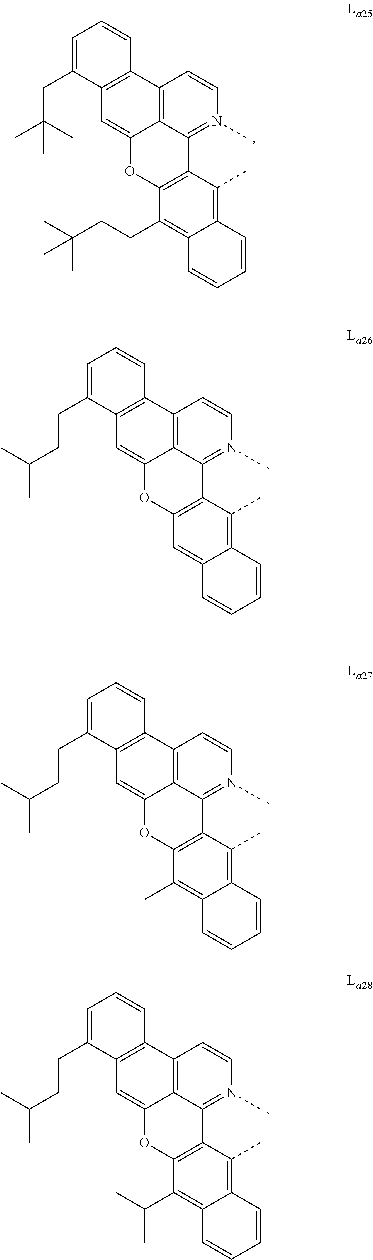 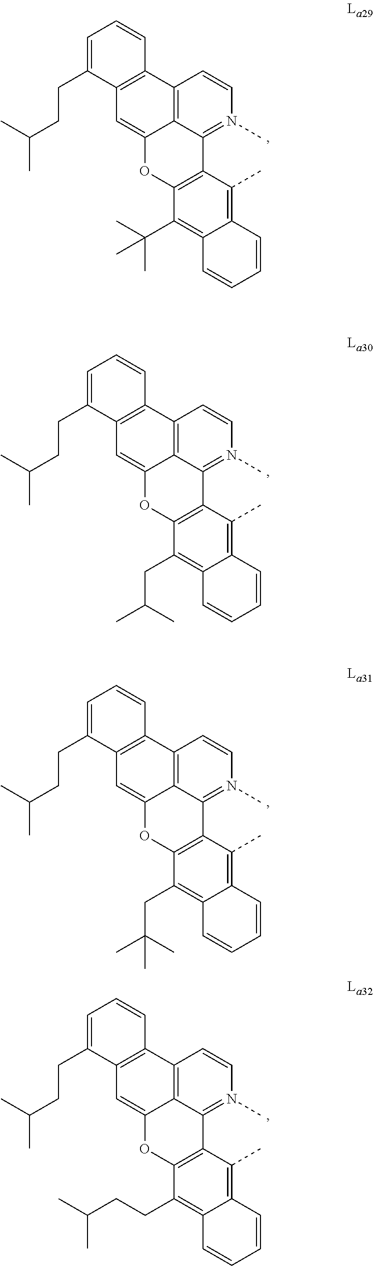 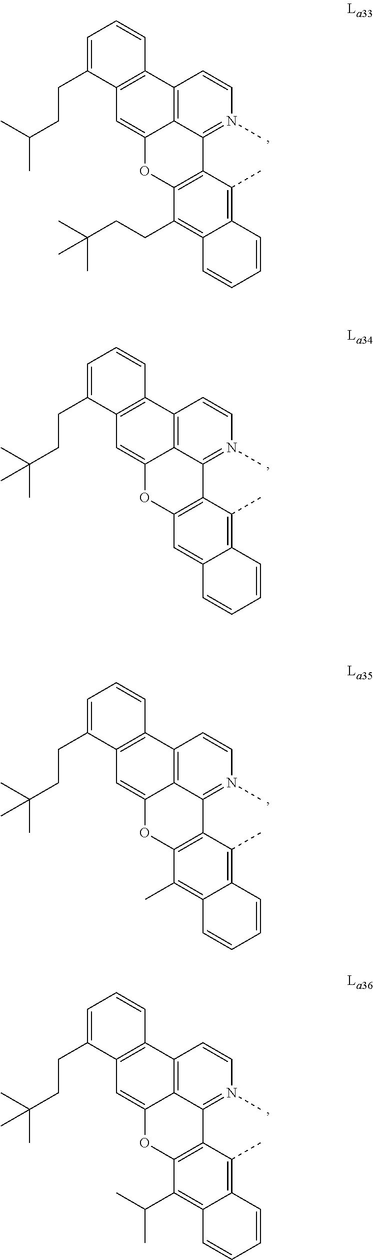 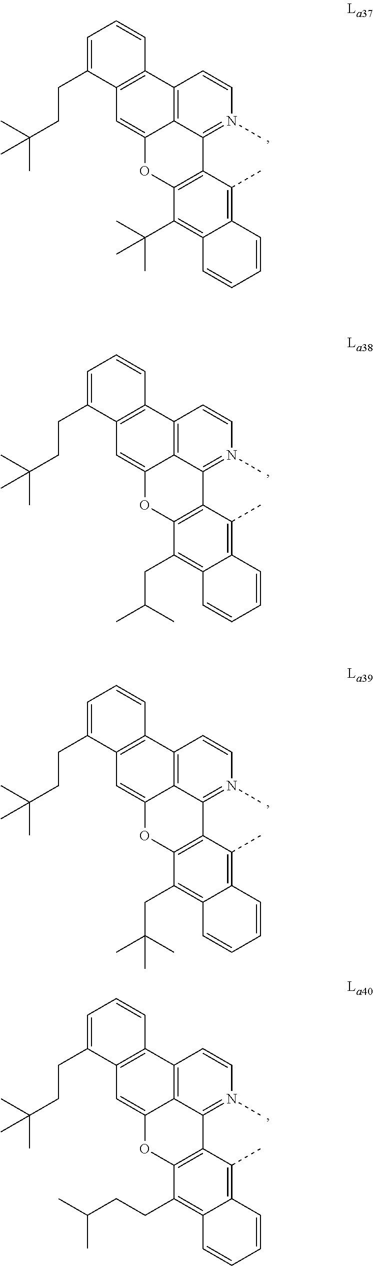 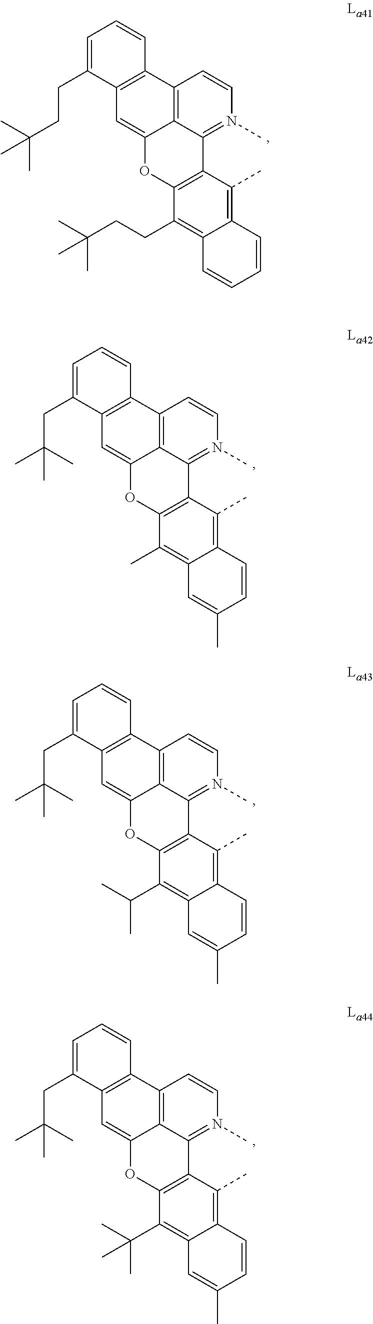 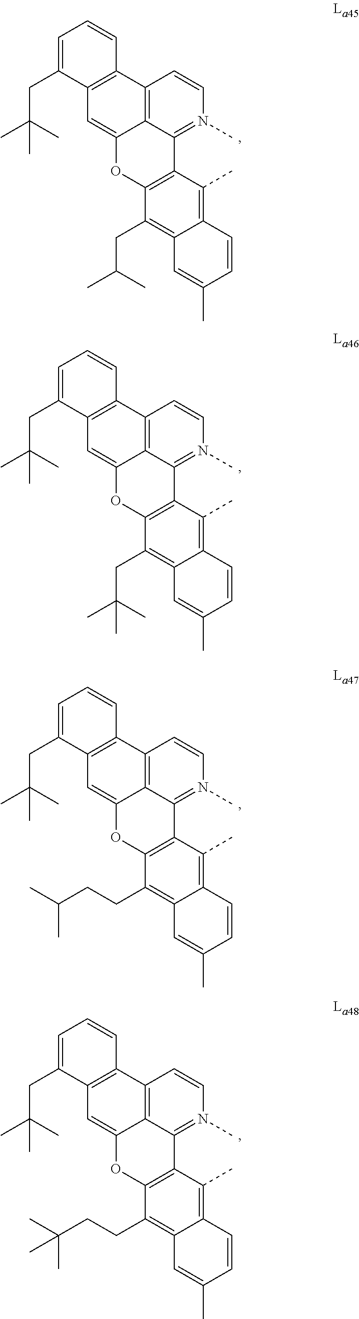 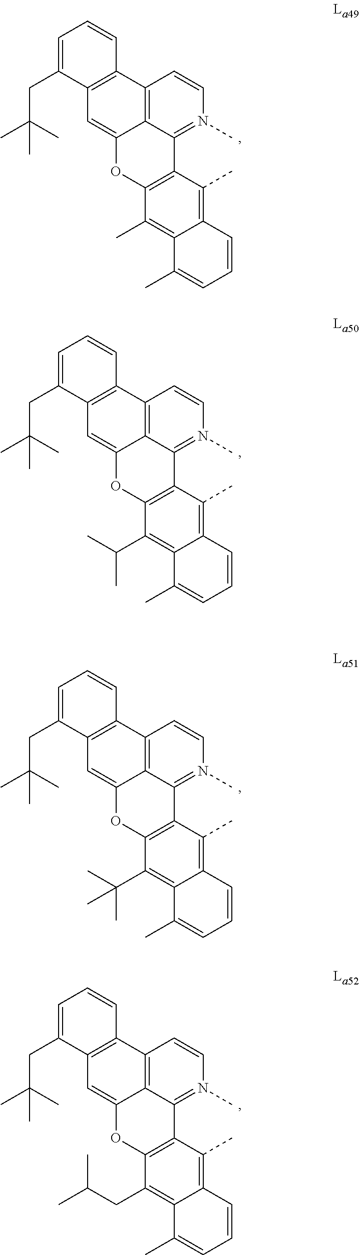 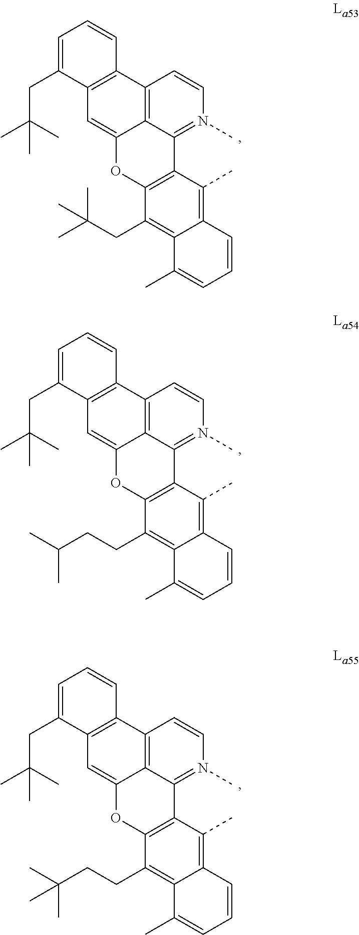 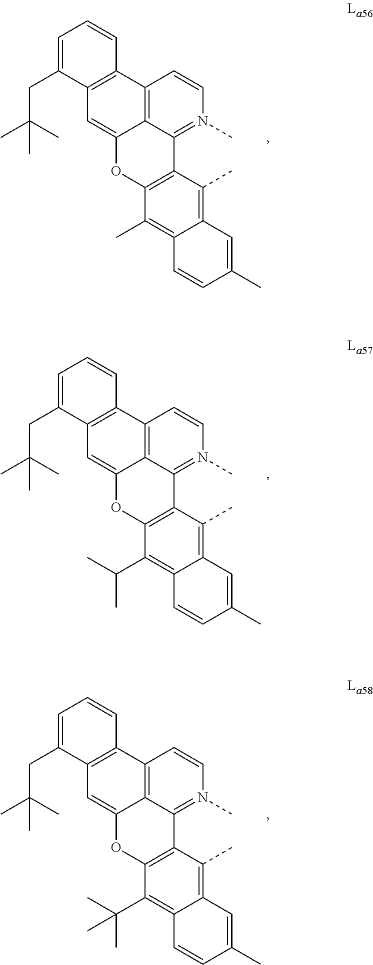 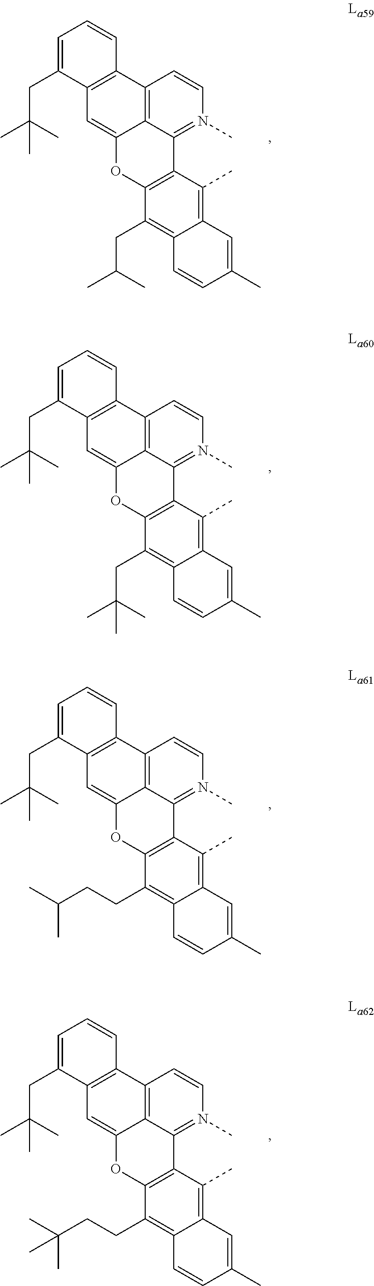 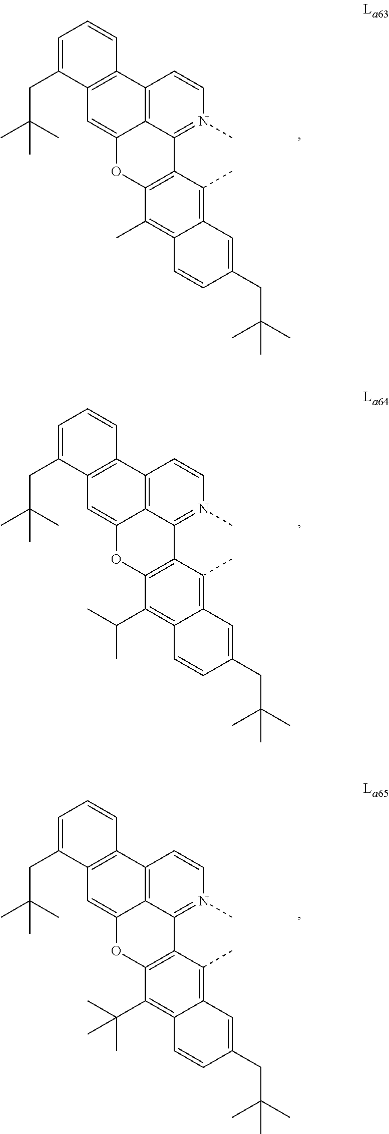 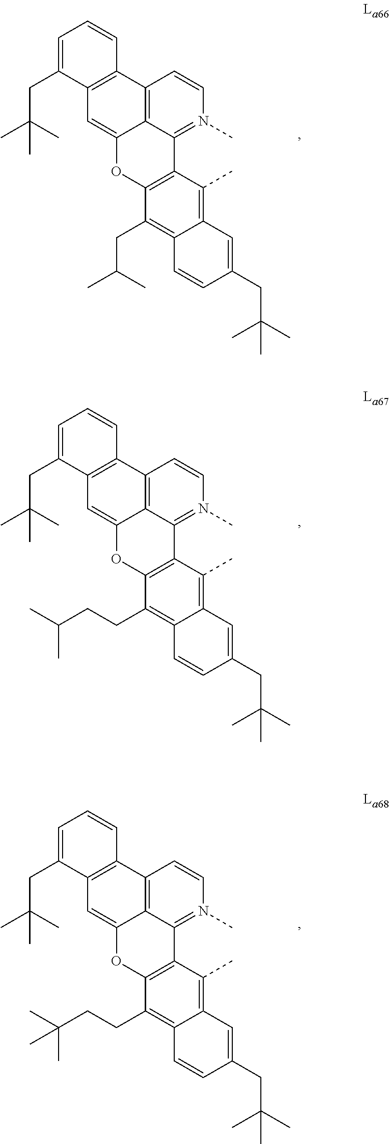 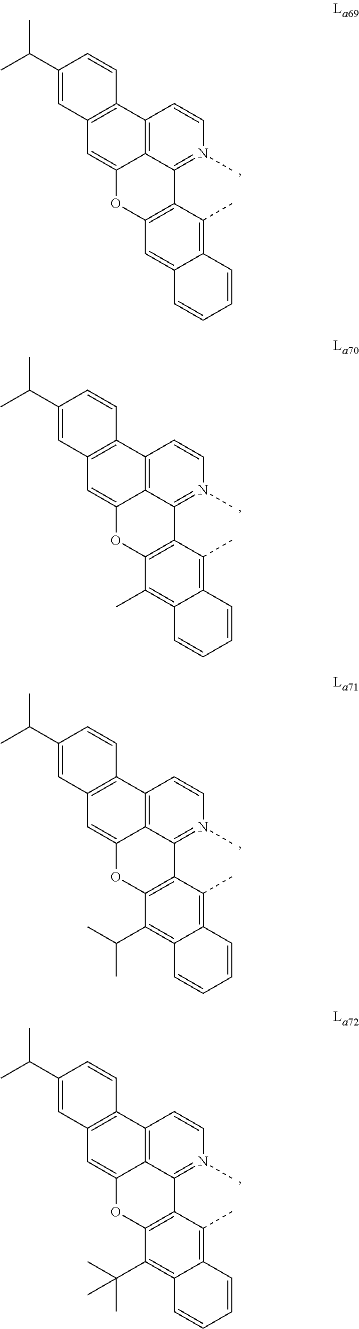 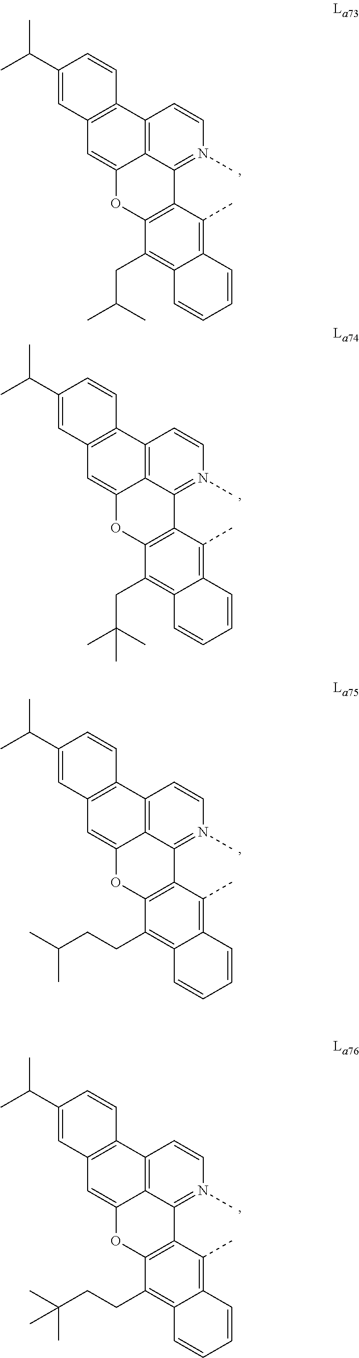 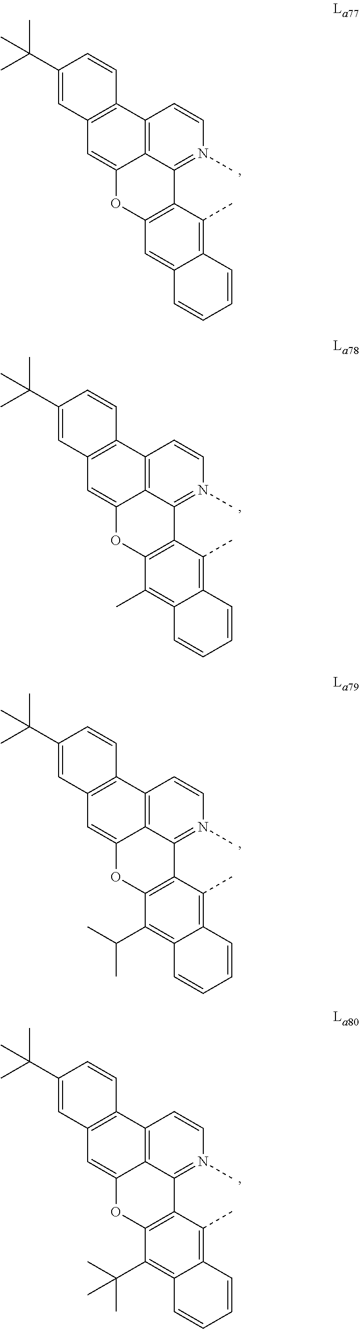 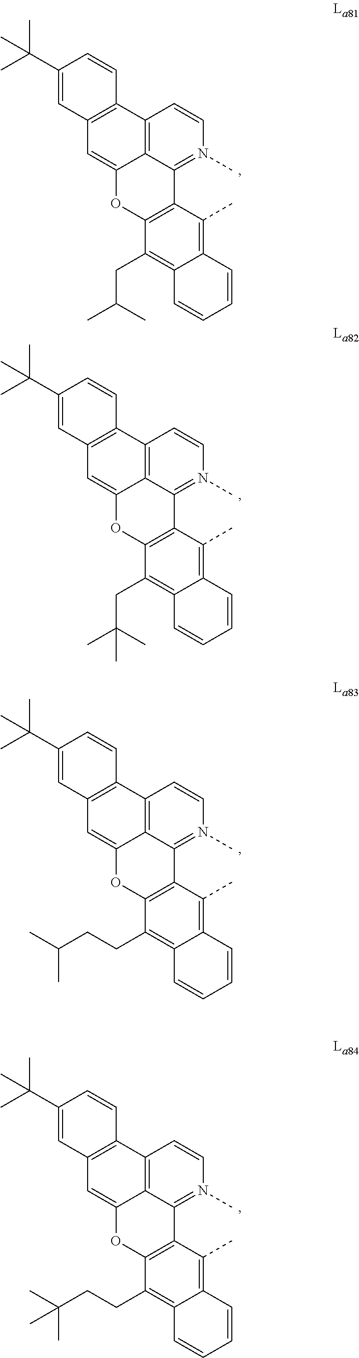 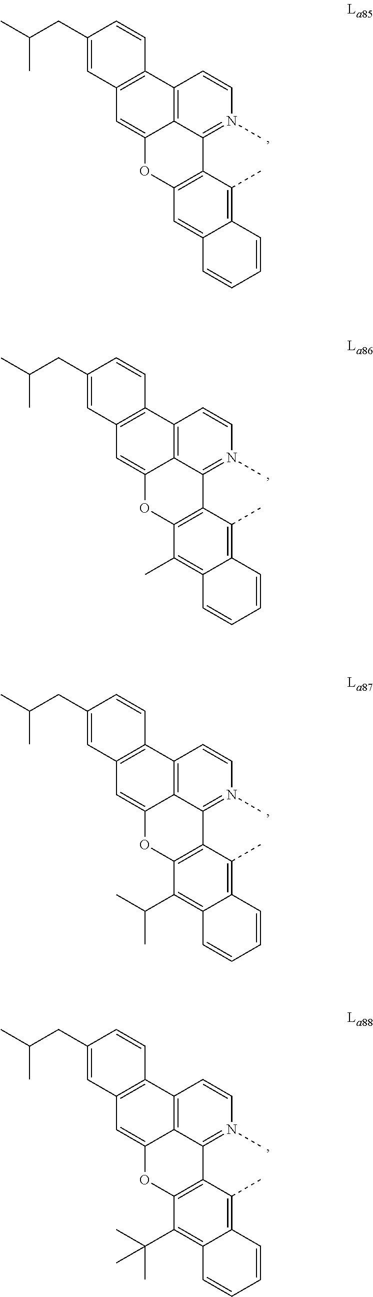 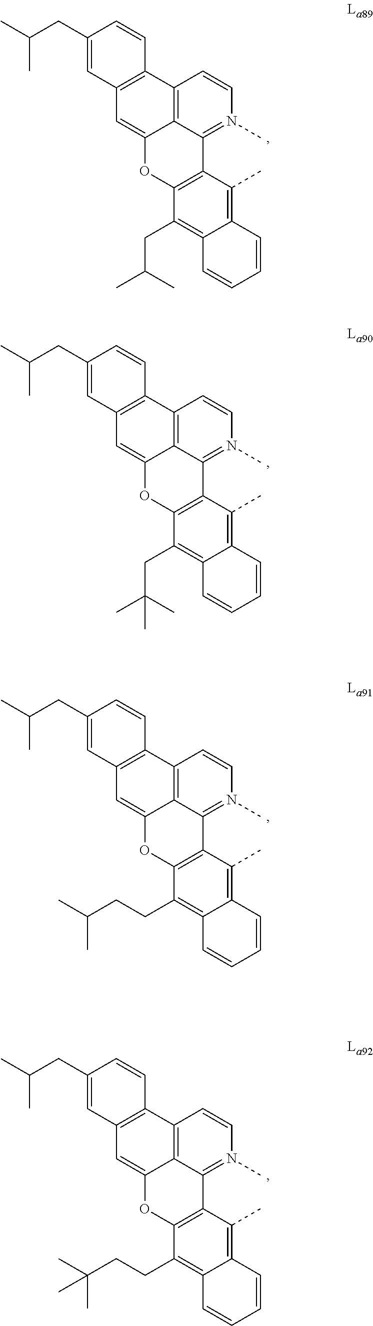 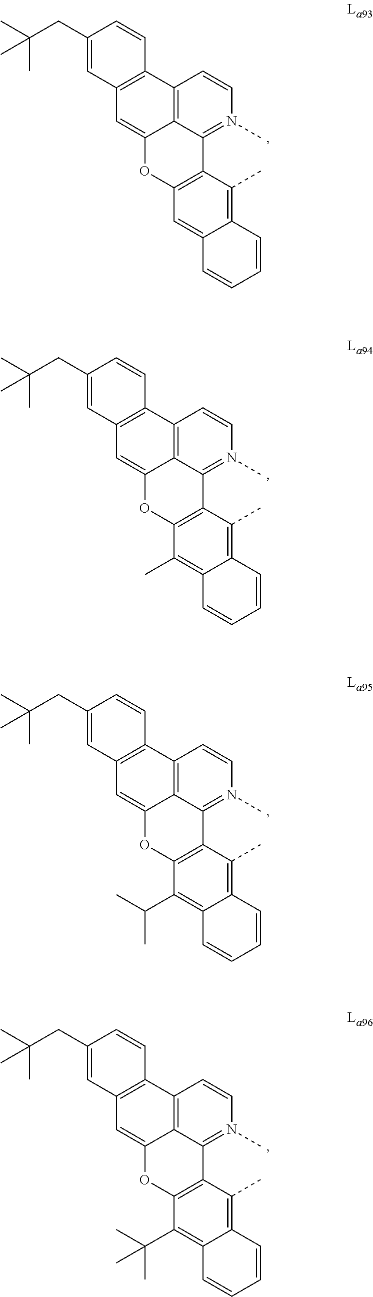 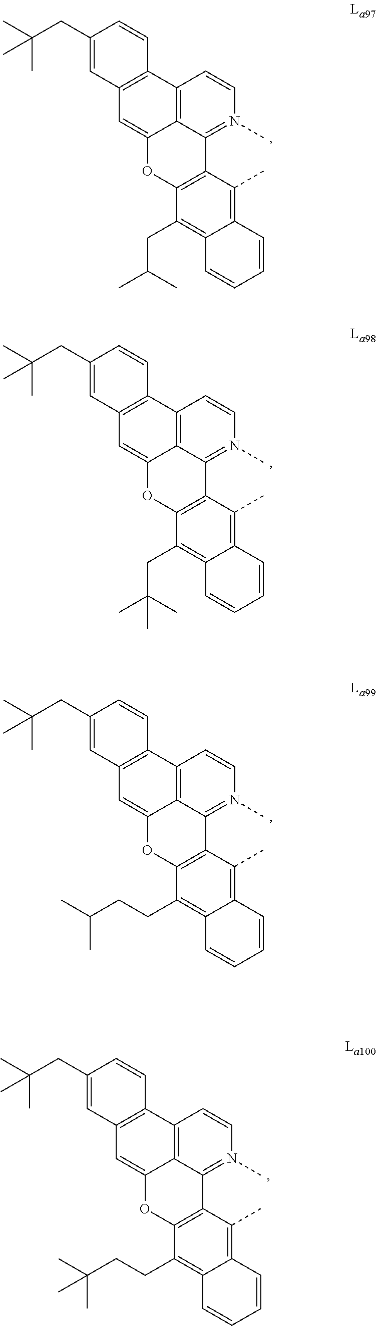 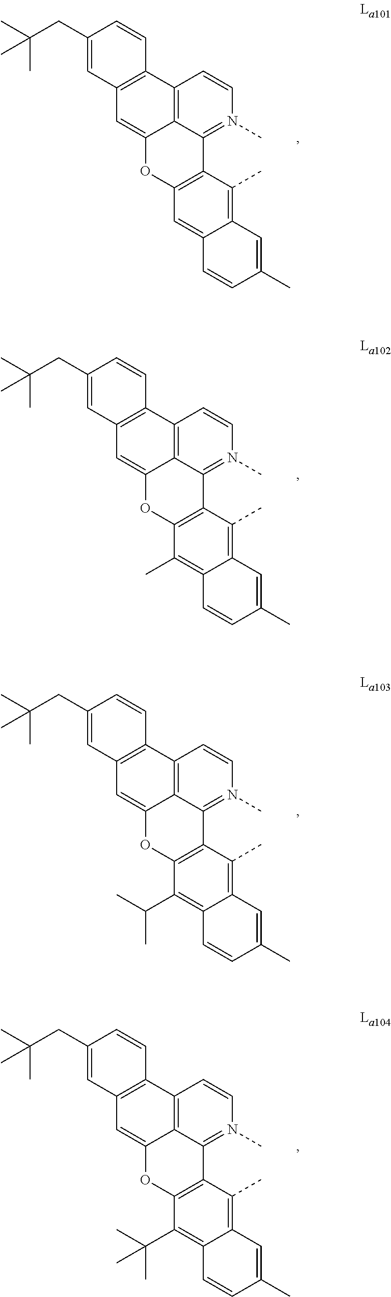 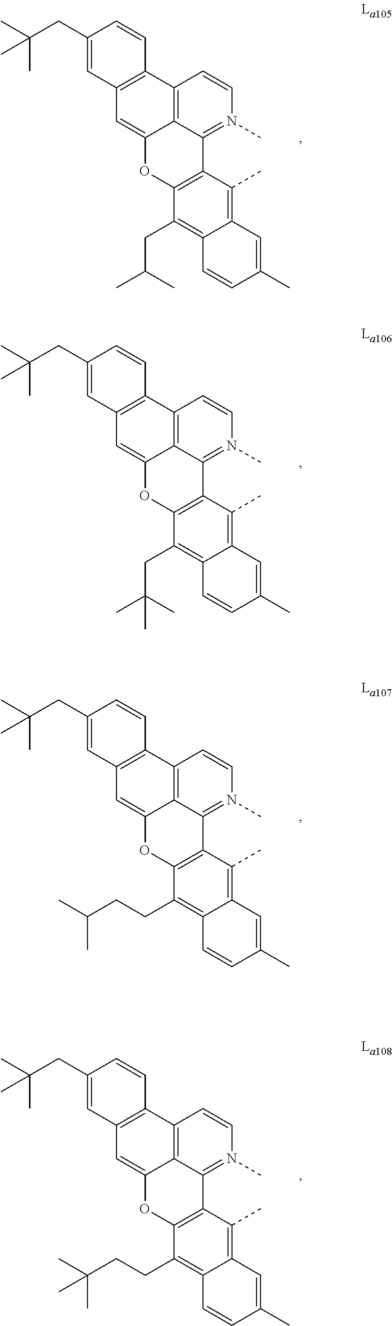 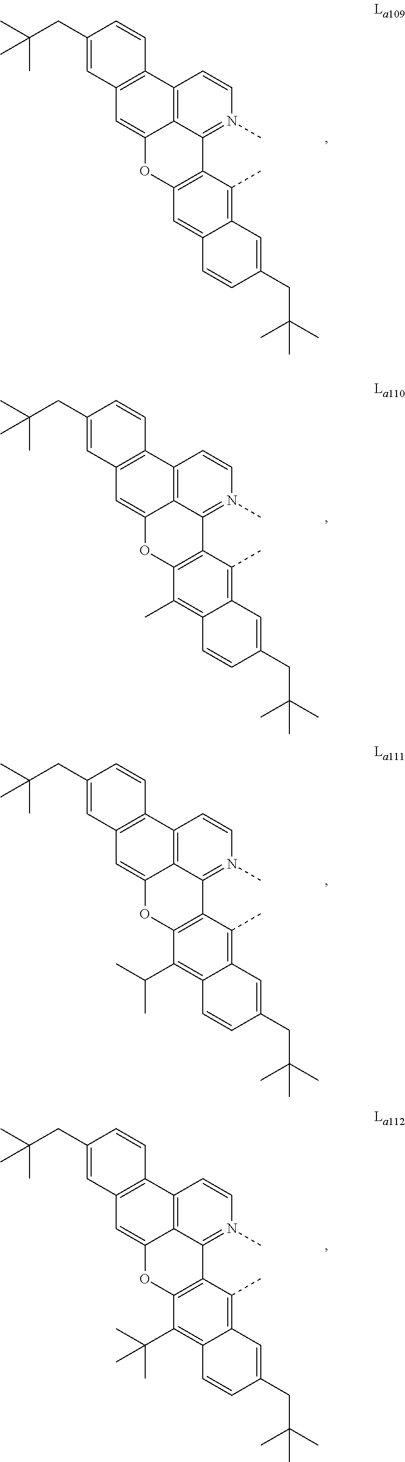 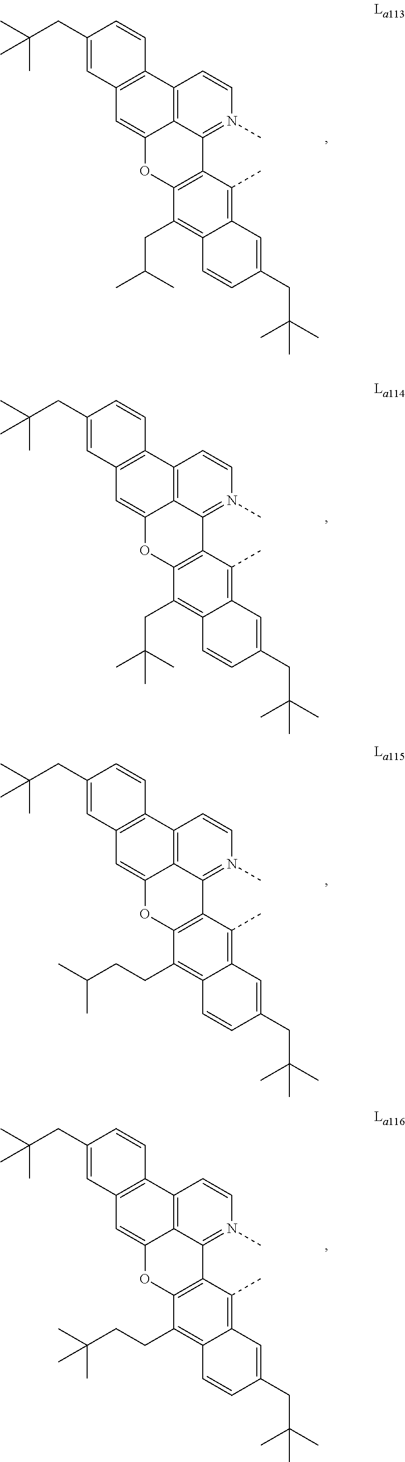 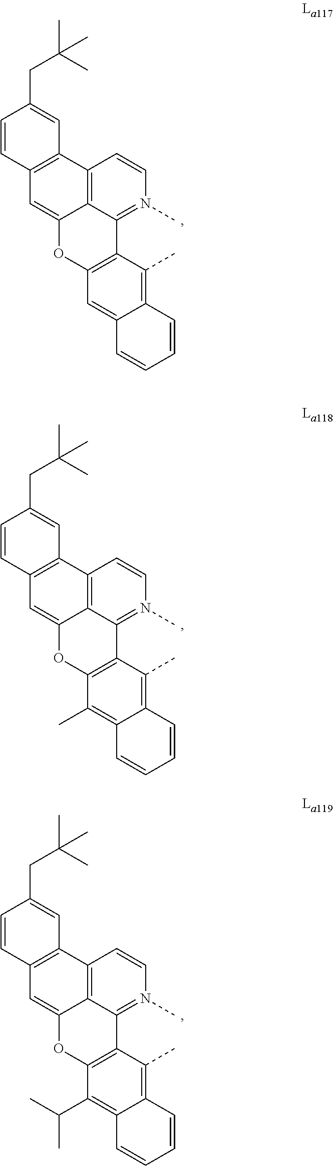 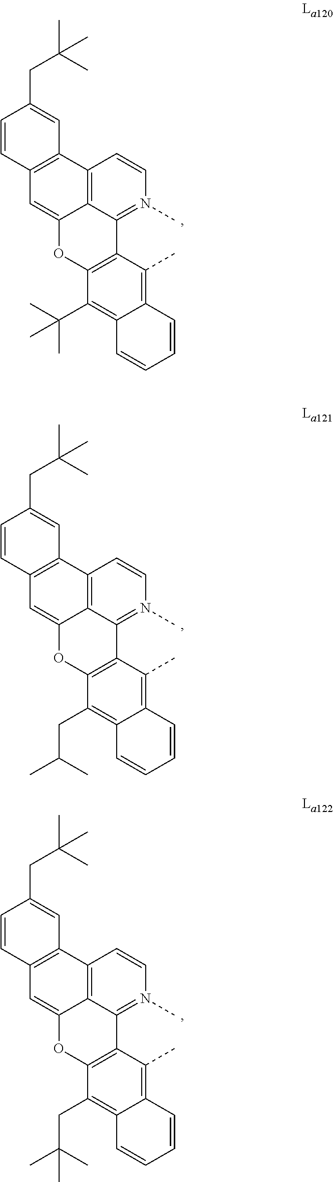 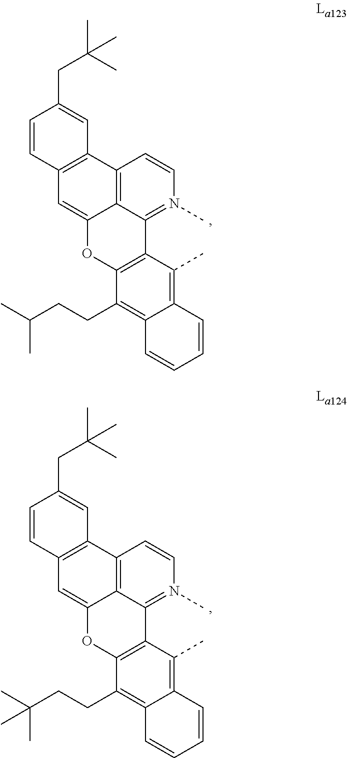 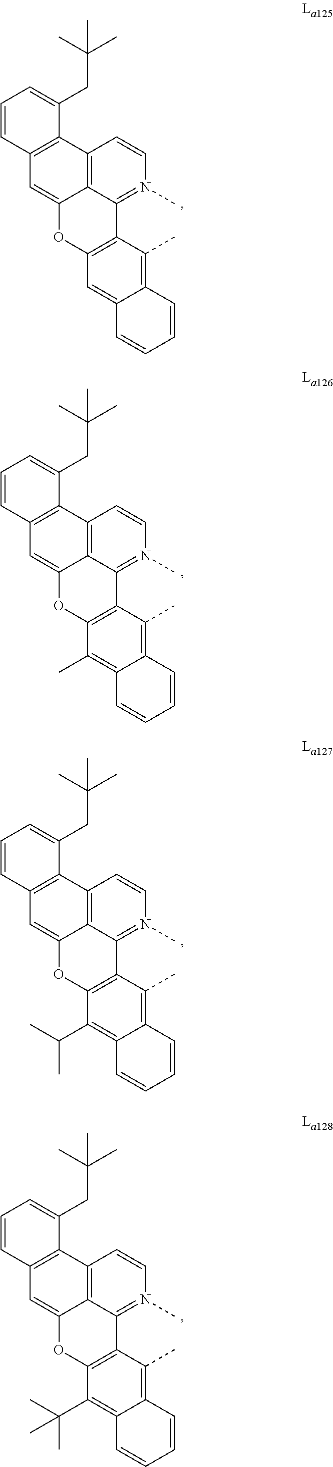 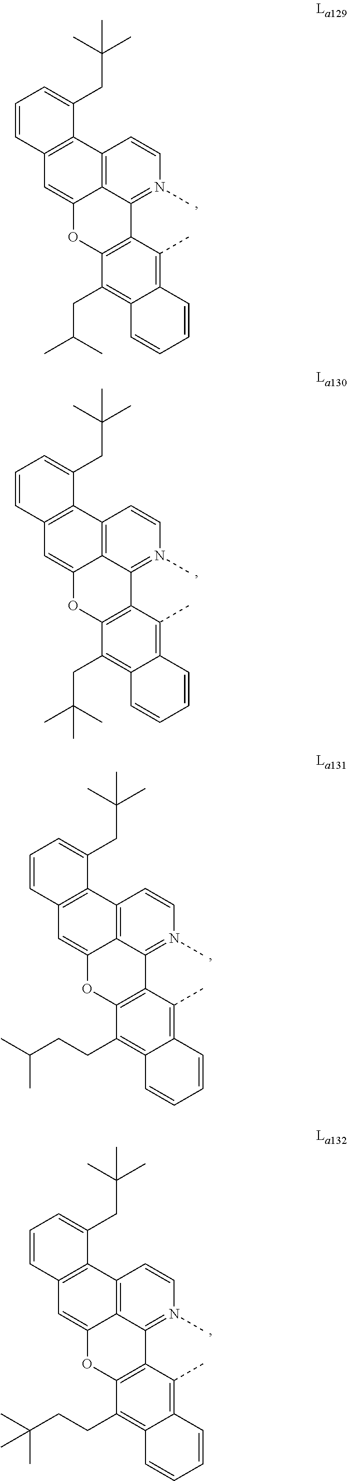 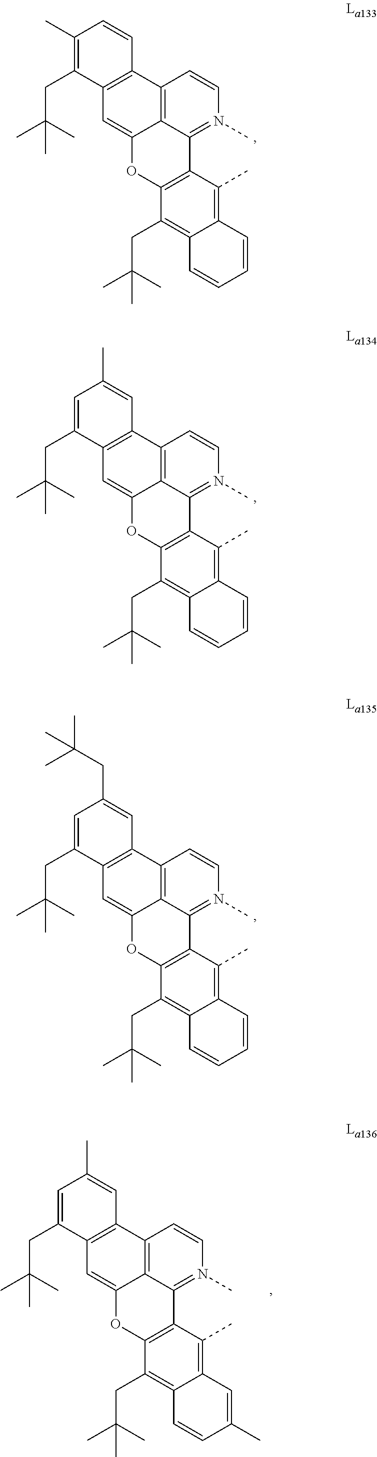 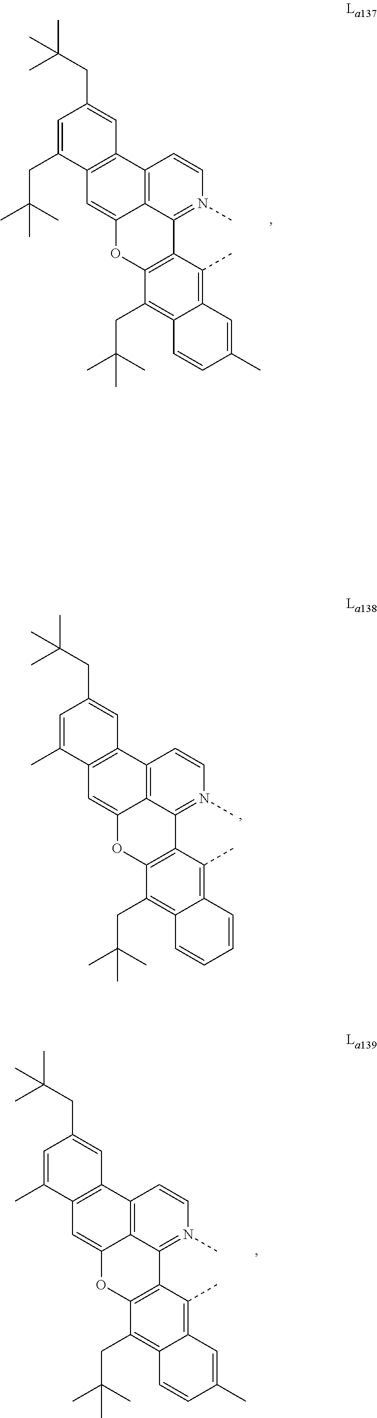 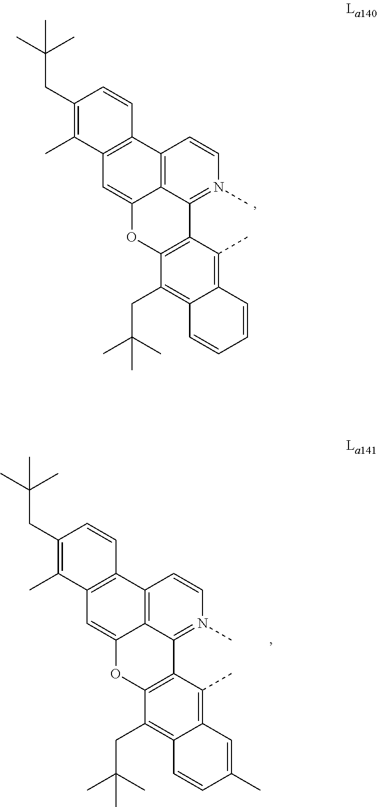 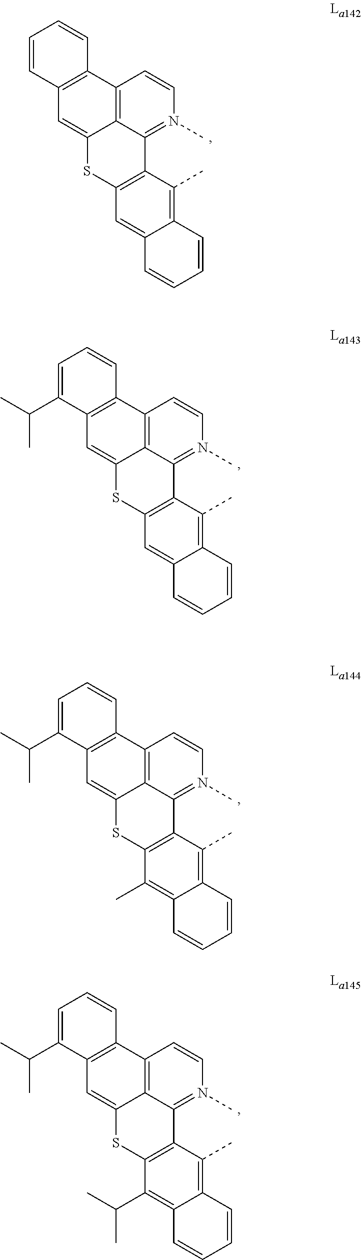 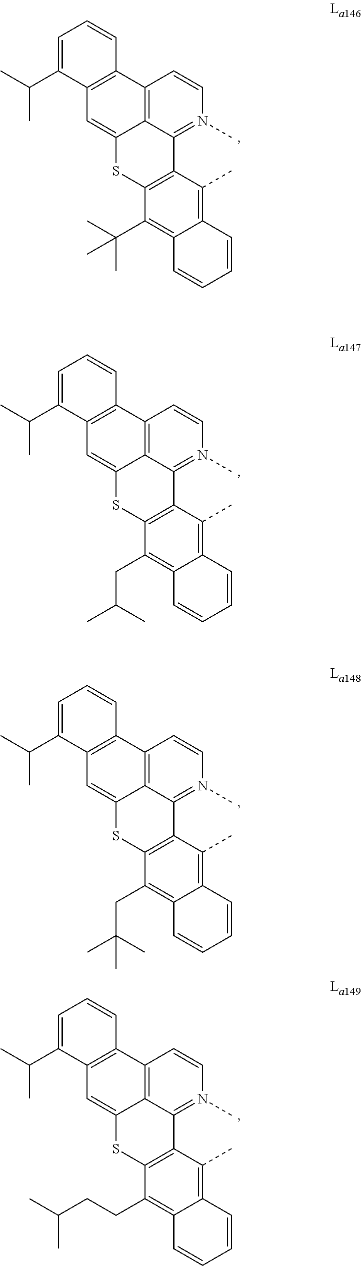 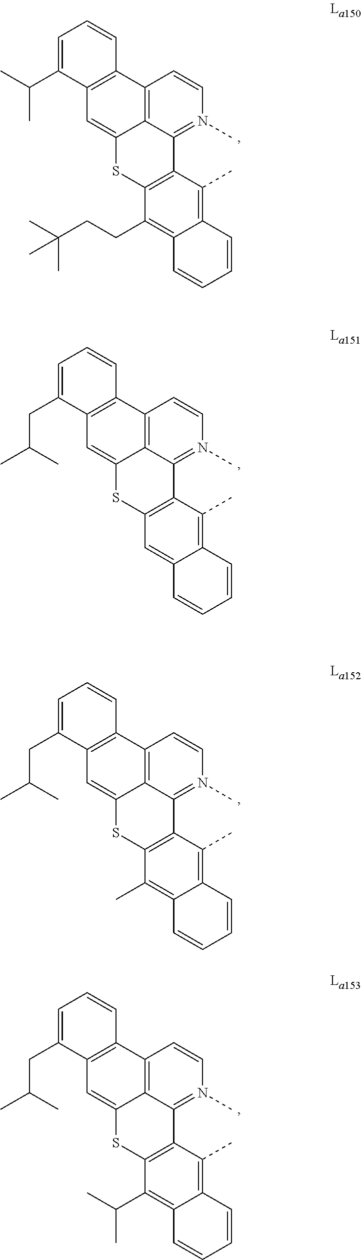 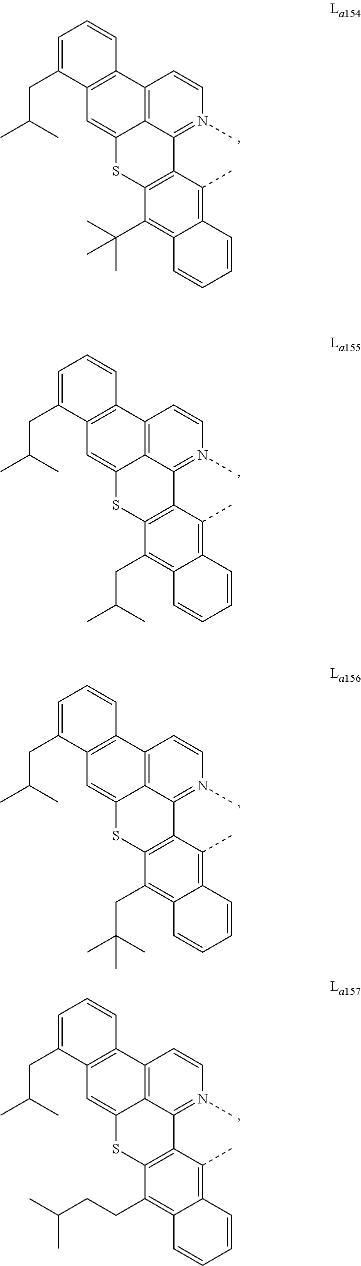 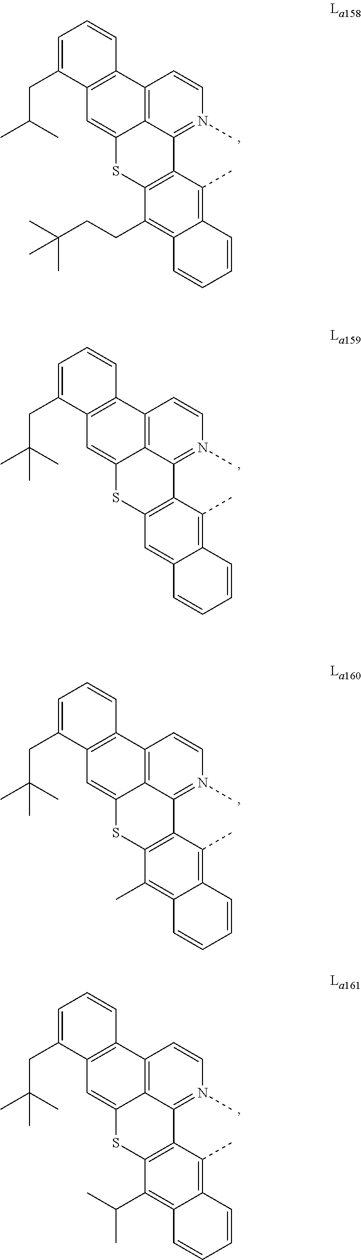 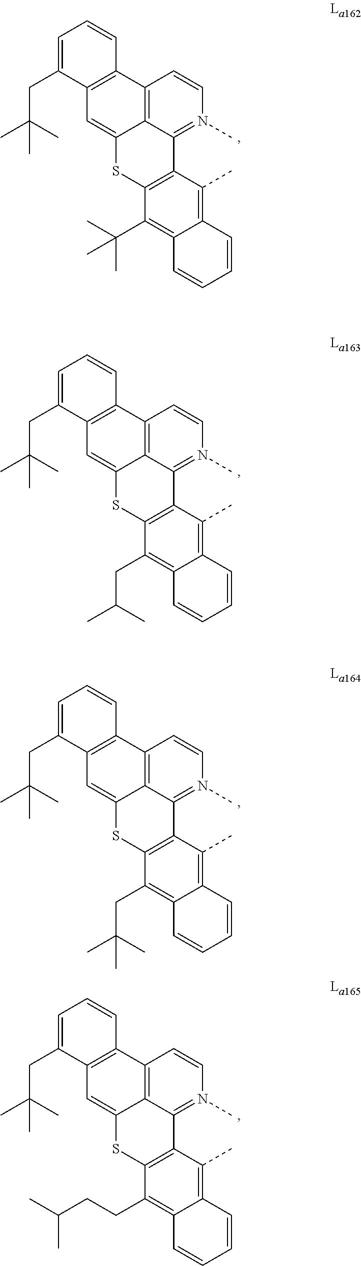 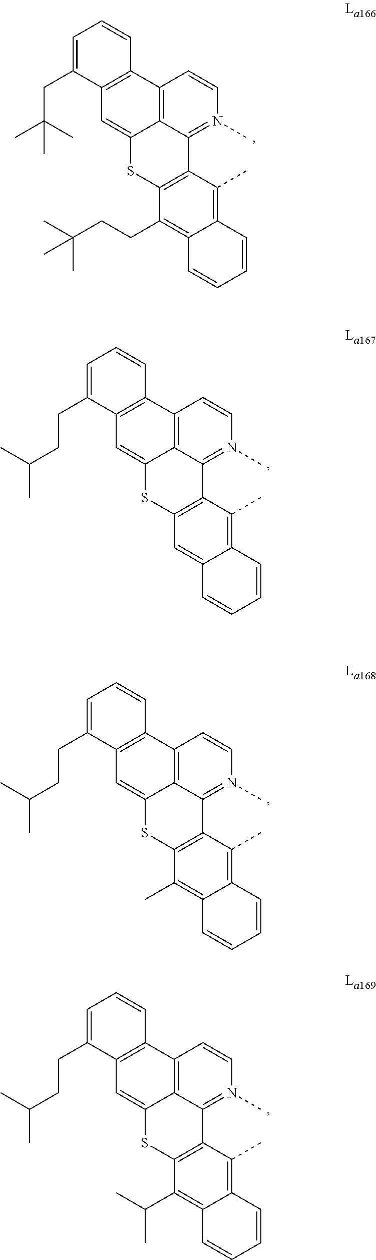 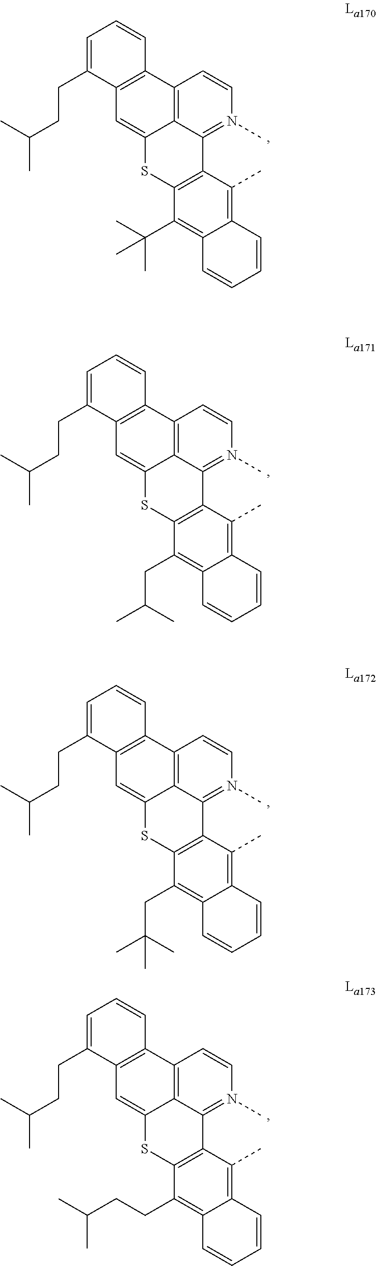 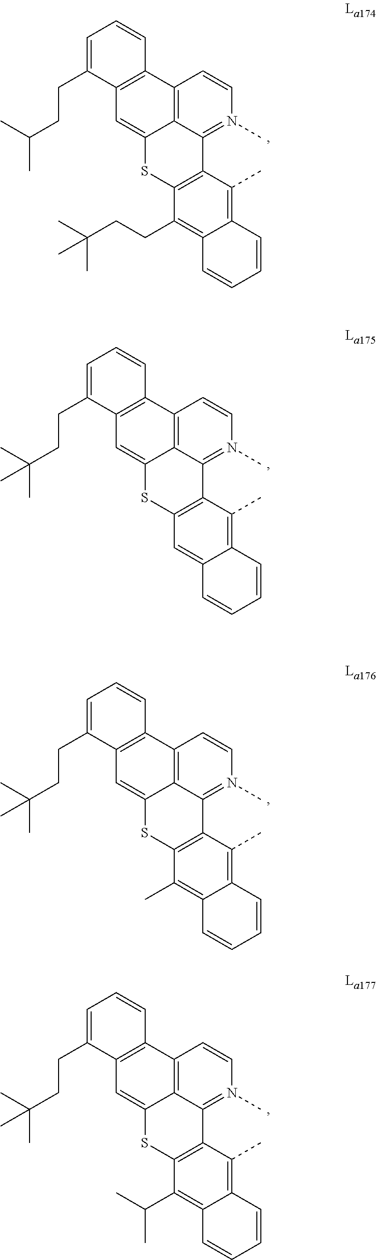 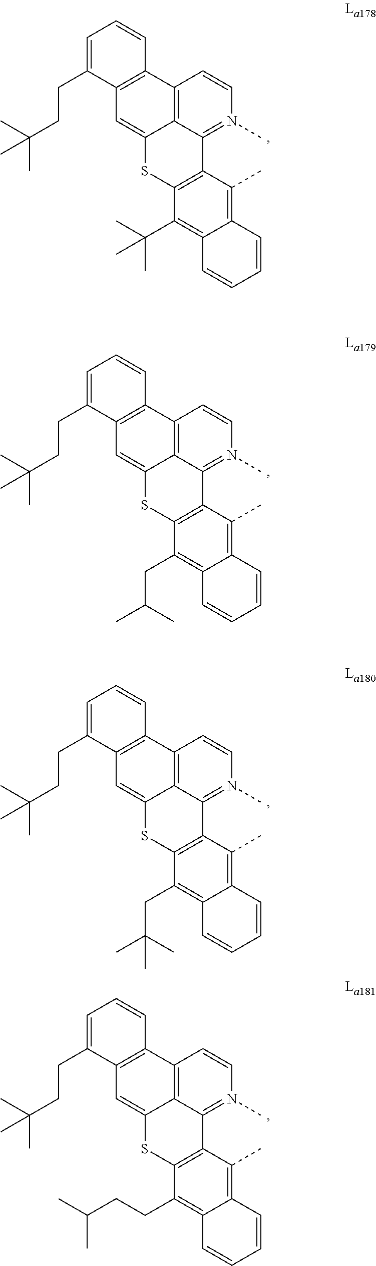 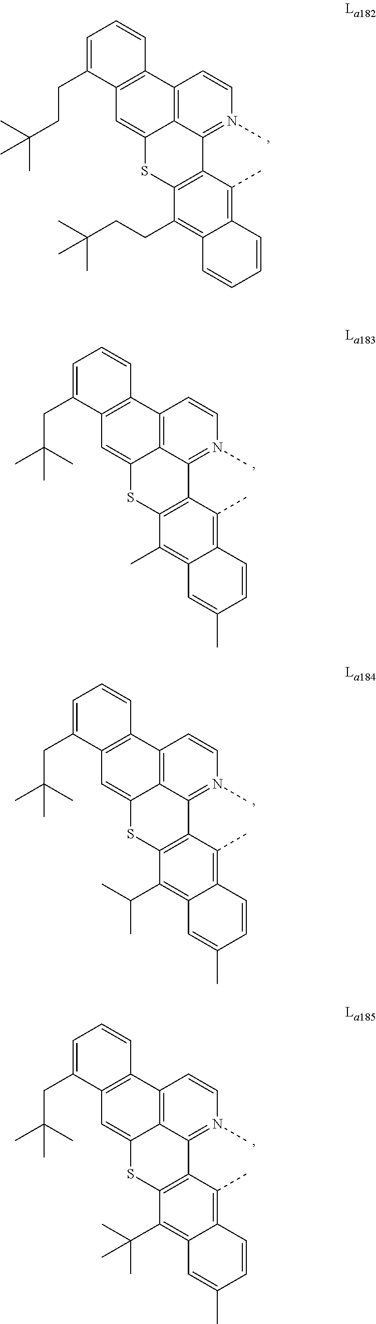 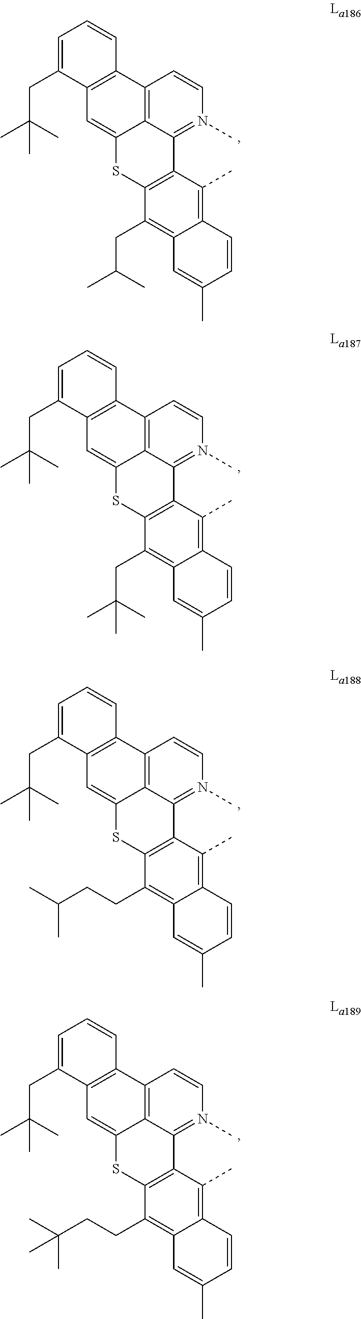 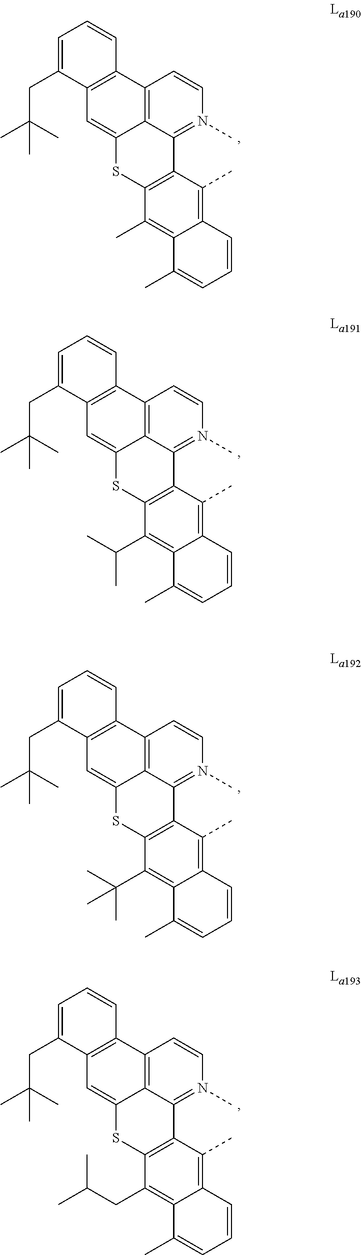 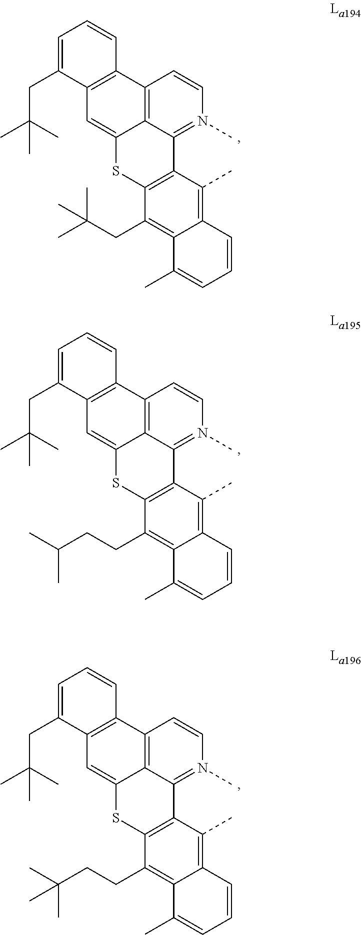 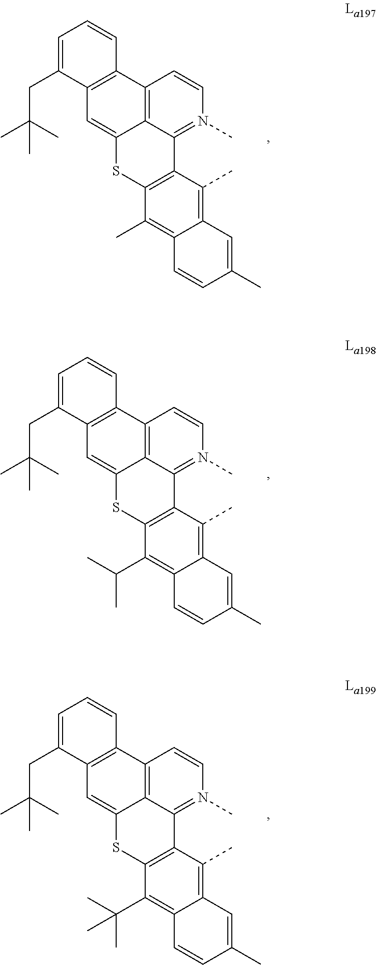 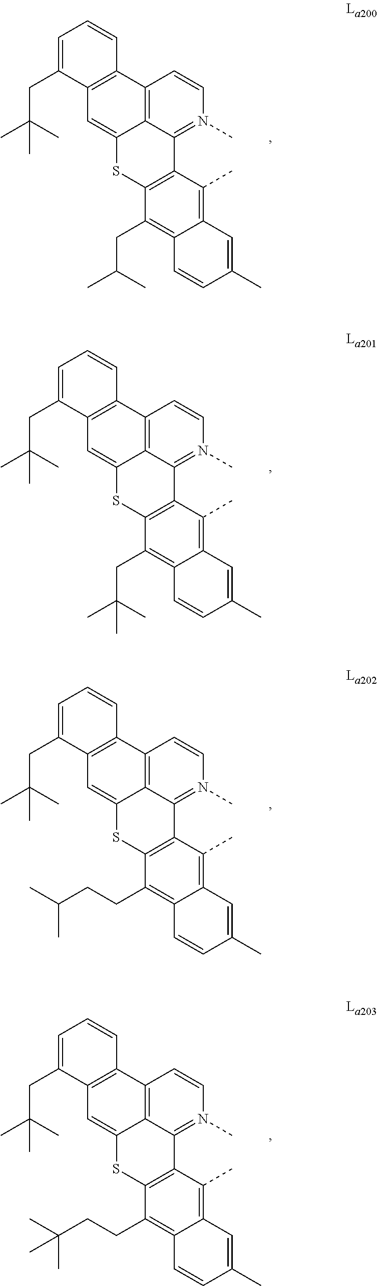 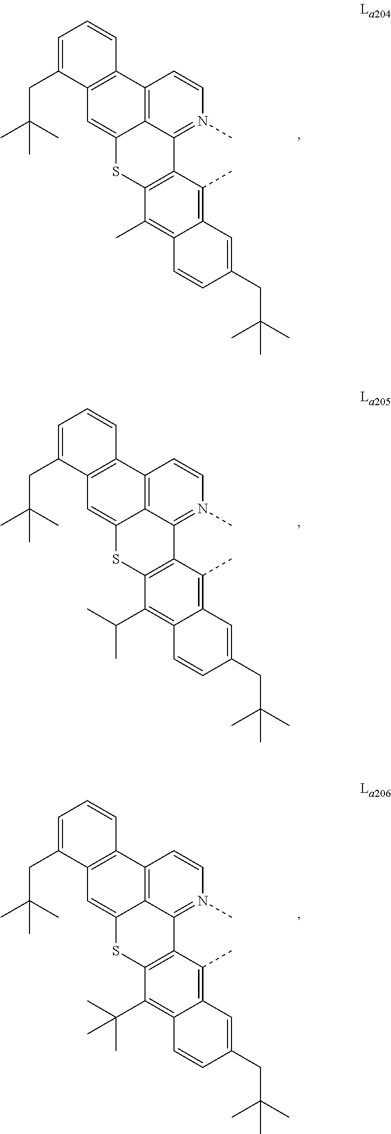 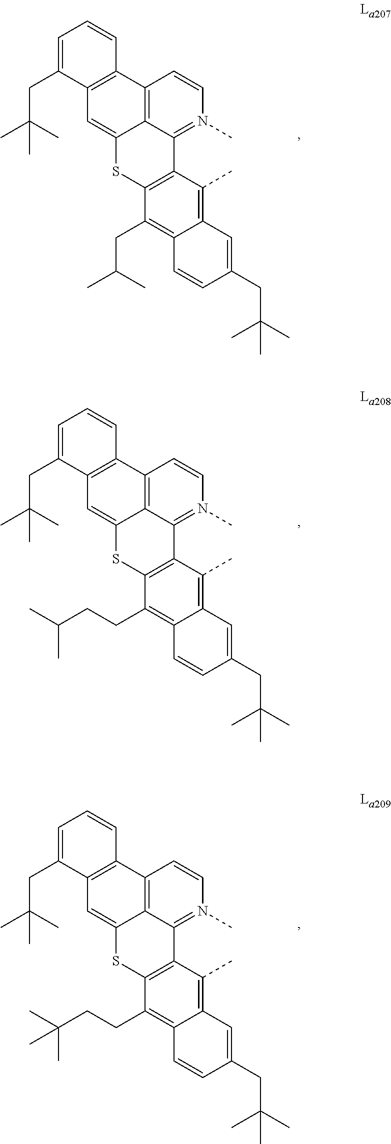 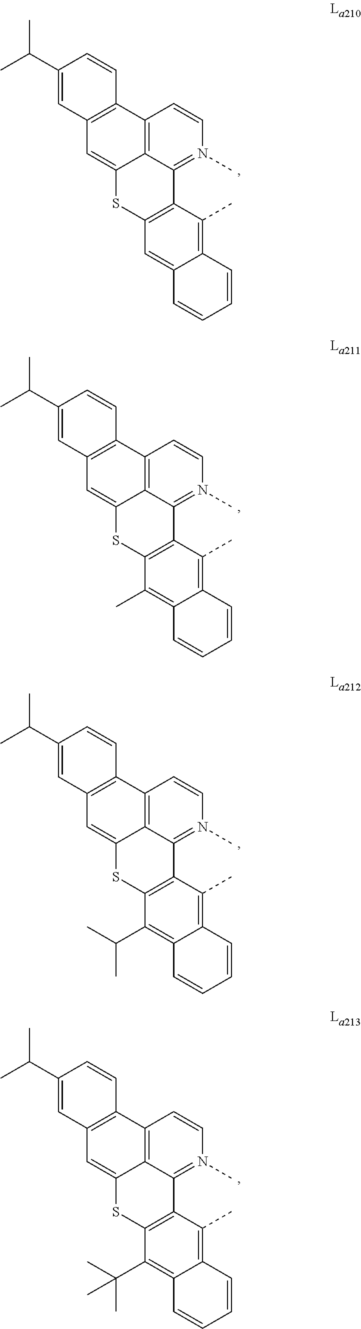 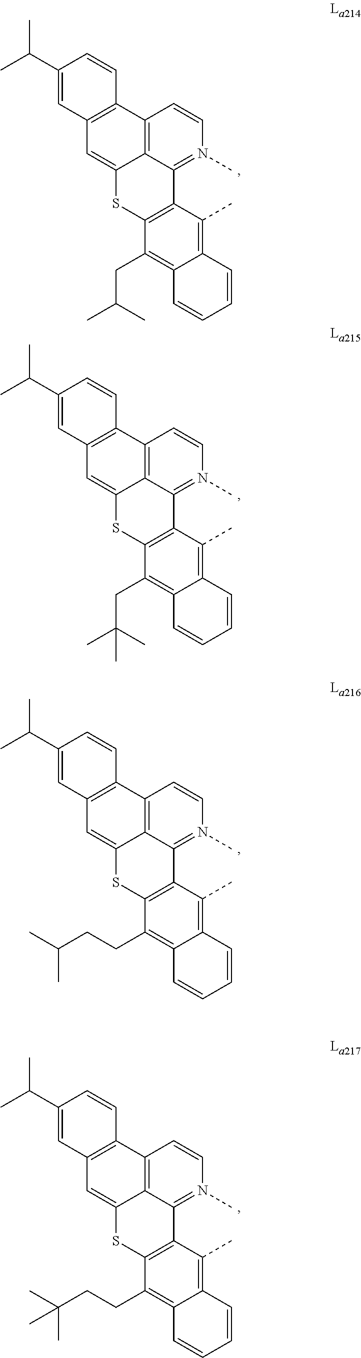 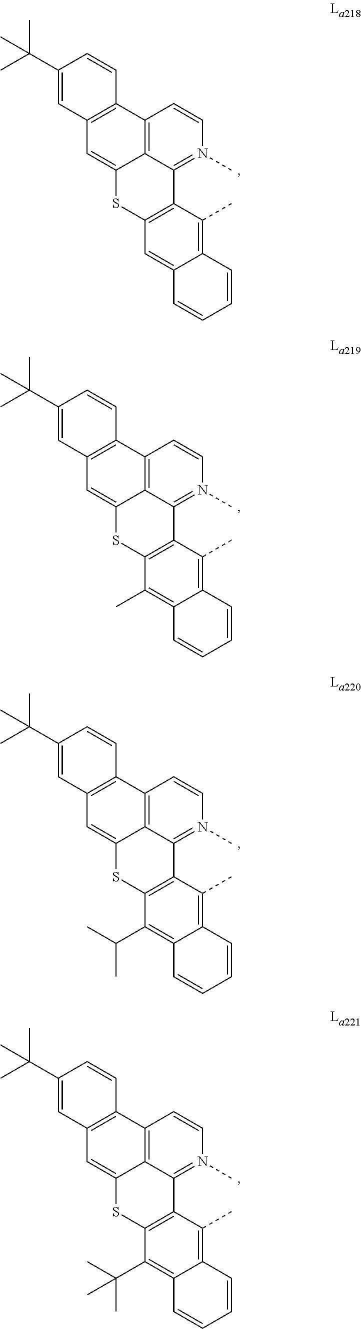 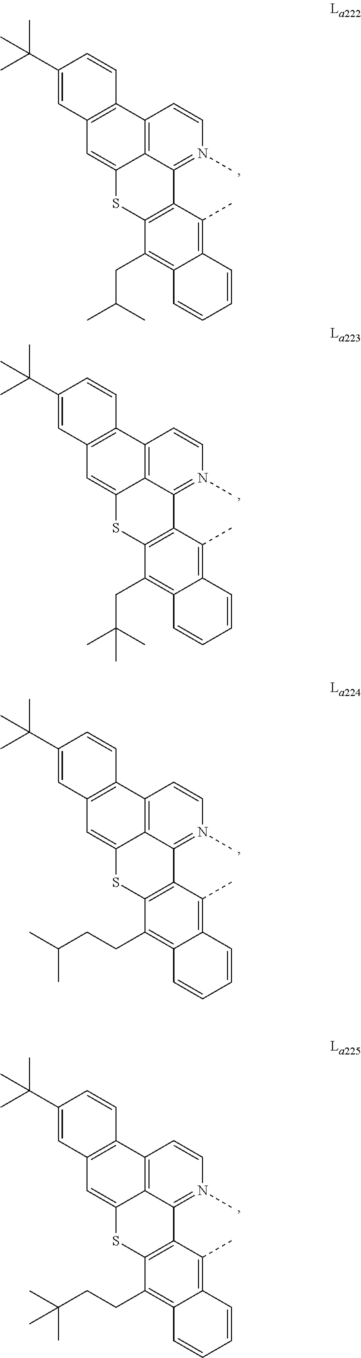 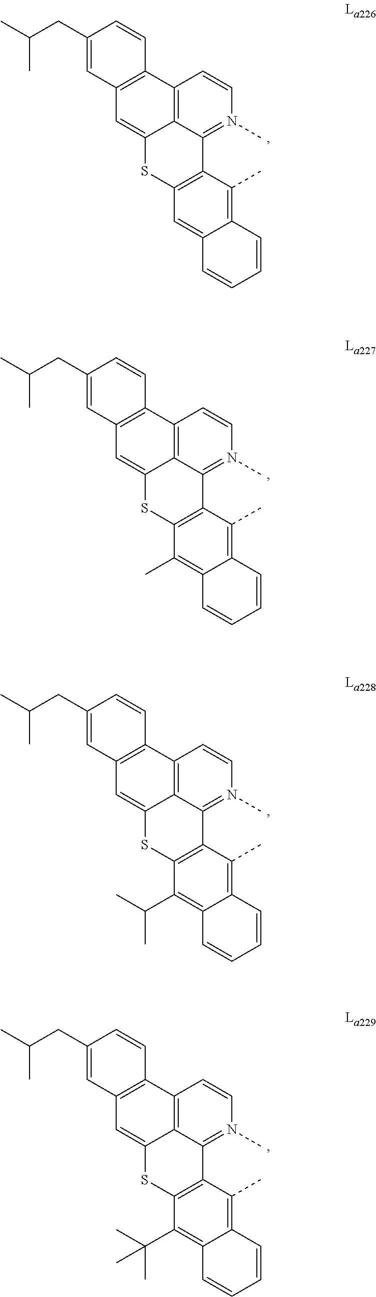 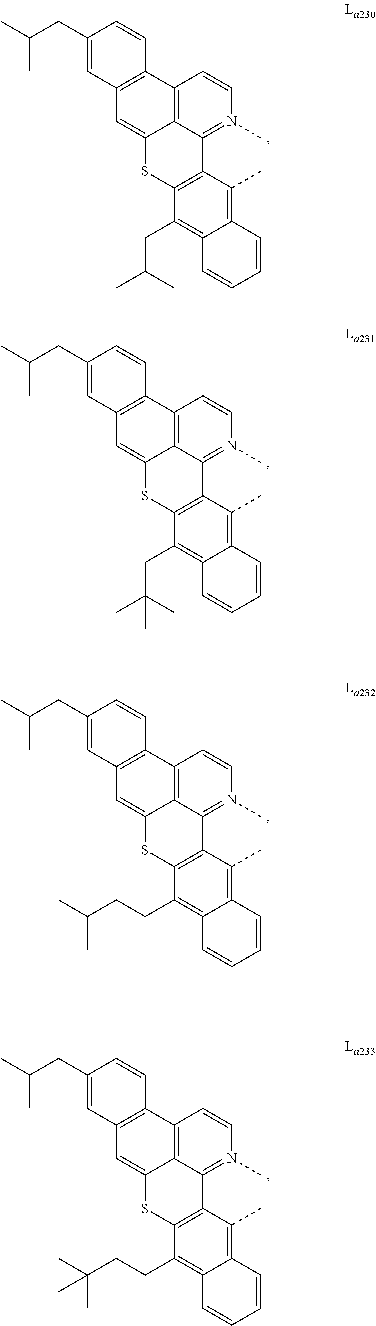 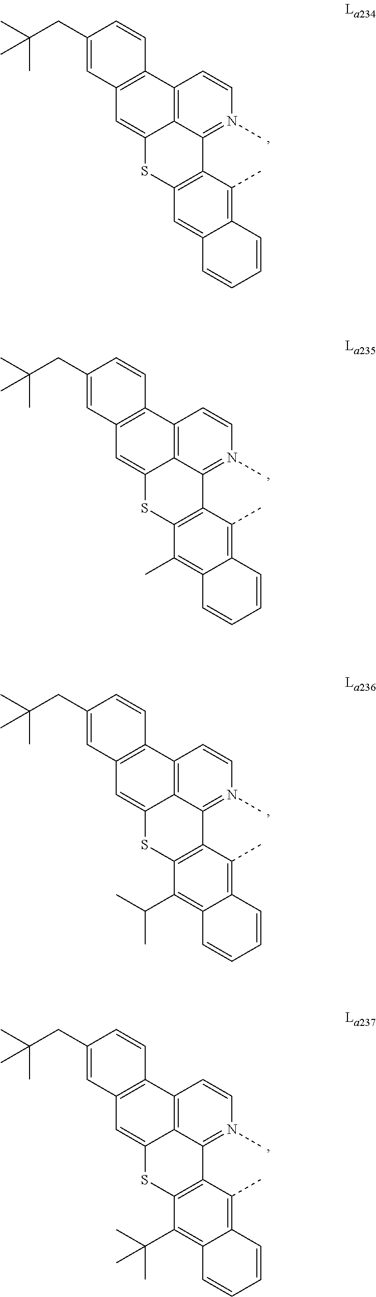 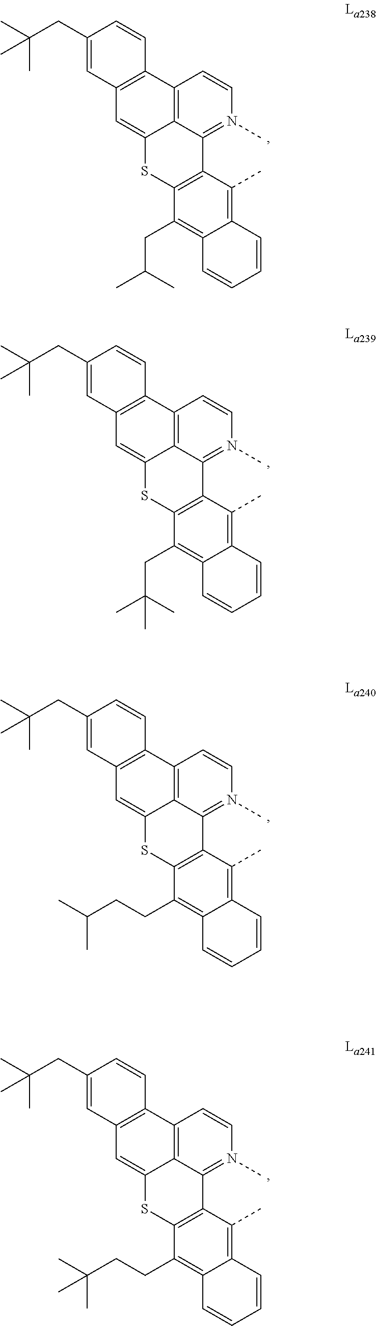 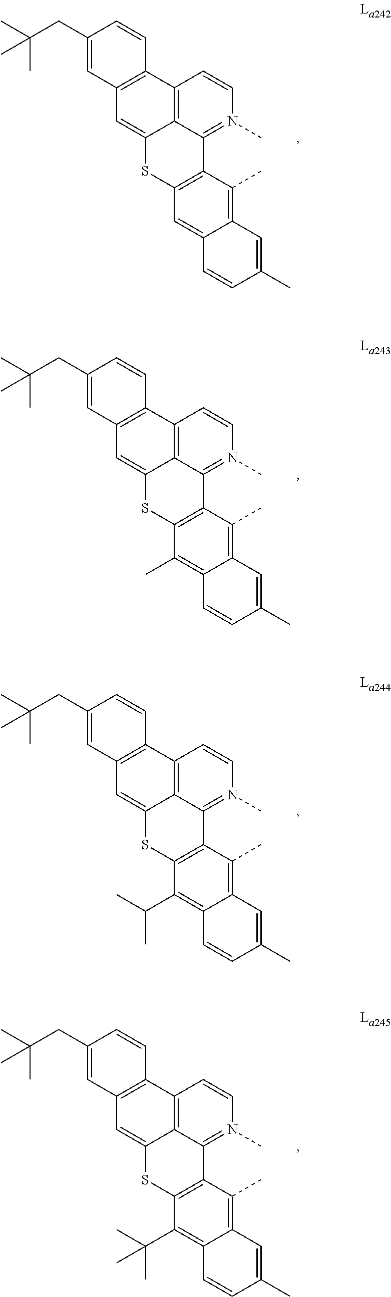 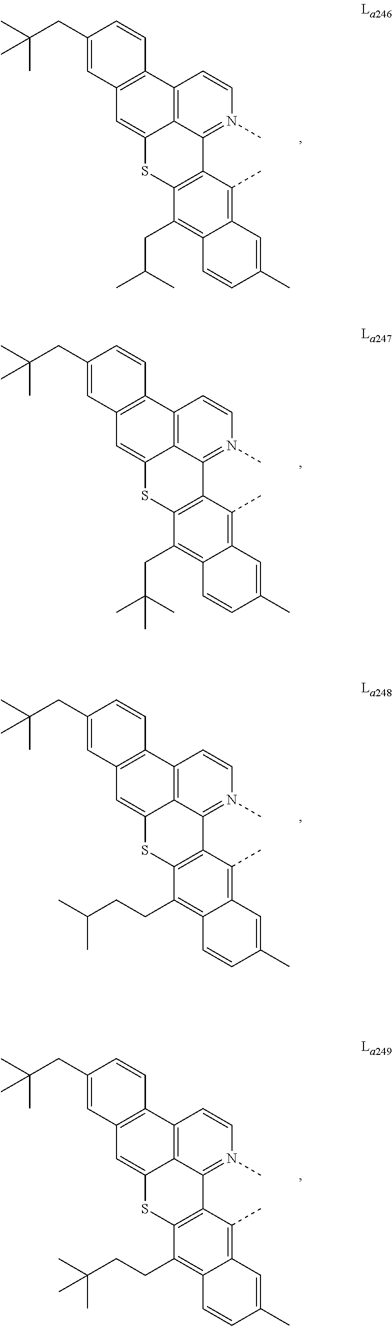 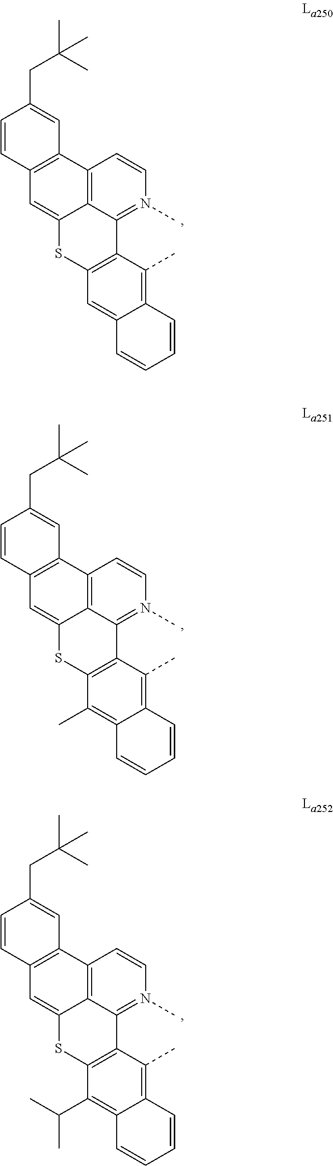 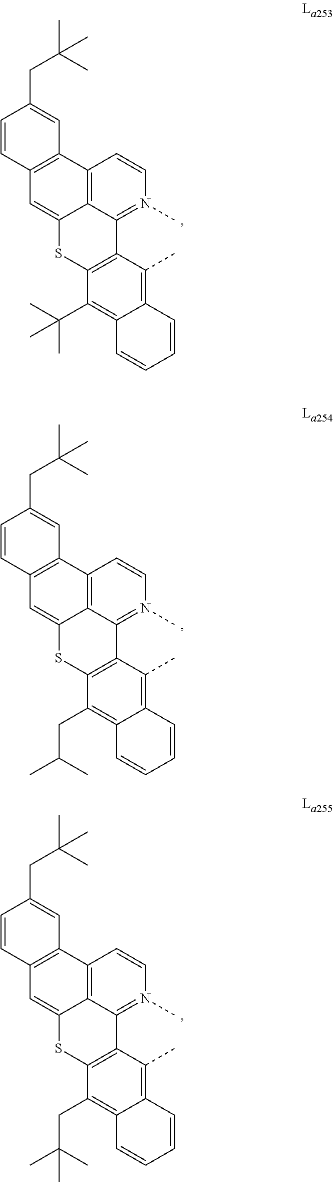 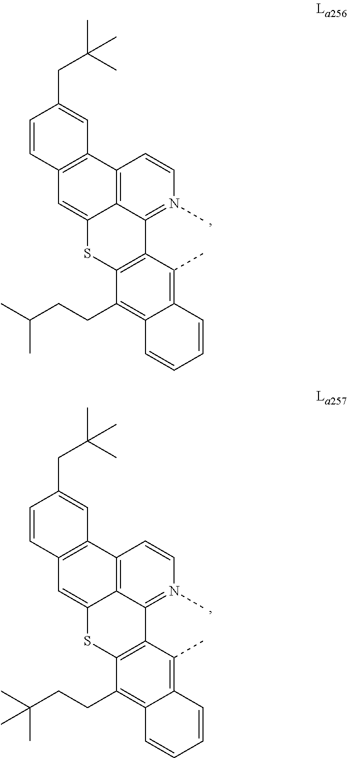 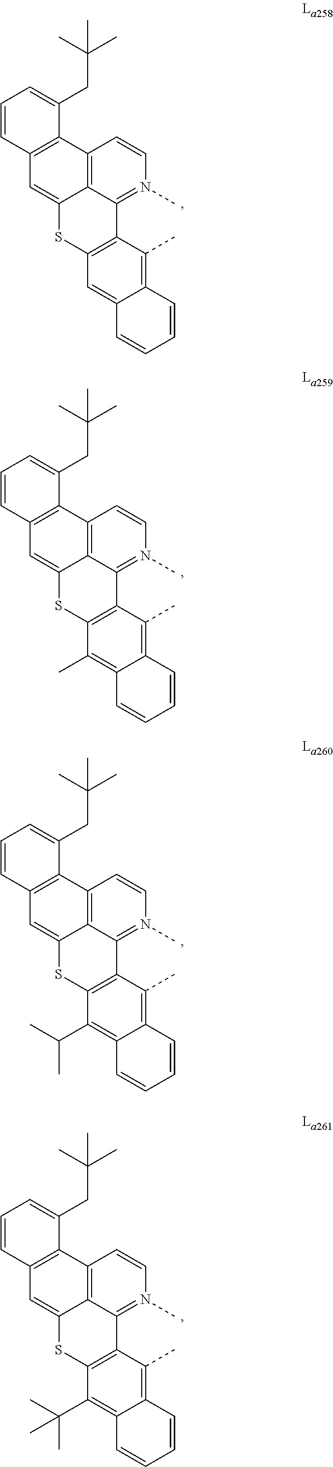 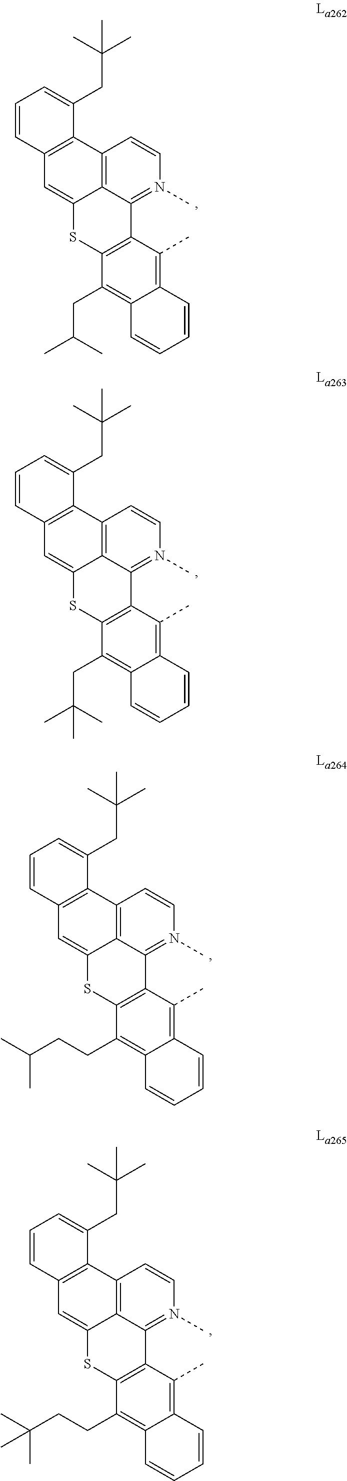 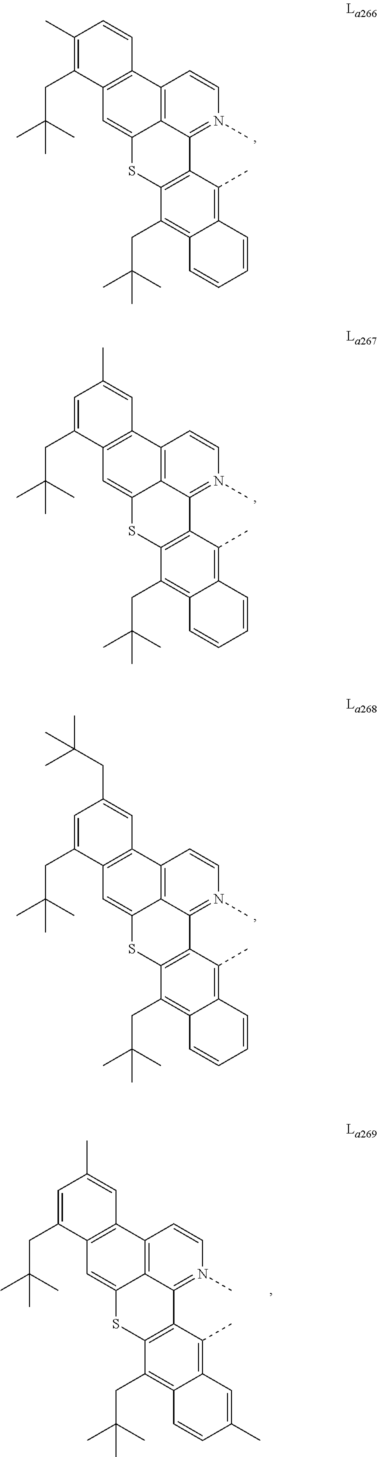 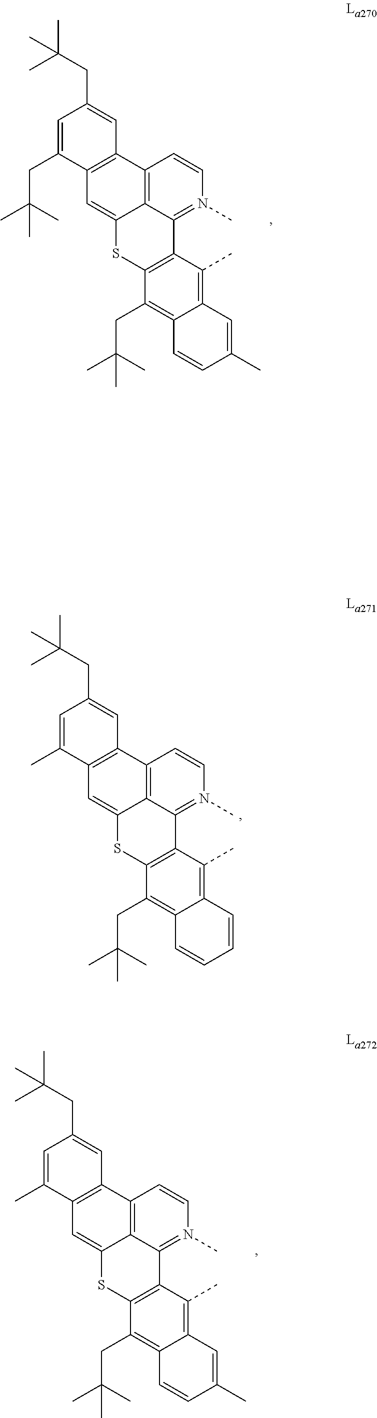 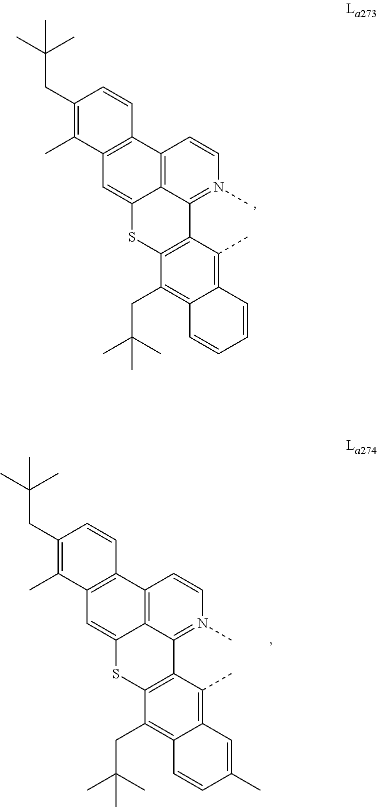 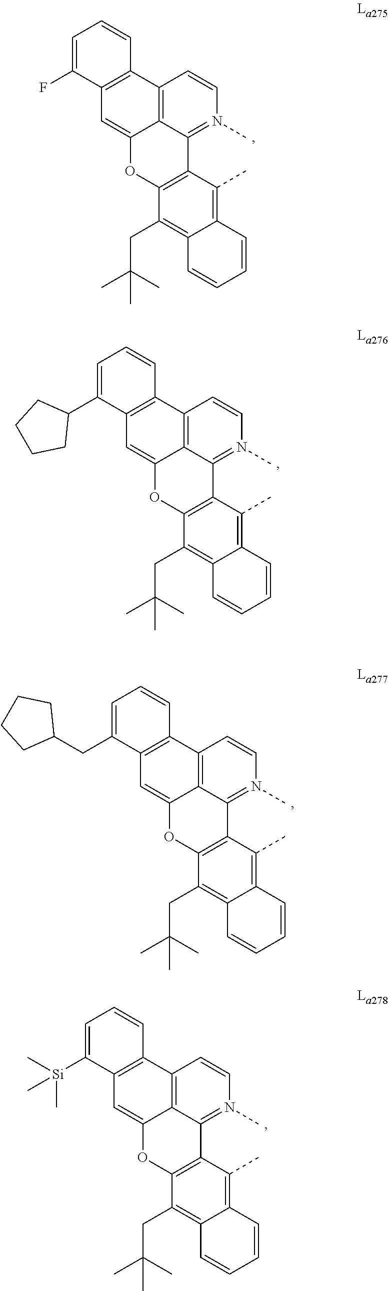 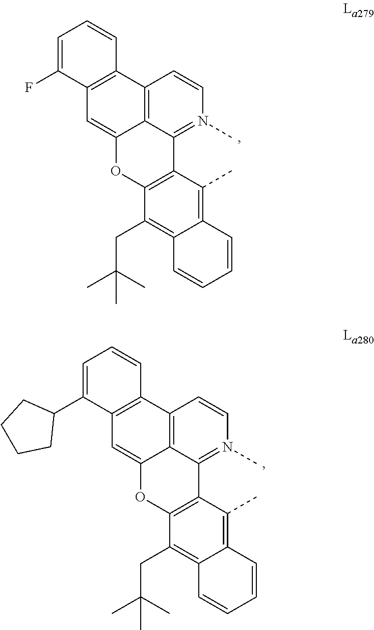 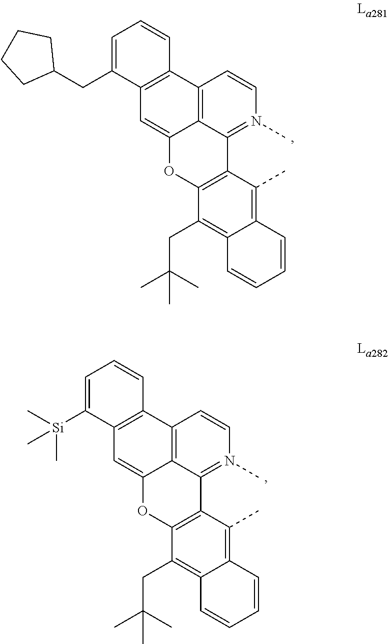 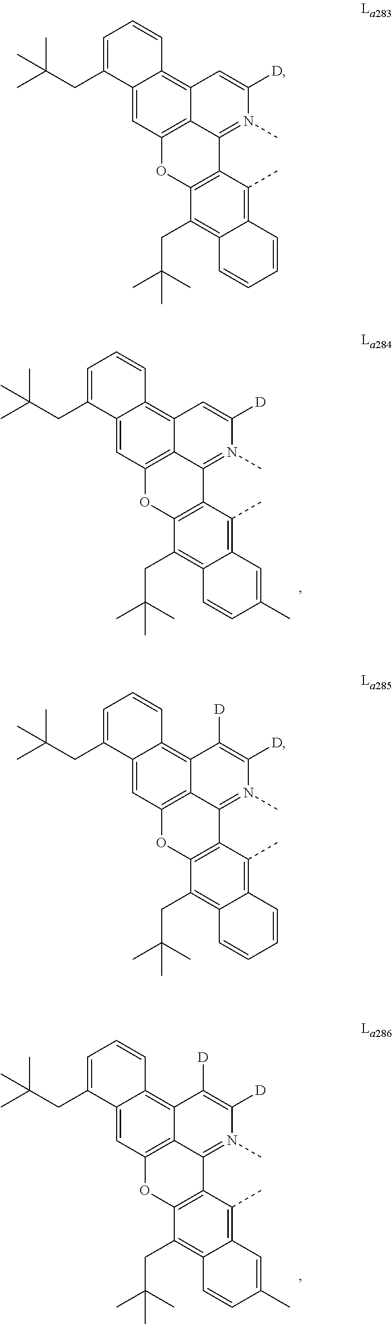 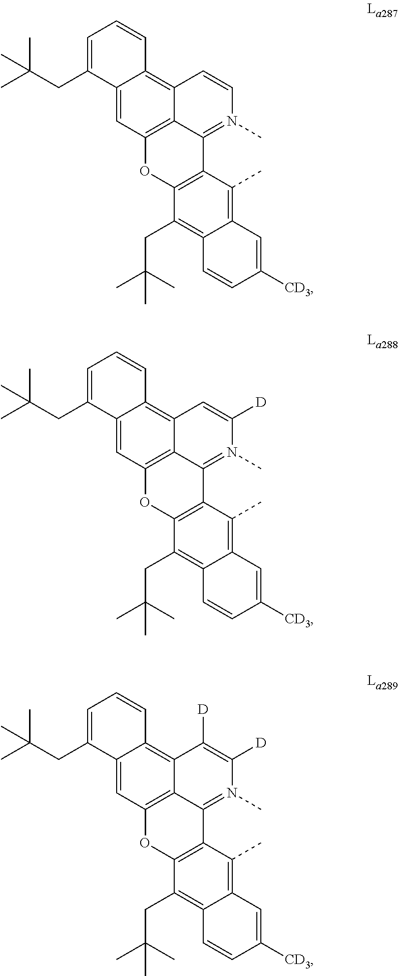 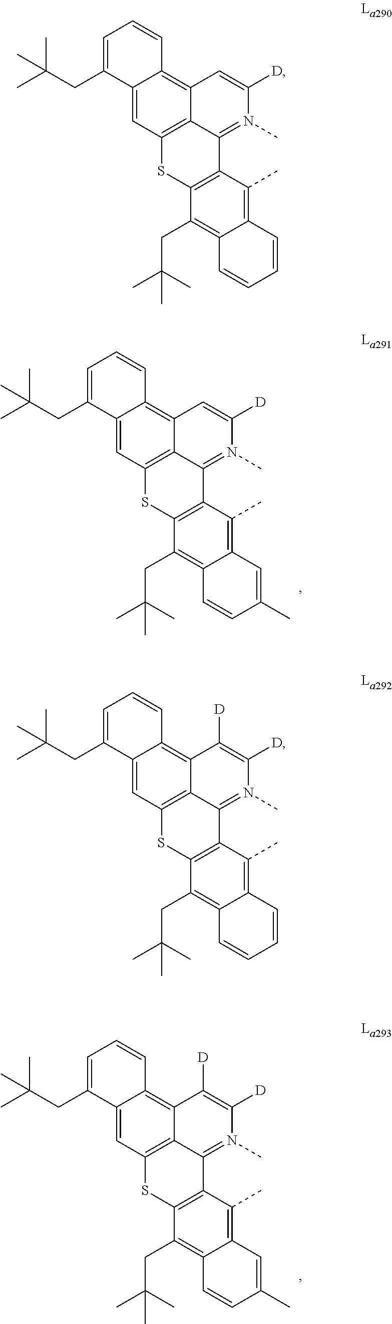 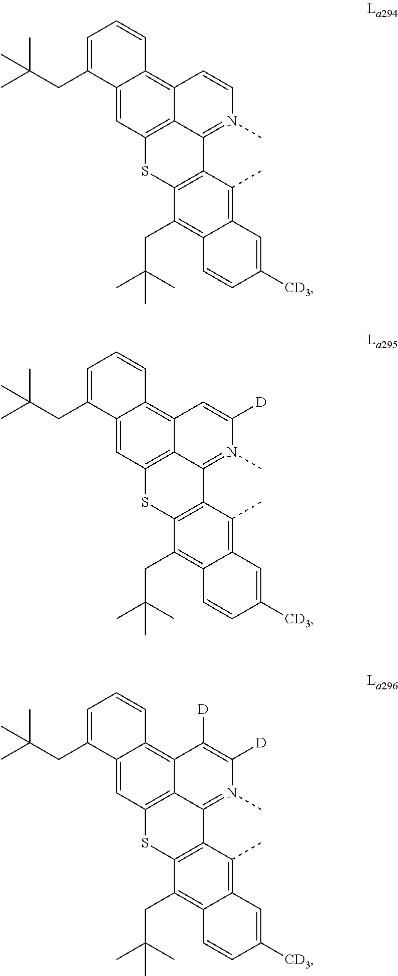 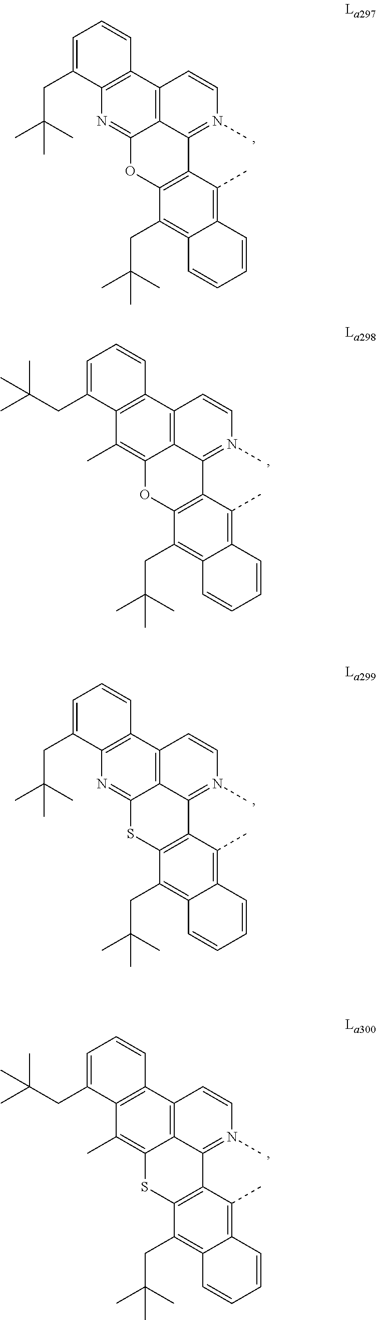 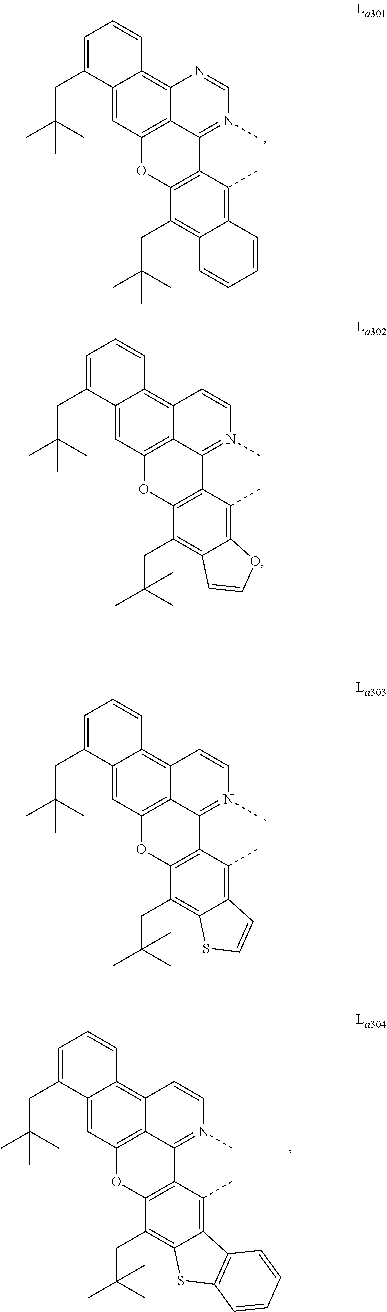 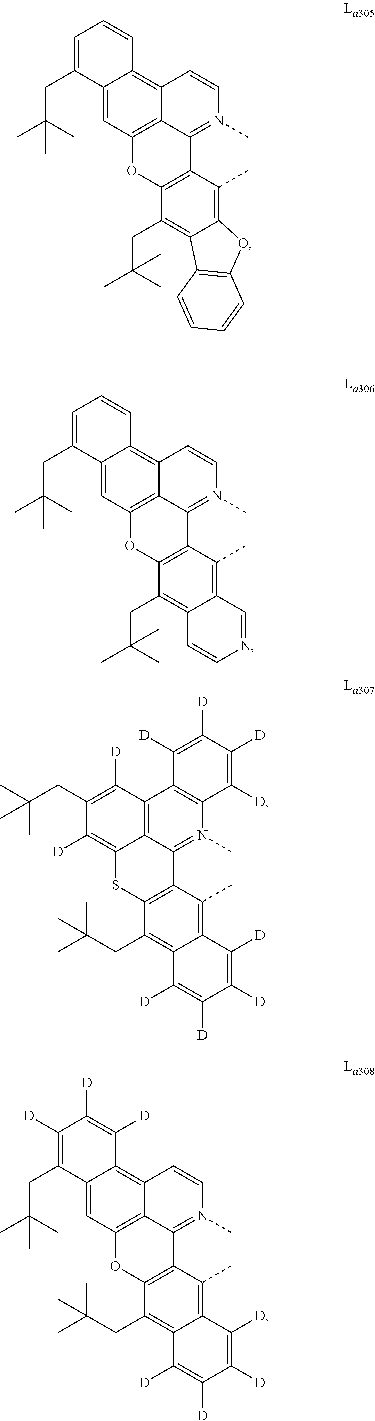 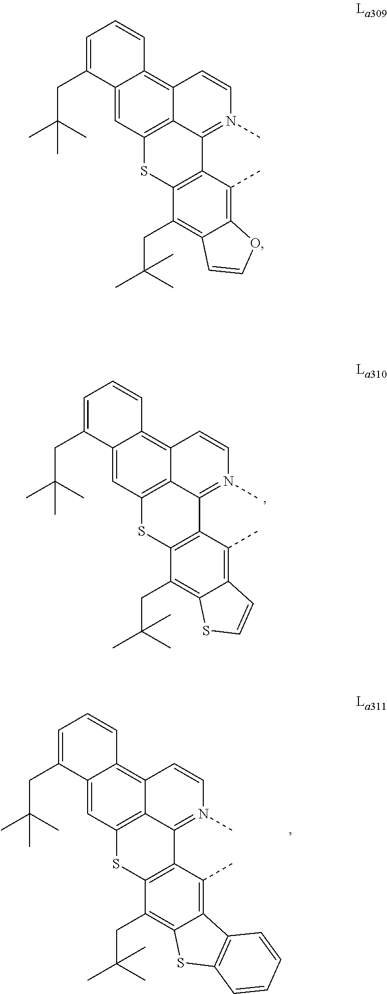 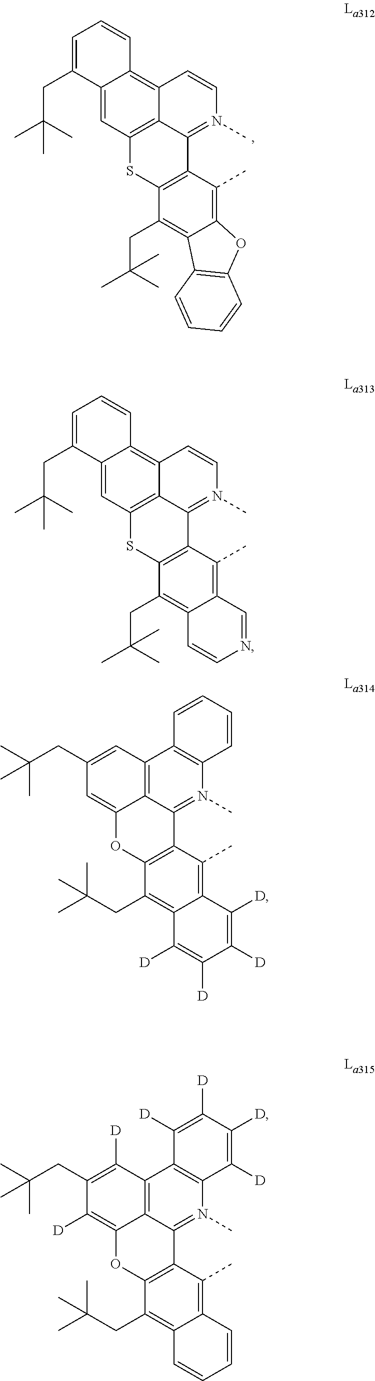 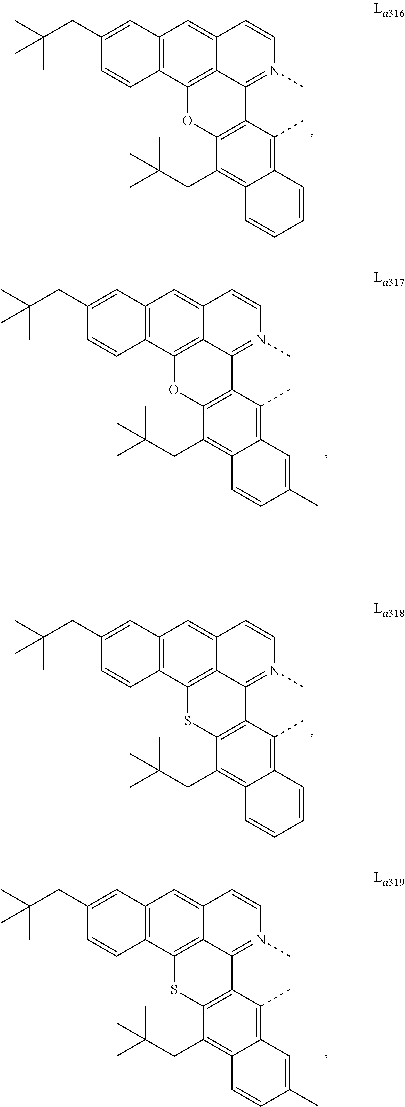 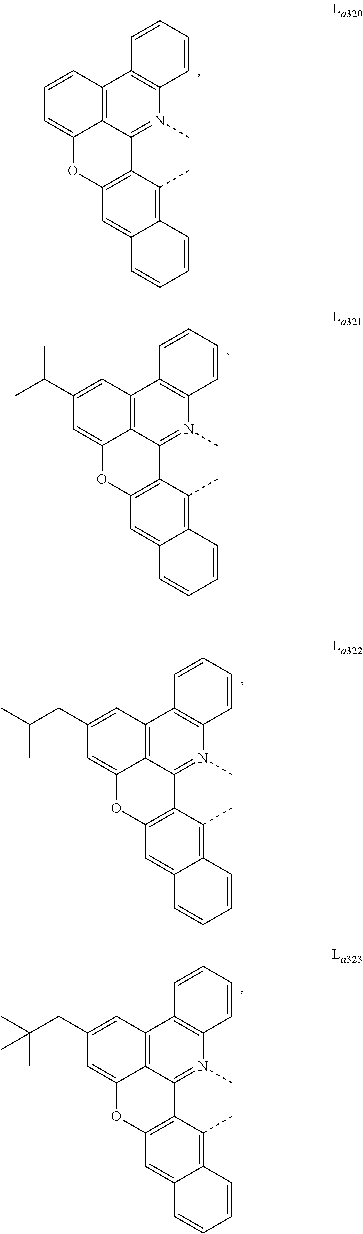 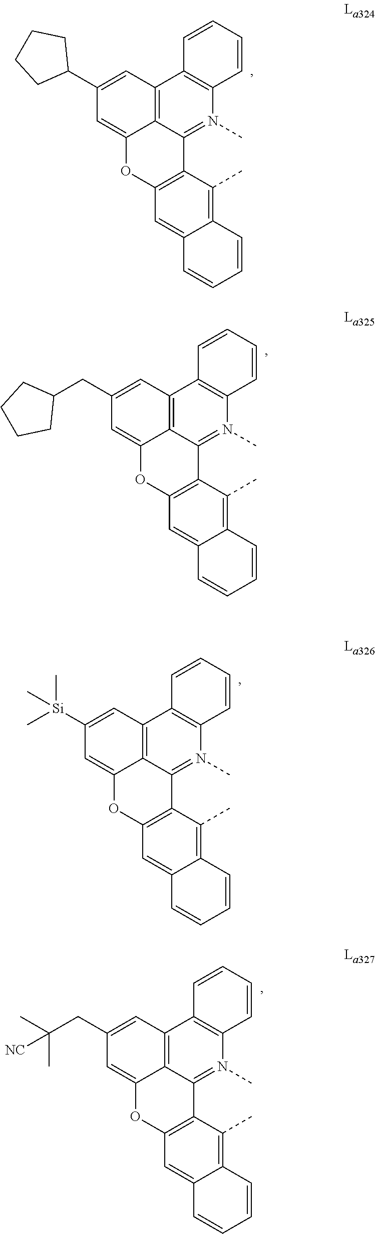 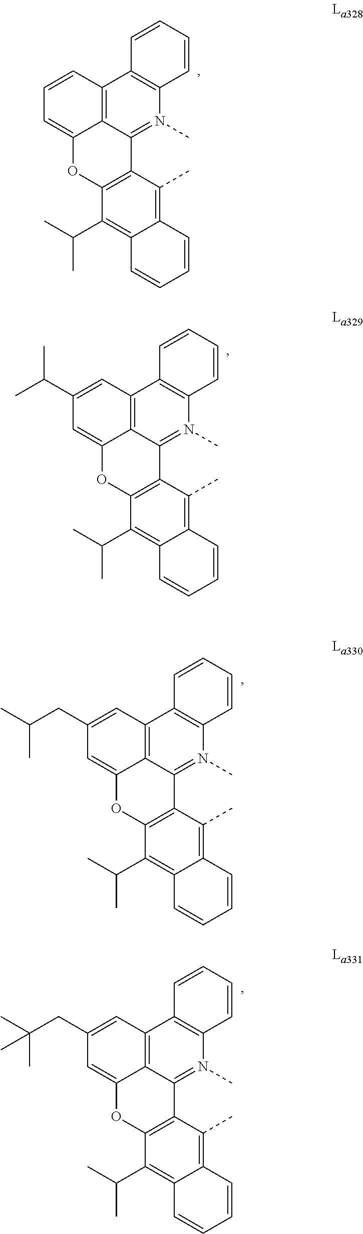 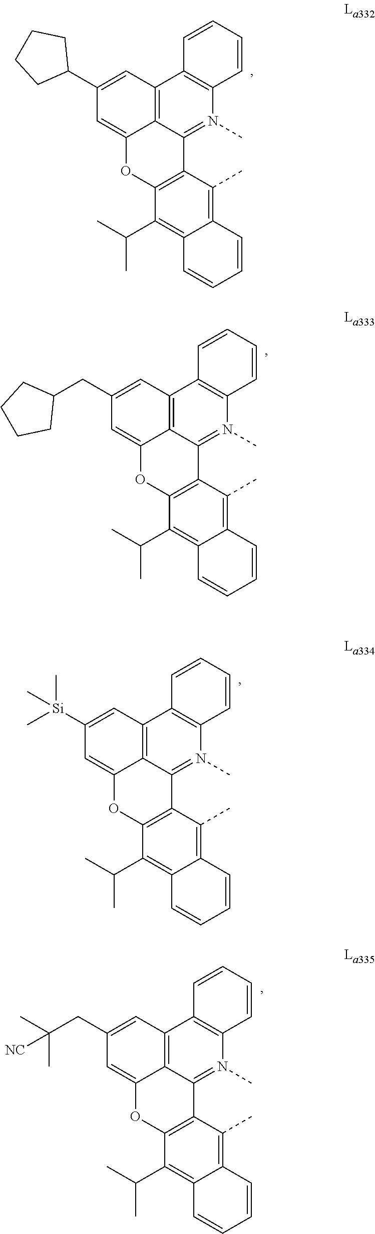 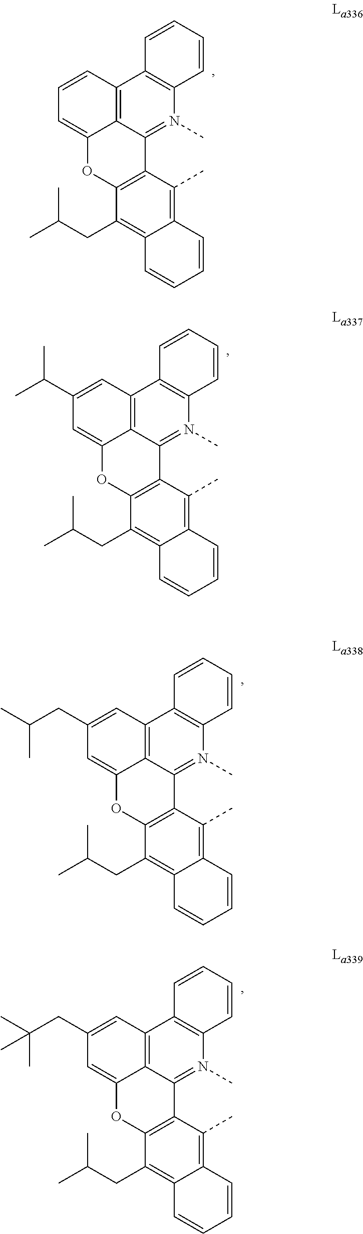 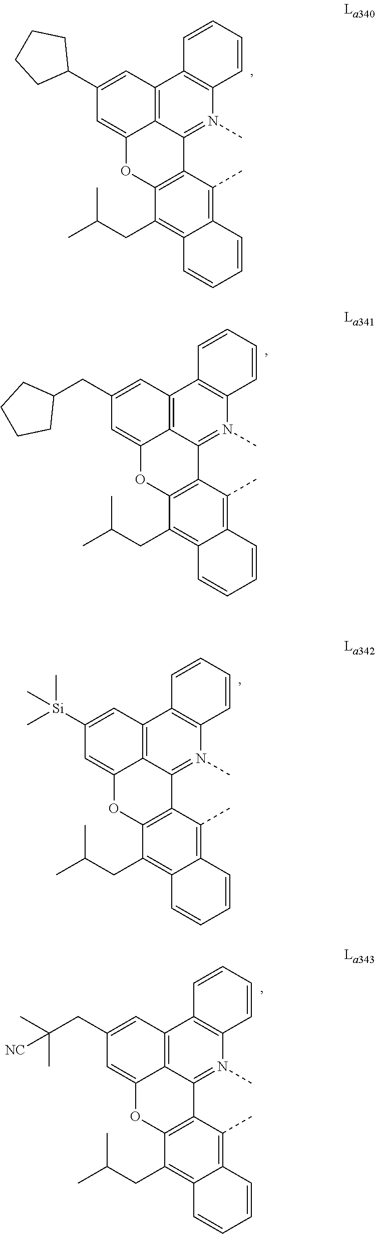 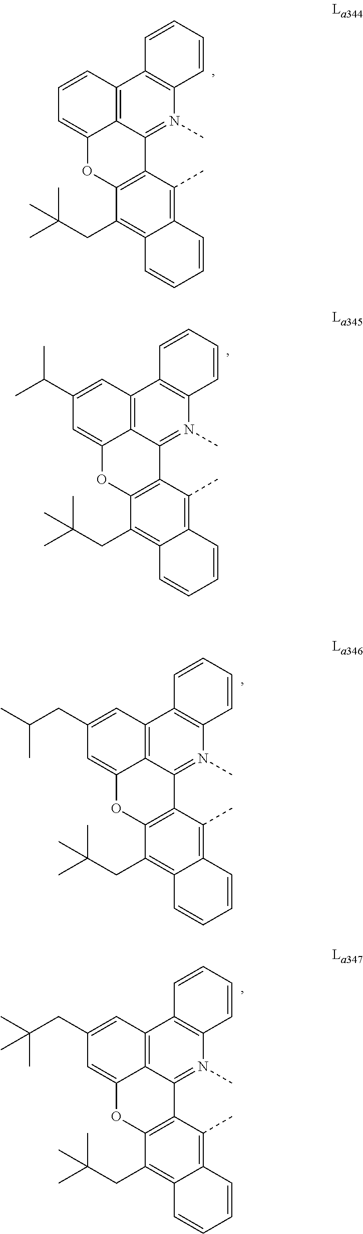 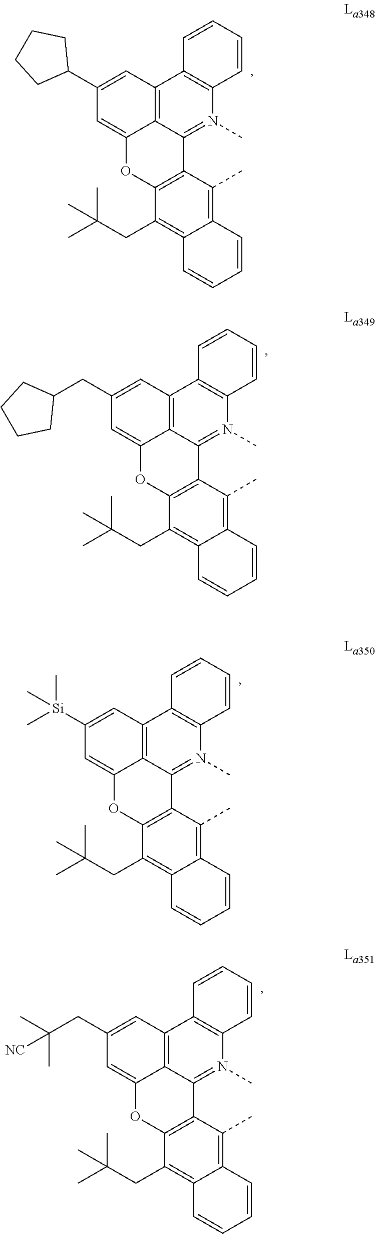 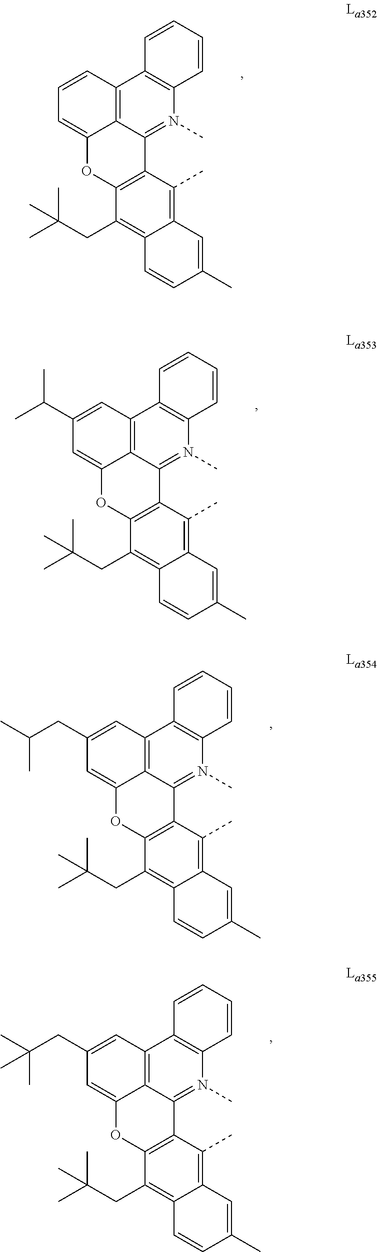 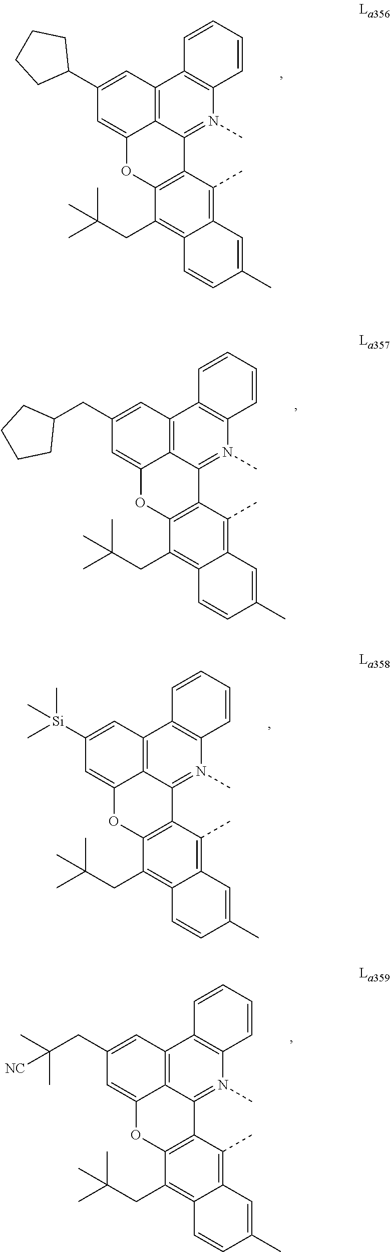 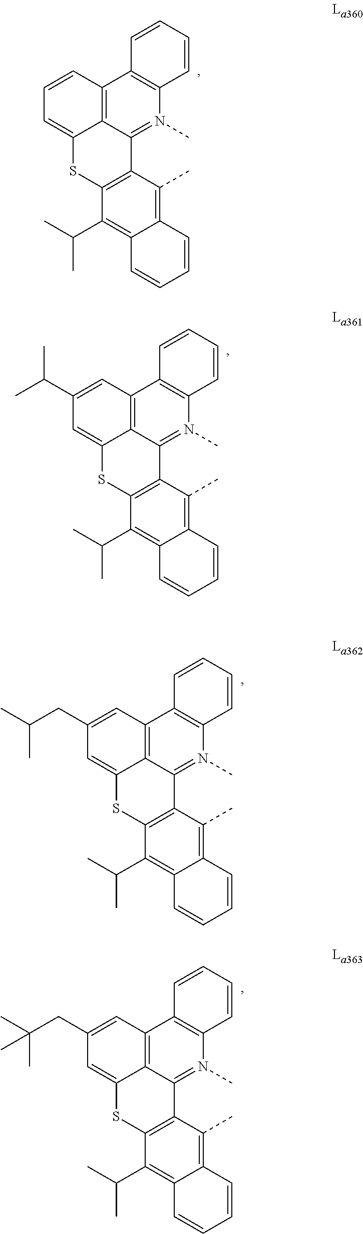 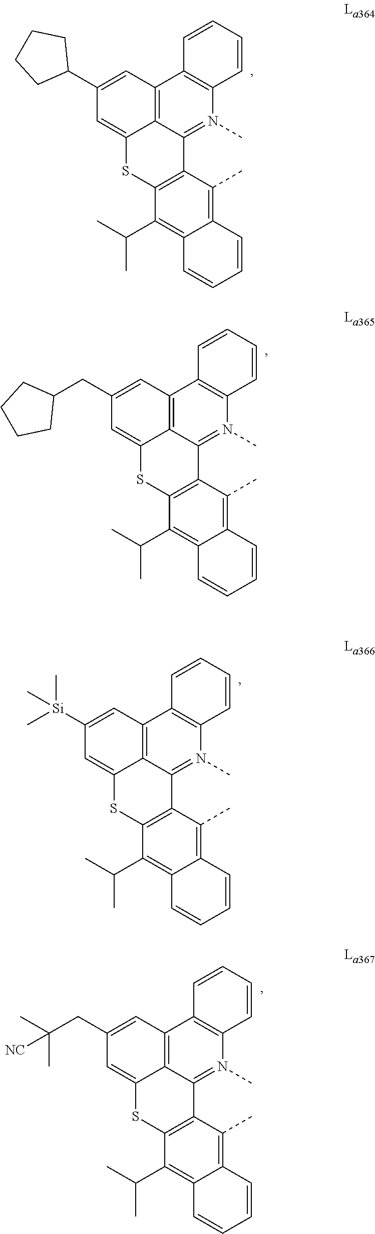 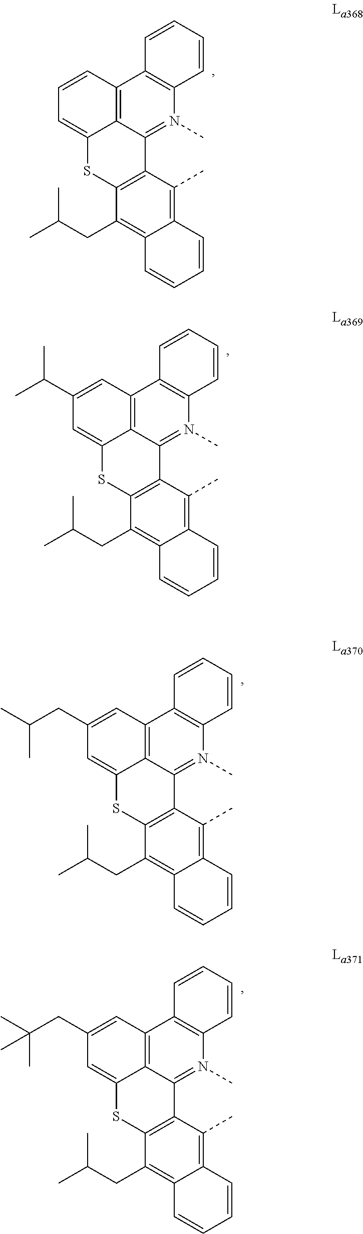 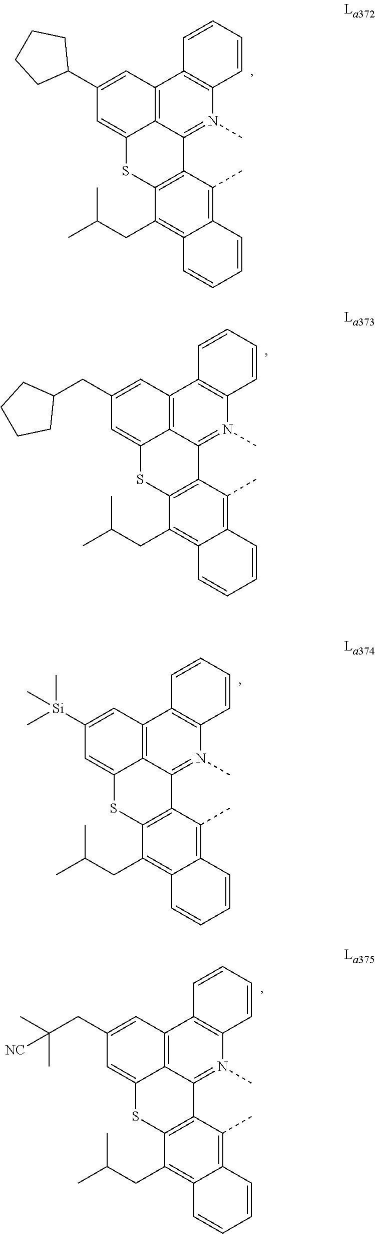 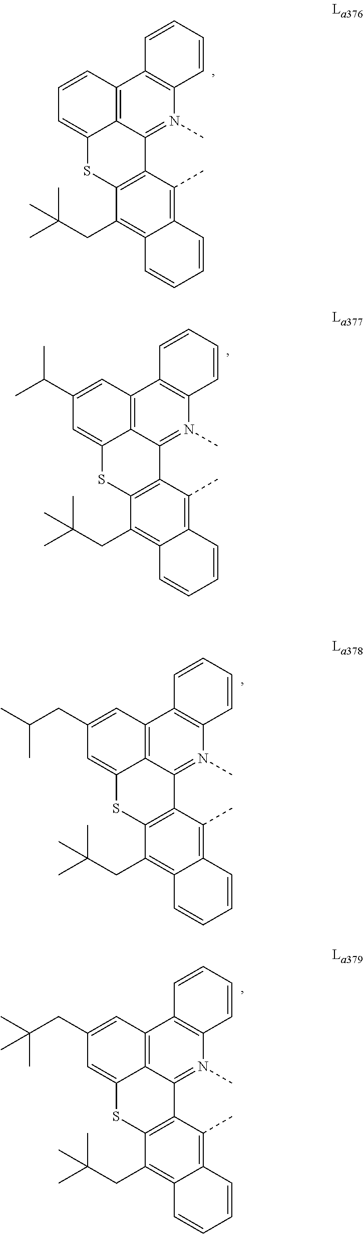 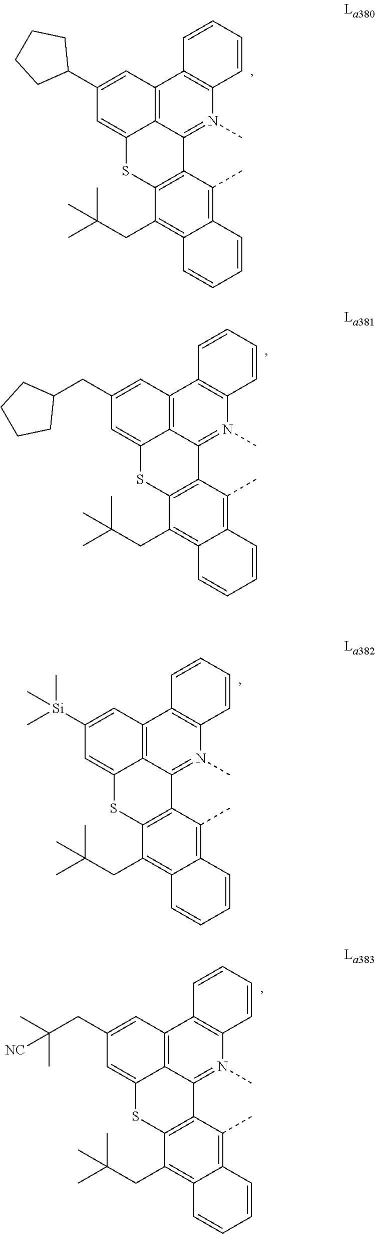 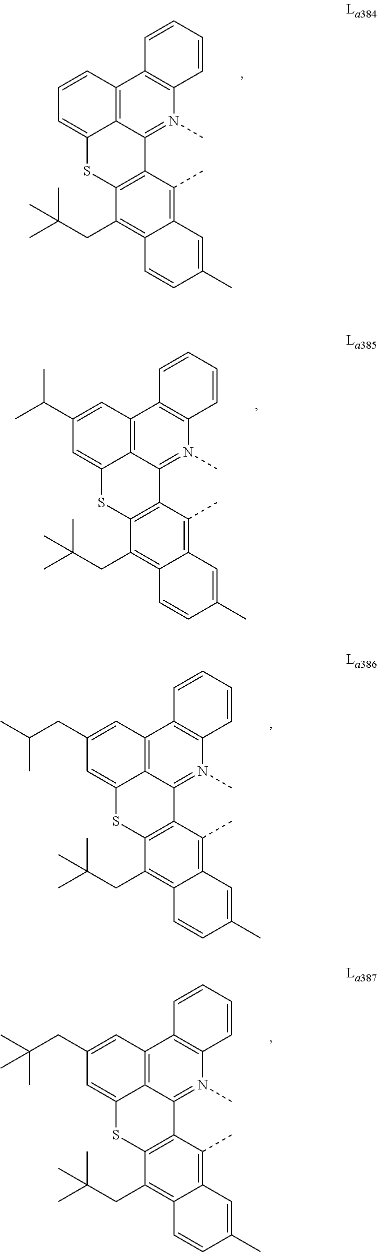 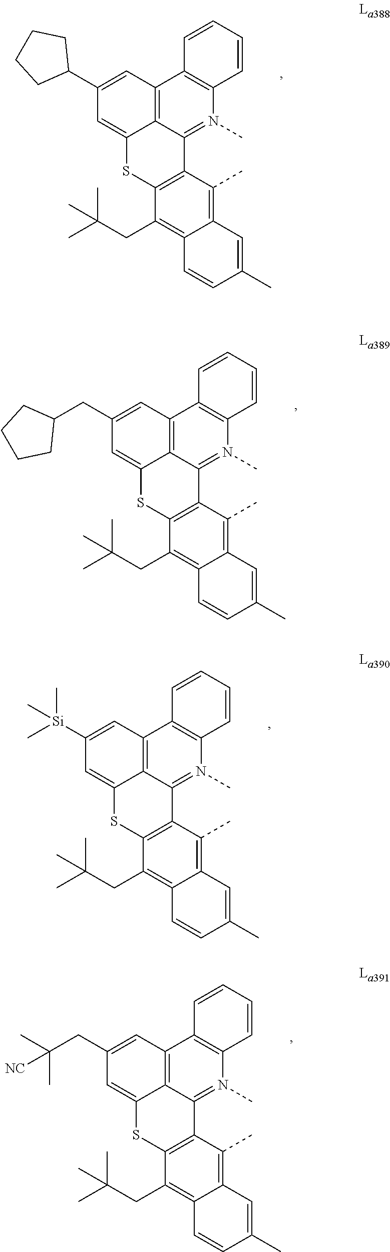 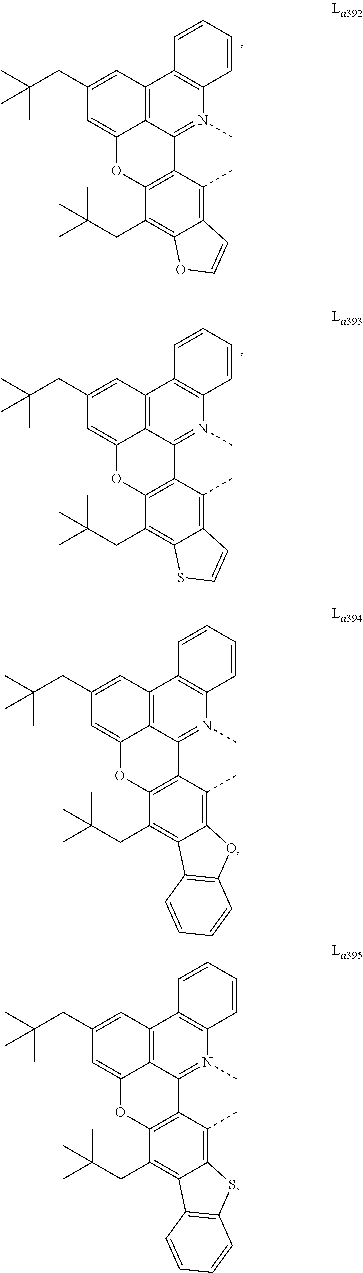 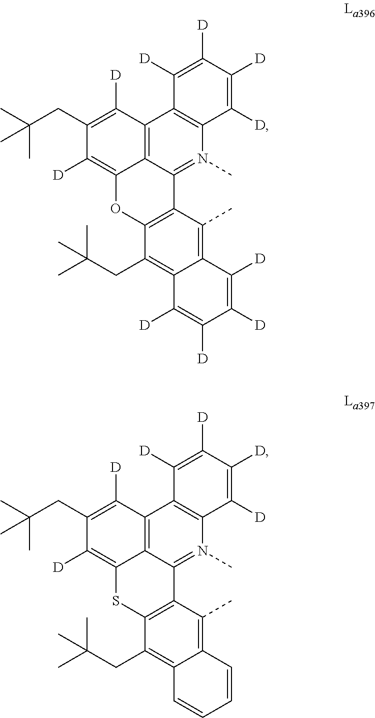 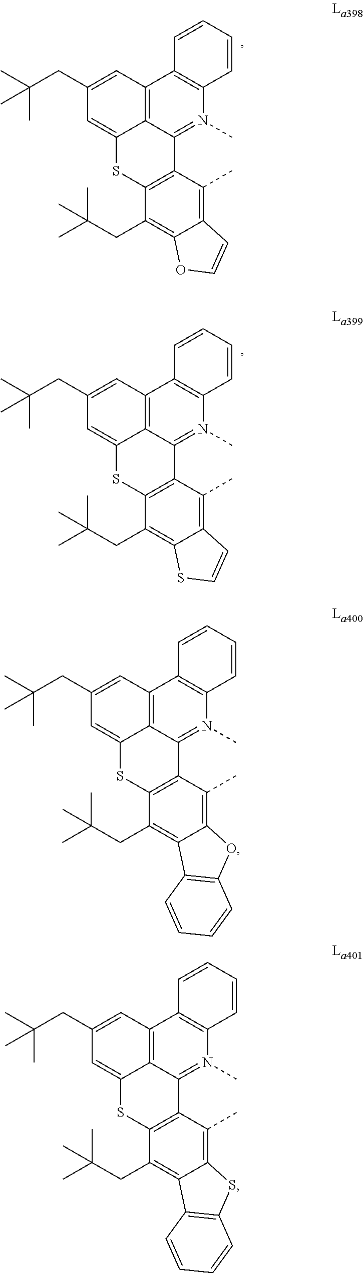 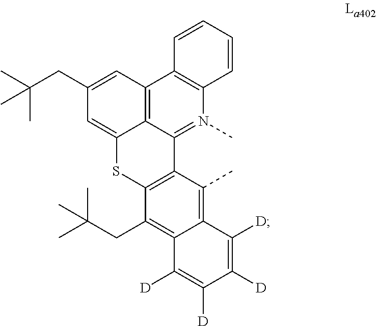
wherein optionally, hydrogens in the structures of Lₐ₁ to Lₐ₄₀₂ can be partially or fully substituted with deuterium.

16. The organic electroluminescent device according to claim 15, wherein the first metal complex has a structure of M(Lₐ)ₘ(L_{b})ₙ(L_{c})_{q};
wherein the metal M is selected from a metal with a relative atomic mass greater than 40;
preferably, the metal M is, at each occurrence identically or differently, selected from the group consisting of Cu, Ag, Au, Ru, Rh, Pd, Os, Ir, and Pt; more preferably, the metal M is, at each occurrence identically or differently, selected from Pt or Ir;
Lₐ, L_{b}, and L_{c} are a first ligand, a second ligand, and a third ligand of the first metal complex, respectively; m is 1, 2, or 3, n is 0, 1, or 2, q is 0, 1, or 2, and m+n+q is equal to an oxidation state of the metal M; when m is greater than 1, multiple Lₐ are the same or different; when n is 2, two L_{b} are the same or different; when q is 2, two L_{c} are the same or different;
Lₐ, L_{b}, and L_{c} can be optionally joined to form a multidentate ligand;
L_{b} and L_{c} are, at each occurrence identically or differently, selected from the group consisting of the following structures: 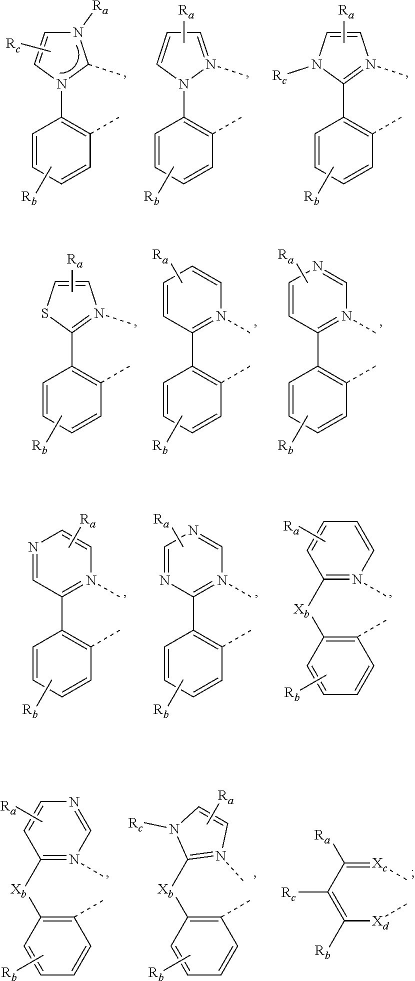
wherein Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{N2}, R_{C1}, and R_{C2} can be optionally joined to form a ring.

17. The organic electroluminescent device according to claim 16, wherein L_{b} is, at each occurrence identically or differently, selected from the following structure: 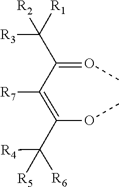
wherein R₁ to R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one or two of R₁ to R₃ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof; and/or at least one or two of R₄ to R₆ are, at each occurrence identically or differently, selected from substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, or a combination thereof;
more preferably, at least two of R₁ to R₃ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof; and/or at least two of R₄ to R₆ are, at each occurrence identically or differently, selected from substituted or unsubstituted alkyl having 2 to 20 carbon atoms, substituted or unsubstituted cycloalkyl having 3 to 20 ring carbon atoms, substituted or unsubstituted heteroalkyl having 2 to 20 carbon atoms, or a combination thereof.

18. The organic electroluminescent device according to claim 17, wherein L_{b} is, at each occurrence identically or differently, selected from the group consisting of L_{b1} to L_{b322}: 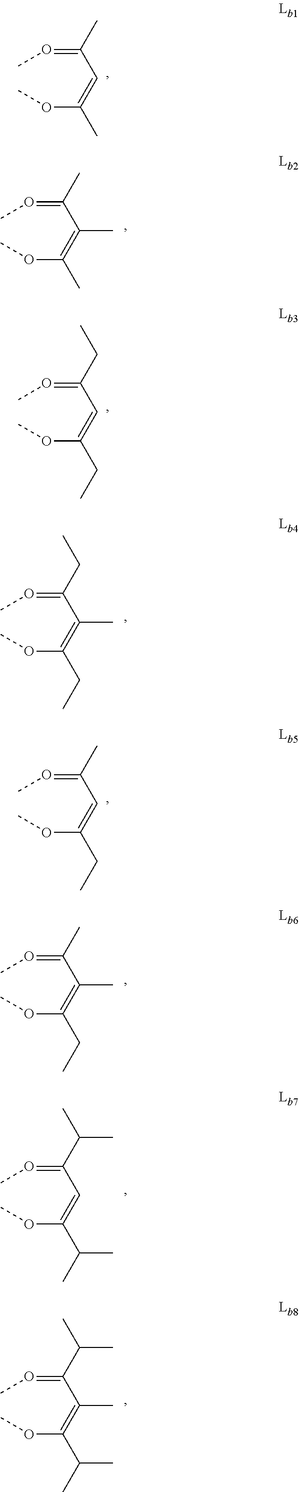 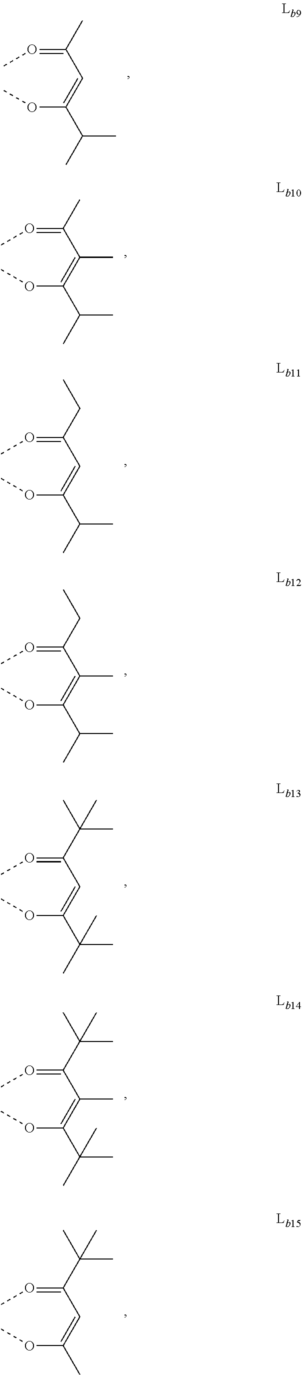 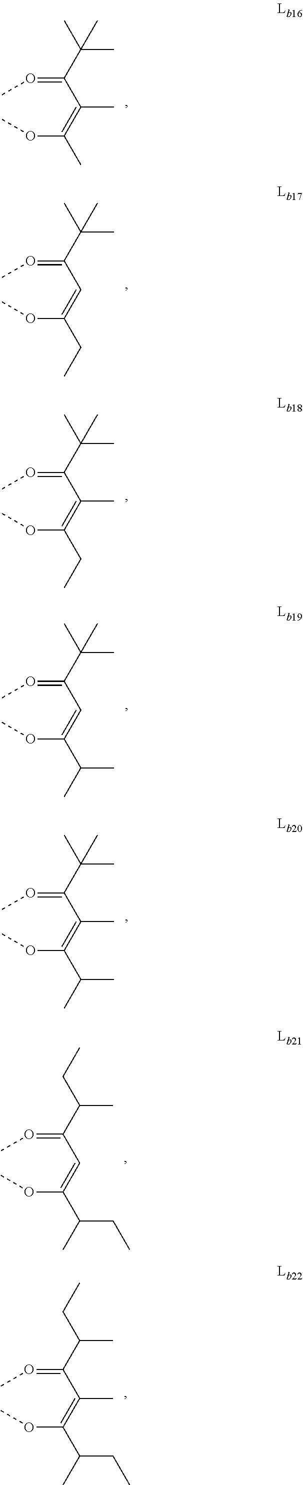 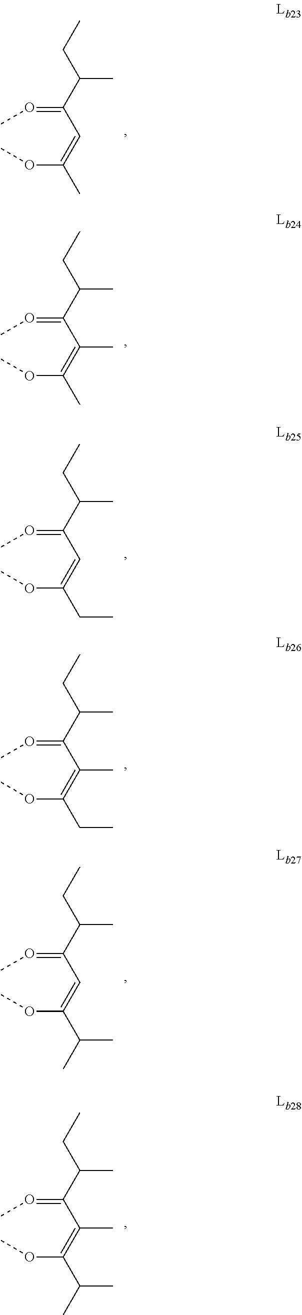 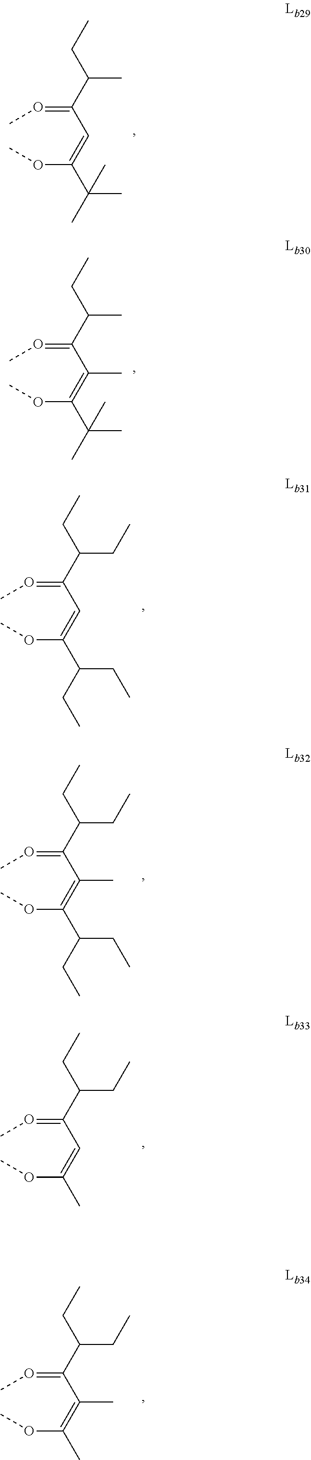 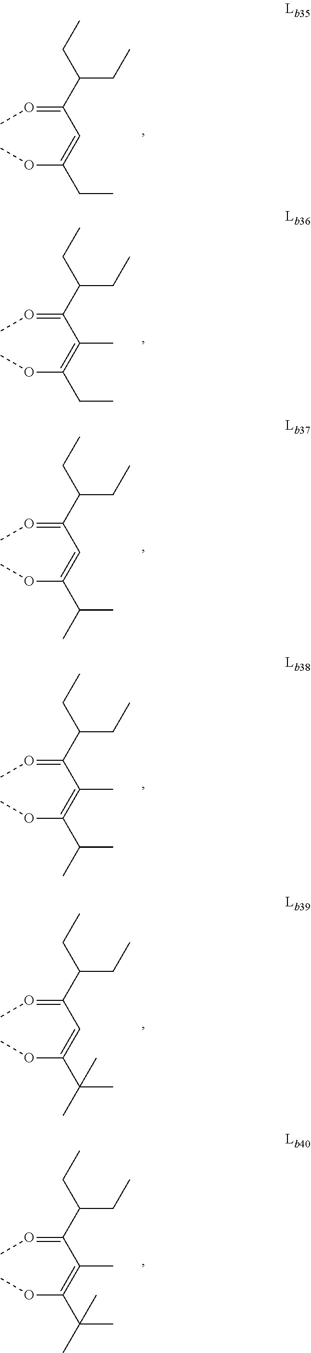 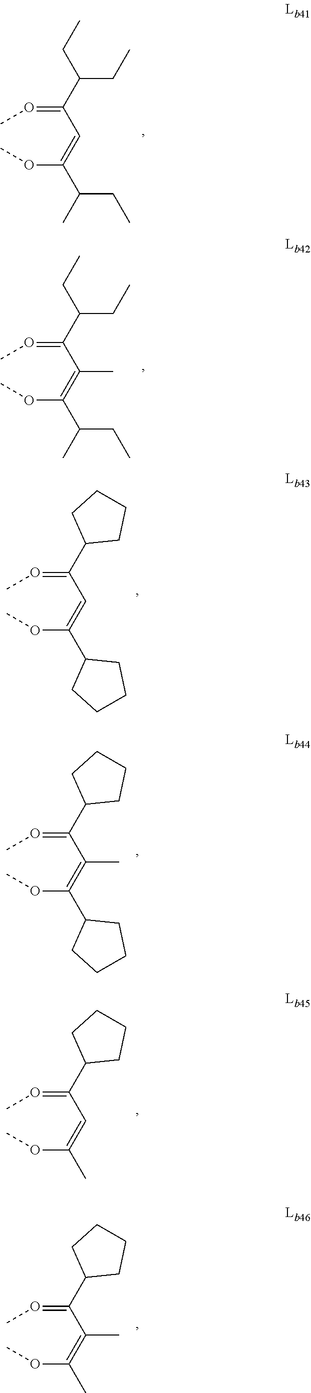 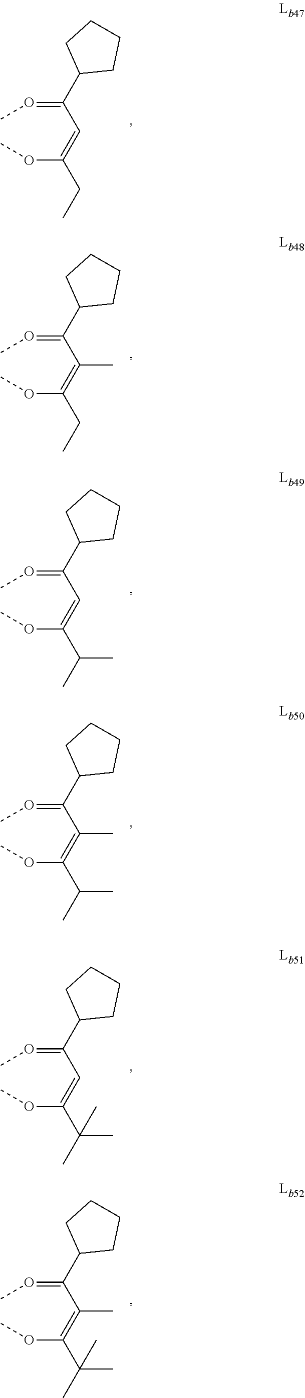 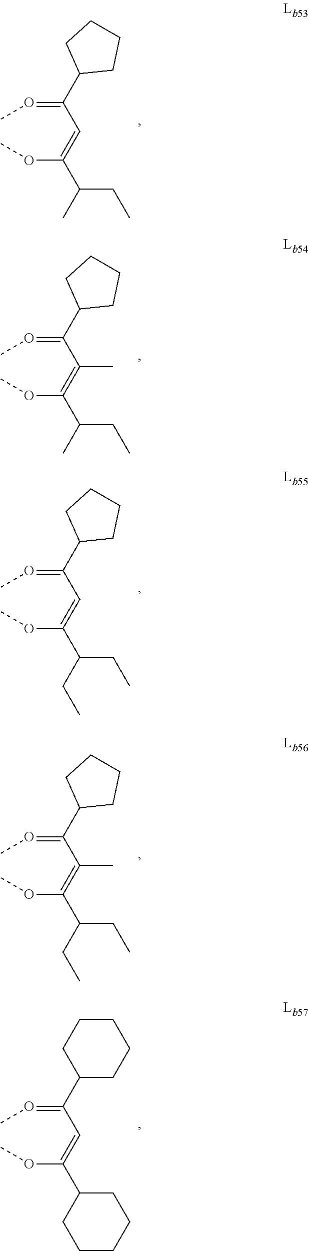 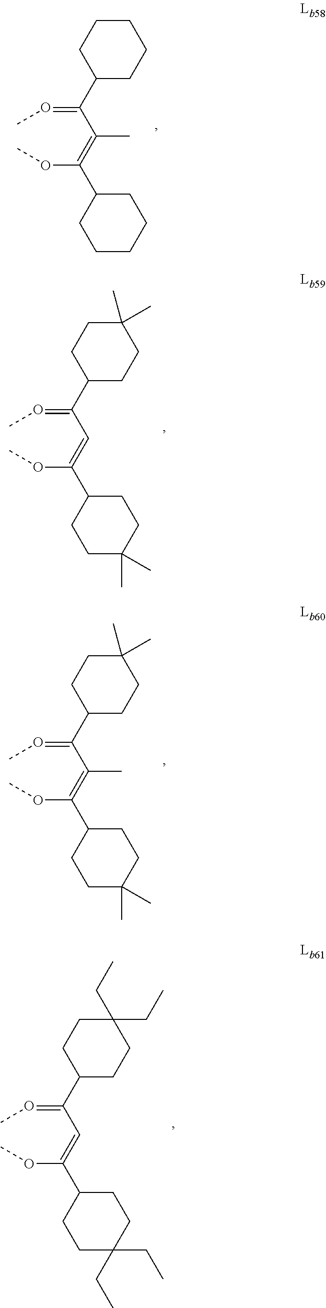 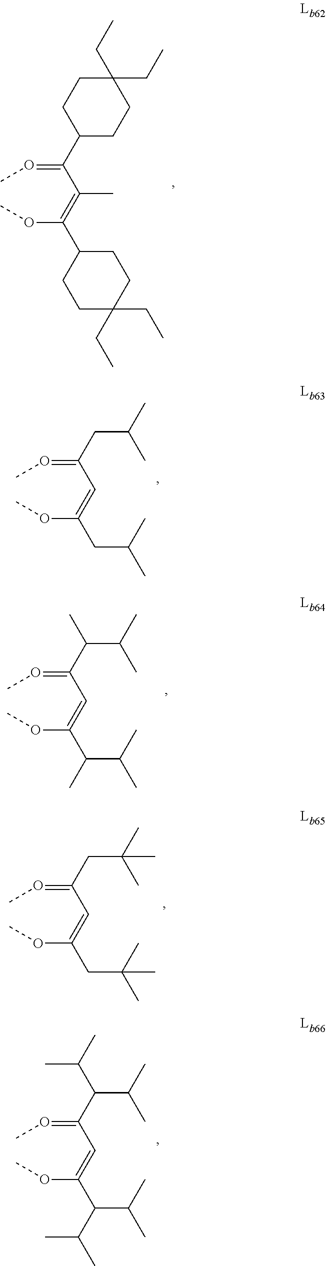 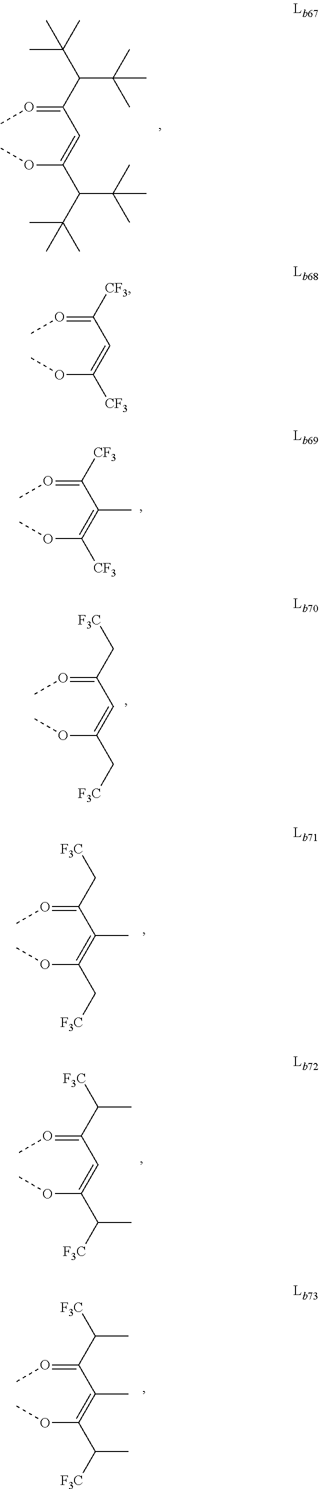 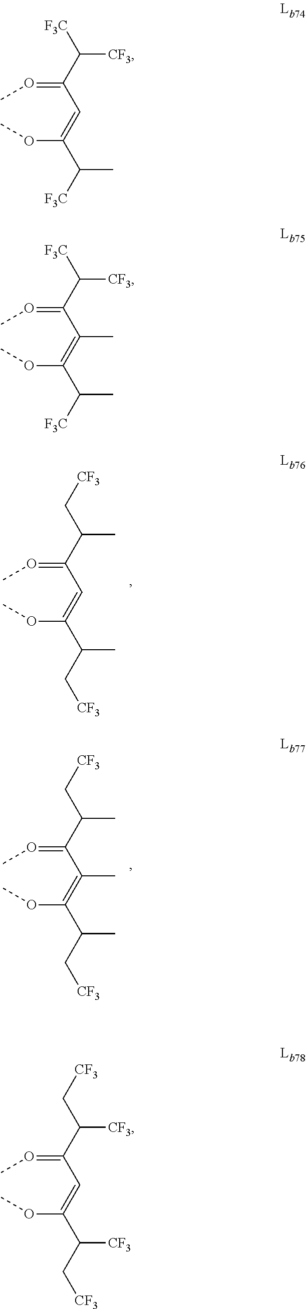 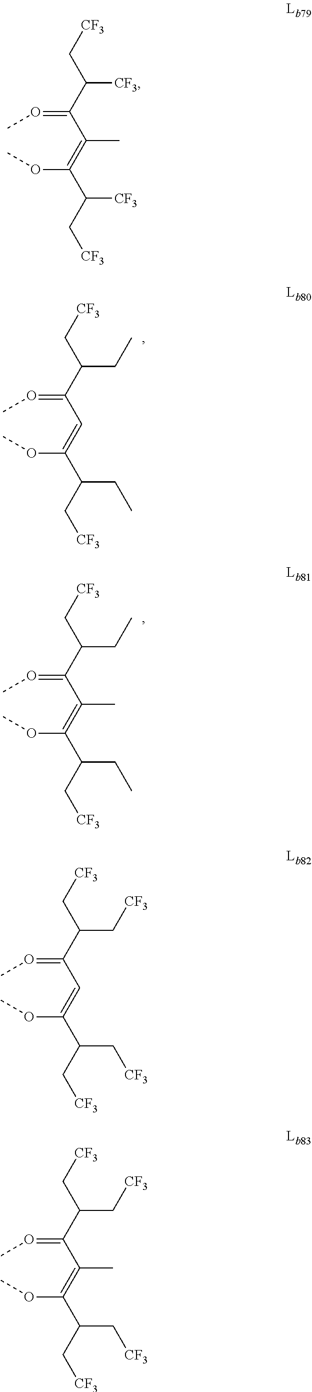 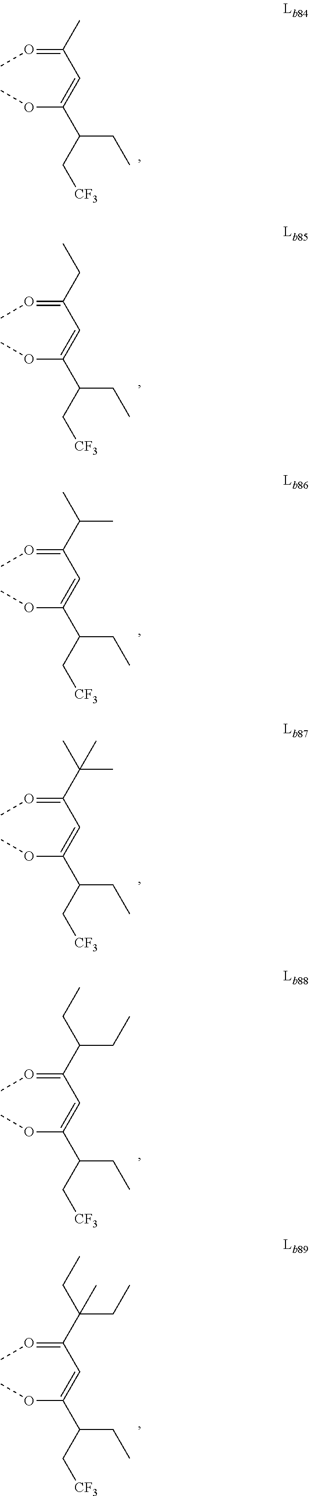 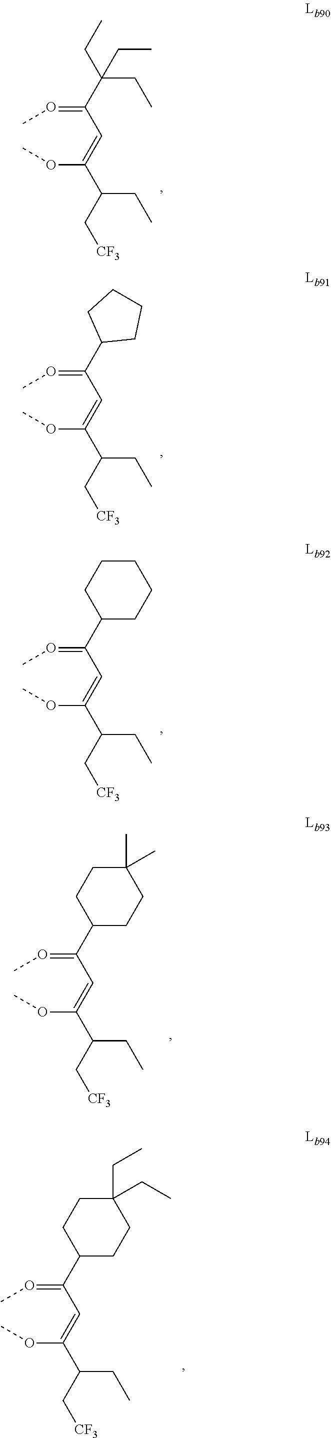 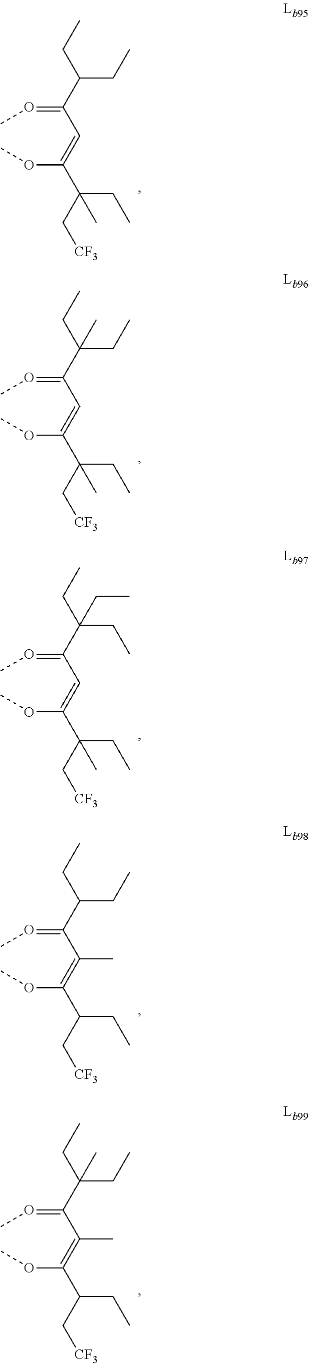 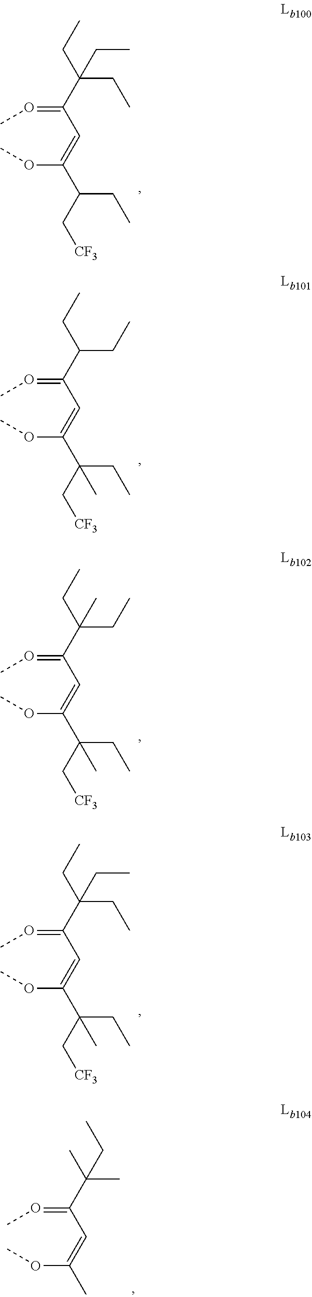 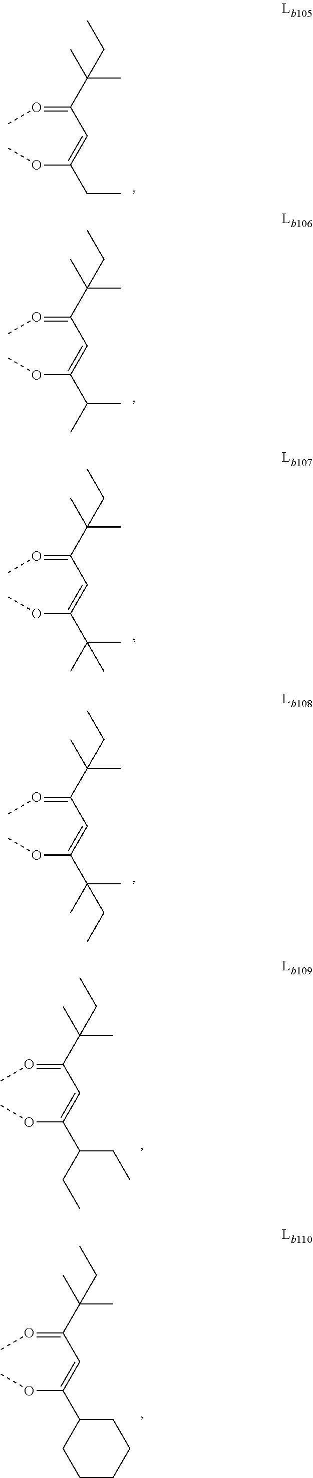 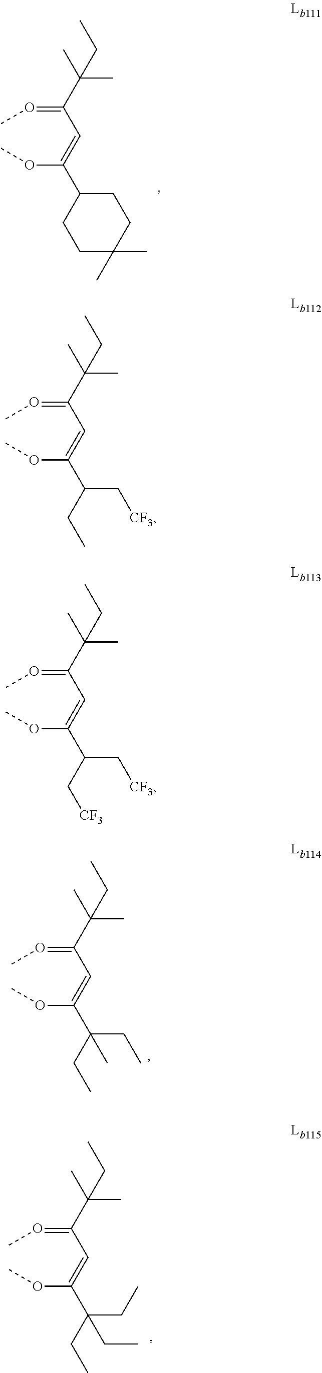 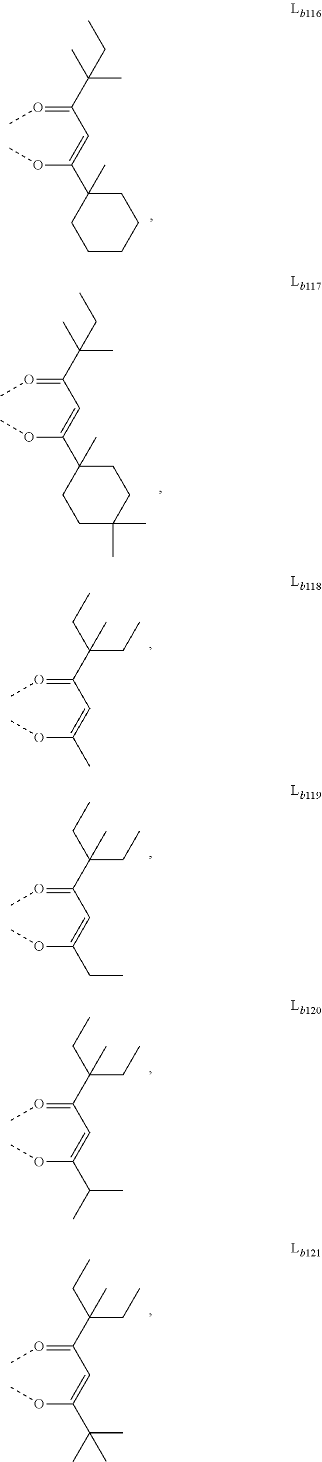 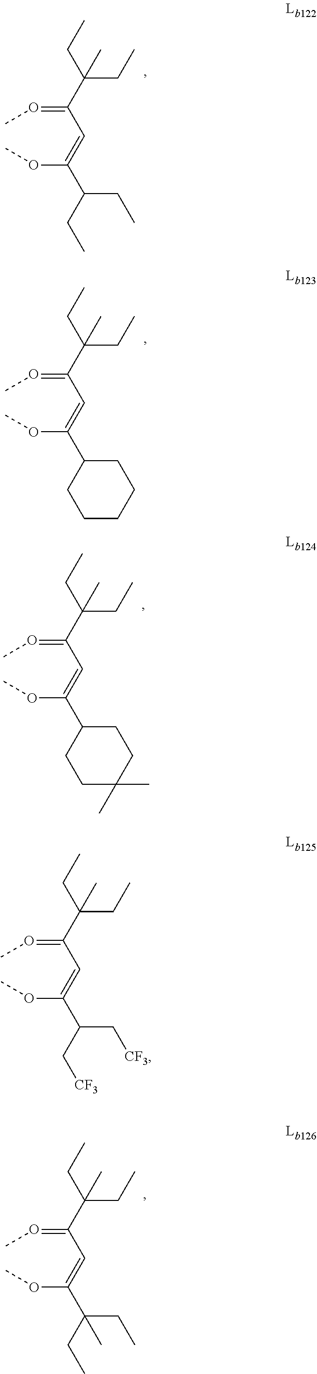 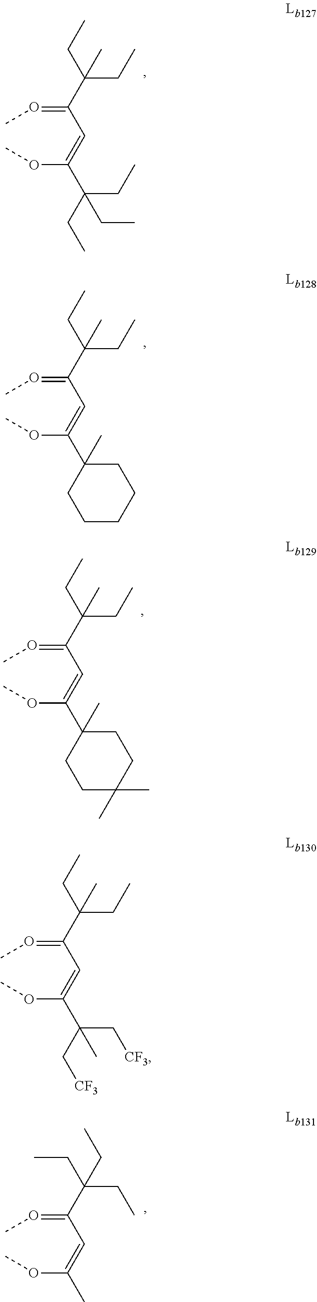 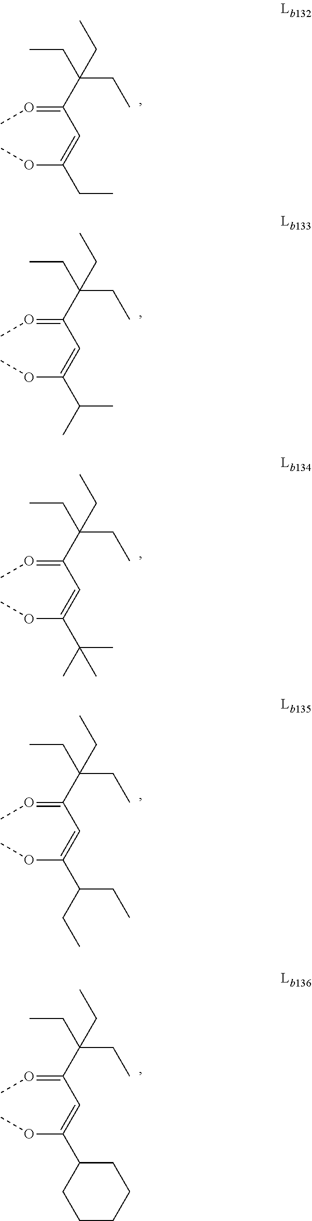 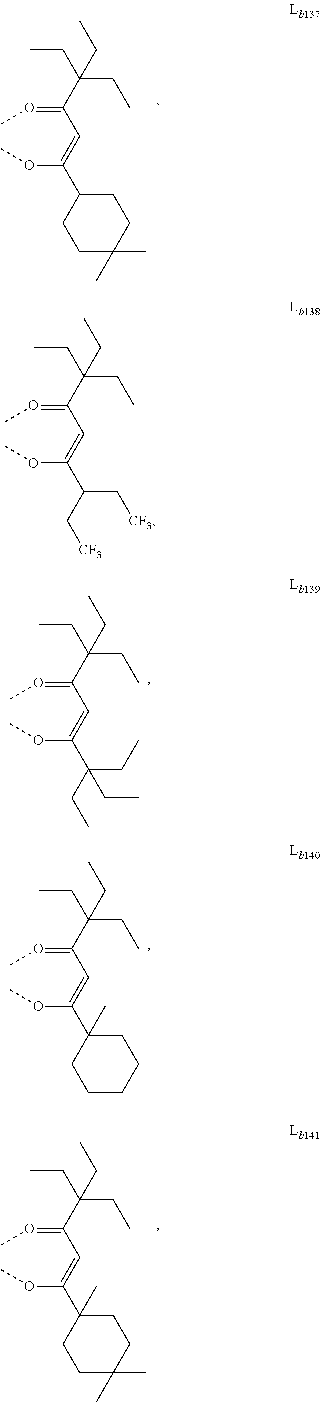 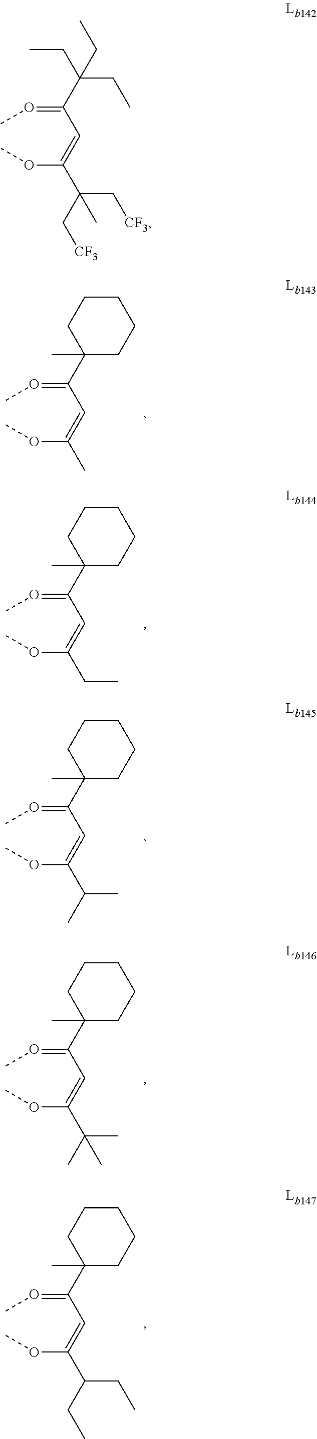 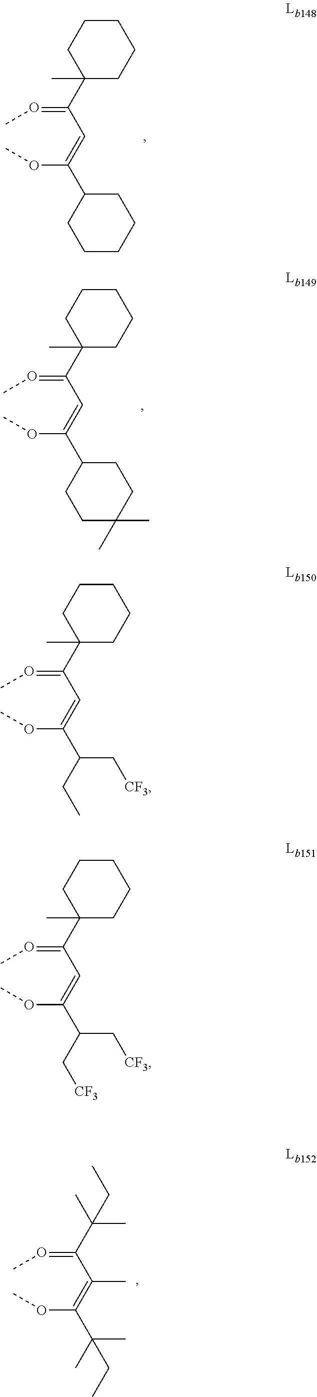 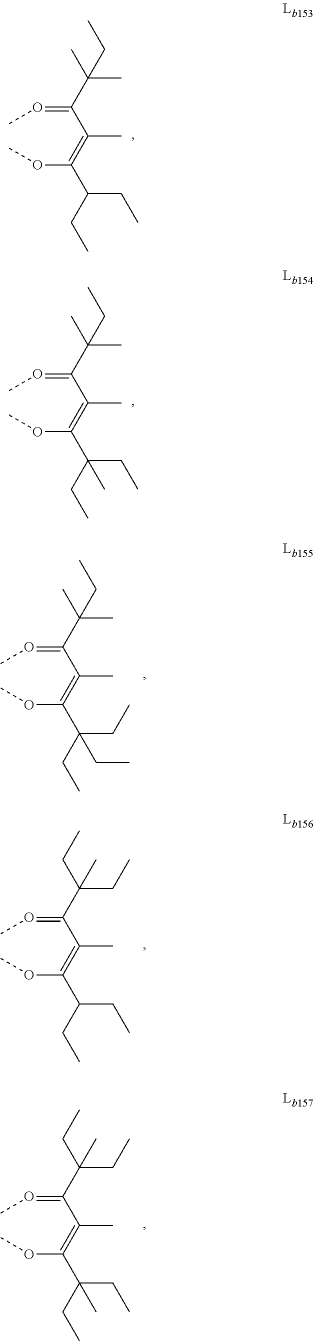 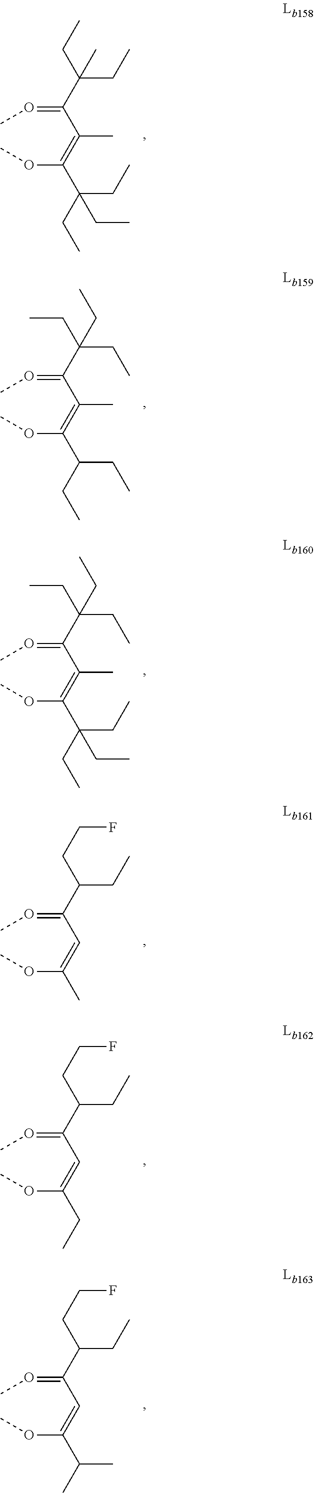 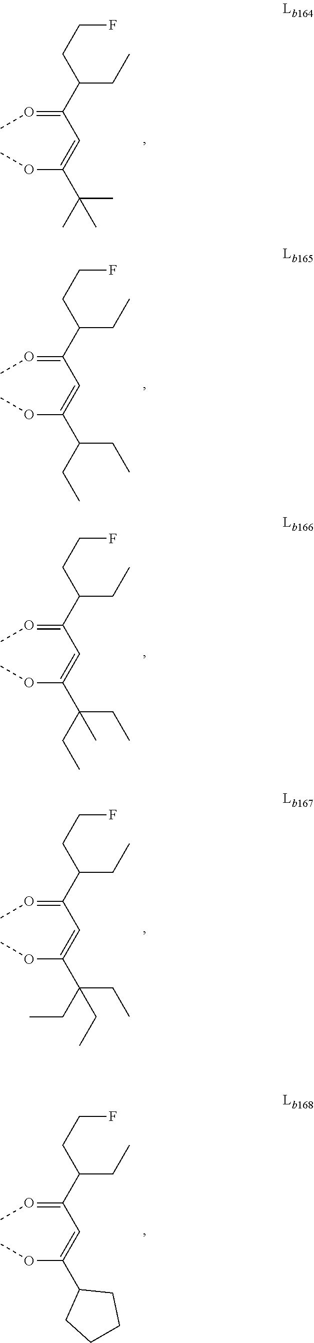 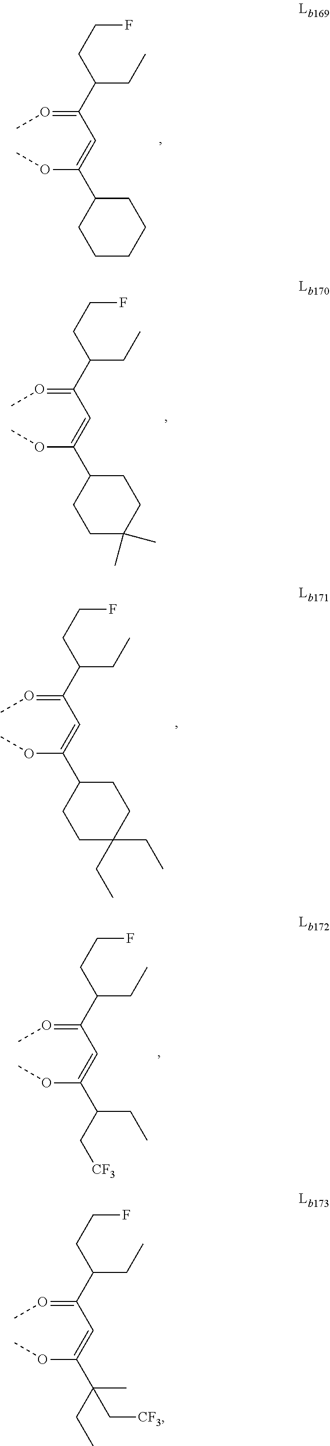 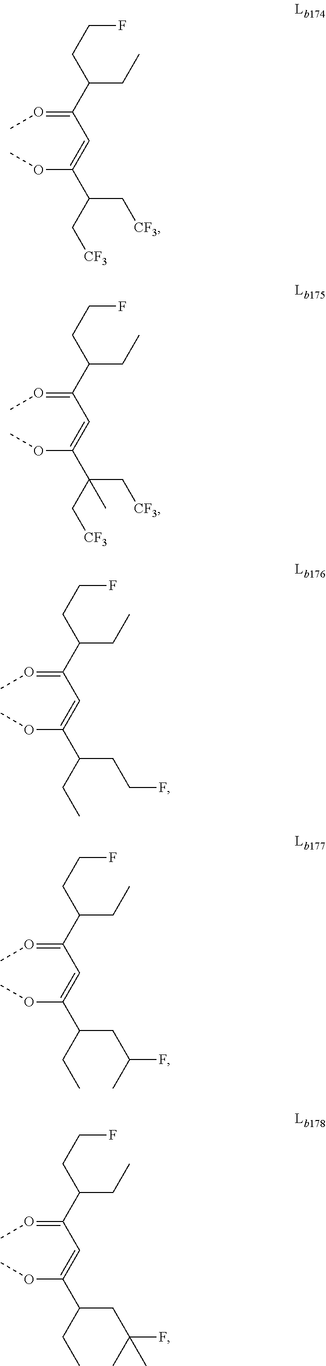 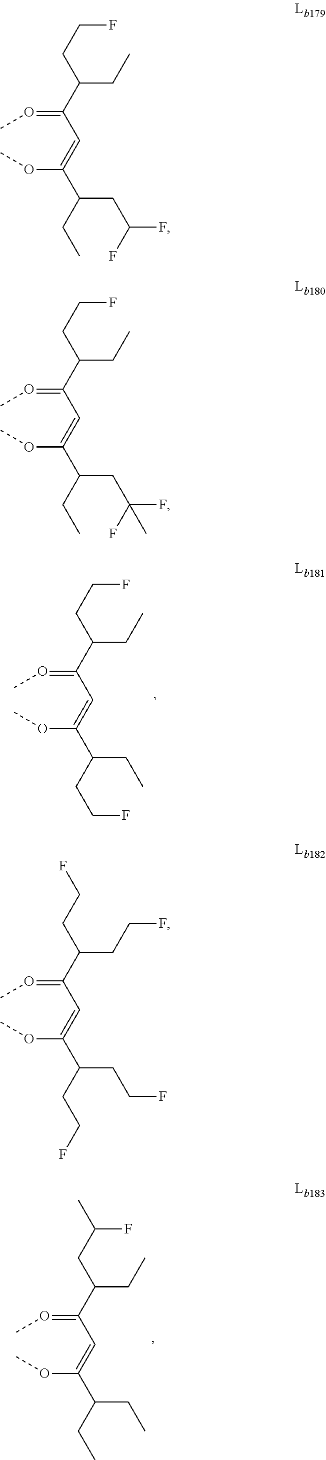 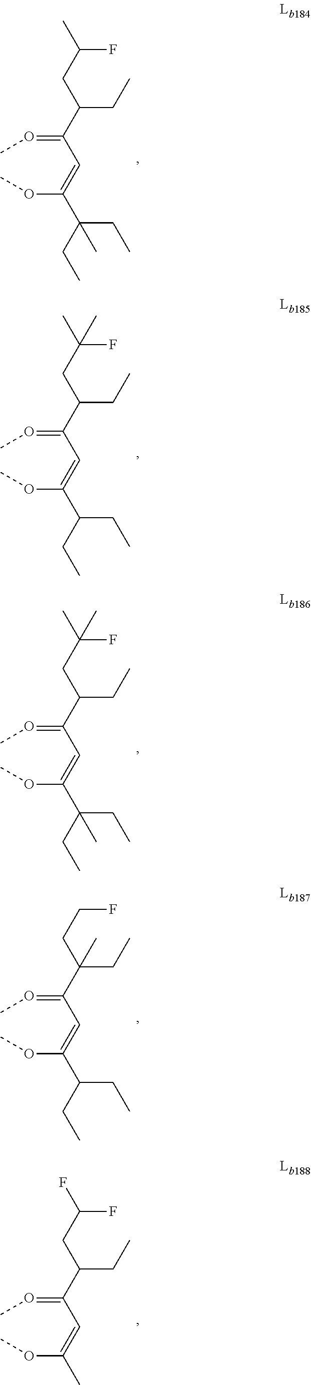 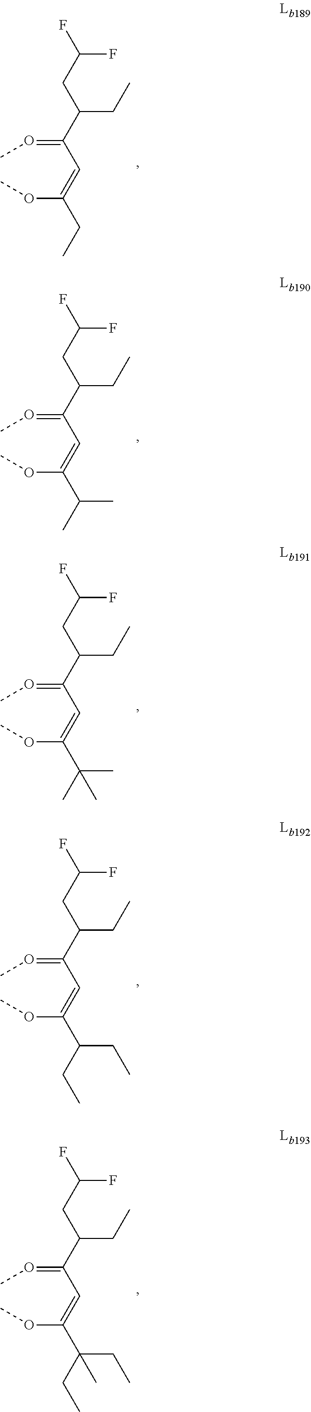 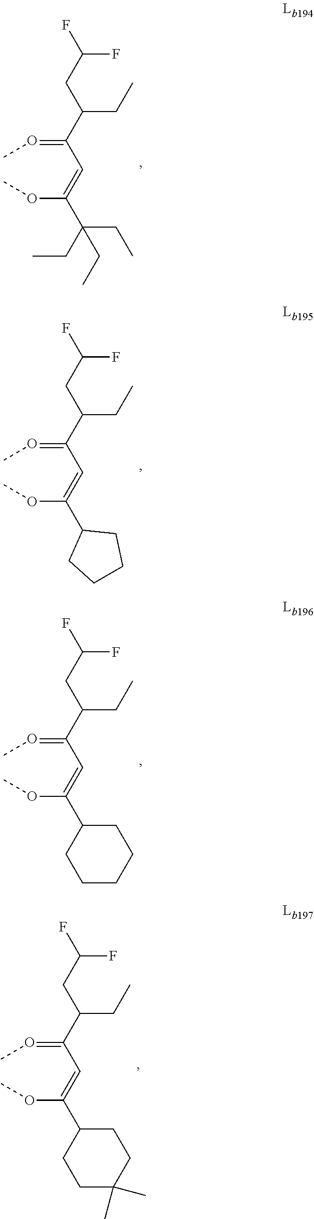 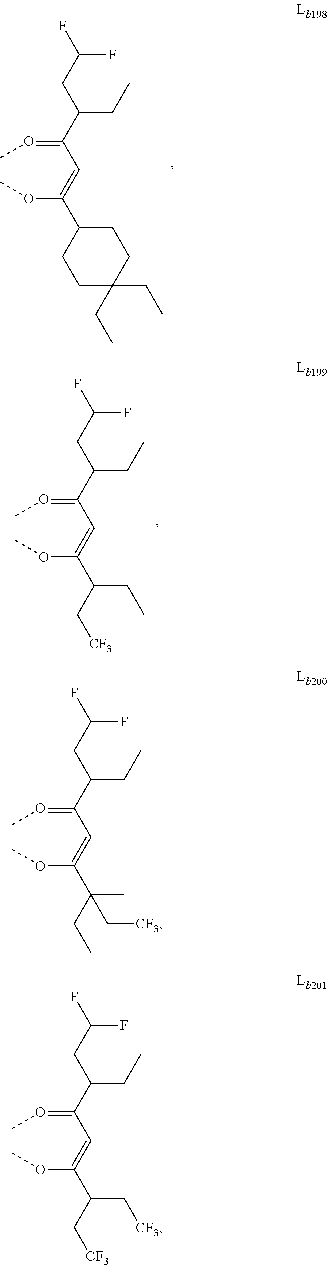 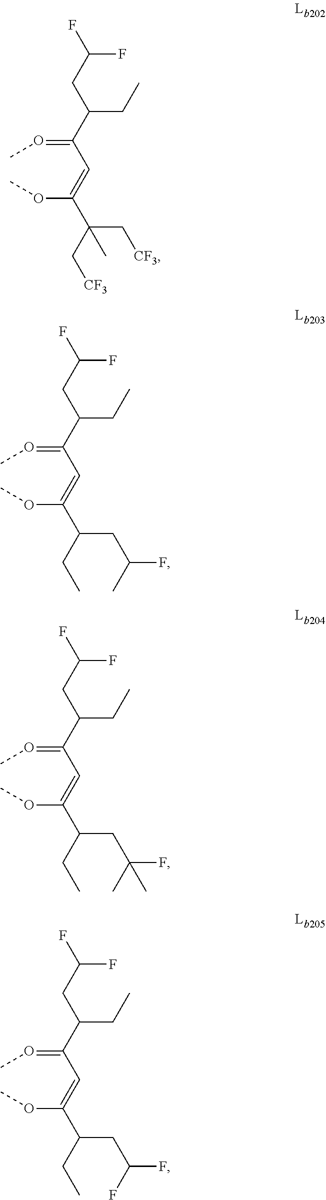 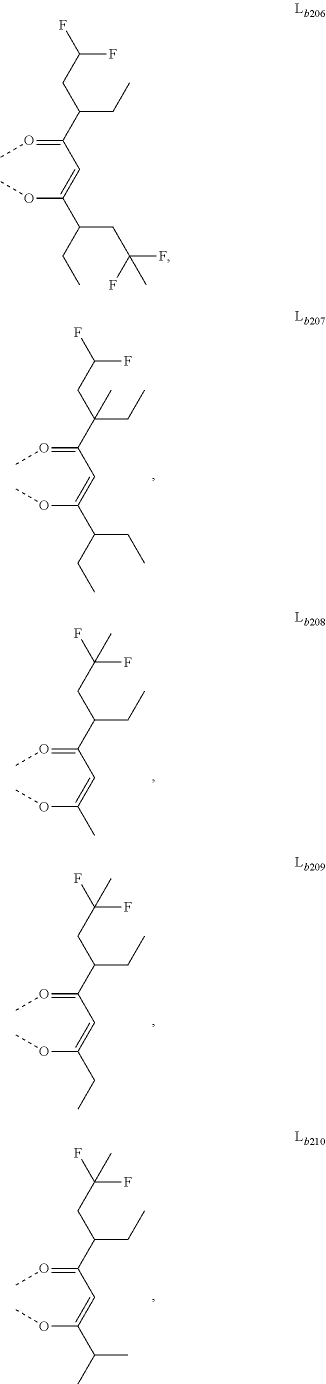 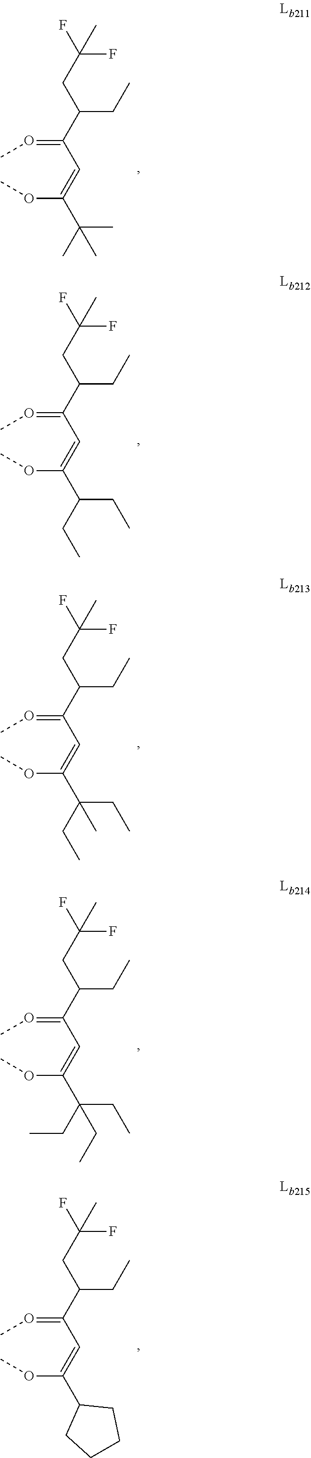 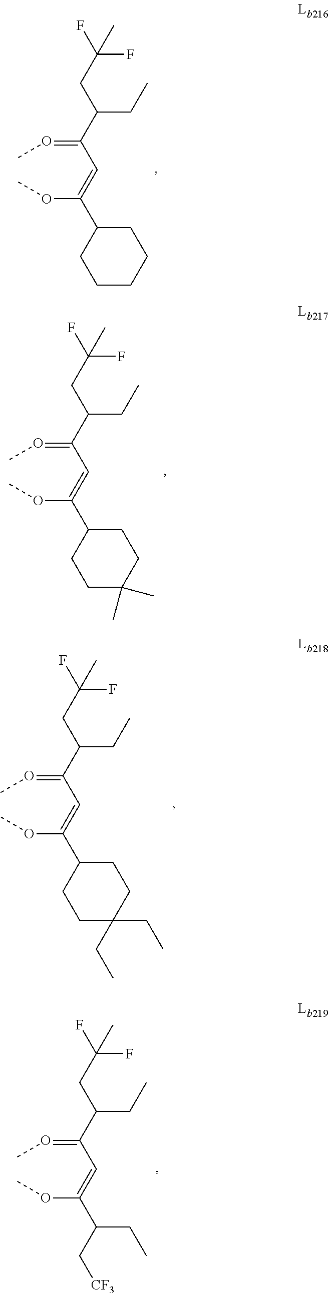 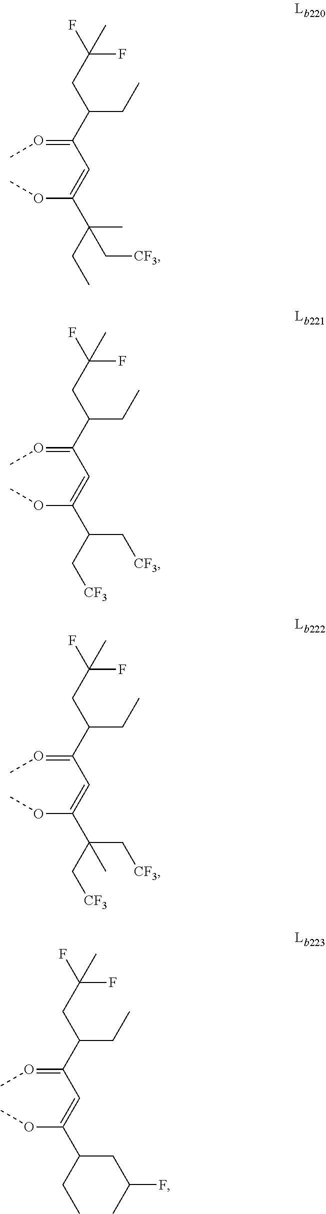 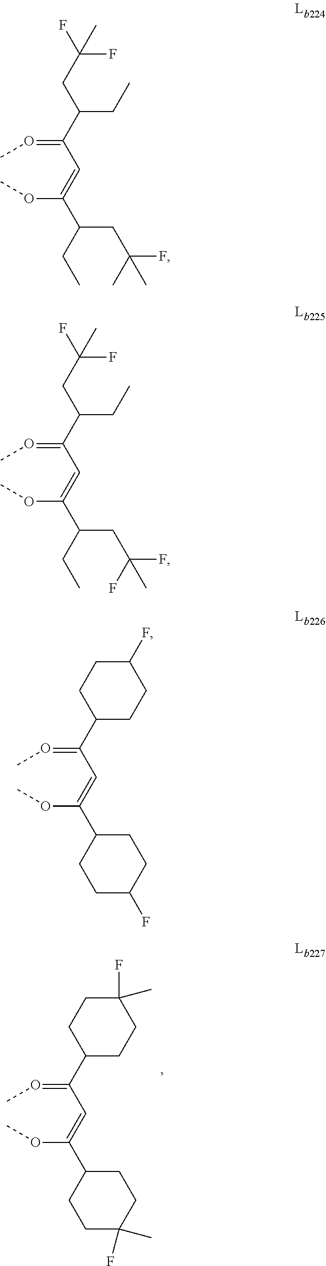 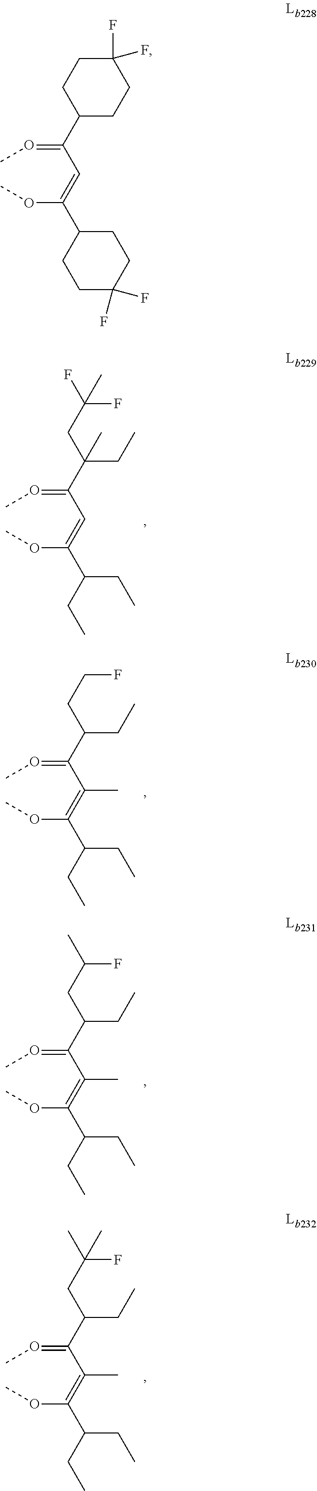 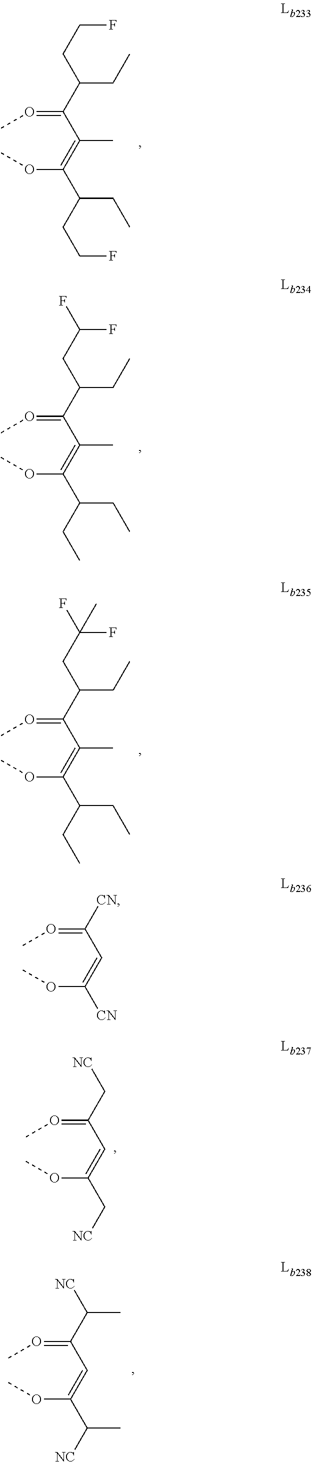 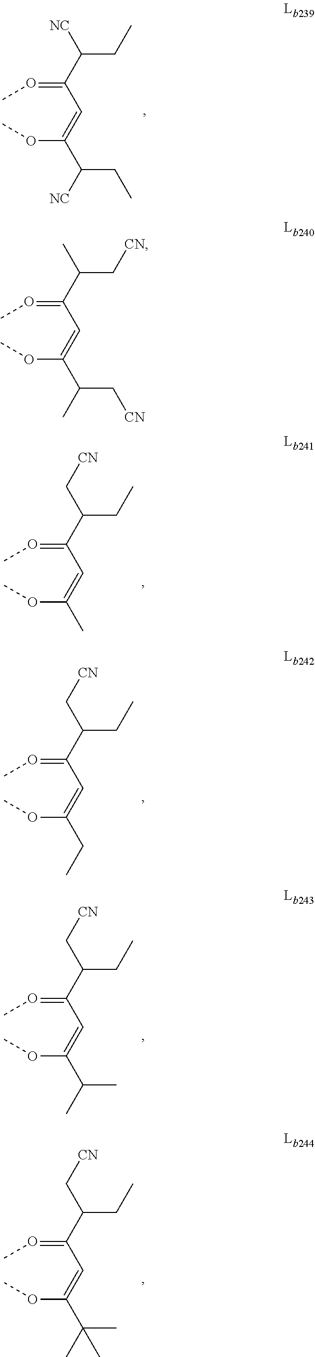 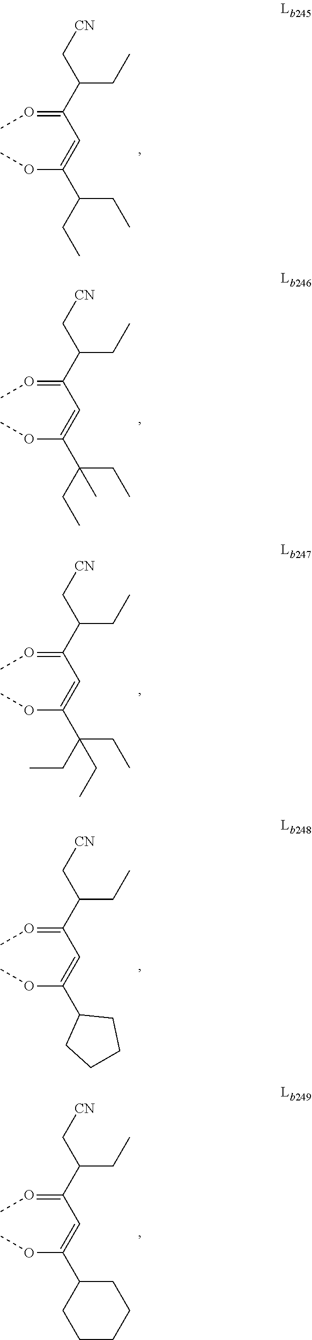 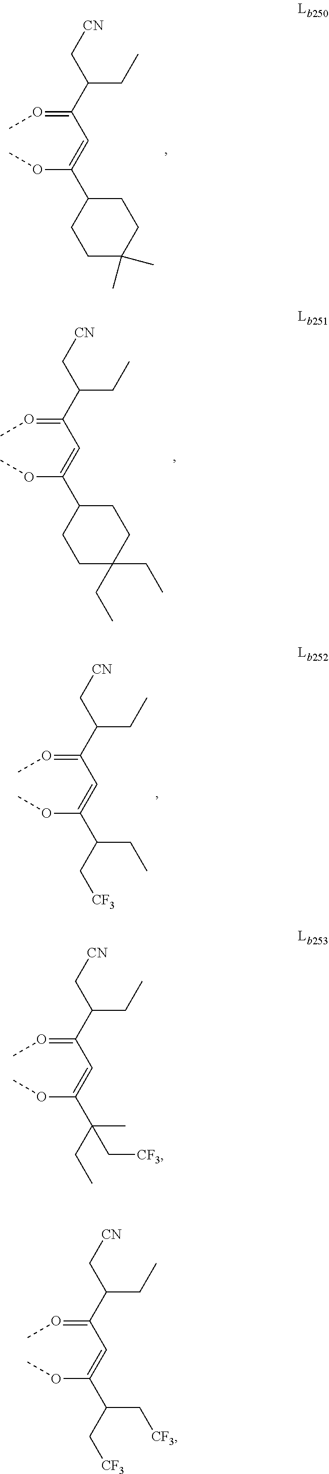 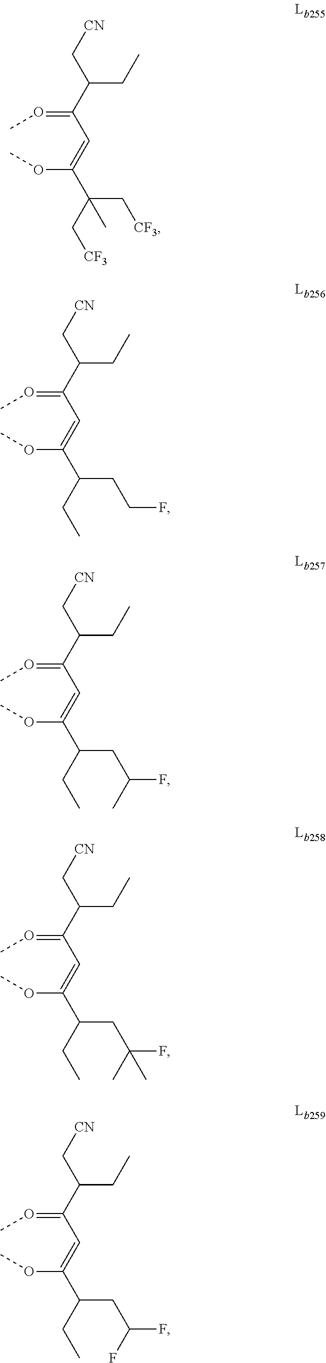 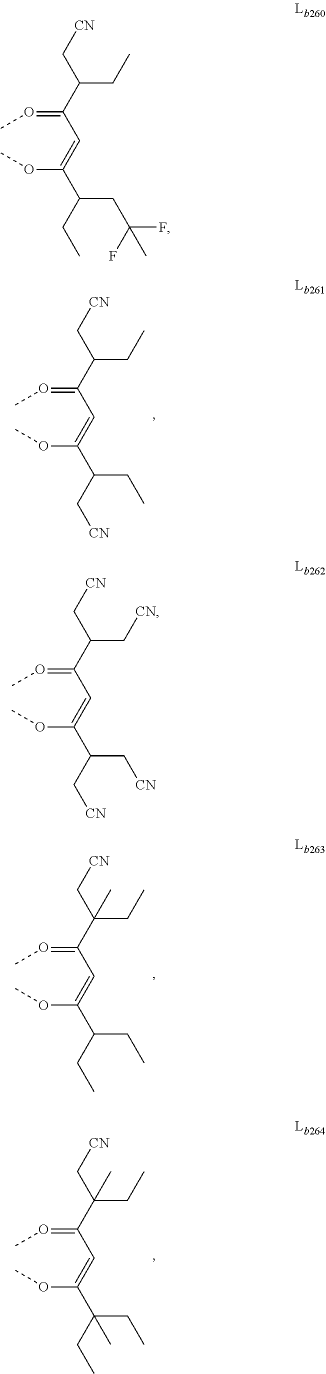 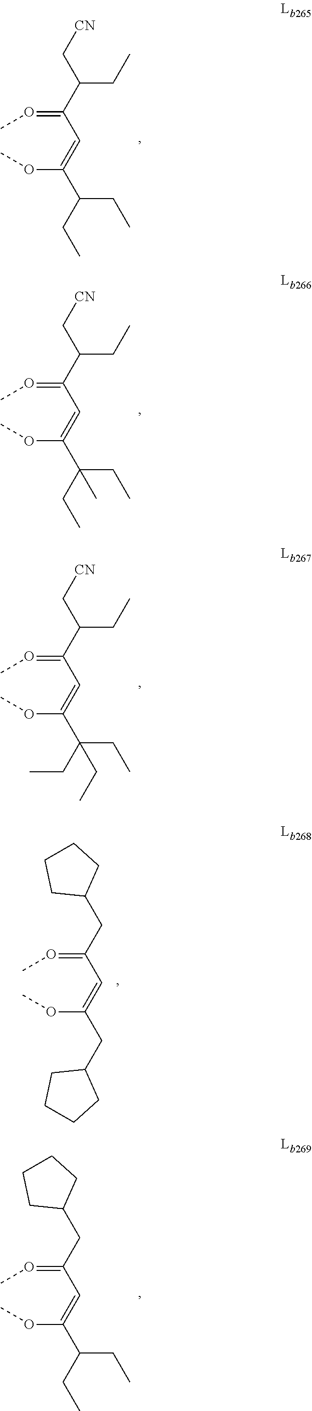 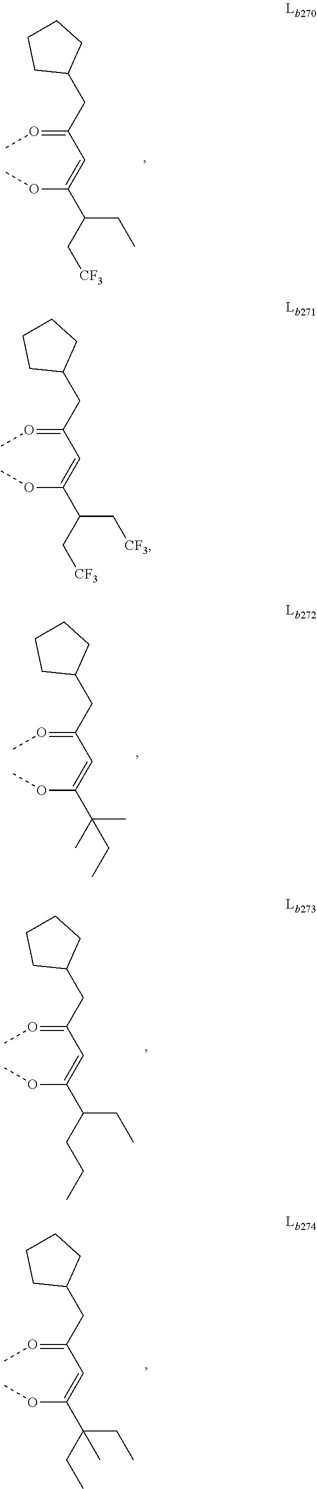 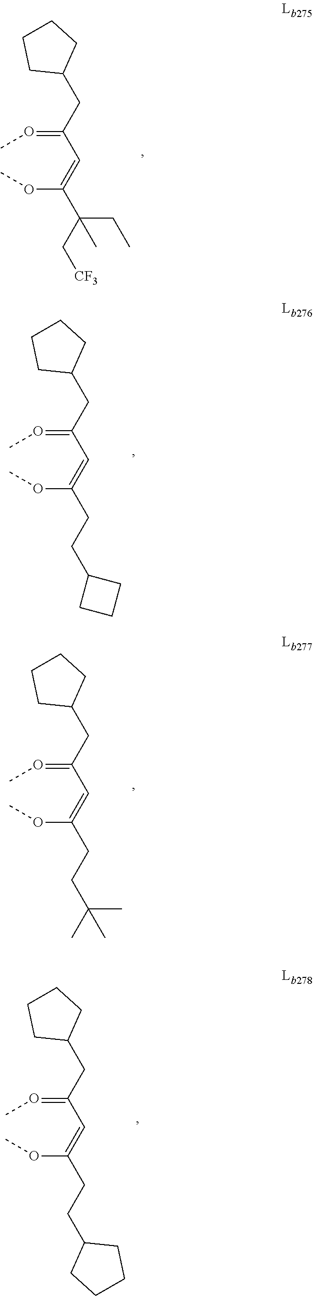 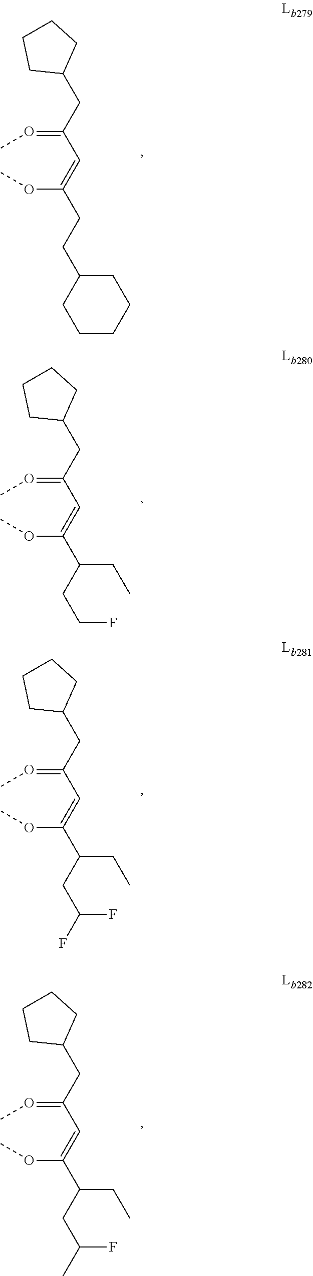 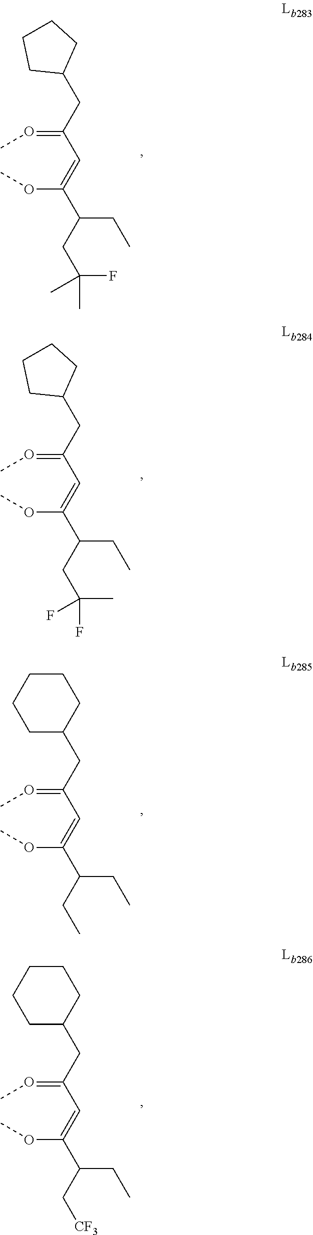 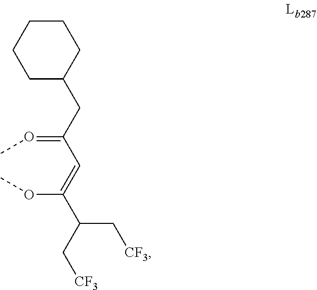 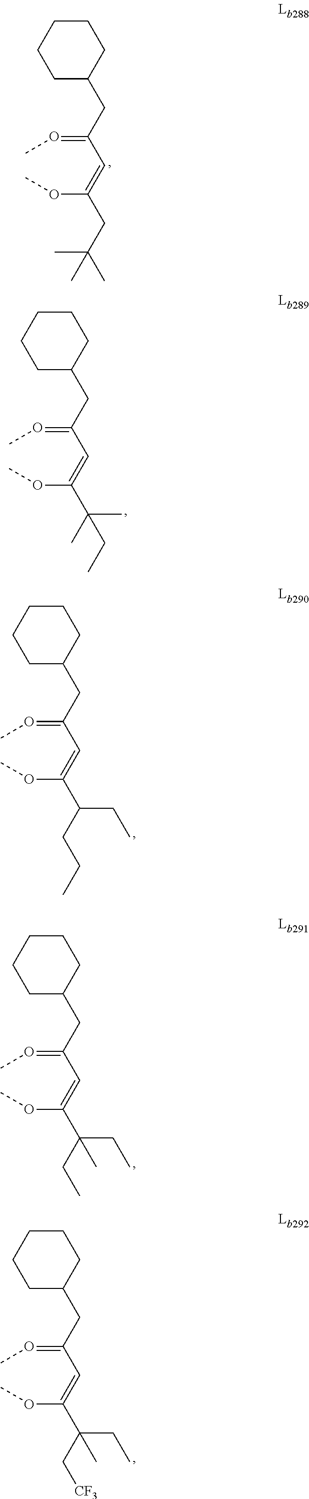 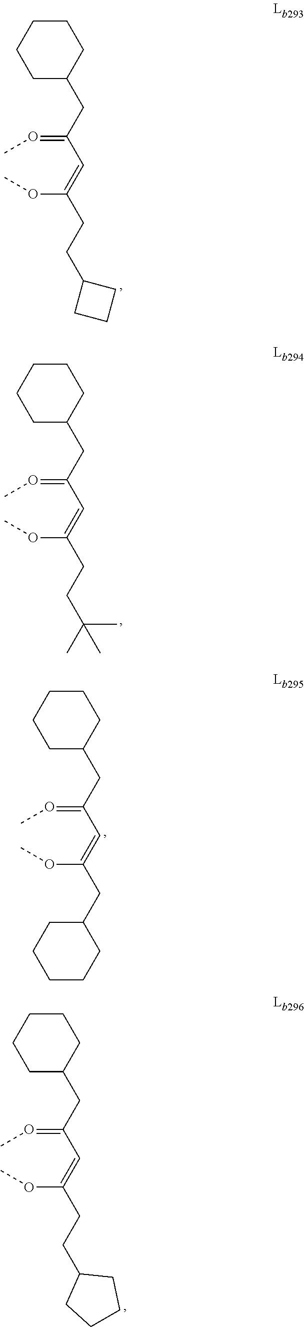 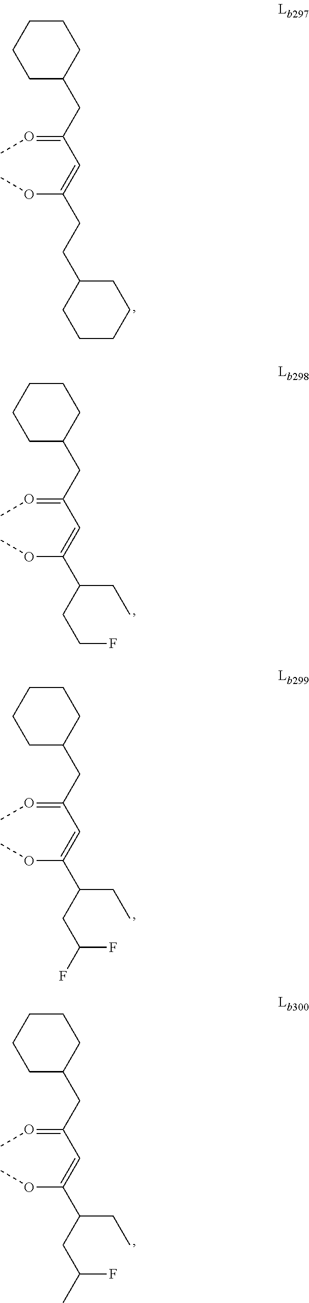 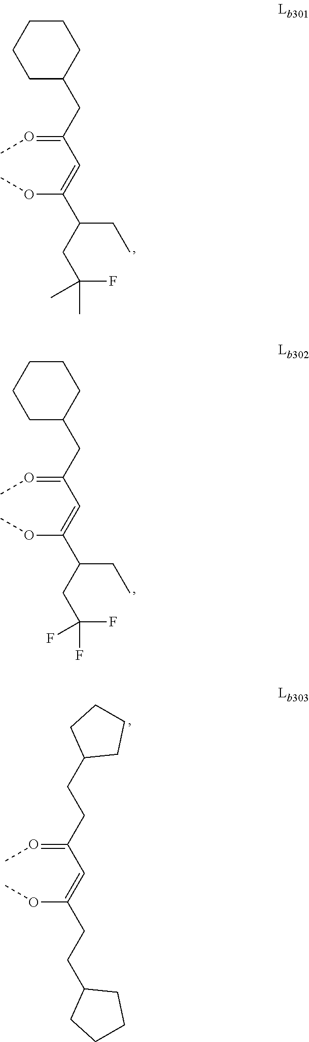 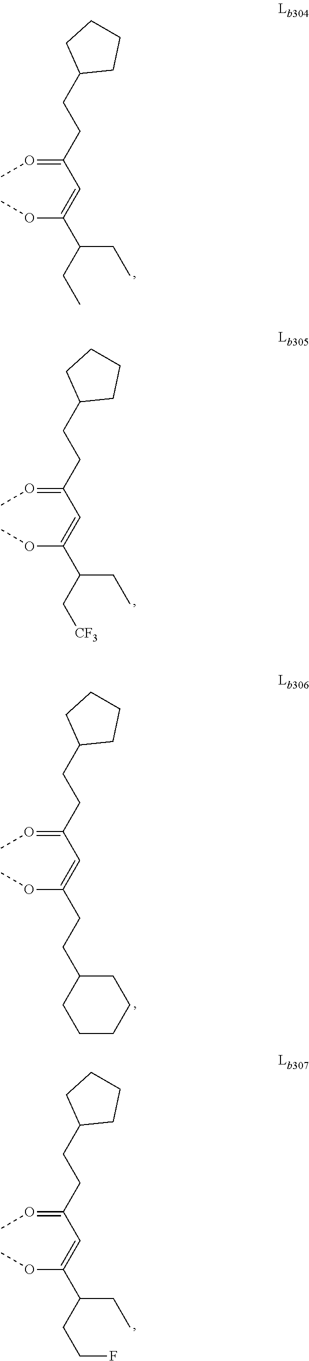 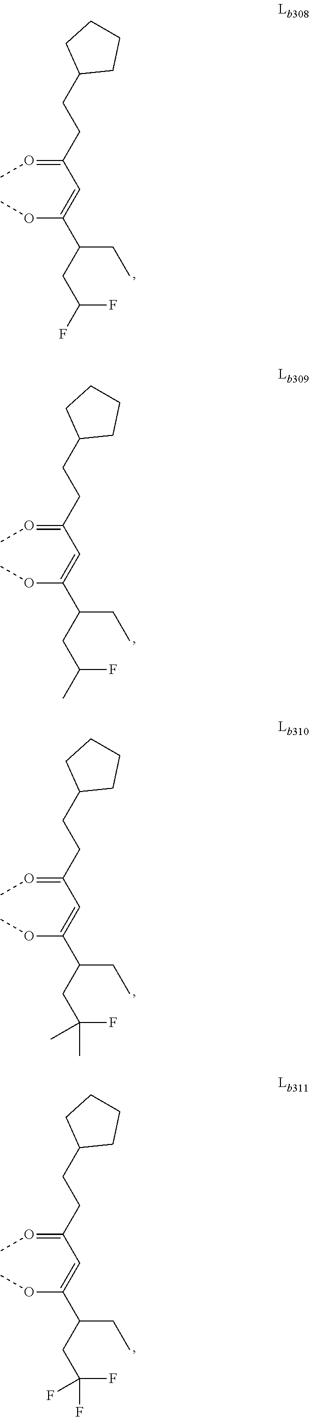 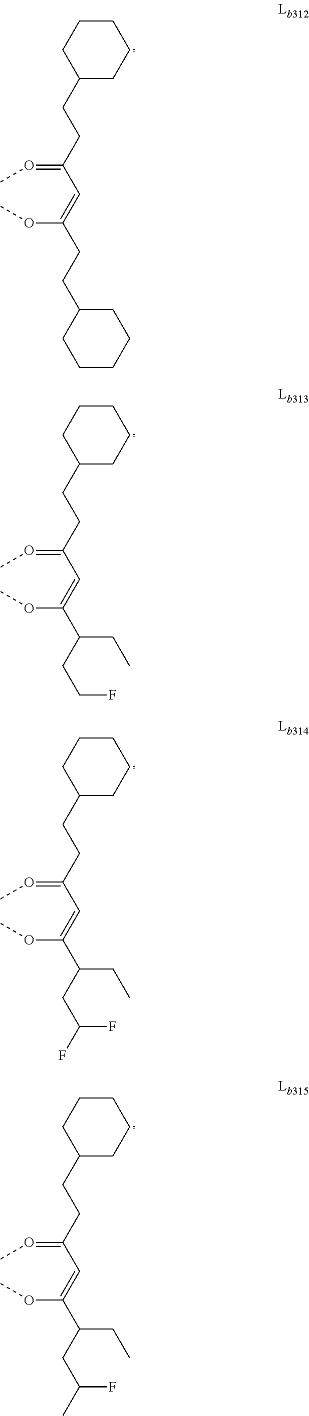 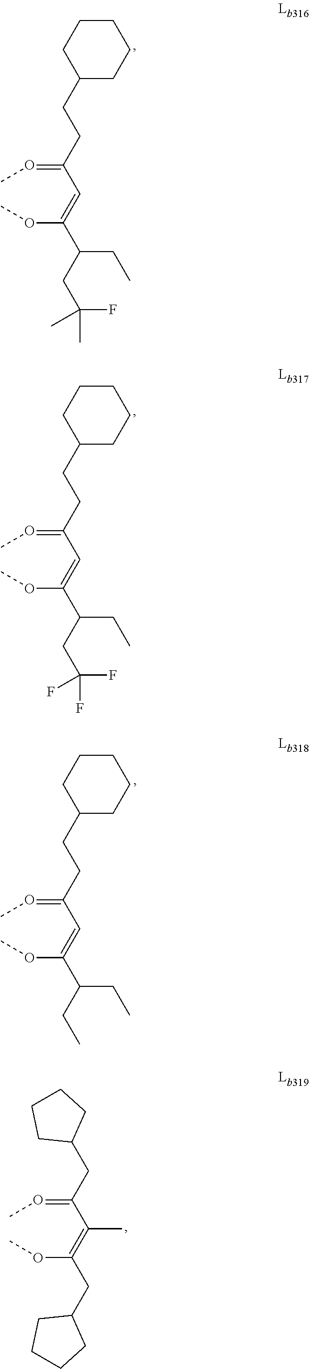 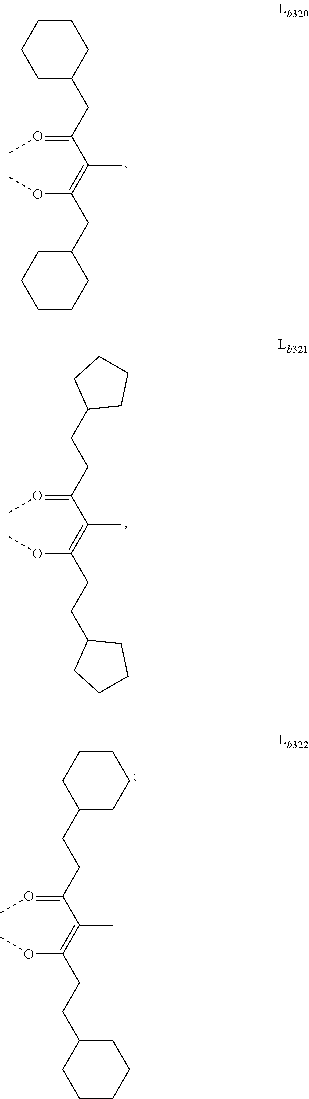
wherein L_{c} is, at each occurrence identically or differently, selected from the group consisting of L_{c1} to L_{c231}:

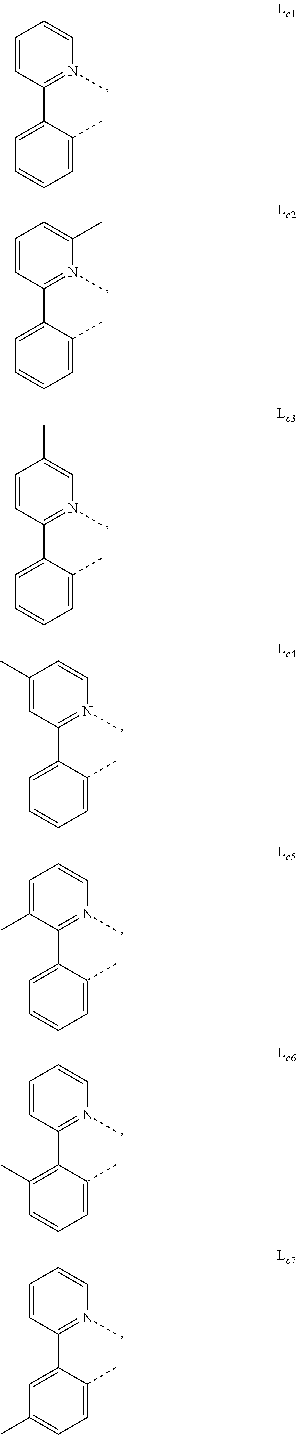

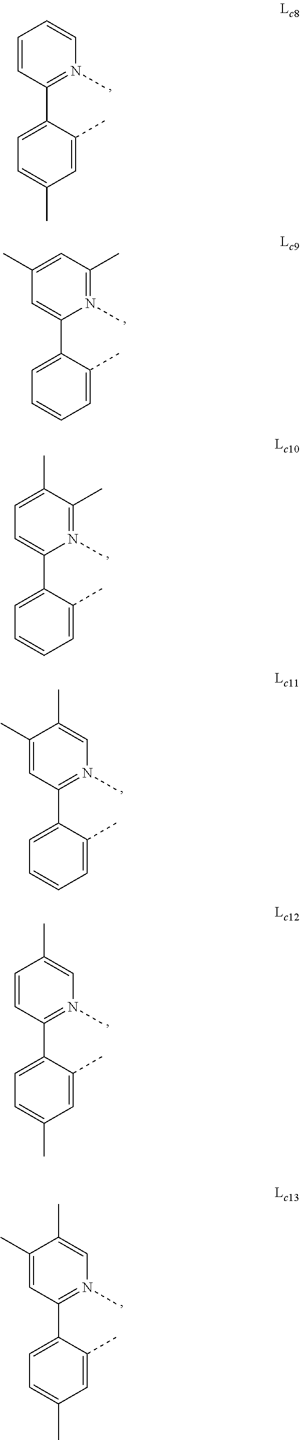

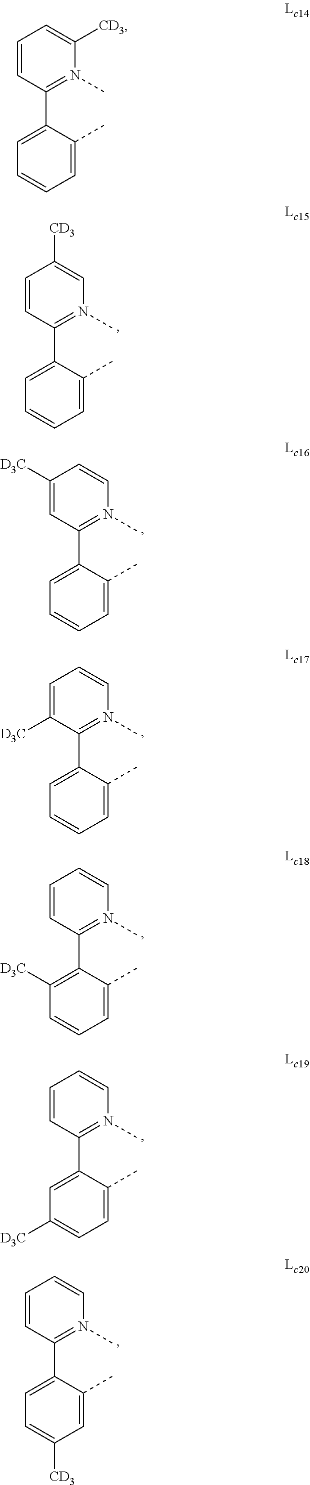

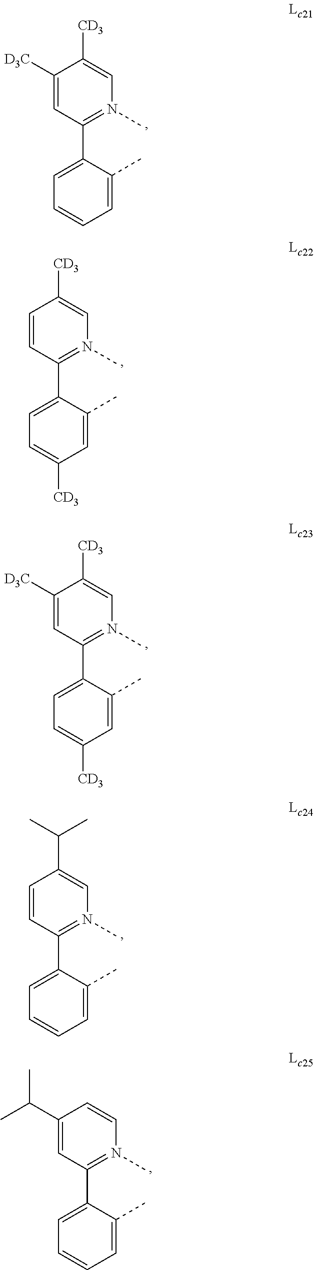

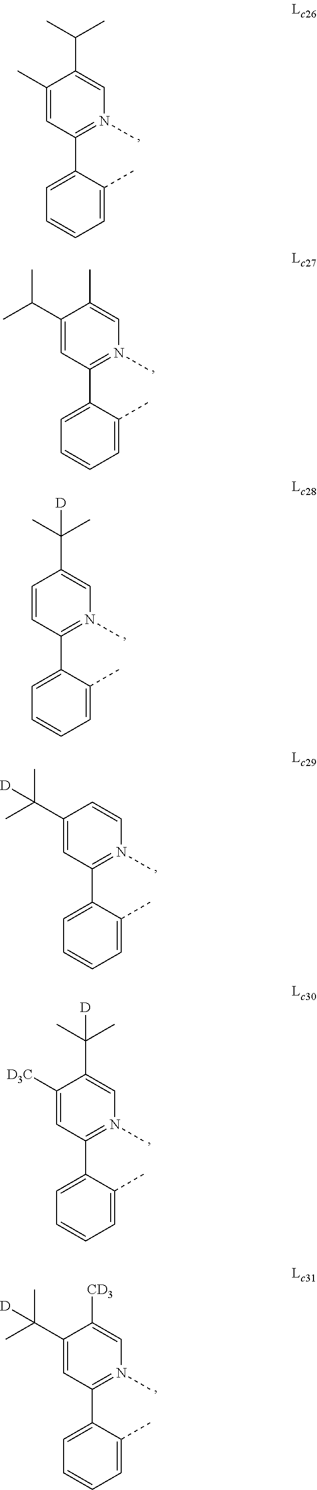

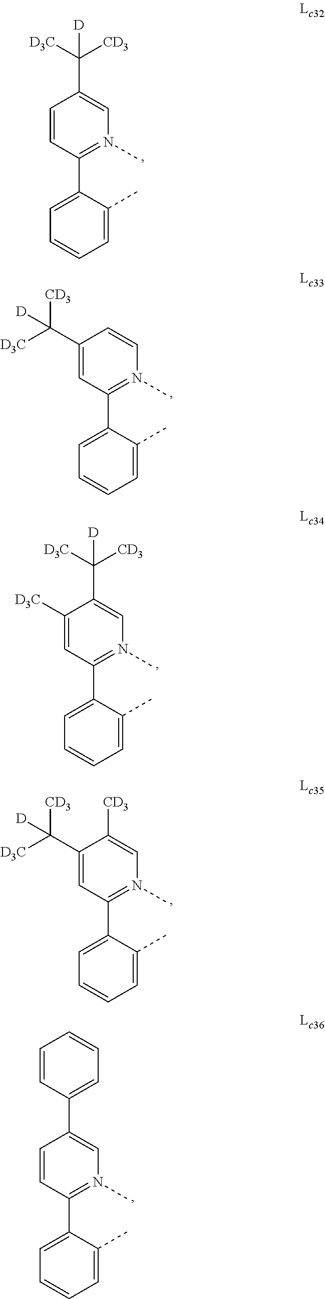

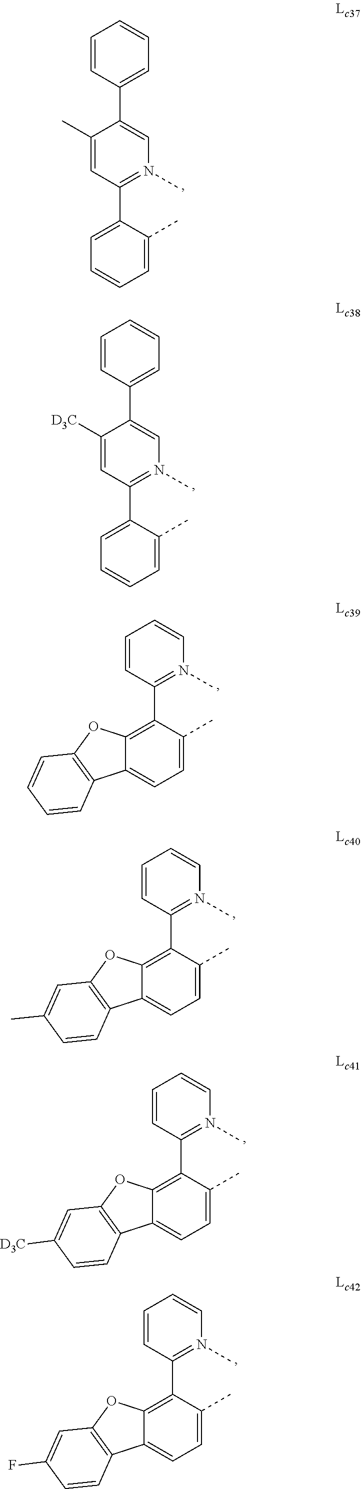

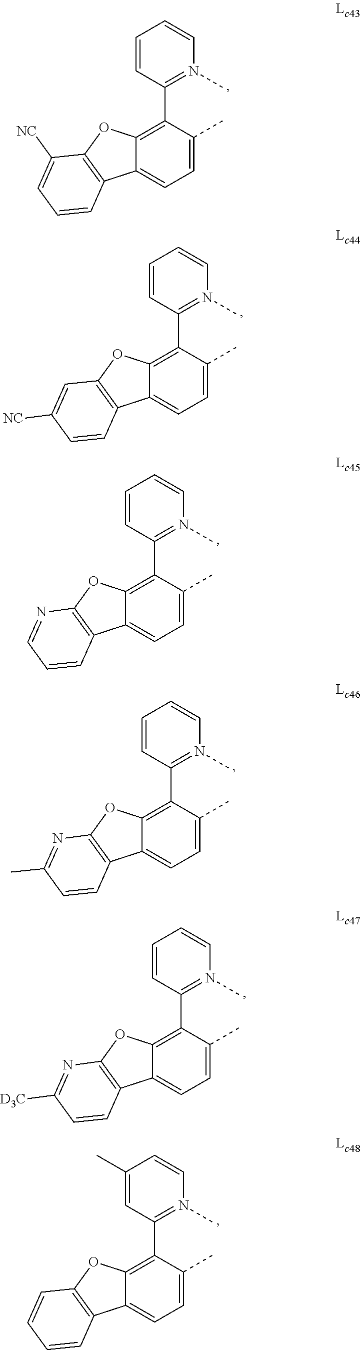

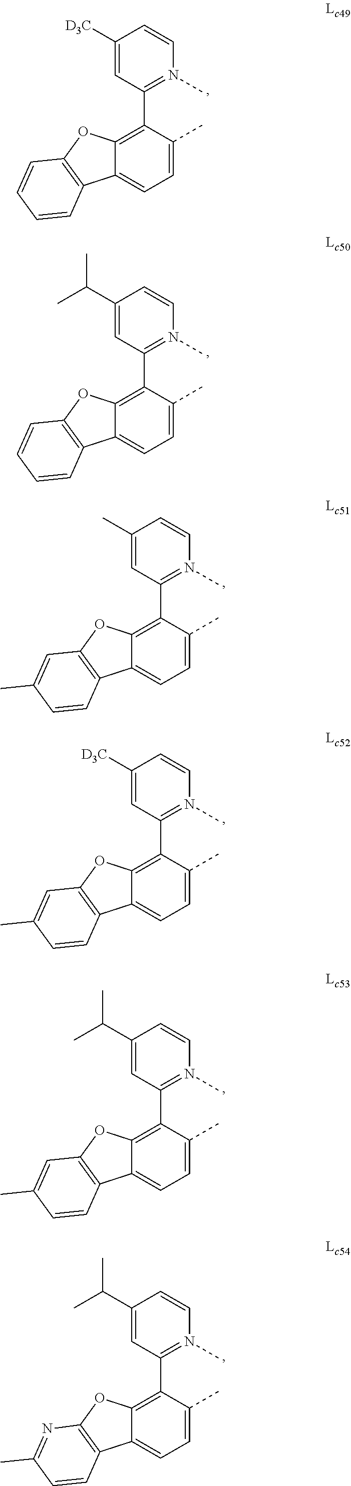

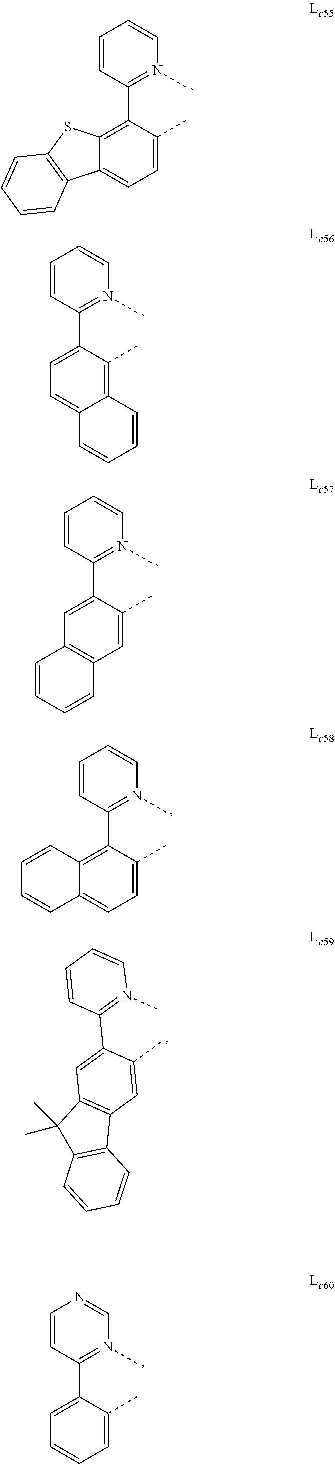

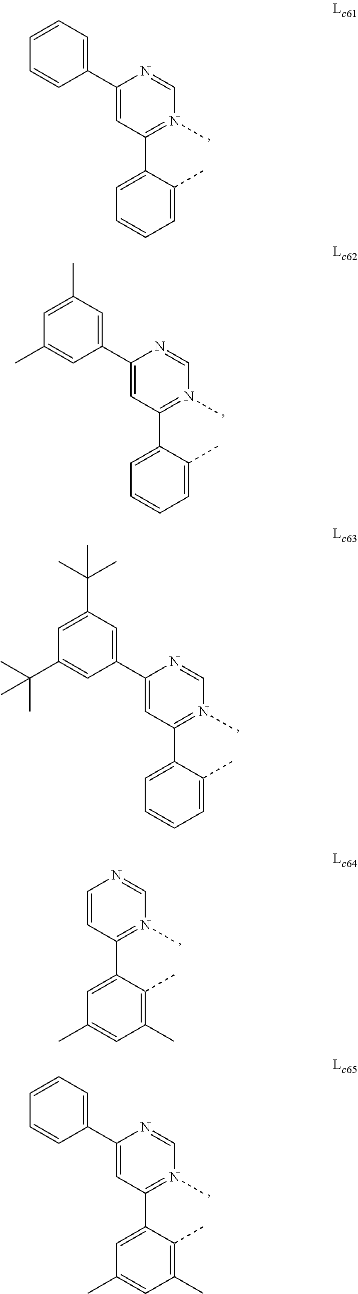

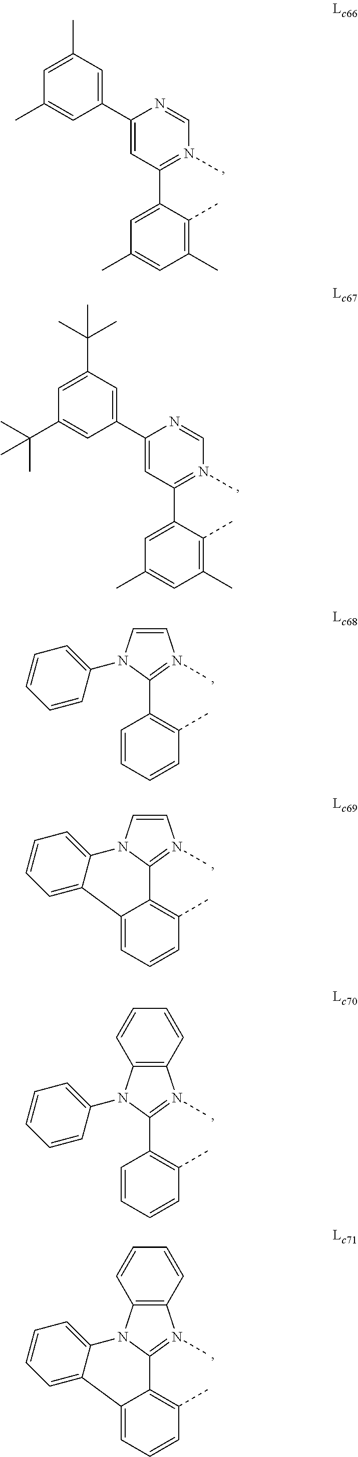

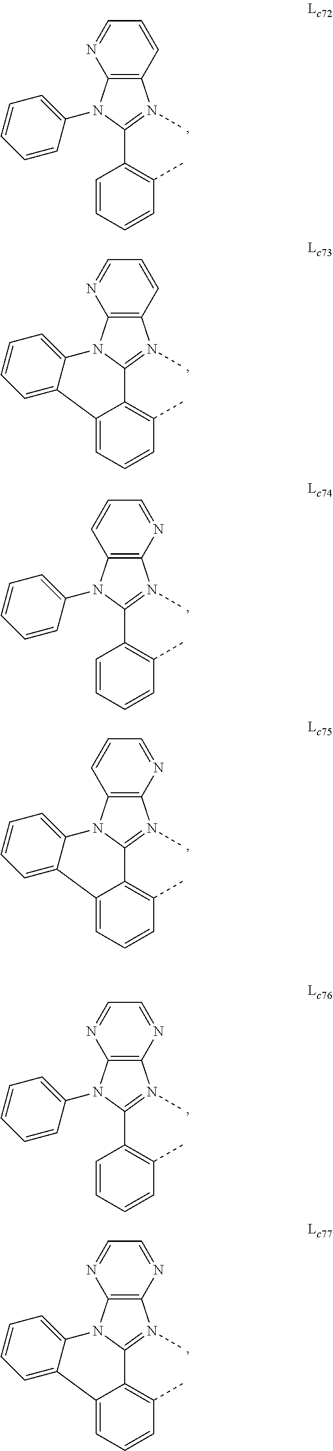

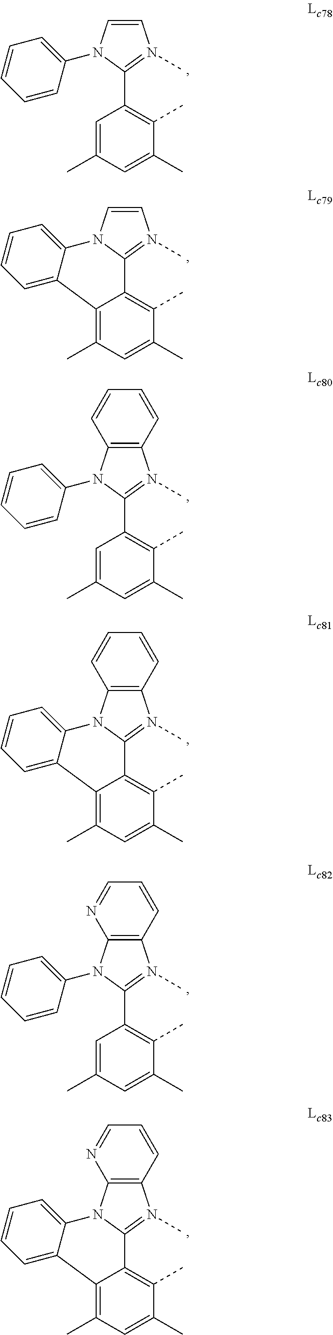

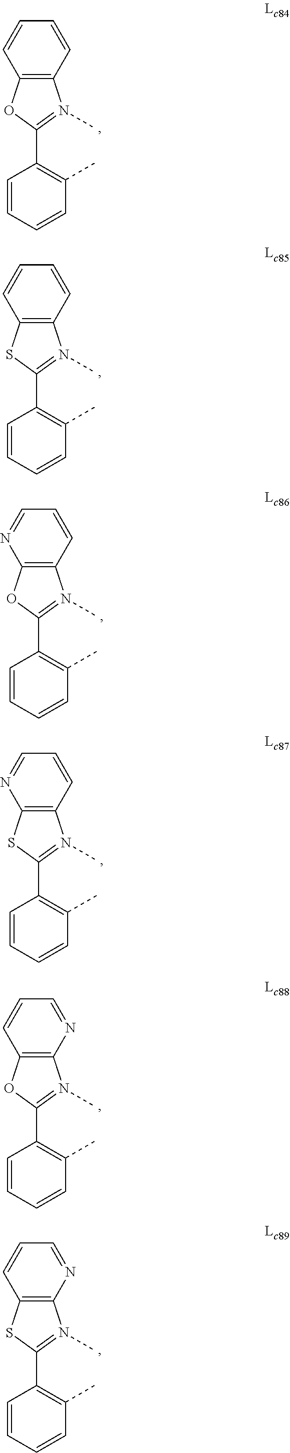

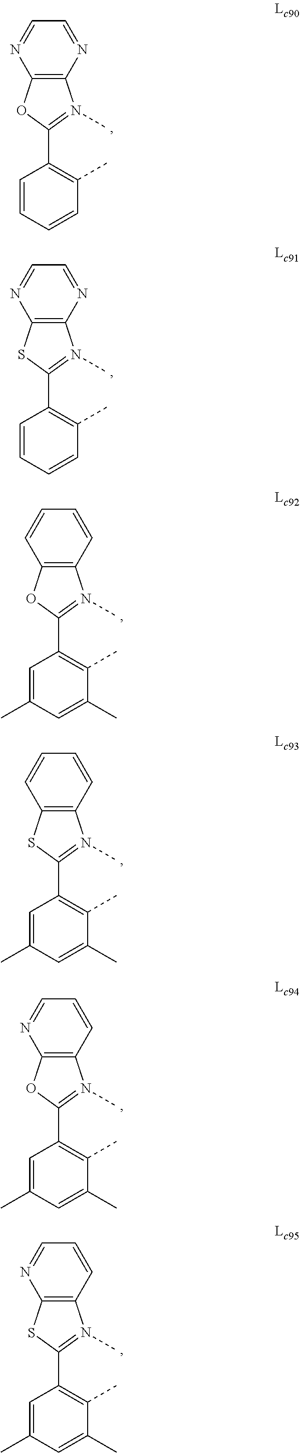

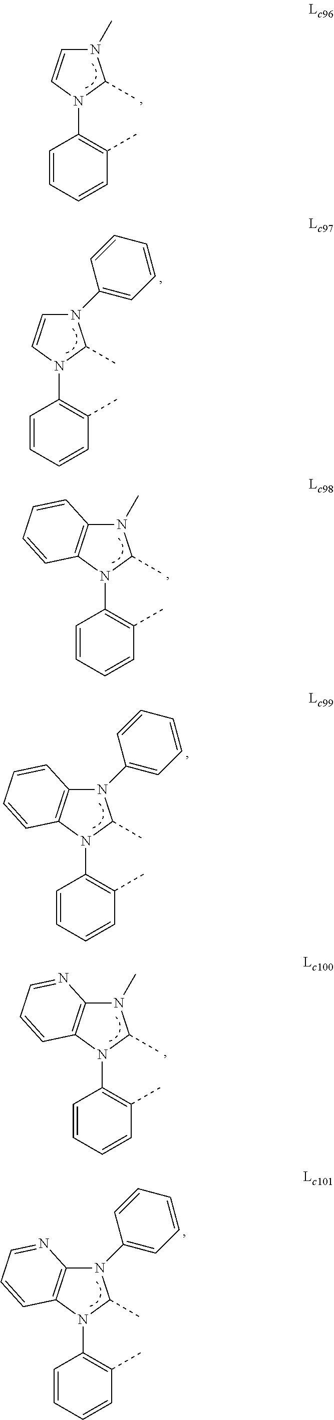

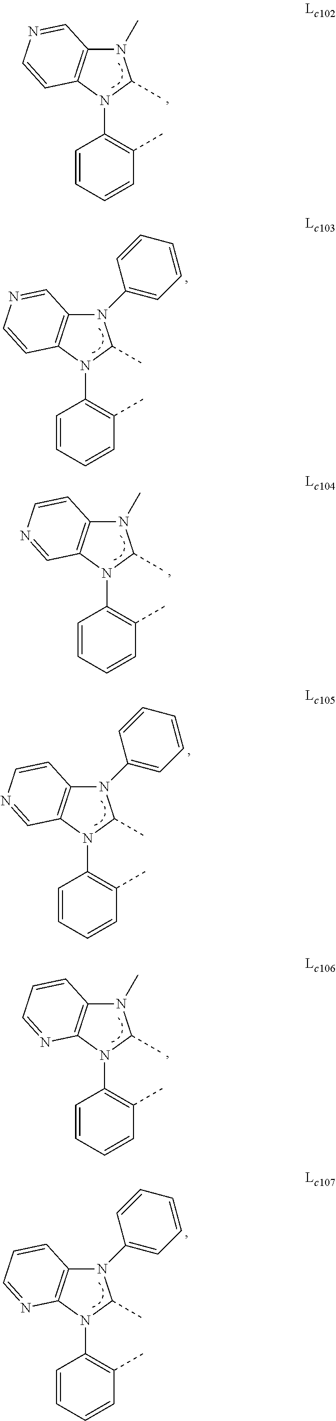

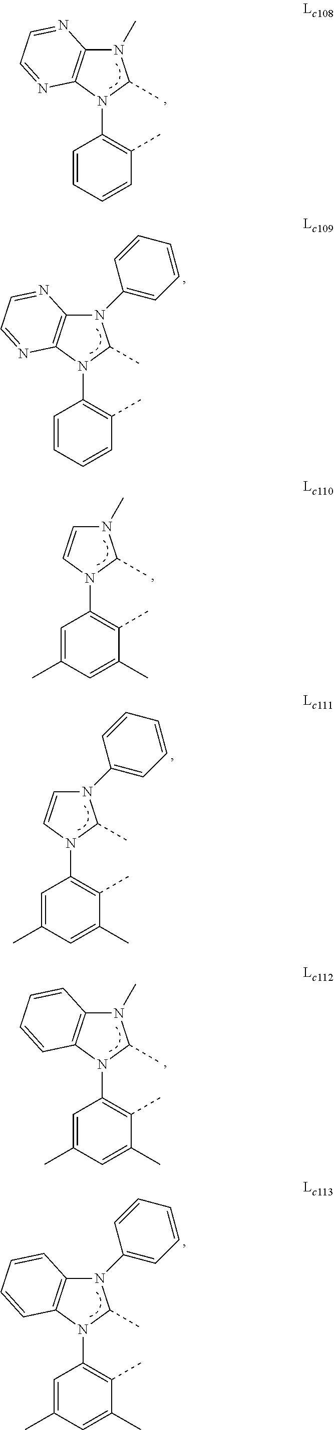

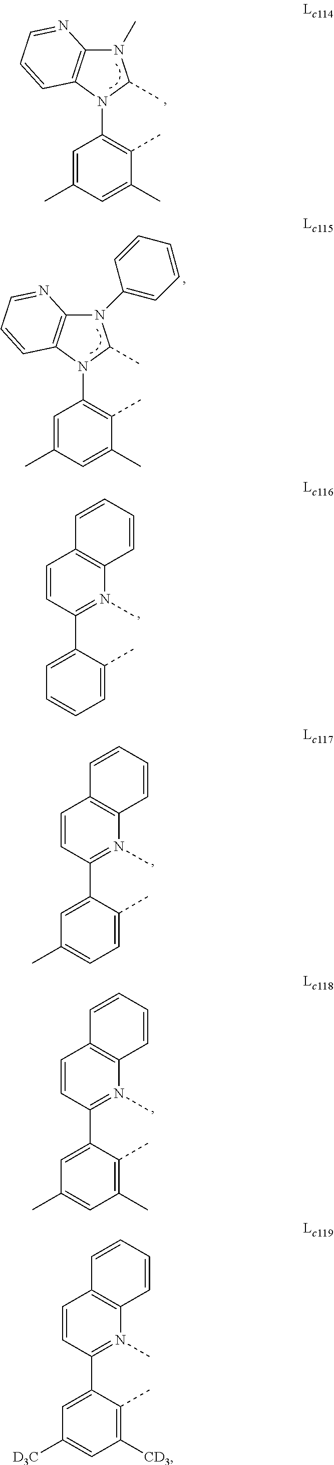

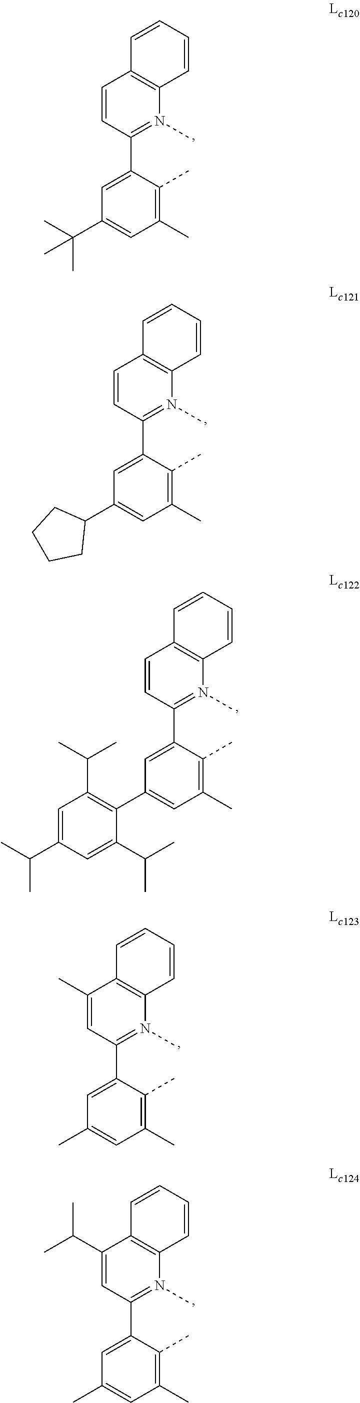

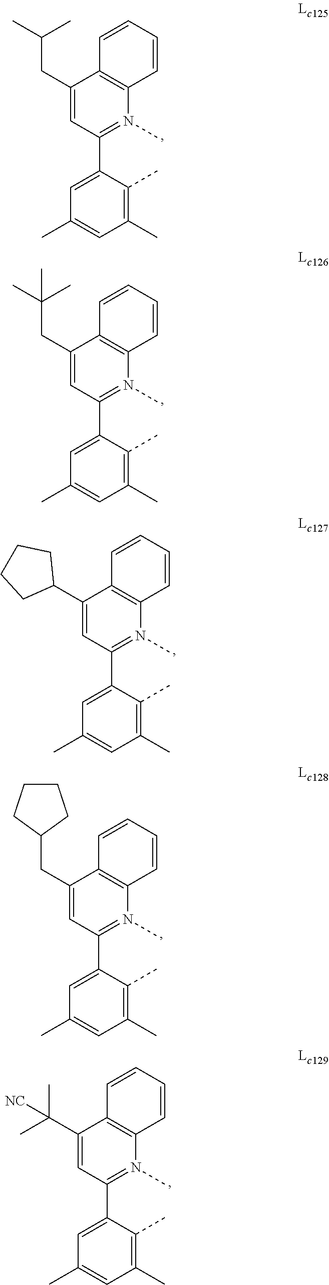

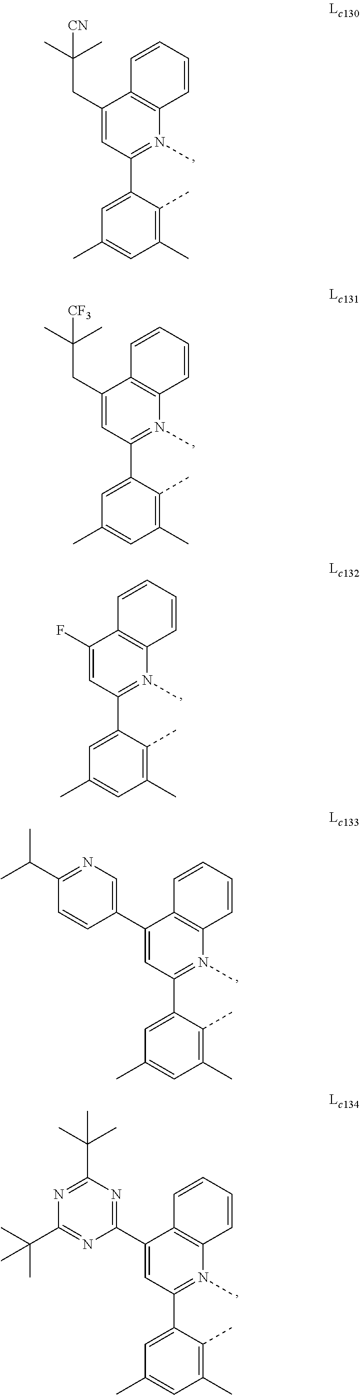

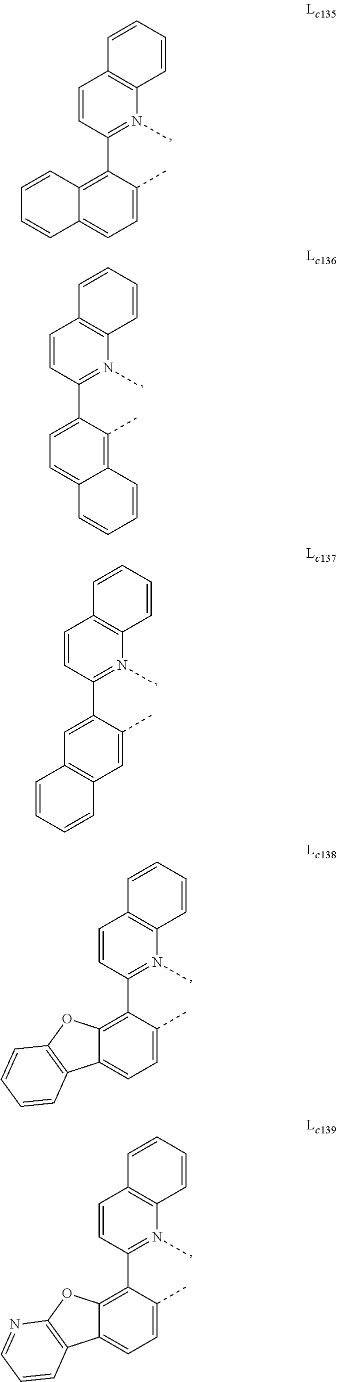

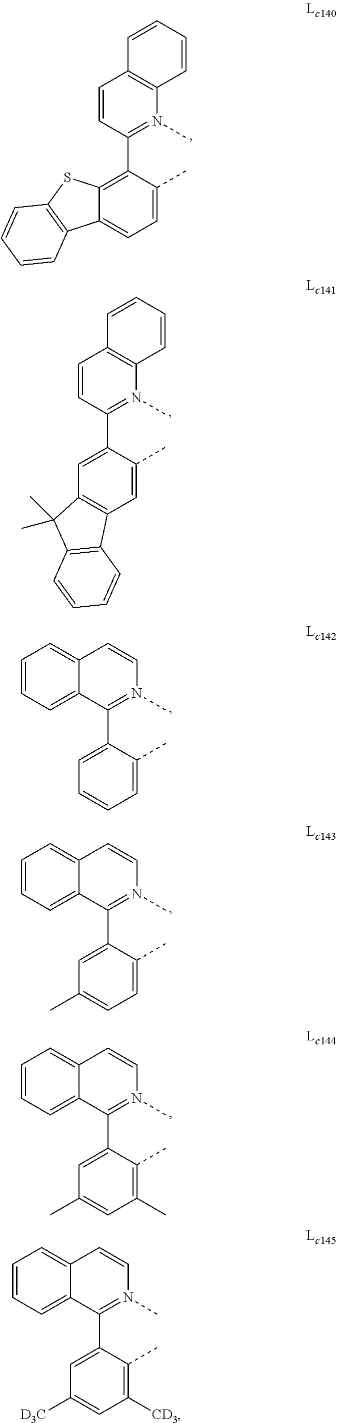

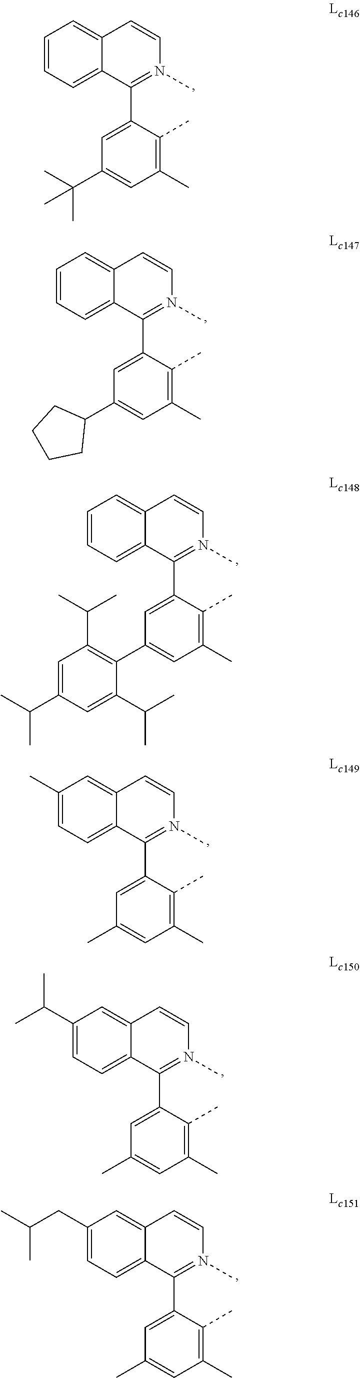

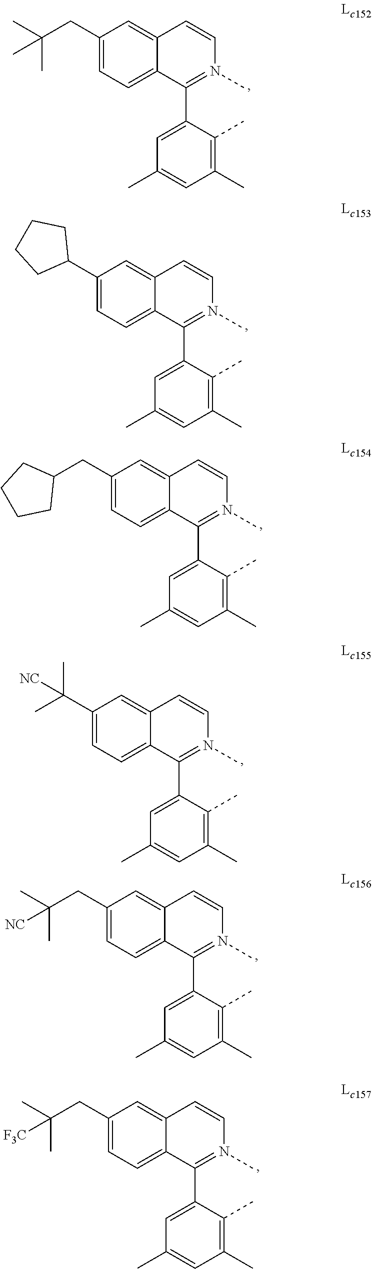

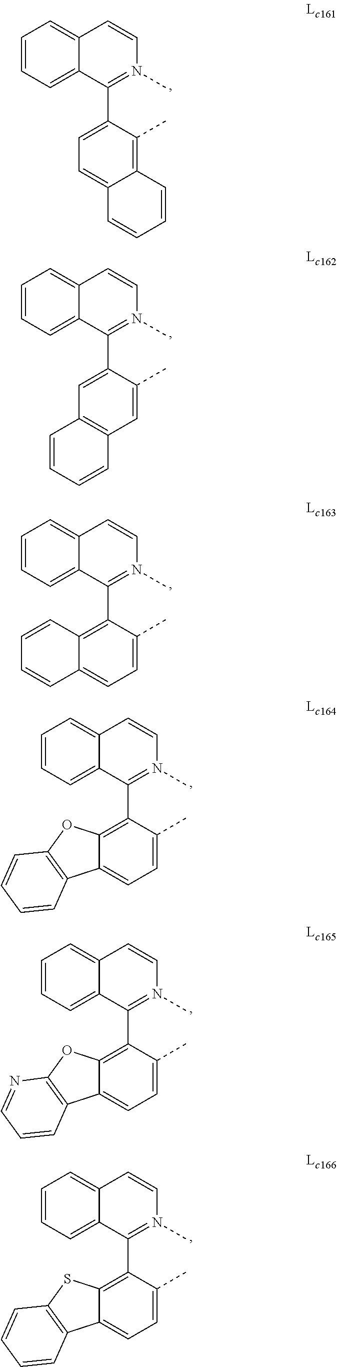

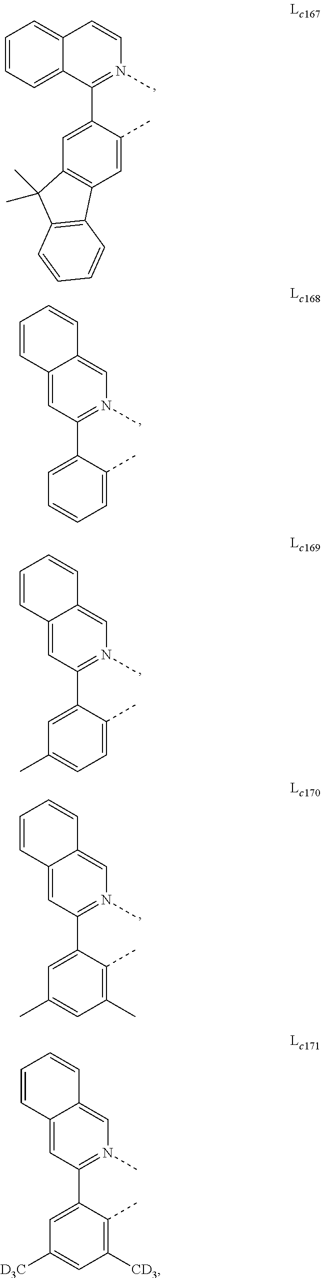

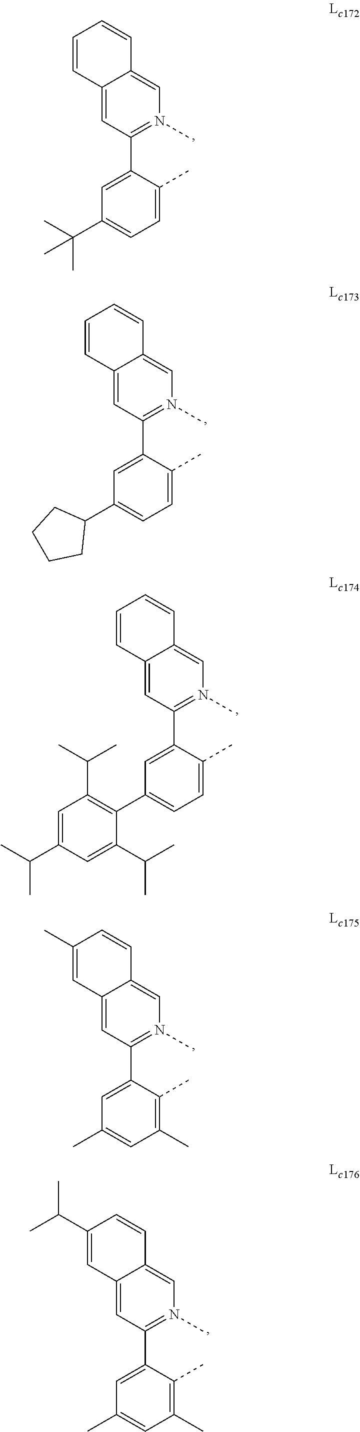

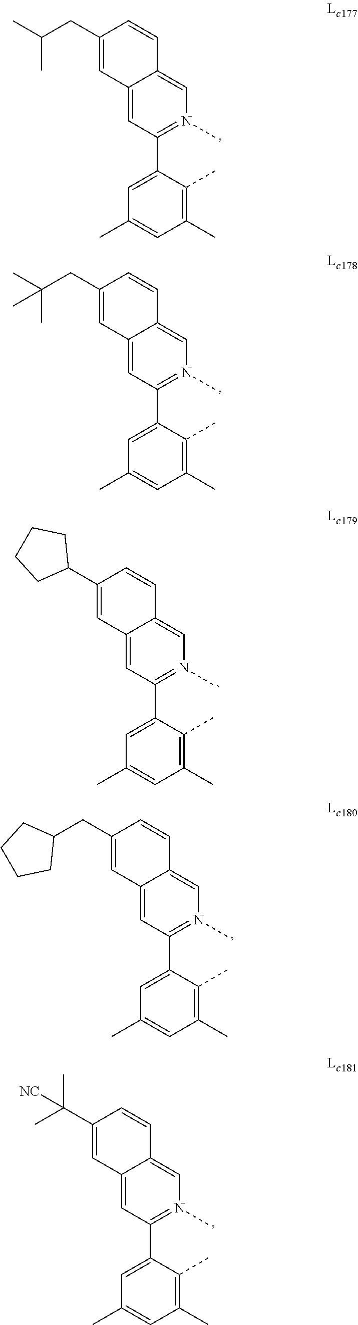

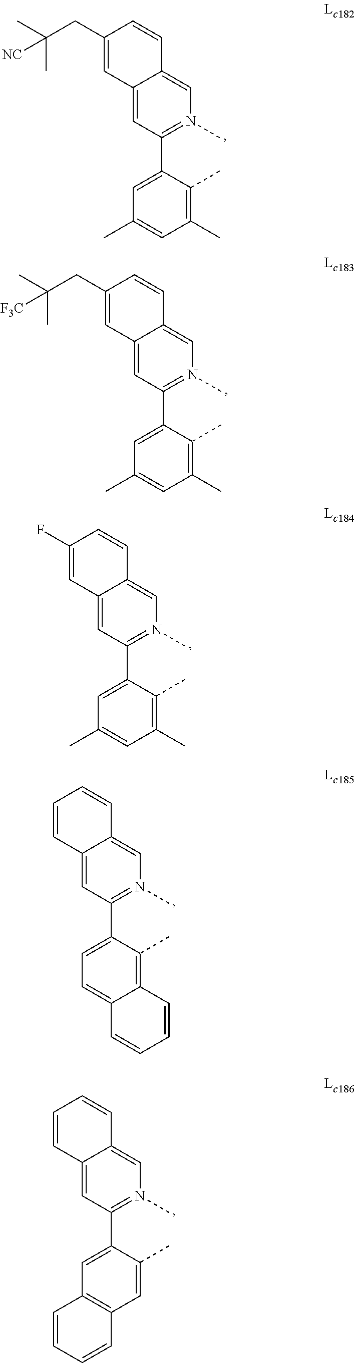

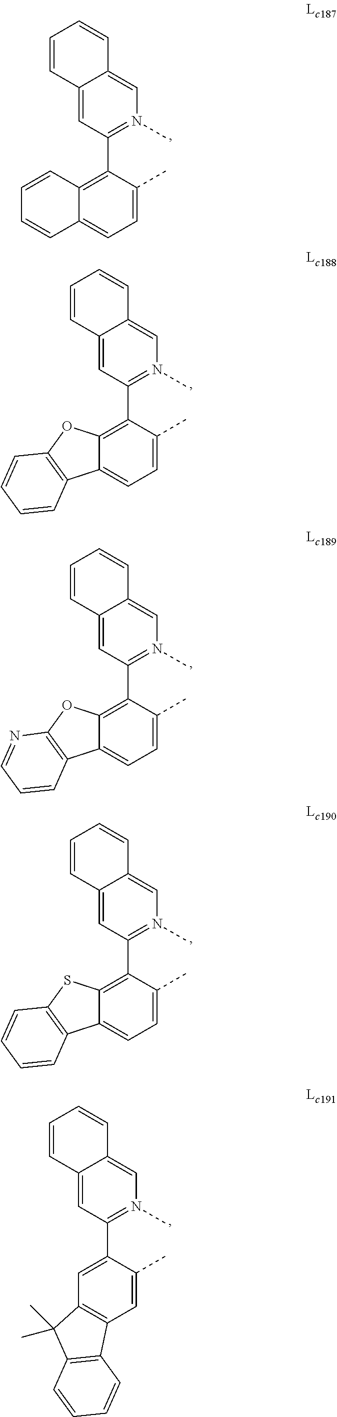

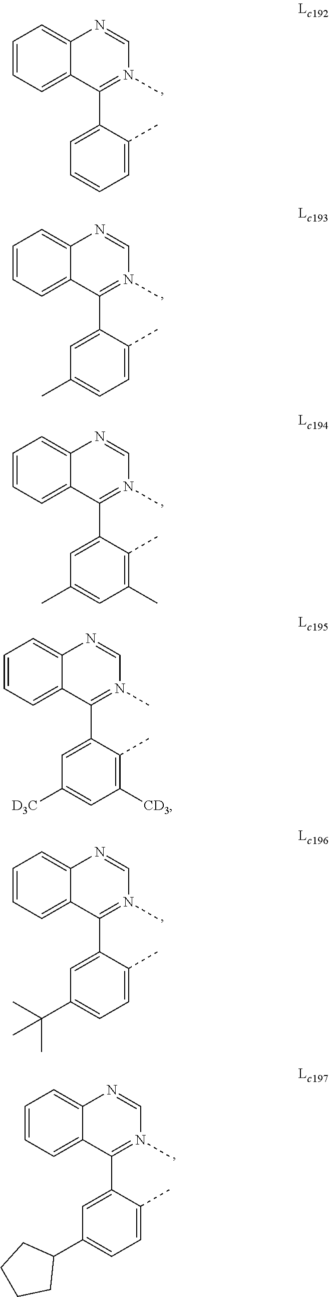

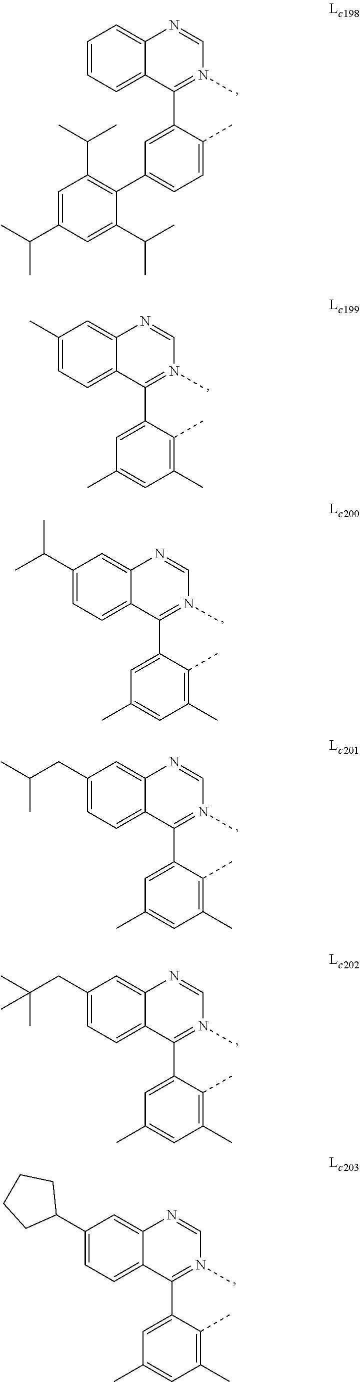

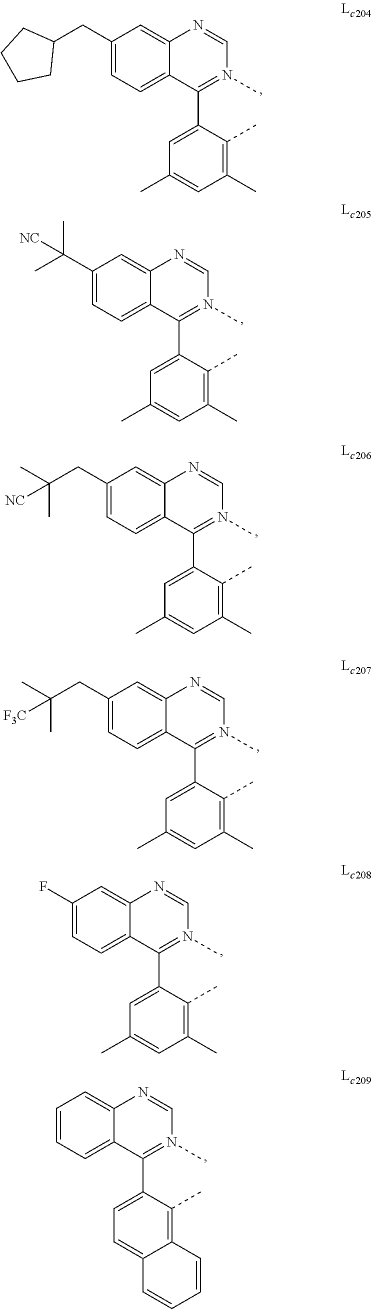

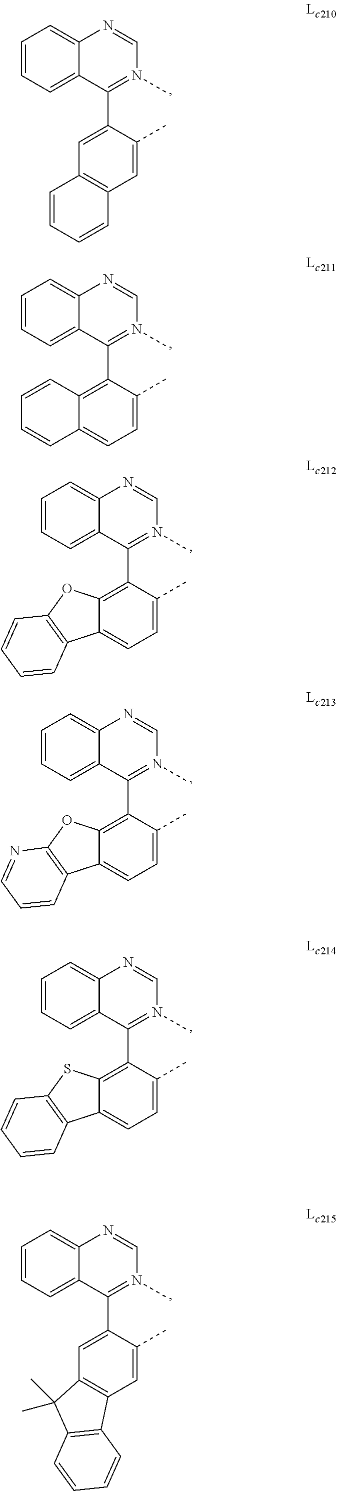

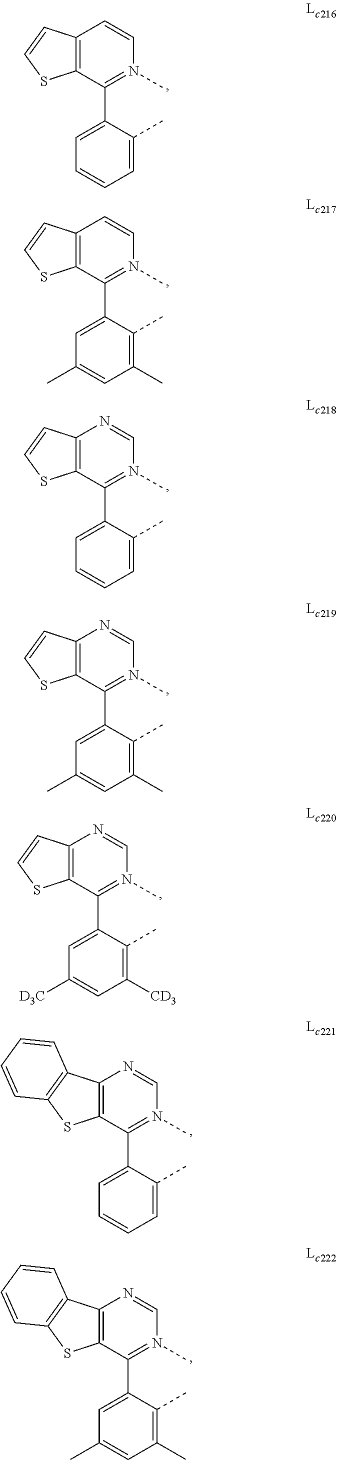

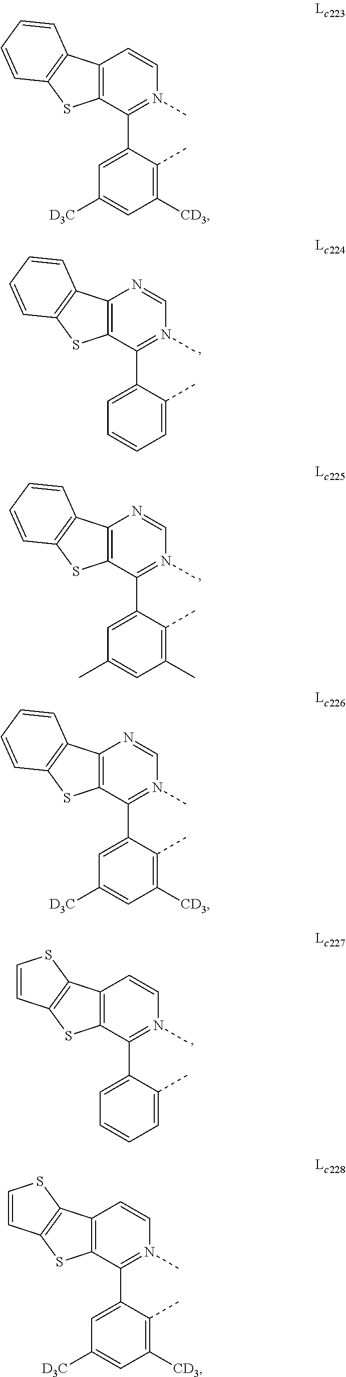

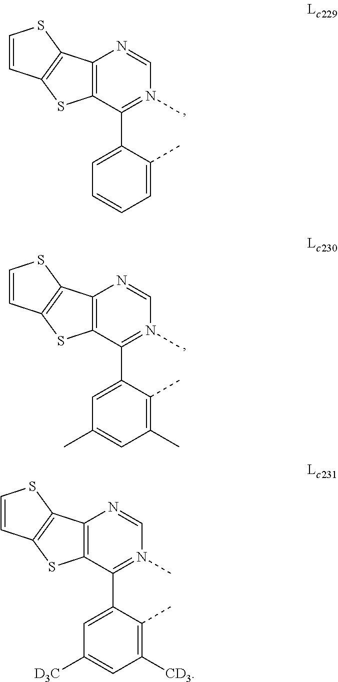

19. The organic electroluminescent device according to claim 18, wherein the first metal complex has a structure of Ir(Lₐ)₂(L_{b}) or Ir(Lₐ)₂(L_{c}) or Ir(Lₐ)(L_{c})₂;
wherein when the first metal complex has a structure of Ir(Lₐ)₂(L_{b}), Lₐ is, at each occurrence identically or differently, selected from any one or any two of the group consisting of Lₐ₁ to Lₐ₄₀₂ and L_{b} is selected from any one of the group consisting of L_{b1} to L_{b322}; when the first metal complex has a structure of Ir(Lₐ)₂(L_{c}), Lₐ is, at each occurrence identically or differently, selected from any one or any two of the group consisting of Lₐ₁ to Lₐ₄₀₂ and L_{c} is selected from any one of the group consisting of L_{c1} to L_{c231}; and when the first metal complex has a structure of Ir(Lₐ)(L_{c})₂, Lₐ is selected from any one of the group consisting of Lₐ₁ to Lₐ₄₀₂ and L_{c} is, at each occurrence identically or differently, selected from any one or any two of the group consisting of L_{c1} to L_{c231};
preferably, the first metal complex is selected from the group consisting of Compound RD-1 to Compound RD-114:

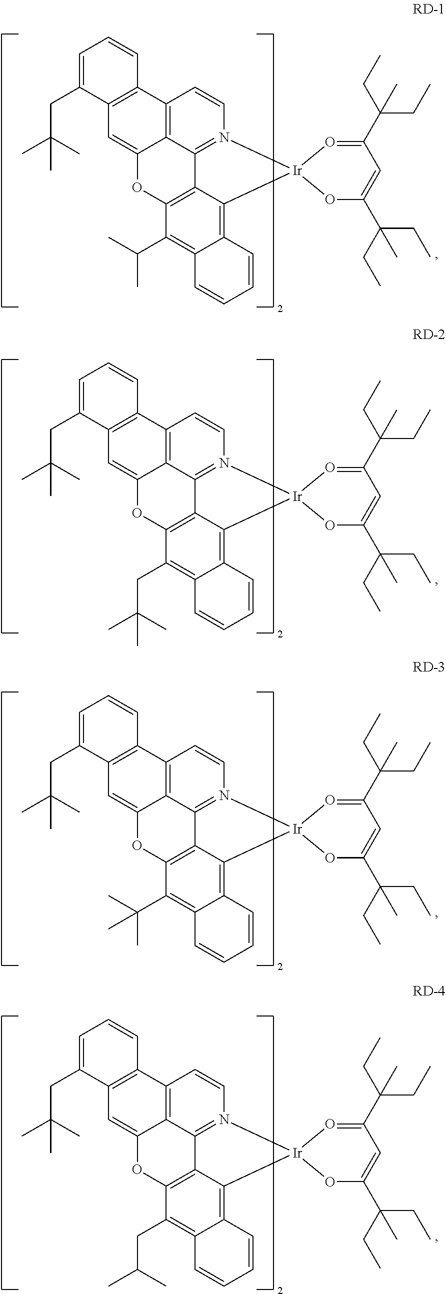

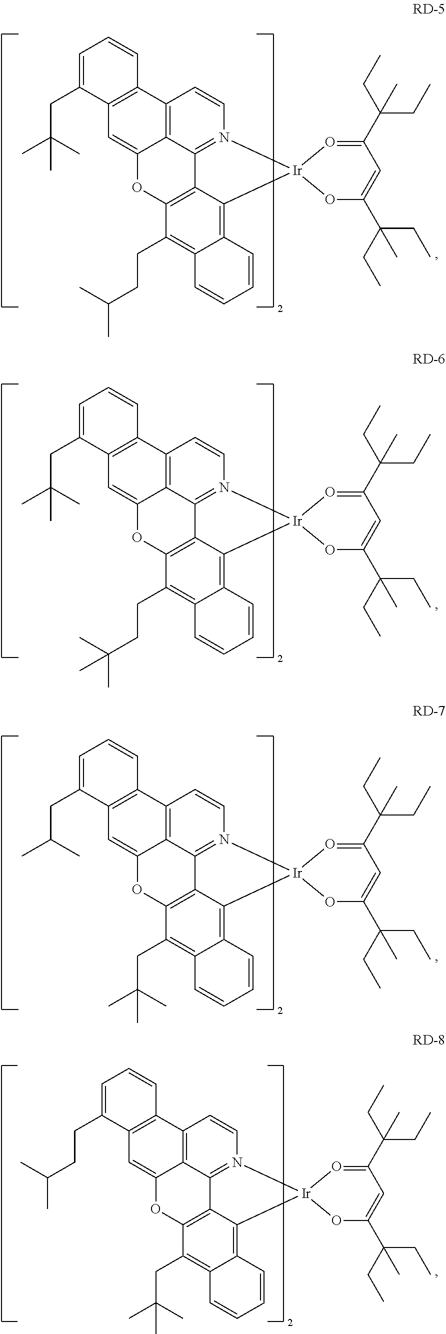

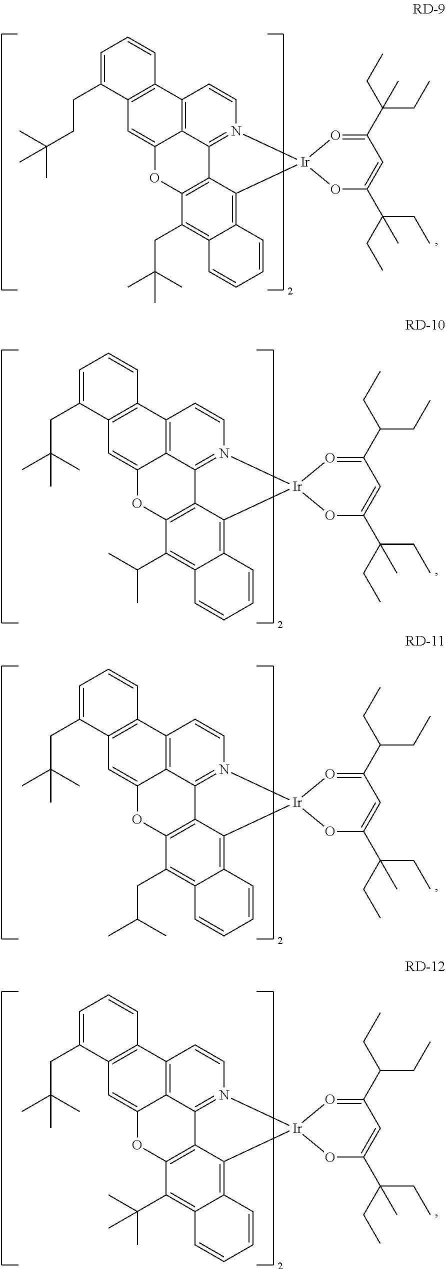

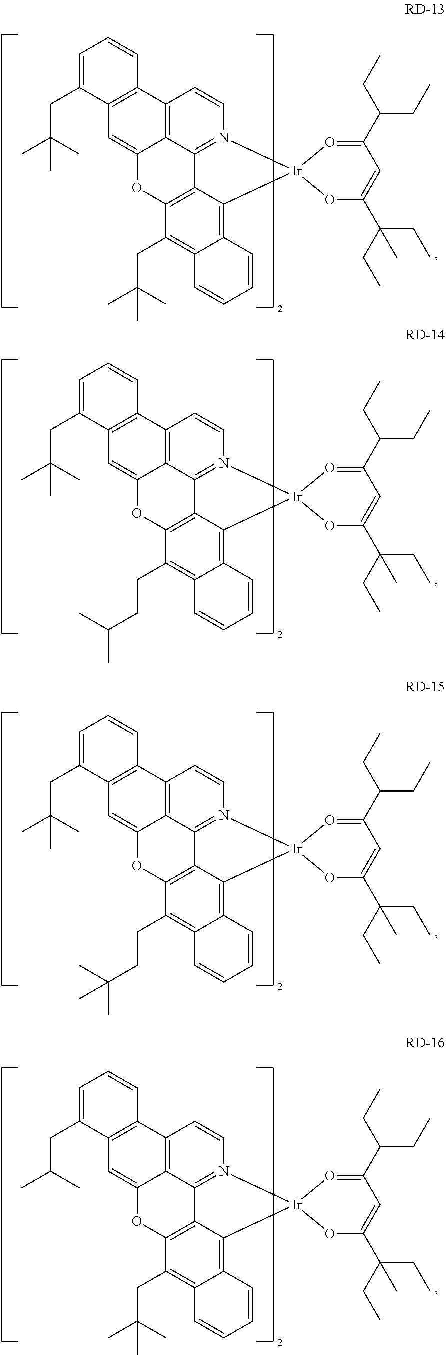

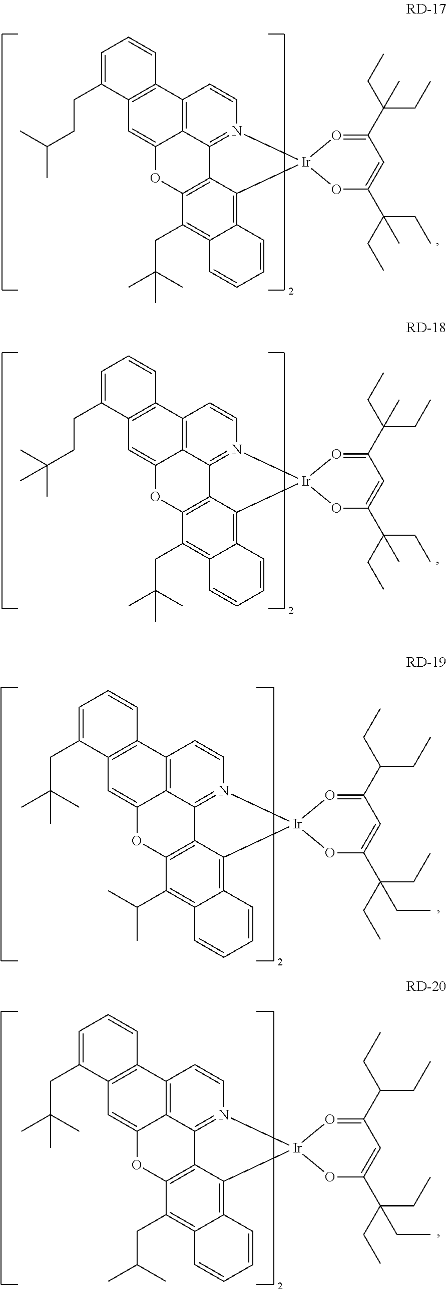

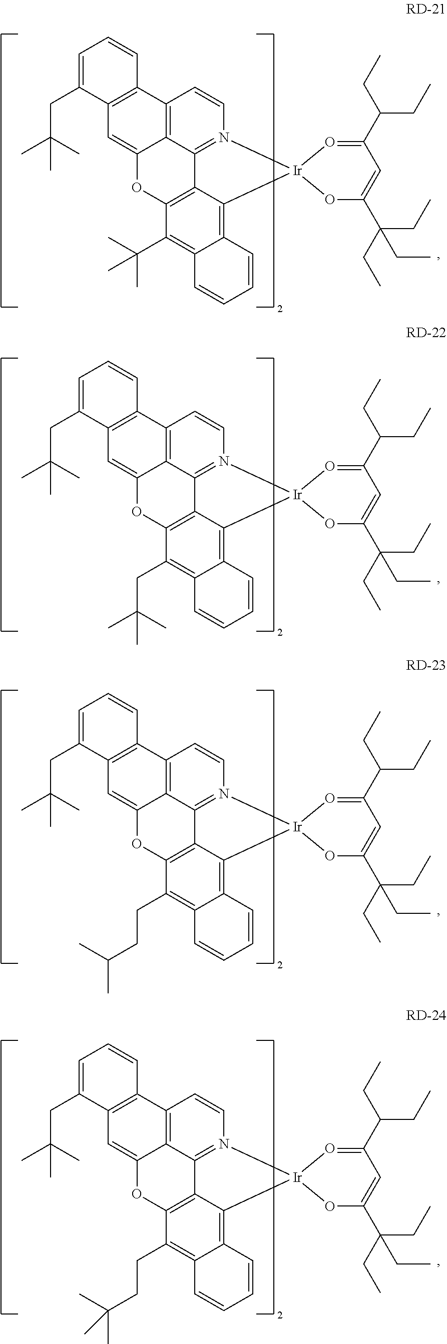

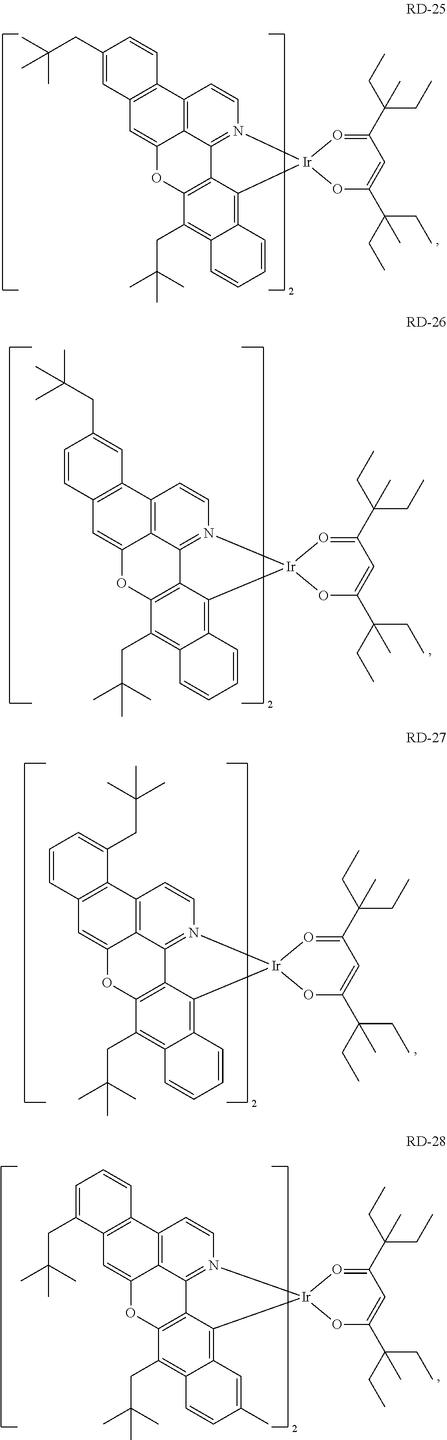

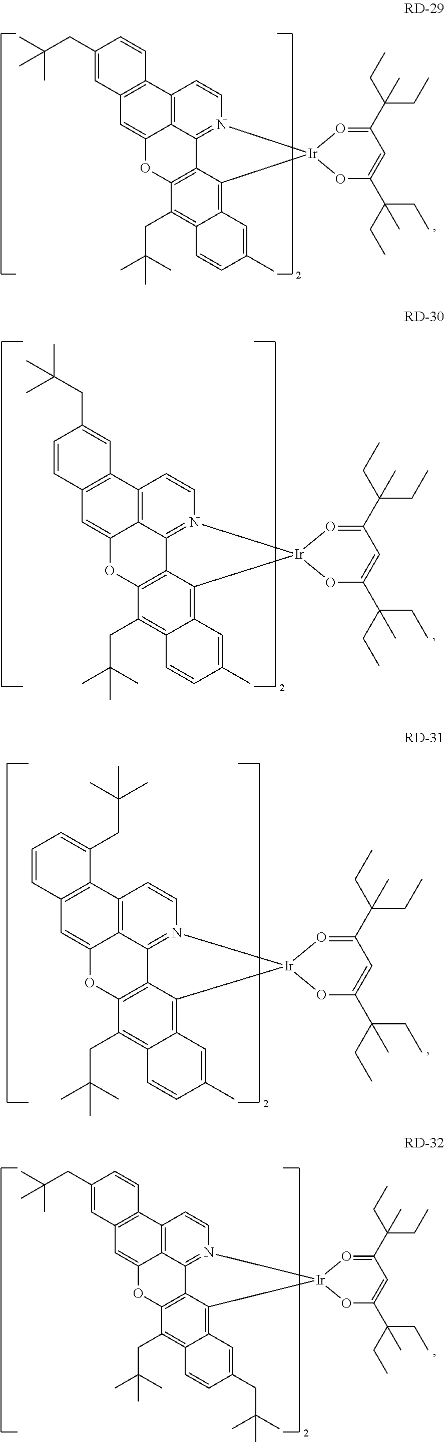

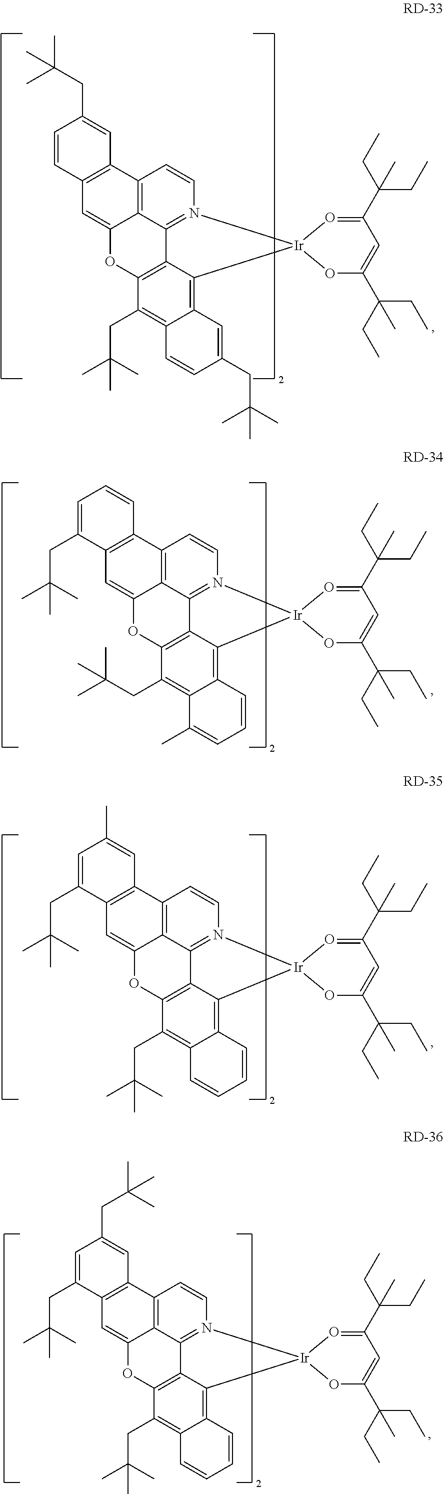

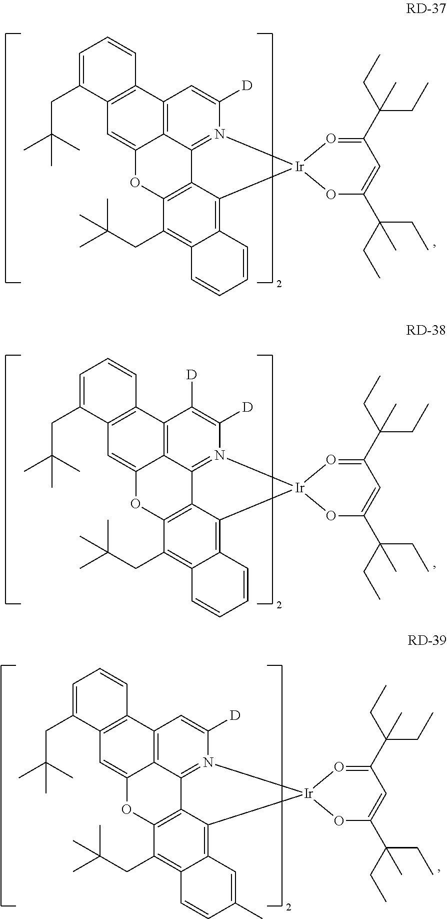

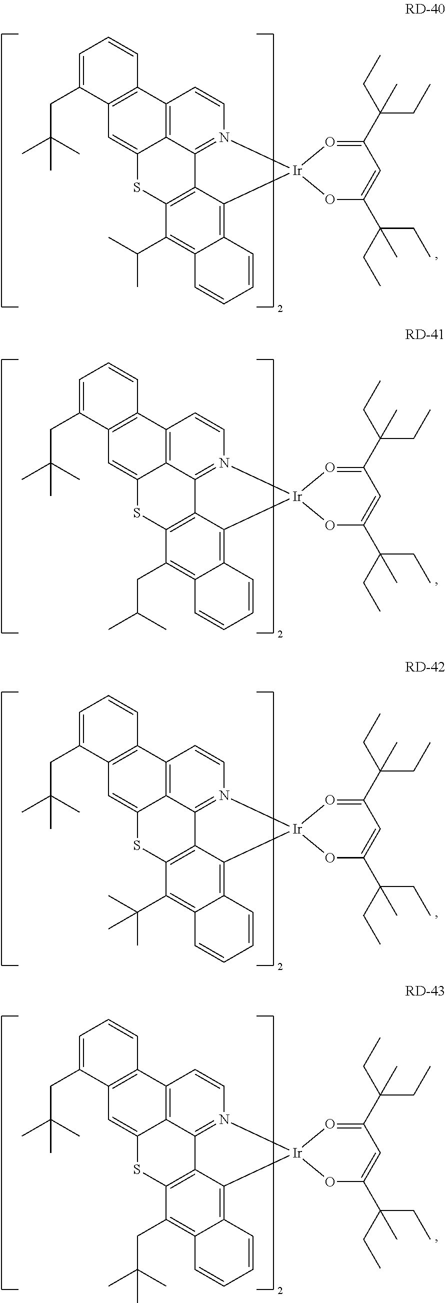

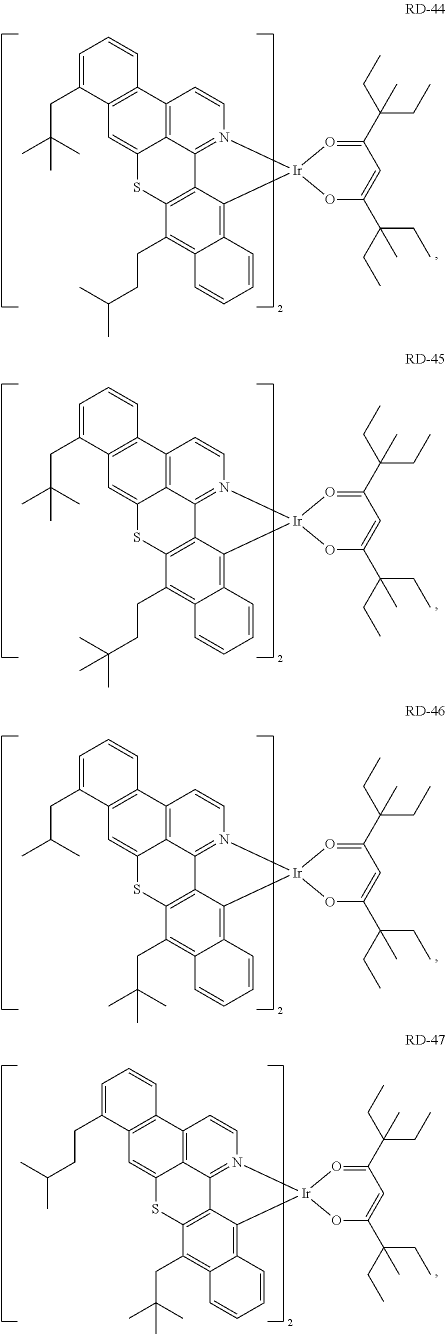

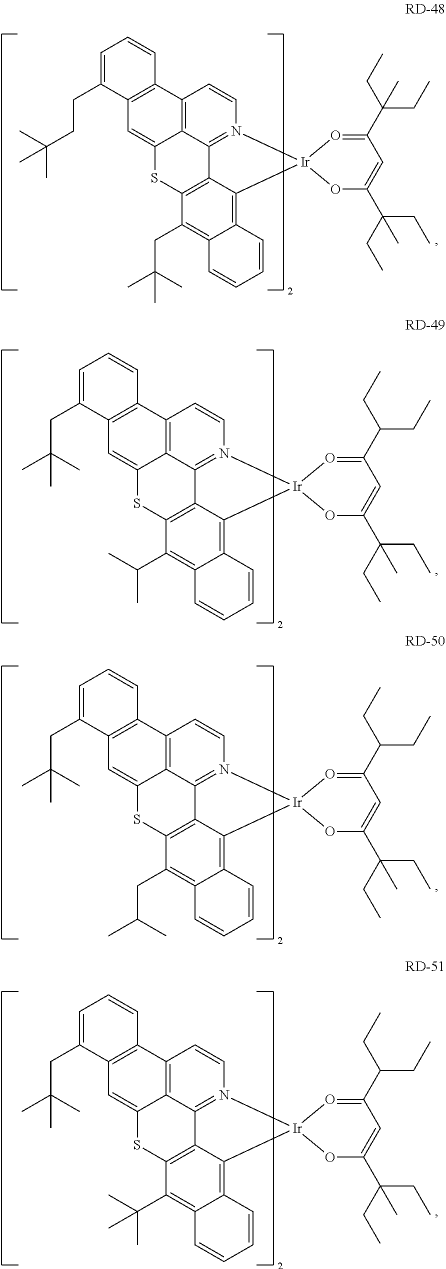

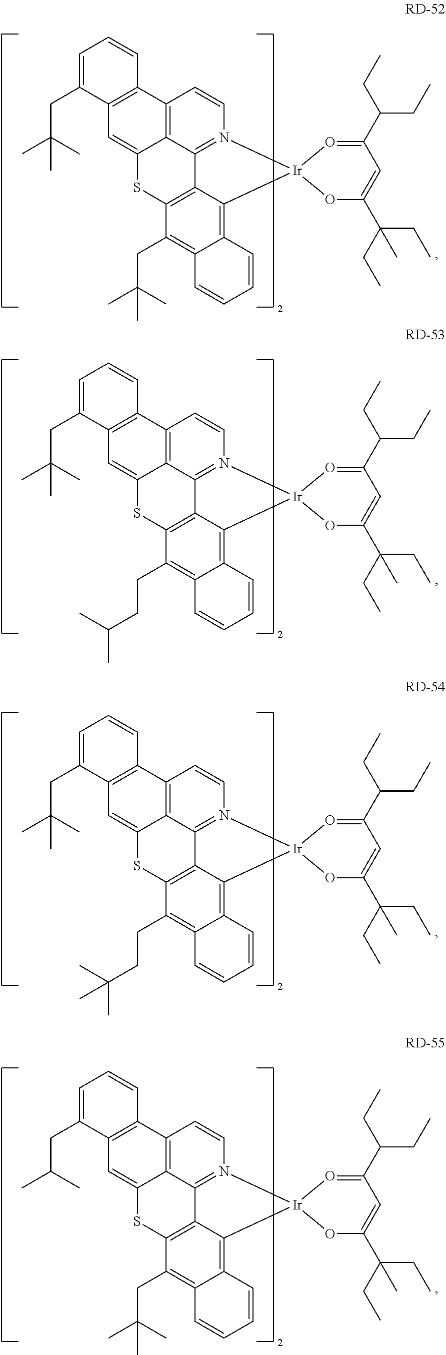

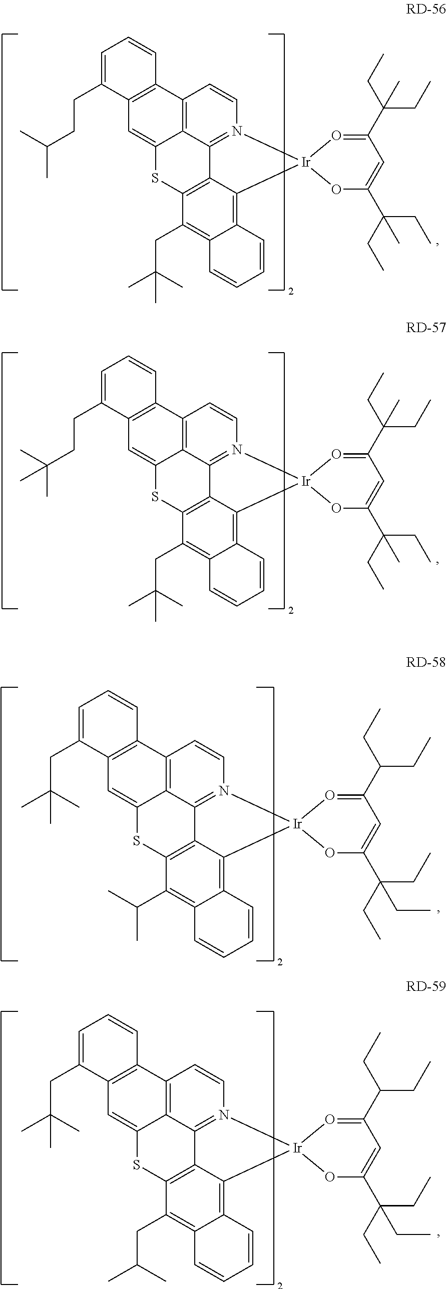

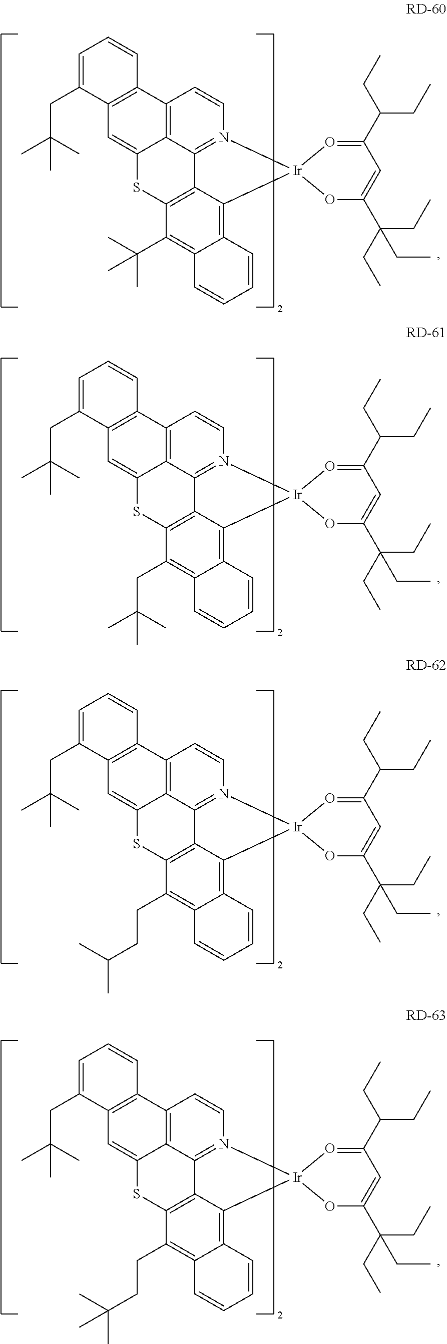

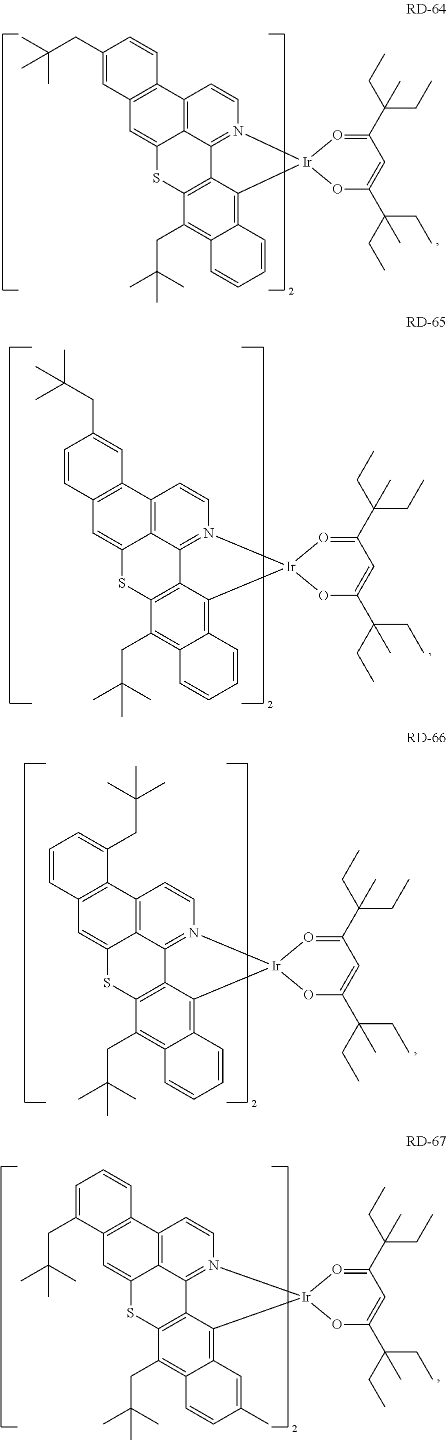

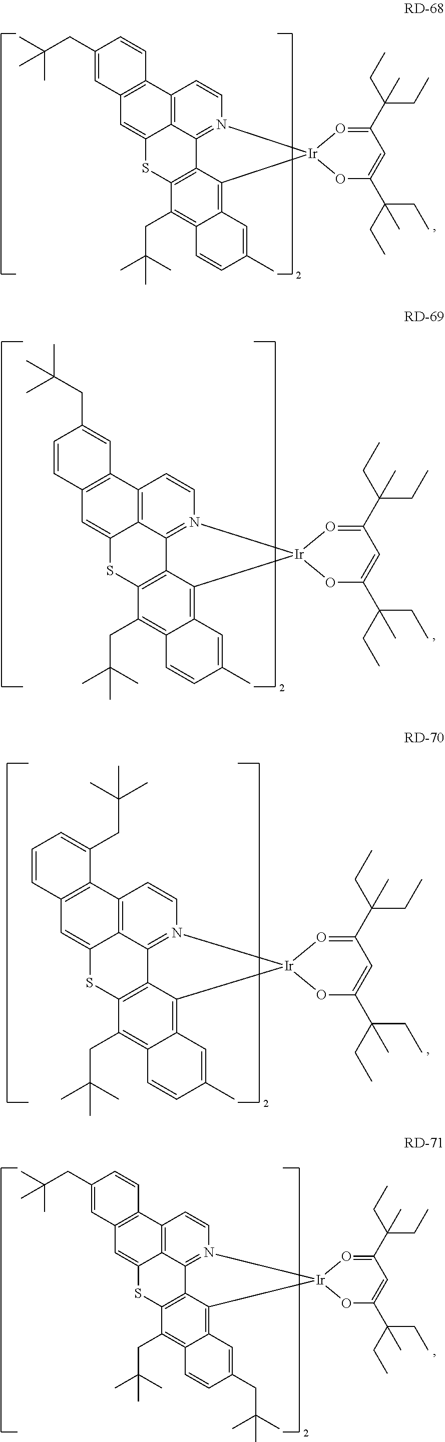

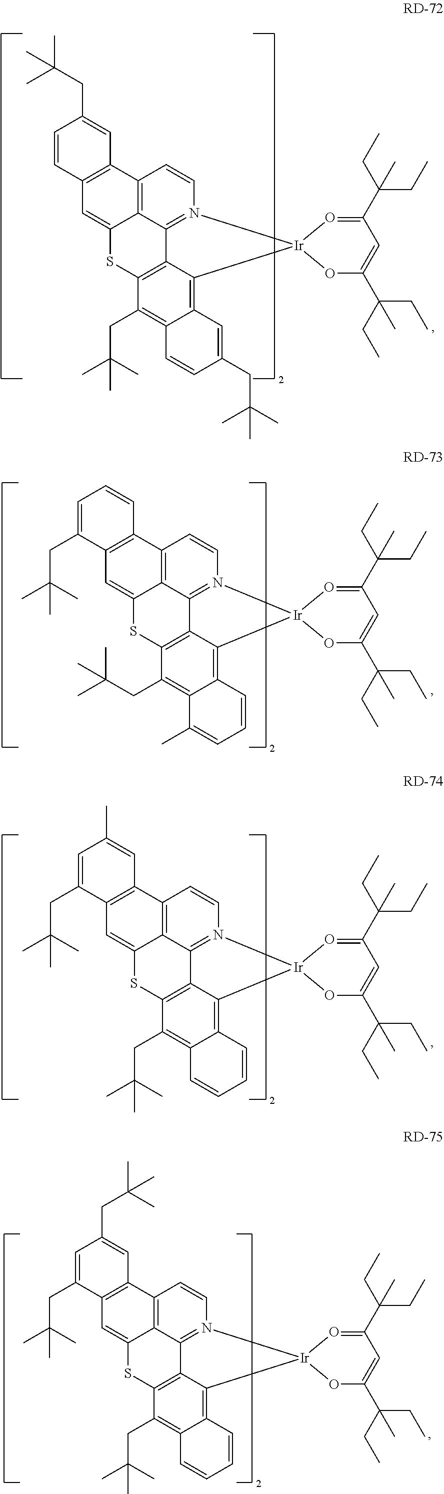

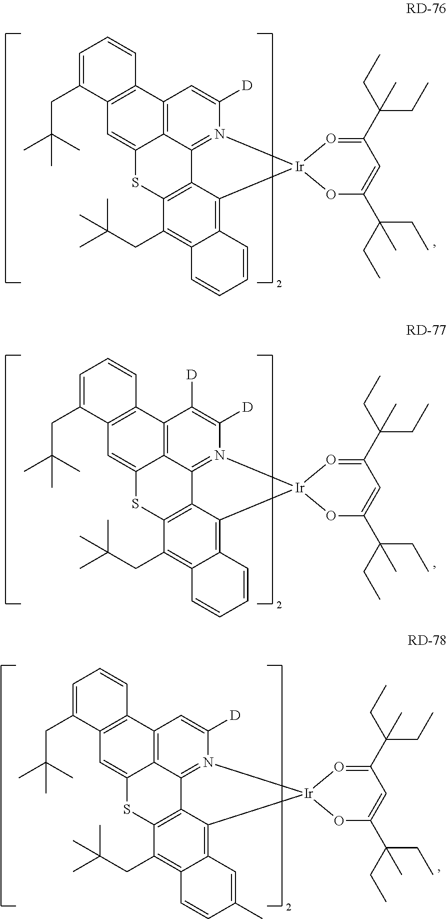

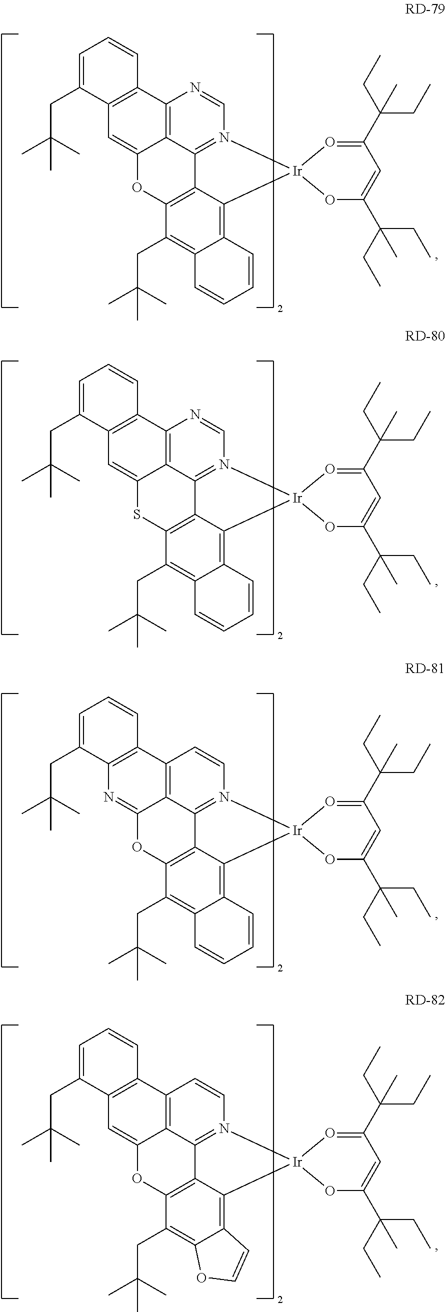

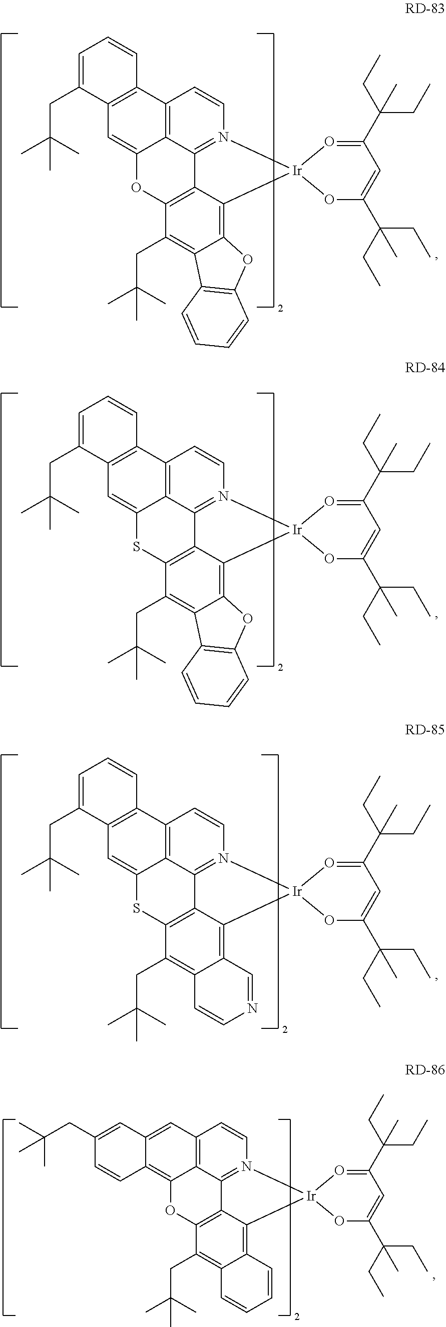

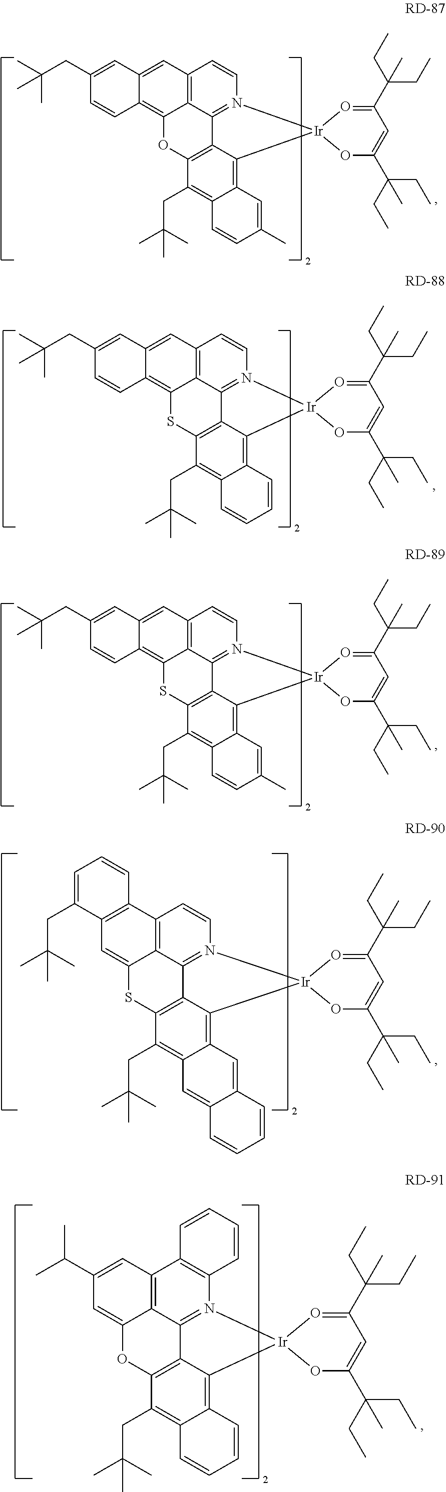

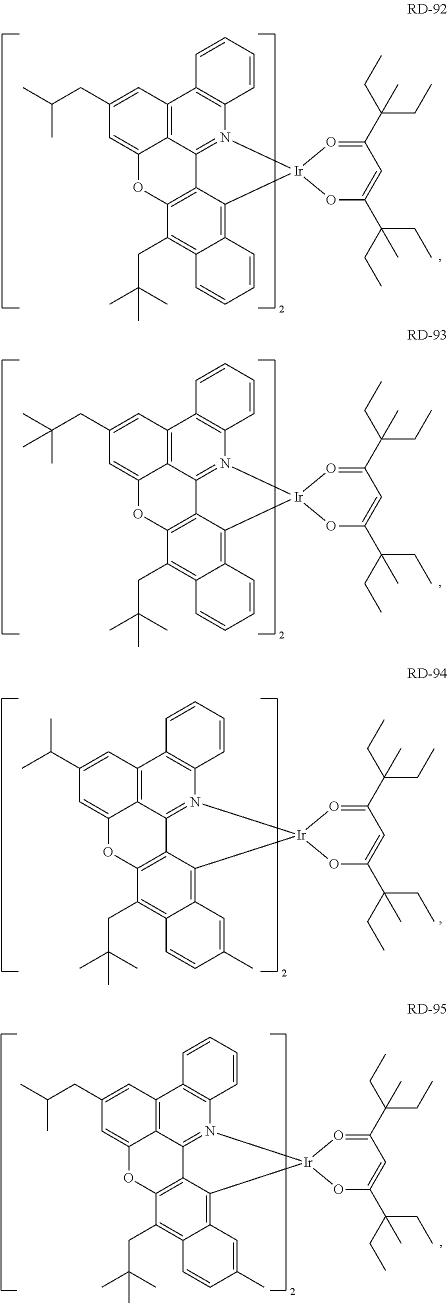

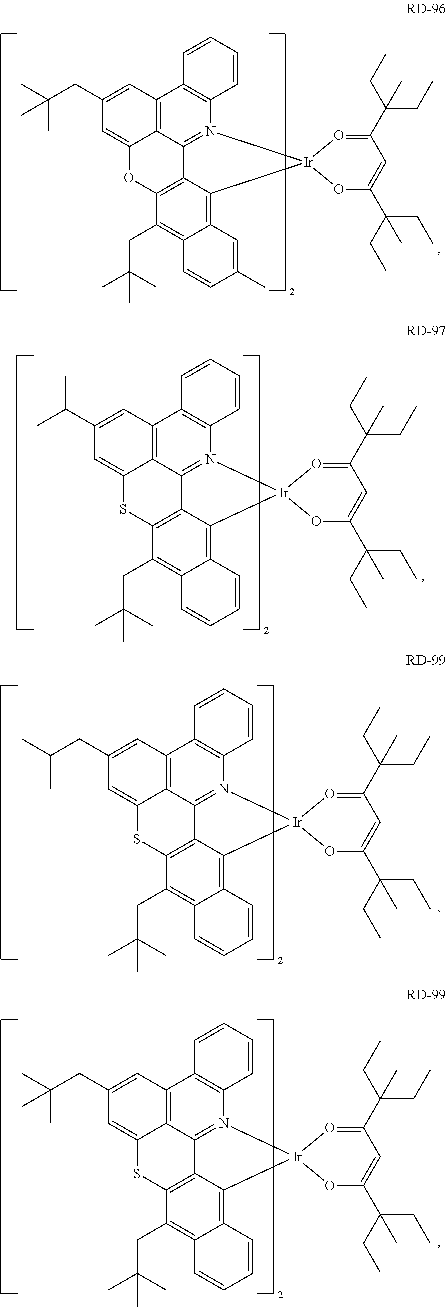

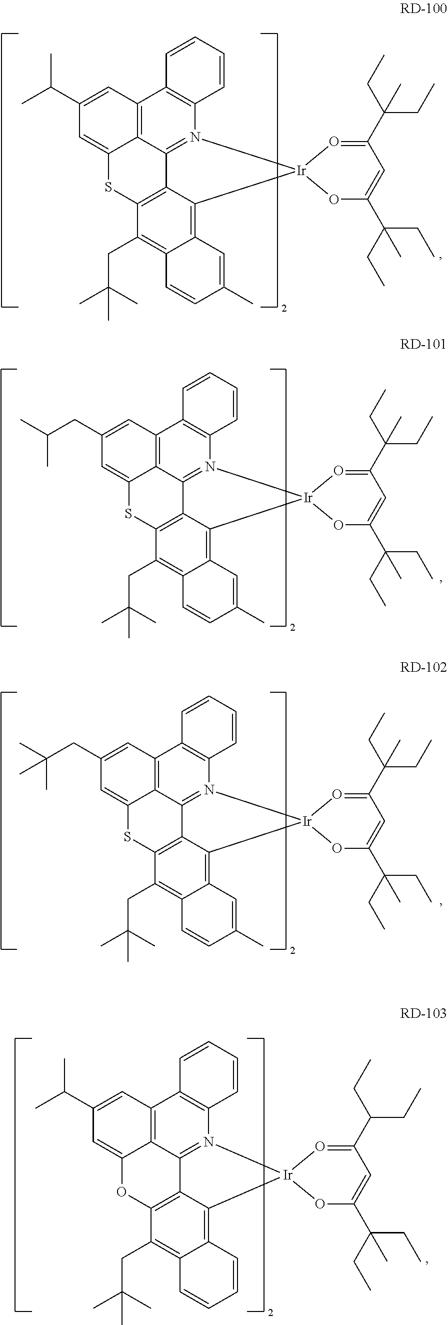

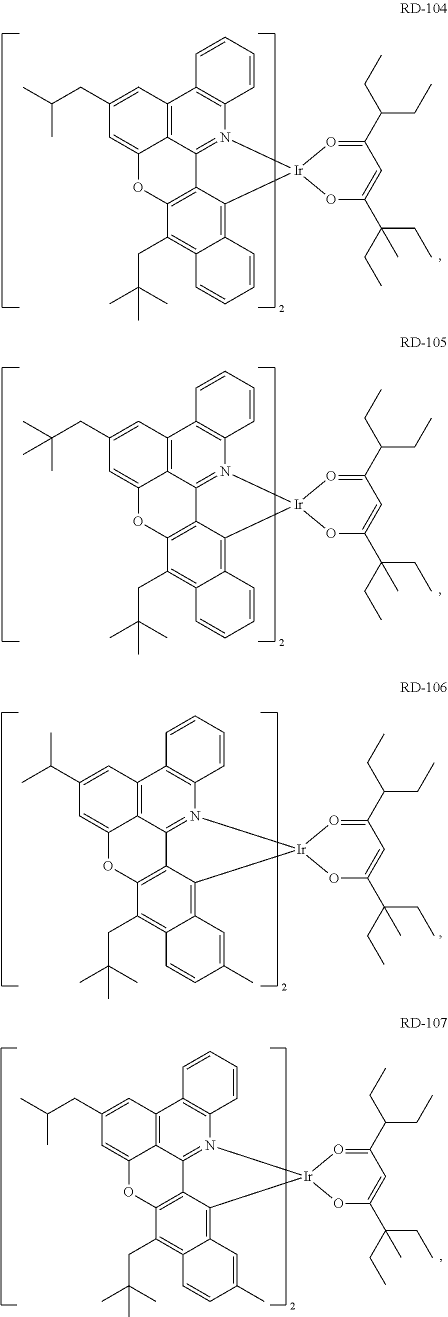

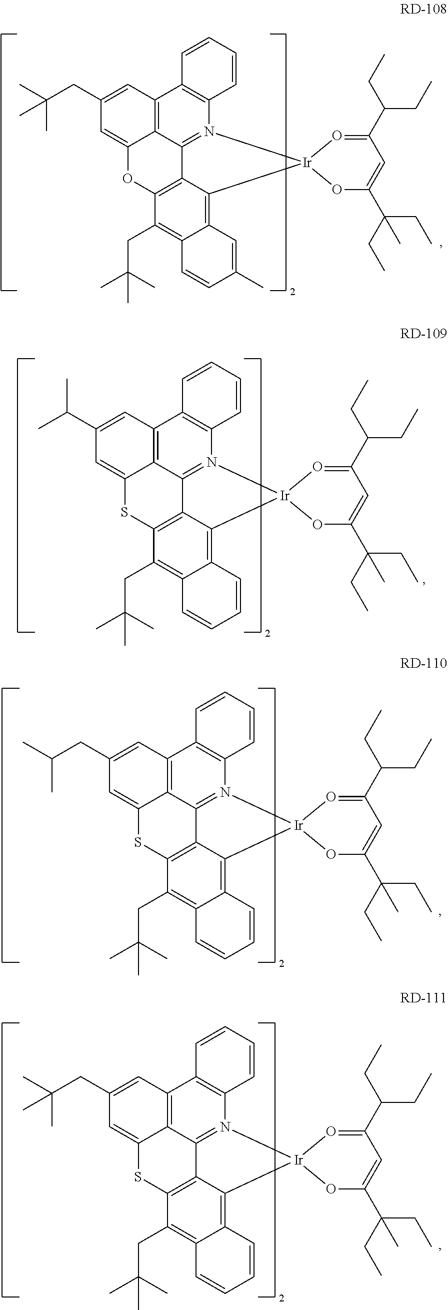

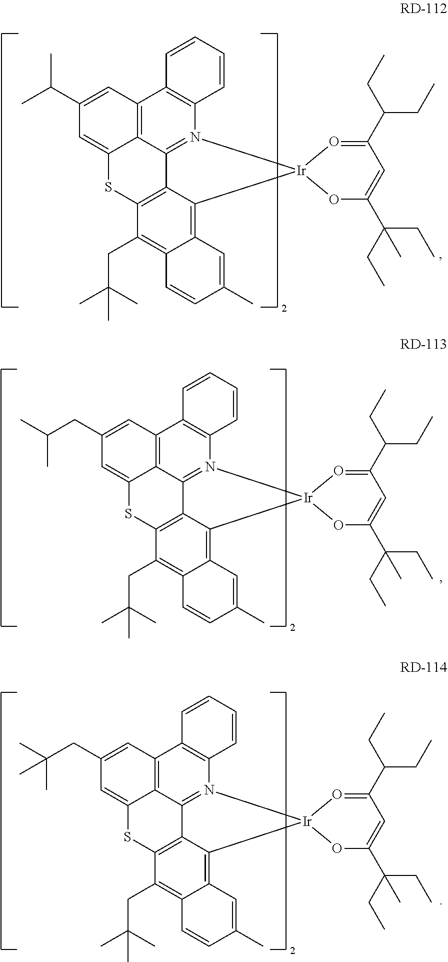

20. The organic electroluminescent device according to claim 1, wherein the capacitance property of the organic electroluminescent device satisfies the following condition:
at 500 Hz, a maximum capacitance value per unit of emissive area of the organic electroluminescent device is Cₘₐₓ₋ₛ, and Cₘₐₓ₋ₛ−Cₘₐₓ₀₋ₛ≤−5 nF/cm²;
wherein Cₘₐₓ₀₋ₛ denotes a maximum capacitance value per unit of emissive area of the organic electroluminescent device A at 500 Hz; and the organic electroluminescent device A is the same as the organic electroluminescent device except that the first host compound and the second host compound in the emissive layer of the organic electroluminescent device are replaced with Compound RH0 as the host compound;
preferably, at 500 Hz, Cₘₐₓ₋ₛ−Cₘₐₓ₀₋ₛ≤−7.5 nF/cm²;
more preferably, at 500 Hz, Cₘₐₓ₋ₛ−Cₘₐₓ₀₋ₛ≤−18.75 nF/cm².

21. A display assembly, comprising the organic electroluminescent device according to claim 1.
